(19) United States
(12) Patent Application Publication
(10) Pub. No.: US 2025/0133960 A1
(43) Pub. Date: Apr. 24, 2025

(54) ORGANIC ELECTROLUMINESCENT LIGHT-EMITTING ELEMENT MATERIAL, ORGANIC ELECTROLUMINESCENT LIGHT-EMITTING ELEMENT, ORGANIC EL DISPLAY DEVICE, ORGANIC EL LIGHTING, ORGANIC ELECTROLUMINESCENT LIGHT-EMITTING ELEMENT-FORMING COMPOSITION, AND METHOD FOR PRODUCING ORGANIC ELECTROLUMINESCENT LIGHT-EMITTING ELEMENT

(71) Applicant: MITSUBISHI CHEMICAL CORPORATION, Tokyo (JP)

(72) Inventors: Kazuki OKABE, Tokyo (JP); Mayuko UEDA, Tokyo (JP); Kazuhiro NAGAYAMA, Tokyo (JP); Koichiro IIDA, Tokyo (JP); Toshimitsu NAKAI, Tokyo (JP)

(73) Assignee: MITSUBISHI CHEMICAL CORPORATION, Tokyo (JP)

(21) Appl. No.: 19/002,024

(22) Filed: Dec. 26, 2024

Related U.S. Application Data
(63) Continuation of application No. PCT/JP2023/023675, filed on Jun. 26, 2023.

(30) Foreign Application Priority Data
Jun. 27, 2022 (JP) 2022-103028
Jun. 27, 2022 (JP) 2022-103031

(51) Int. Cl. H10K 85/60; C09K 11/02; C09K 11/06; H10K 50/12; H10K 71/12; H10K 85/30

(52) U.S. Cl. CPC H10K 85/654; C09K 11/02; C09K 11/06; H10K 85/342; H10K 85/6572; H10K 85/658; C09K 2211/1018; H10K 50/12; H10K 71/12

(57) ABSTRACT

An object of the present invention is to provide an organic electroluminescent element material which can provide an organic electroluminescent element having high luminescent efficiency and a long operating lifetime.

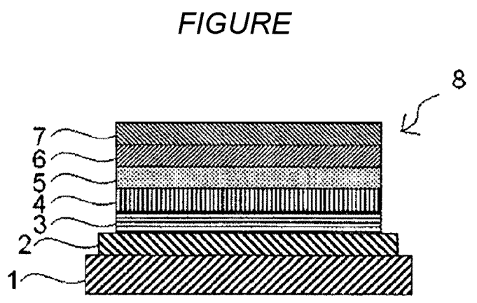

### CROSS-REFERENCE TO RELATED APPLICATIONS

This application is a continuation of International Application No. PCT/JP2023/023675, filed on Jun. 26, 2023, and claims the benefit of priority to Japanese Application No. 2022-103028 filed on Jun. 27, 2022 and Japanese Application No. 2022-filed on Jun. 27, 2022. The content of each of these applications is hereby incorporated by reference in its entirety.

### TECHNICAL FIELD

The present invention relates to an organic electroluminescent element material.

### BACKGROUND ART

In recent years, an organic electroluminescent element using an organic thin film instead of an inorganic material has been developed as a thin-film type electroluminescent element. An organic electroluminescent element (OLED) generally includes a hole injection layer, a hole transport layer, an organic emission layer, an electron transport layer, and the like between an anode and a cathode, and materials suitable for each of these layers are currently being developed, with emission colors of red, green, and blue being developed for each.

Examples of a method for forming an organic layer of an organic electroluminescent element include a vacuum deposition method and a wet-process film formation method (a coating method). The vacuum deposition method has advantages that charge injection from an anode and/or a cathode can be improved and excitons can be easily confined in an emission layer since lamination is easy. On the other hand, the wet-process film formation method has advantages that a layer containing a plurality of materials with various functions can be easily formed by using a coating liquid in which a plurality of materials with various functions are mixed, without requiring a vacuum process, and can be easily increased in area. Therefore, in recent years, research and development of organic electroluminescent elements using film formation by a coating method have been actively conducted.

For example, Patent Literatures 1 to 3 describe an organic electroluminescent element including a hole injection layer containing polystyrene sulfonic acid and an emission layer containing a luminescent material having a polycyclic heterocyclic compound skeleton containing boron and nitrogen.

Research and development are being conducted to utilize a triplet excited state, which accounts for 75% of excitons generated in the organic electroluminescent element. For example, Non Patent Literature 1 reports that, as a method for increasing luminescent efficiency of an organic electroluminescent element, in addition to a luminescent material having a polycyclic heterocyclic compound skeleton, an organometallic compound having iridium as a central metal, which is a phosphorescent material as a material that assists luminescence, is contained in an emission layer formed by a vacuum deposition method.

### CITATION LIST

### Patent Literature

Patent Literature 1: WO2016/152418
Patent Literature 2: WO2019/198699
Patent Literature 3: WO2019/235452

### Non-Patent Literature

Non Patent Literature 1: Angewandte Chemie International Edition, 2022, Vol. 61, No. 14, p. e202117181

### SUMMARY OF INVENTION

### Technical Problem

In general, a polycyclic heterocyclic compound containing boron has an empty p-orbital on boron, and is likely to react with various reactive groups. Therefore, in the techniques disclosed in Patent Literatures 1 to 3, an operating voltage of the organic electroluminescent element is insufficiently reduced, and an operating lifetime cannot be improved. In the techniques disclosed in Patent Literatures 1 to 3, this is considered to be due to the fact that a hole injection layer containing strongly acidic polystyrene sulfonic acid is used, moisture or a sulfonic acid group incorporated during formation of the hole injection layer reacts with a polycyclic heterocyclic compound containing boron during element driving. In the technique disclosed in Non Patent Literature 1, it is necessary to keep deposition rate ratios of three or more materials, including a host material, constant, making it difficult to obtain stable performance.

The present invention has been made in view of the above circumstances in related art, and an object of the present invention is to provide an organic electroluminescent element material which can provide an organic electroluminescent element having high luminescent efficiency and a long operating lifetime.

### Solution to Problem

As a result of intensive studies, the present inventors have found that the above problems can be solved by using an organic electroluminescent element material which contains a luminescent compound, an organometallic compound, and a host material, in which a molecular weight of the organometallic compound is in a specific range, the host material has a specific structure, a triplet energy level of the organometallic compound is equal to or higher than a triplet energy level of the luminescent compound, and a singlet energy level and the triplet energy level of the luminescent compound have a specific relationship, and have completed the present invention.

That is, the gist of the present invention is as follows.

<1>

An organic electroluminescent element material, containing:
a luminescent compound;
an organometallic compound; and
a host material, in which
the organometallic compound has a molecular weight of 1,200 or more,
the host material contains at least one selected from the group consisting of a compound represented by the following formula (240), a compound represented by the following formula (250), and a compound represented by the following formula (260), and
the following relational expression (E-1) and the following relational expression (E-2) are satisfied.

$$T 1 A \geq T 1 B \qquad Expression ( E - 1 )$$

$$Δ EST = S 1 B - T 1 B \leq 0.3 eV \qquad Expression ( E - 2 )$$

(In the expression (E-1) and the expression (E-2),
T1A: a triplet energy level (eV) of the organometallic compound
T1B: a triplet energy level (eV) of the luminescent compound
S1B: a singlet energy level (eV) of the luminescent compound)

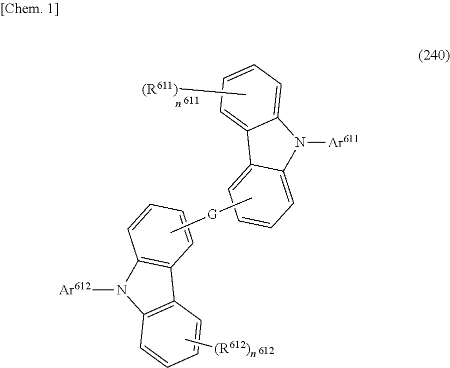

(In the formula (240),
Ar⁶¹¹ and Ar⁶¹² each independently represent a monovalent aromatic hydrocarbon group having 6 to 50 carbon atoms which may have a substituent,
R⁶¹¹ and R⁶¹² each independently represent a deuterium atom, a halogen atom, or a monovalent aromatic hydrocarbon group having 6 to 50 carbon atoms which may have a substituent,
G represents a single bond, or a divalent aromatic hydrocarbon group having 6 to 50 carbon atoms which may have a substituent, and
n⁶¹¹ and n⁶¹² each independently represent an integer of 0 to 4.)

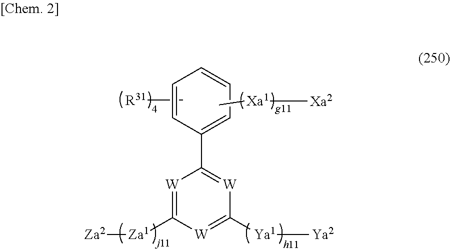

(In the formula (250),
W's each independently represent CH or N, and at least one W represents N,
Xa¹, Ya¹, and Za¹ each independently represent a divalent aromatic hydrocarbon group having 6 to 30 carbon atoms which may have a substituent, or a divalent aromatic heterocyclic group having 3 to 30 carbon atoms which may have a substituent,
Xa², Ya², and Za² each independently represent a hydrogen atom, a monovalent aromatic hydrocarbon group having 6 to 30 carbon atoms which may have a substituent, or a monovalent aromatic heterocyclic group having 3 to 30 carbon atoms which may have a substituent,
g11, h11, and j11 each independently represent an integer of 0 to 6,
at least one of g11, h11, and j11 represents an integer of 1 or more,
when g11 is 2 or more, a plurality of Xa¹'s may be the same as or different from each other,
when h11 is 2 or more, a plurality of Ya¹'s may be the same as or different from each other,
when j11 is 2 or more, a plurality of Za¹'s may be the same as or different from each other,
R³¹ represents a hydrogen atom or a substituent, and four R³¹'s may be the same as or different from each other, and
when g11, h11, or j11 is 0, the respective corresponding Xa², Ya², and Za² are not a hydrogen atom.

In Xa¹, Ya¹, Za¹, Xa², Ya² and Za², the substituent which the aromatic hydrocarbon group having 6 to 30 carbon atoms may have, and the substituent which the aromatic heterocyclic group having 3 to 30 carbon atoms may have are each independently selected from the following substituent group Z2, and the substituent selected from the following substituent group Z2 does not have any further substituent.

### <Substituent Group Z2>

Alkyl group, alkoxy group, aryloxy group, heteroaryloxy group, alkoxycarbonyl group, dialkylamino group, diarylamino group, arylalkylamino group, acyl group, halogen atom, haloalkyl group, alkylthio group, arylthio group, silyl group, siloxy group, cyano group, aromatic hydrocarbon group, and aromatic heterocyclic group)

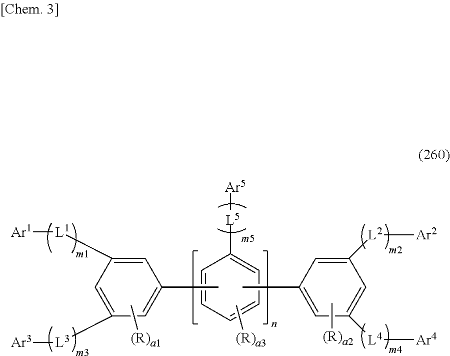

(In the formula (260),
Ar¹ to Ar⁵ each independently represent a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent,
R's each independently represent a substituent,
m1 to m5 each independently represent an integer of 0 to 5,
n represents an integer of 0 to 10,
a1 to a3 each independently represent an integer of 0 to 3, and
at least one of Ar¹, Ar², Ar³, Ar⁴, and at least one Ar⁵ when n is 1 or more is not a hydrogen atom.)
   <2>

The organic electroluminescent element material according to <1>, in which the organometallic compound is represented by the following formula (201).

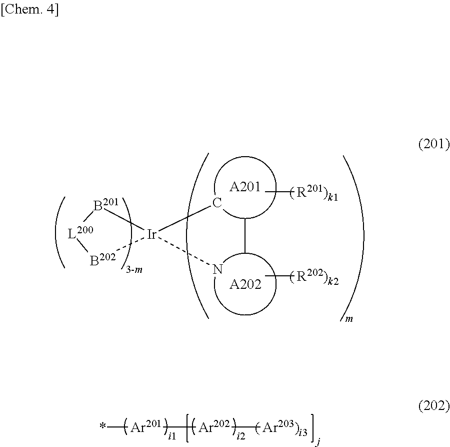

[Ring A201 represents an aromatic hydrocarbon ring structure which may have a substituent or an aromatic heterocyclic structure which may have a substituent.
Ring A202 represents an aromatic heterocyclic structure which may have a substituent.
R²⁰¹ and R²⁰² each independently represent a structure represented by the above formula (202).
When a plurality of R²⁰¹'s and a plurality of R²⁰²'s are present, they may be the same as or different from each other.
Ar²⁰¹ and Ar²⁰³ each independently represent an aromatic hydrocarbon ring structure which may have a substituent or an aromatic heterocyclic structure which may have a substituent.
Ar²⁰² represents an aromatic hydrocarbon ring structure which may have a substituent, an aromatic heterocyclic structure which may have a substituent, or an aliphatic hydrocarbon structure which may have a substituent.
When a plurality of Ar²⁰¹'s, a plurality of Ar²⁰²'s, and a plurality of Ar²⁰³'s are present, they may be the same as or different from each other.
* represents bonding to ring A201 or ring A202.
B²⁰¹-L²⁰⁰-B²⁰² represents an anionic bidentate ligand. B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure. L²⁰⁰ represents a single bond or an atomic group constituting a bidentate ligand together with B²⁰¹ and B²⁰².

When a plurality of B²⁰¹-L²⁰⁰-B²⁰²'s are present, they may be the same as or different from each other.
i1 and i2 each independently represent an integer of 0 or more and 12 or less.
i3 is an integer of 0 or more, an upper limit of which is the number that can be substituted for Ar²⁰².
j is an integer of 0 or more, an upper limit of which is the number that can be substituted for Ar²⁰¹.
k1 and k2 each independently represent an integer of 0 or more, an upper limit of which is the number that can be substituted for ring A201 and ring A202.
m represents an integer of 1 to 3.]

<3>

The organic electroluminescent element material according to <1>, in which the luminescent compound is a polycyclic heterocyclic compound represented by the following formula (1).

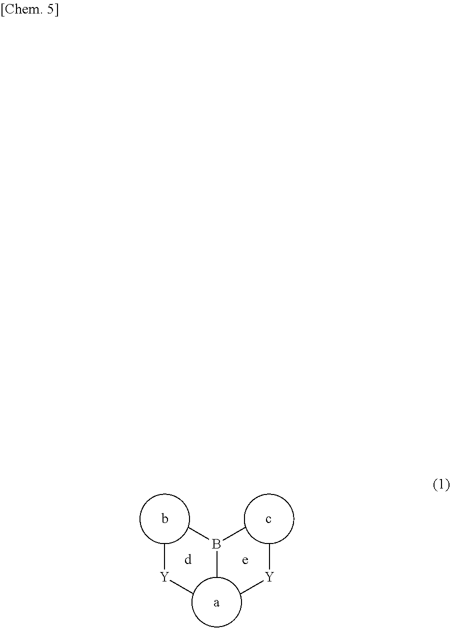

(In the formula (1),
ring a, ring b, and ring c each independently represent an aromatic hydrocarbon ring which may have a substituent or an aromatic heterocyclic ring which may have a substituent,
Y's each independently represent O, N—R, or S,
the R is an aromatic hydrocarbon ring group which may have a substituent, an aromatic heterocyclic group which may have a substituent, or an alkyl group,
the R may be bonded to a carbon atom adjacent to an atom bonded to the Y in at least one ring selected from the group consisting of the ring a, the ring b, and the ring c by —O—, —S—, —C(—R^{a})₂—, or a single bond,
the R^{a}'s each independently represent a hydrogen atom or an alkyl group, and
the adjacent carbon atom is not a carbon atom constituting a central fused bicyclic structure of the formula (1) containing B and the Y.

At least one hydrogen atom in the polycyclic heterocyclic compound represented by the formula (1) may be substituted with a halogen atom or deuterium.

Ring d is a ring constituted by B, Y, and some of atoms constituting ring a and ring b, and ring e is a ring constituted by B, Y, and some of atoms constituting ring a and ring c.)

<4>

The organic electroluminescent element material according to <1>, in which the organometallic compound is represented by the following formula (201), and the luminescent compound is a polycyclic heterocyclic compound represented by the following formula (1).

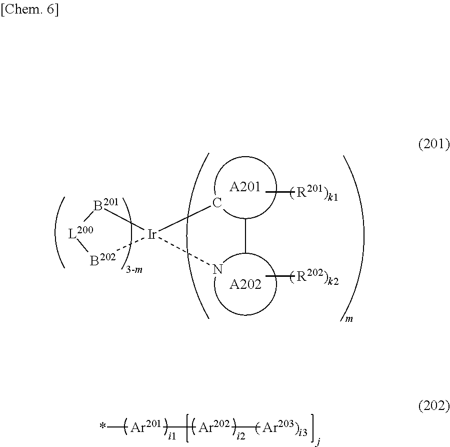

[Ring A201 represents an aromatic hydrocarbon ring structure which may have a substituent or an aromatic heterocyclic structure which may have a substituent.
Ring A202 represents an aromatic heterocyclic structure which may have a substituent.
R²⁰¹ and R²⁰² each independently represent a structure represented by the above formula (202).

When a plurality of R²⁰¹'s and a plurality of R²⁰²'s are present, they may be the same as or different from each other.
Ar²⁰¹ and Ar²⁰³ each independently represent an aromatic hydrocarbon ring structure which may have a substituent or an aromatic heterocyclic structure which may have a substituent.
Ar²⁰² represents an aromatic hydrocarbon ring structure which may have a substituent, an aromatic heterocyclic structure which may have a substituent, or an aliphatic hydrocarbon structure which may have a substituent.

When a plurality of Ar²⁰¹'s, a plurality of Ar²⁰²'s, and a plurality of Ar²⁰³'s are present, they may be the same as or different from each other.
* represents bonding to ring A201 or ring A202.
B²⁰¹-L²⁰⁰-B²⁰² represents an anionic bidentate ligand. B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure. L²⁰⁰ represents a single bond or an atomic group constituting a bidentate ligand together with B²⁰¹ and B²⁰².

When a plurality of B²⁰¹-L²⁰⁰-B²⁰²'s are present, they may be the same as or different from each other.
i1 and i2 each independently represent an integer of 0 or more and 12 or less.
i3 is an integer of 0 or more, an upper limit of which is the number that can be substituted for Ar²⁰².
j is an integer of 0 or more, an upper limit of which is the number that can be substituted for Ar²⁰¹.
K1 and k2 each independently represent an integer of 0 or more, an upper limit of which is the number that can be substituted for ring A201 and ring A202.
m represents an integer of 1 to 3.]

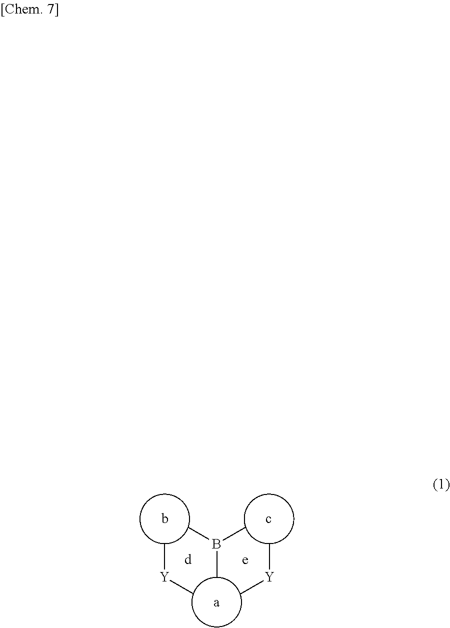

(In the formula (1),
ring a, ring b, and ring c each independently represent an aromatic hydrocarbon ring which may have a substituent or an aromatic heterocyclic ring which may have a substituent,
Y's each independently represent O, N—R, or S,
the R is an aromatic hydrocarbon ring group which may have a substituent, an aromatic heterocyclic group which may have a substituent, or an alkyl group,
the R may be bonded to a carbon atom adjacent to an atom bonded to the Y in at least one ring selected from the group consisting of the ring a, the ring b, and the ring c by —O—, —S—, —C(—R^{a})₂—, or a single bond,
the R^{a}'s each independently represent a hydrogen atom or an alkyl group, and
the adjacent carbon atom is not a carbon atom constituting a central fused bicyclic structure of the formula (1) containing B and the Y.

At least one hydrogen atom in the polycyclic heterocyclic compound represented by the formula (1) may be substituted with a halogen atom or deuterium.

Ring d is a ring constituted by B, Y, and some of atoms constituting ring a and ring b, and ring e is a ring constituted by B, Y, and some of atoms constituting ring a and ring c.)

<5>

The organic electroluminescent element material according to <4>, in which the polycyclic heterocyclic compound represented by the formula (1) is represented by the following formula (21).

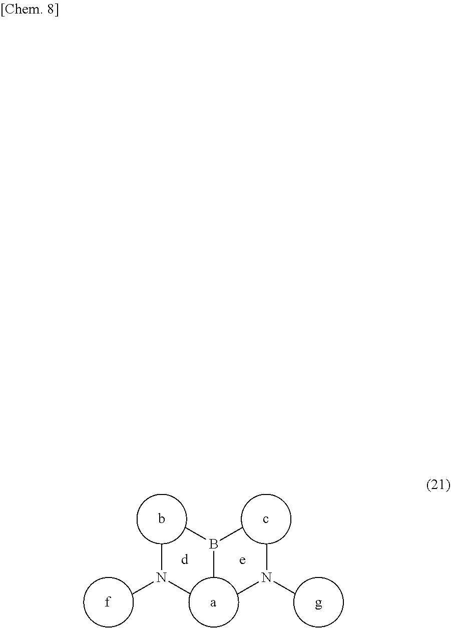

(In the formula (21),
ring a, ring b, and ring c are the same as those defined in the formula (1),
ring d is a ring constituted by B, N, and some of atoms constituting ring a and ring b, and ring e is a ring constituted by B, N, and some of atoms constituting ring a and ring c,
ring f and ring g each independently represent an aromatic hydrocarbon ring which may have a substituent or an aromatic heterocyclic ring which may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group,
the adjacent carbon atom is not a carbon atom constituting ring d and ring e each containing B and N, and
at least one hydrogen atom in the polycyclic heterocyclic compound represented by the formula (21) may be substituted with a halogen atom or deuterium.)
   <6>

The organic electroluminescent element material according to <4>, in which the polycyclic heterocyclic compound represented by the formula (1) is represented by the following formula (22).

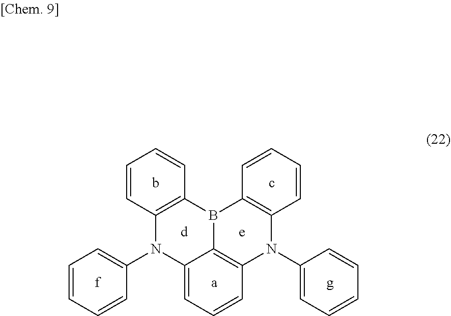 [SMILES: c1ccc(N2c3ccccc3B3c4ccccc4N(c4ccccc4)c4cccc2c43)cc1]

(In the formula (22),
ring d is a ring constituted by B, N, and some of atoms constituting ring a and ring b, and ring e is a ring constituted by B, N, and some of atoms constituting ring a and ring c,
ring a, ring b, ring c, ring f, and ring g may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group, and
at least one hydrogen atom in the polycyclic heterocyclic compound represented by the formula (22) may be substituted with a halogen atom or deuterium.)
   <7>

The organic electroluminescent element material according to <4>, in which the polycyclic heterocyclic compound represented by the formula (1) is represented by the following formula (71).

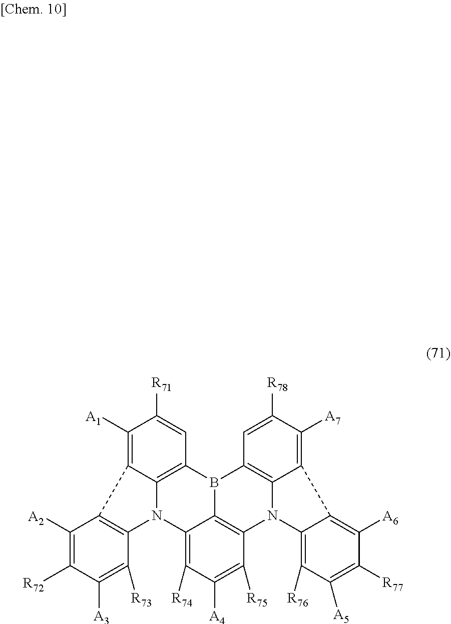

(In the formula (71),
A₁ to A₇ each independently represent a hydrogen atom; a fluorine atom; an alkyl group which may have a substituent; an electron-accepting heteroaryl group; a nitro group; a cyano group; or an aromatic hydrocarbon group or an aromatic heterocyclic group which has an electron-accepting heteroaryl group, a nitro group, or a cyano group as a substituent,
R₇₁ to R₇₈ each independently represent a hydrogen atom, an alkyl group which may have a substituent, an aromatic hydrocarbon group which may have a substituent, an aromatic heterocyclic group which may have a substituent, an electron-donating substituent, or a combination thereof,
at least one hydrogen atom in the polycyclic heterocyclic compound represented by the formula (71) may be substituted with a halogen atom or deuterium, and
a dotted line represents a single bond or no bond.)
   <8>

The organic electroluminescent element material according to <7>, in which A₁ to A₇ in the formula (71) are an electron-accepting substituent, and each independently represent a group represented by the following formula (71-5), a group represented by the following formula (71-6), a group represented by the following formula (71-7), or a group represented by the following formula (71-8).

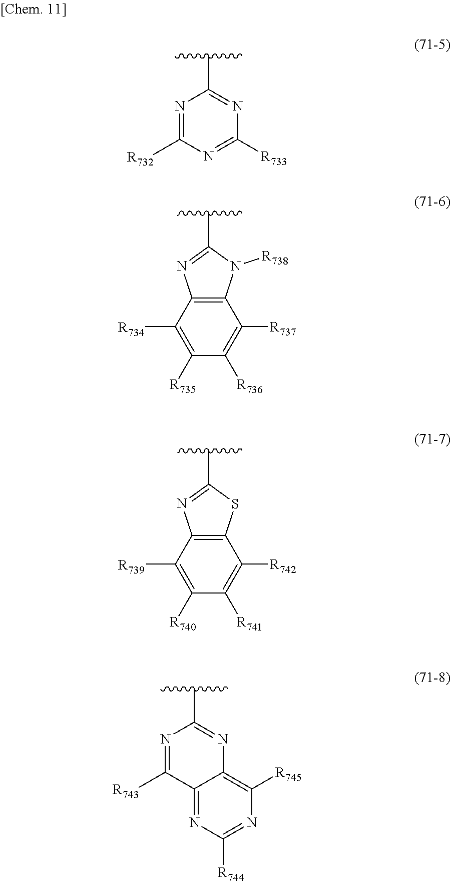

(In the formulae (71-5) to (71-8),
R₇₃₂ to R₇₄₅ each independently represent a hydrogen atom, an alkyl group which may have a substituent, or an aromatic hydrocarbon group which may have a substituent.)
   <9>

The organic electroluminescent element material according to <7>, in which R₇₁ to R₇₈ in the formula (71) are an electron-donating substituent, and each independently represent a group represented by the following formula (71-2), a group represented by the following formula (71-3), or a group represented by the following formula (71-4).

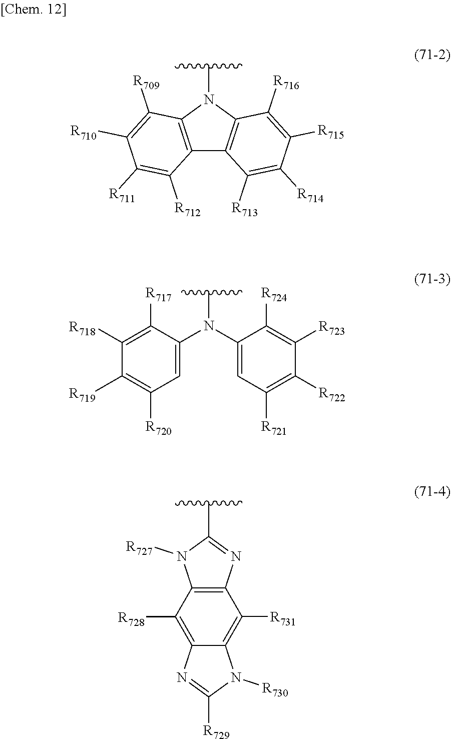

(In the formulae (71-2) to (71-4),
R₇₀₉ to R₇₂₄ and R₇₂₇ to R₇₃₁ each independently represent an alkyl group which may have a substituent, an aromatic hydrocarbon group which may have a substituent, or a hydrogen atom.)
   <10>

The organic electroluminescent element material according to <1>, in which the T1A is 2.10 eV or more and 2.80 eV or less.

<11>

The organic electroluminescent element material according to <1>, in which MwA/MwB is 2.0 or more, where MwA is a molecular weight of the organometallic compound and MwB is a molecular weight of the luminescent compound.

<12>

The organic electroluminescent element material according to <1>, in which in the formula (250), (Xa¹)_{g11} when g11 is 1 or more, (Ya¹)ₕ₁₁ when h11 is 1 or more, and (Za¹)ⱼ₁₁ when j11 is 1 or more each independently have a partial structure selected from partial structures each represented by the following formulae (11) to (17).

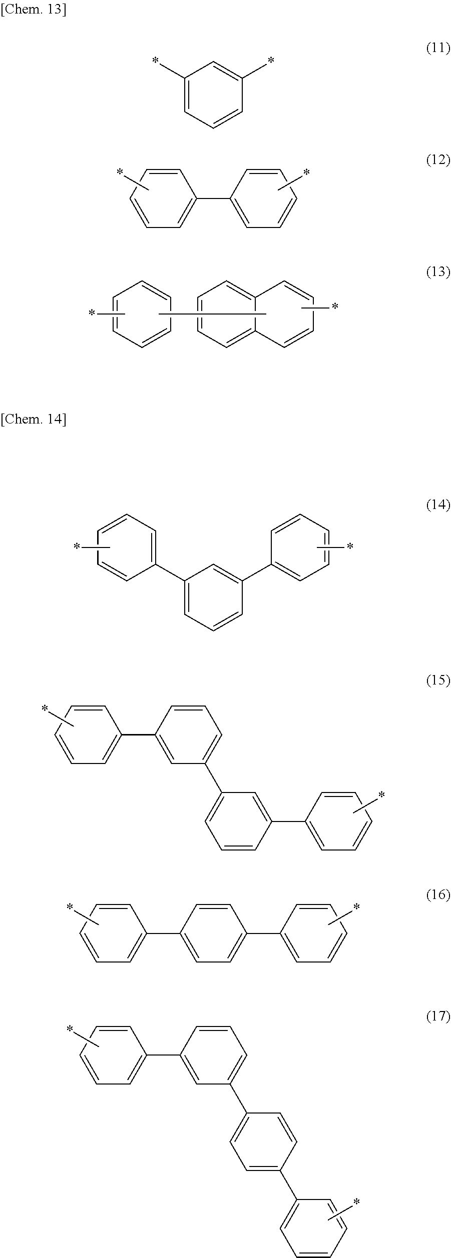

(In each of the formulae (11) to (17), * represents a bond with an adjacent structure, or when Xa², Ya², or Za² in the formula (250) represents a hydrogen atom, * represents the hydrogen atom, and at least one of two present *'s represents a bonding site with an adjacent structure.)

<13>

The organic electroluminescent element material according to <1>, in which at least two of W's in the formula (250) are N.

<14>

The organic electroluminescent element material according to <1>, in which in the formula (250), at least one of -(Xa¹)_{g11}-(Xa²), -(Ya¹)ₕ₁₁-(Ya²), and -(Za¹)ⱼ₁₁-(Za²) has any one of partial structures or terminal structures each represented by the following formula (250-1) to formula (250-10).

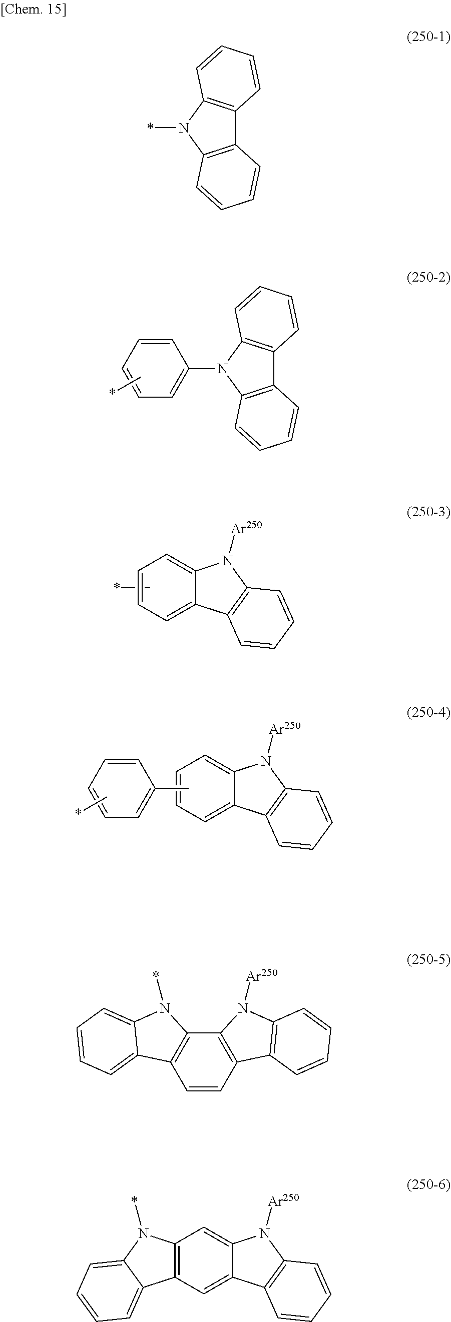

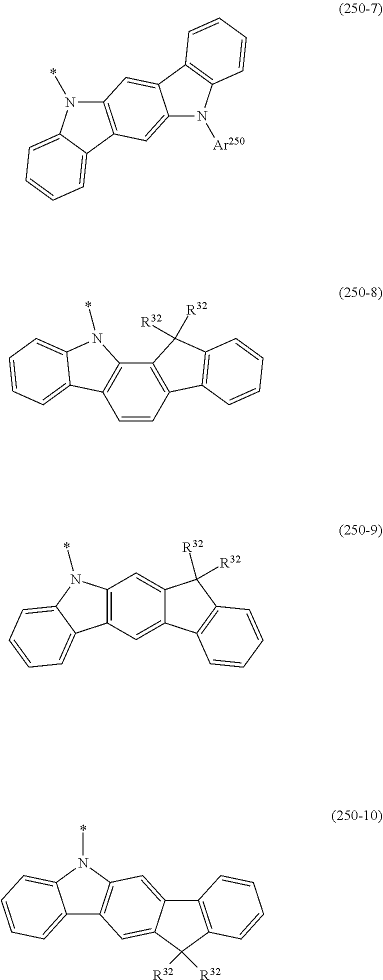

[In the formula (250-1) to formula (250-10), * represents a bonding site. Ar²⁵⁰ represents an aromatic hydrocarbon group having 6 to 20 carbon atoms. R³² represents a substituent, and the structures each represented by the formula (250-1) to formula (250-10) may further have a substituent.]

<15>

The organic electroluminescent element material according to <1>, in which in the formula (240), Ar⁶¹¹ and Ar⁶¹² each independently have a partial structure selected from the following formulae (11) to (13) and the following formulae (21) to (24).

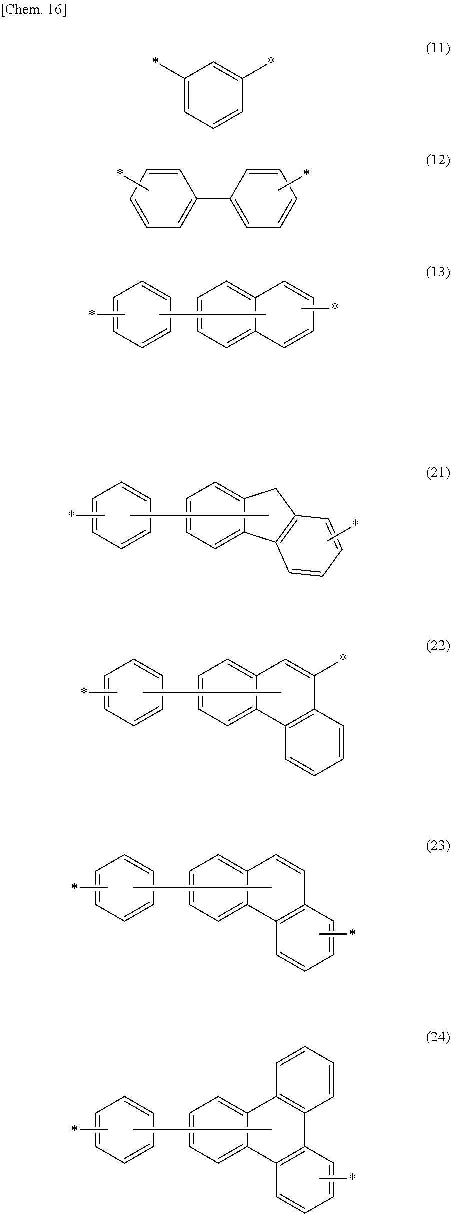

(In each of the formula (11) to formula (13) and formula (21) to formula (24), * represents a bond with an adjacent structure or a hydrogen atom, and at least one of two present *'s represents a bonding site with an adjacent structure.)

<16>

The organic electroluminescent element material according to <1>, in which in the formula (260), (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more each independently have a partial structure selected from partial structures each represented by the following formula (11) to formula (17).

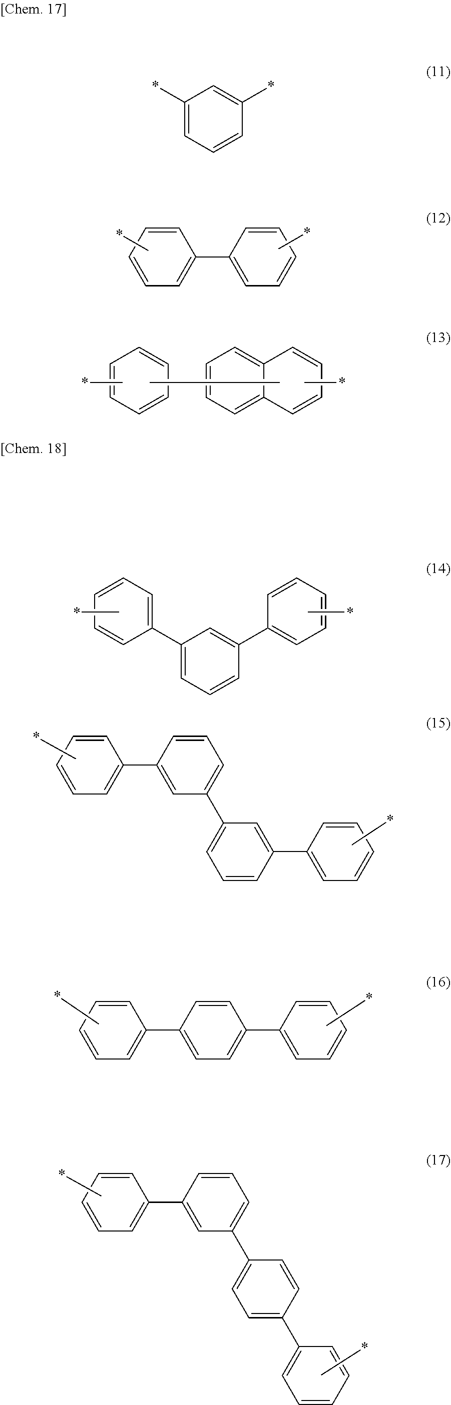

(In each of the formula (11) to formula (17), * represents a bond with an adjacent structure, or when Ar¹, Ar², Ar³, Ar⁴, or Ar⁵ represents a hydrogen atom, * represents the hydrogen atom, and at least one of two present *'s represents a bonding site with an adjacent structure.)

<17>

The organic electroluminescent element material according to <1>, in which in the formula (260), one or more and three or less of Ar¹, Ar², and at least one Ar⁵ are represented by the following formula (4) or the following formula (5).

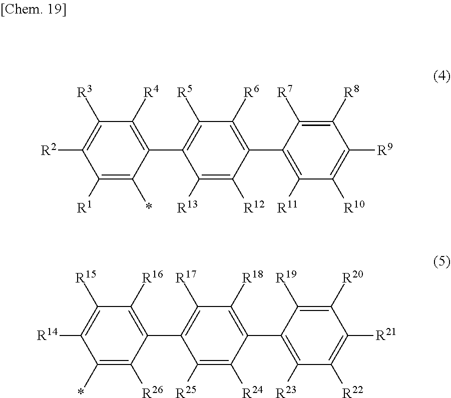

(In the formula (4) and formula (5),
* represents a bonding site with the formula (260), and
R¹ to R²⁶ each independently represent a hydrogen atom or a substituent.)
   <18>

An organic electroluminescent element including:
an anode;
a cathode;
an emission layer; and
a hole injection layer, in which
the emission layer is provided between the anode and the cathode,
the hole injection layer is provided between the anode and the emission layer, and
the emission layer contains the organic electroluminescent element material according to any one of <1> to <17>.
   <19>

An organic EL display device or an organic EL illuminator, including the organic electroluminescent element according to <18>.

<20>

An organic electroluminescent element formation composition, containing the organic electroluminescent element material according to any one of <1> to <17>; and an organic solvent.

<21>

A method for producing an organic electroluminescent element, the organic electroluminescent element including an anode, an emission layer, and a cathode in this order on a substrate, the method including:
a step of forming the emission layer by a wet-process film formation method using the composition according to <20>.

### Advantageous Effects of Invention

The organic electroluminescent element material of the present invention provides an organic electroluminescent element that exhibits excellent element characteristics and particularly has high luminescent efficiency and a long operating lifetime.

### BRIEF DESCRIPTION OF DRAWINGS

The FIGURE is a schematic cross-sectional view showing an example of a structure of an organic electroluminescent element of the present invention.

### DESCRIPTION OF EMBODIMENTS

Hereinafter, an embodiment of an organic electroluminescent element, an organic EL display device including the organic electroluminescent element, and an organic EL illuminator including the organic electroluminescent element, which is one embodiment of the present invention, will be described in detail. The following description is a first embodiment which is an example (representative example) of the embodiment of the present invention, but the present invention is not limited thereto as long as it does not exceed the gist thereof.

An organic electroluminescent element material according to the first embodiment of the present invention is an organic electroluminescent element material containing:
a luminescent compound; an organometallic compound; and a host material, in which
the organometallic compound has a molecular weight of 1,200 or more,
the host material contains at least one selected from the group consisting of a compound represented by the following formula (240), a compound represented by the following formula (250), and a compound represented by the following formula (260), and
the following relational expression (E-1) and the following relational expression (E-2) are satisfied.

$$T 1 A \geq T 1 B \qquad Expression ( E - 1 )$$

$$Δ EST = S 1 B - T 1 B \leq 0.3 eV \qquad Expression ( E - 2 )$$

(In the expression (E-1) and the expression (E-2),
T1A: a triplet energy level (eV) of the organometallic compound
T1B: a triplet energy level (eV) of the luminescent compound
S1B: a singlet energy level (eV) of the luminescent compound)

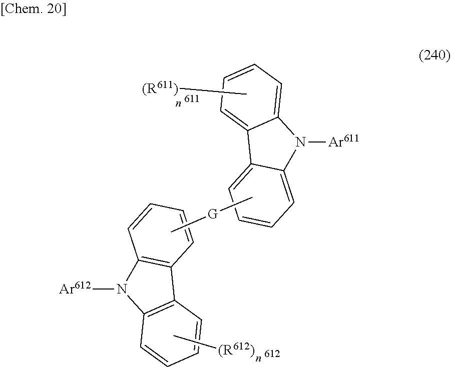

(In the formula (240),
Ar⁶¹¹ and Ar⁶¹² each independently represent a monovalent aromatic hydrocarbon group having 6 to 50 carbon atoms which may have a substituent,
R⁶¹¹ and R⁶¹² each independently represent a deuterium atom, a halogen atom, or a monovalent aromatic hydrocarbon group having 6 to 50 carbon atoms which may have a substituent,
G represents a single bond, or a divalent aromatic hydrocarbon group having 6 to 50 carbon atoms which may have a substituent, and
n⁶¹¹ and n⁶¹² each independently represent an integer of 0 to 4.)

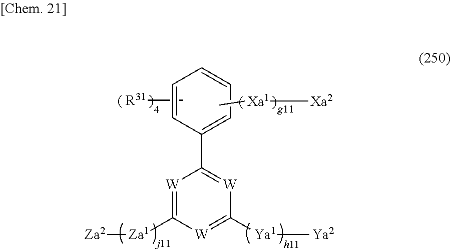

(In the formula (250),
W's each independently represents CH or N, and at least one W represents N,
Xa¹, Ya¹, and Za¹ each independently represent a divalent aromatic hydrocarbon group having 6 to 30 carbon atoms which may have a substituent, or a divalent aromatic heterocyclic group having 3 to 30 carbon atoms which may have a substituent,
Xa², Ya², and Za² each independently represent a hydrogen atom, a monovalent aromatic hydrocarbon group having 6 to 30 carbon atoms which may have a substituent, or a monovalent aromatic heterocyclic group having 3 to 30 carbon atoms which may have a substituent,
g11, h11, and j11 each independently represent an integer of 0 to 6,
at least one of g11, h11, and j11 represents an integer of 1 or more,
when g11 is 2 or more, a plurality of Xa¹'s may be the same as or different from each other,
when h11 is 2 or more, a plurality of Ya¹'s may be the same as or different from each other,
when j11 is 2 or more, a plurality of Za¹'s may be the same as or different from each other,
R³¹ represents a hydrogen atom or a substituent, and four R³¹'s may be the same as or different from each other, and
when g11, h11, or j11 is 0, the respective corresponding Xa², Ya², and Za² are not a hydrogen atom.

In Xa¹, Ya¹, Za¹, Xa², Ya² and Za², the substituent which the aromatic hydrocarbon group having 6 to 30 carbon atoms may have, and the substituent which the aromatic heterocyclic group having 3 to 30 carbon atoms may have are each independently selected from the following substituent group Z2, and the substituent selected from the following substituent group Z2 does not have any further substituent.

### <Substituent Group Z2>

Alkyl group, alkoxy group, aryloxy group, heteroaryloxy group, alkoxycarbonyl group, dialkylamino group, diarylamino group, arylalkylamino group, acyl group, halogen atom, haloalkyl group, alkylthio group, arylthio group, silyl group, siloxy group, cyano group, aromatic hydrocarbon group, and aromatic heterocyclic group)

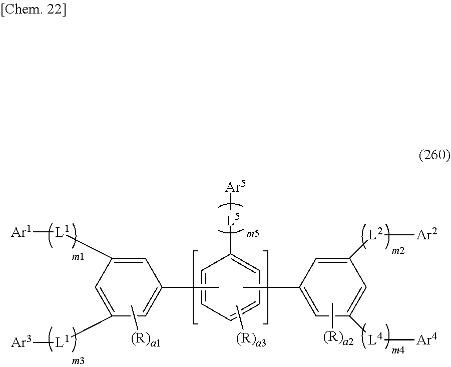

(In the formula (260),
Ar¹ to Ar⁵ each independently represent a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent,
R's each independently represent a substituent,
m1 to m5 each independently represent an integer of 0 to 5,
n represents an integer of 0 to 10,
a1 to a3 each independently represent an integer of 0 to 3, and
at least one of Ar¹, Ar², Ar³, Ar⁴, and at least one Ar⁵ when n is 1 or more is not a hydrogen atom.)

An organic electroluminescent element according to the first embodiment of the present invention is an organic electroluminescent element including an anode, a cathode, an emission layer, and a hole injection layer, in which
the emission layer is provided between the anode and the cathode,
the hole injection layer is provided between the anode and the emission layer,
the emission layer contains a polycyclic heterocyclic compound represented by the following formula (1), an organometallic compound represented by the following formula (201), and a host material,
the polycyclic heterocyclic compound and the organometallic compound satisfy the following relational expression (E-1),

$$T 1 A \geq T 1 B \qquad Expression ( E - 1 )$$

(in the formula (E-1),
T1A: a triplet energy level (eV) of the organometallic compound
T1B: a triplet energy level (eV) of the polycyclic heterocyclic compound), and
the host material contains at least one selected from a compound represented by the following formula (250), a compound represented by the following formula (240), and a compound represented by the following formula (260).

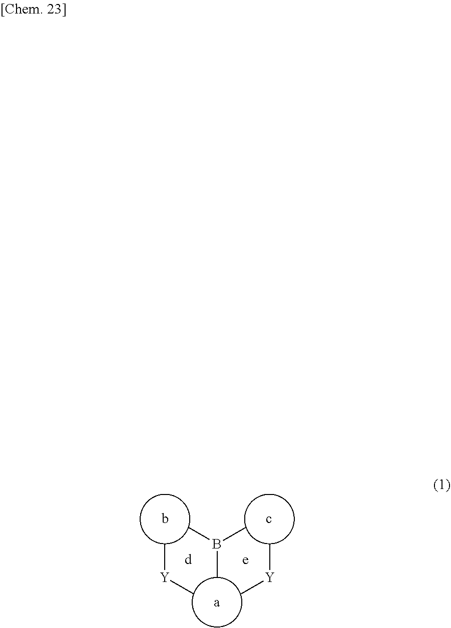

(In the formula (1),
ring a, ring b, and ring c each independently represent an aromatic hydrocarbon ring which may have a substituent or an aromatic heterocyclic ring which may have a substituent,
Y's each independently represent O, N—R, or S,
the R is an aromatic hydrocarbon ring group which may have a substituent, an aromatic heterocyclic group which may have a substituent, or an alkyl group,
the R may be bonded to a carbon atom adjacent to an atom bonded to the Y in at least one ring selected from the group consisting of the ring a, the ring b, and the ring c by —O—, —S—, —C(—R^{a})₂—, or a single bond,
the R^{a}'s each independently represent a hydrogen atom or an alkyl group, and
the adjacent carbon atom is not a carbon atom constituting a central fused bicyclic structure of the formula (1) containing B and the Y.

At least one hydrogen atom in the polycyclic heterocyclic compound represented by the formula (1) may be substituted with a halogen atom or deuterium.

Ring d is a ring constituted by B, Y, and some of atoms constituting ring a and ring b, and ring e is a ring constituted by B, Y, and some of atoms constituting ring a and ring c.)

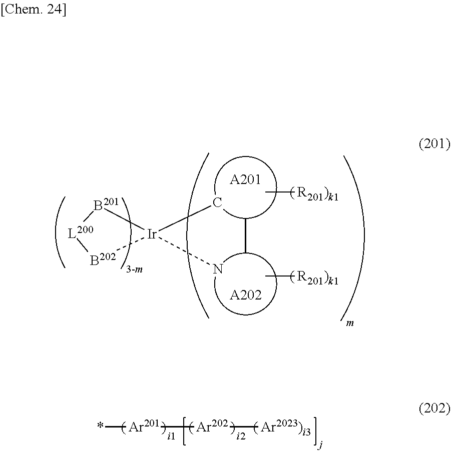

[Ring A201 represents an aromatic hydrocarbon ring structure which may have a substituent or an aromatic heterocyclic structure which may have a substituent.
Ring A202 represents an aromatic heterocyclic structure which may have a substituent.
R²⁰¹ and R²⁰² each independently represent a structure represented by the above formula (202).

When a plurality of R²⁰¹'s and a plurality of R²⁰²'s are present, they may be the same as or different from each other.
Ar²⁰¹ and Ar²⁰³ each independently represent an aromatic hydrocarbon ring structure which may have a substituent or an aromatic heterocyclic structure which may have a substituent.
Ar²⁰² represents an aromatic hydrocarbon ring structure which may have a substituent, an aromatic heterocyclic structure which may have a substituent, or an aliphatic hydrocarbon structure which may have a substituent.

When a plurality of Ar²⁰¹'s, a plurality of Ar²⁰²'s, and a plurality of Ar²⁰³'s are present, they may be the same as or different from each other.
* represents bonding to ring A201 or ring A202.
B²⁰¹-L²⁰⁰-B²⁰² represents an anionic bidentate ligand. B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure.
L²⁰⁰ represents a single bond or an atomic group constituting a bidentate ligand together with B²⁰¹ and B²⁰². When a plurality of B²⁰¹-L²⁰⁰-B²⁰²'s are present, they may be the same as or different from each other.
i1 and i2 each independently represent an integer of 0 or more and 12 or less.
i3 is an integer of 0 or more, an upper limit of which is the number that can be substituted for Ar²⁰².
j is an integer of 0 or more, an upper limit of which is the number that can be substituted for Ar²⁰¹.
K1 and k2 each independently represent an integer of 0 or more, an upper limit of which is the number that can be substituted for ring A201 and ring A202.
m represents an integer of 1 to 3.]

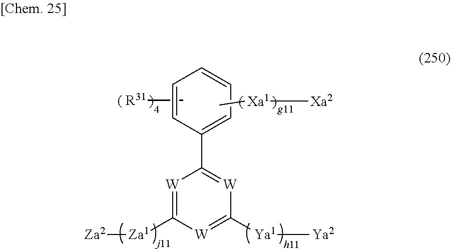

(In the formula (250),
W's each independently represent CH or N, and at least one W represents N,
Xa¹, Ya¹, and Za¹ each independently represent a divalent aromatic hydrocarbon group having 6 to 30 carbon atoms which may have a substituent, or a divalent aromatic heterocyclic group having 3 to 30 carbon atoms which may have a substituent, and
Xa², Ya², and Za² each independently represent a hydrogen atom, a monovalent aromatic hydrocarbon group having 6 to 30 carbon atoms which may have a substituent, or a monovalent aromatic heterocyclic group having 3 to 30 carbon atoms which may have a substituent.
g11, h11, and j11 each independently represent an integer of 0 to 6,
at least one of g11, h11, and j11 is an integer of 1 or more,
when g11 is 2 or more, a plurality of Xa¹'s may be the same as or different from each other,
when h11 is 2 or more, a plurality of Ya¹'s may be the same as or different from each other, and
when j11 is 2 or more, a plurality of Za¹'s may be the same as or different from each other.

R³¹ represents a hydrogen atom or a substituent, and the four R³¹'s may be the same as or different from each other, and
when g11, h11, or j11 is 0, the respective corresponding Xa², Ya², and Za² are not a hydrogen atom.

In Xa¹, Ya¹, Za¹, Xa², Ya² and Za², the substituent which the aromatic hydrocarbon group having 6 to 30 carbon atoms may have, and the substituent which the aromatic heterocyclic group having 3 to 30 carbon atoms may have are each independently selected from the following substituent group Z2, and the substituent selected from the following substituent group Z2 does not have any further substituent.

### <Substituent Group Z2>

Alkyl group, alkoxy group, aryloxy group, heteroaryloxy group, alkoxycarbonyl group, dialkylamino group, diarylamino group, arylalkylamino group, acyl group, halogen atom, haloalkyl group, alkylthio group, arylthio group, silyl group, siloxy group, cyano group, aromatic hydrocarbon group, and aromatic heterocyclic group)

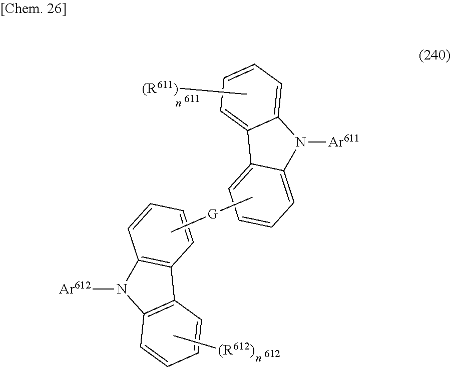

(In the formula (240),
Ar⁶¹¹ and Ar⁶¹² each independently represent a monovalent aromatic hydrocarbon group having 6 to 50 carbon atoms which may have a substituent, and
R⁶¹¹ and R⁶¹² each independently represent a deuterium atom, a halogen atom, or a monovalent aromatic hydrocarbon group having 6 to 50 carbon atoms which may have a substituent.
G represents a single bond, or a divalent aromatic hydrocarbon group having 6 to 50 carbon atoms which may have a substituent, and
n⁶¹¹ and n⁶¹² each independently represent an integer of 0 to 4.)

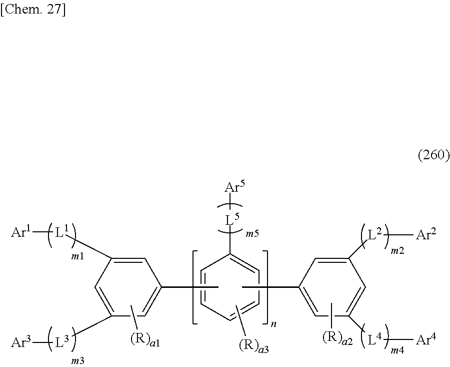

(In the formula (260),
Ar¹ to Ar⁵ each independently represents a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent, and
R's each independently represent a substituent.
m1 to m5 each independently represent an integer of 0 to 5,
n represents an integer of 0 to 10,
a1 to a3 each independently represent an integer of 0 to 3, and
at least one of Ar¹, Ar², Ar³, Ar⁴, and at least one Ar⁵ when n is 1 or more is not a hydrogen atom.)

The reason why the organic electroluminescent element provided by the organic electroluminescent element material according to the present invention has high efficiency and a long operating lifetime is presumed to be as follows.

The organic electroluminescent element material of the present invention contains the organometallic compound, the luminescent compound, and the host material. Among them, the organometallic compound plays a role of efficiently transferring energy in an excited state generated in the emission layer to the luminescent compound.

When excitation energy is transferred from the organometallic compound to the luminescent compound, if the molecular weight of the organometallic compound is small, an interaction between the organometallic compounds cannot be ignored, the energy transferred to the luminescent compound is lost, and high performance cannot be obtained. It is considered that when the molecular weight of the organometallic compound has a certain value or more, and the triplet energy level and the singlet energy level of the organometallic compound and the luminescent compound have a specific relationship, the interaction between the organometallic compounds can be appropriately prevented, and high performance is exhibited.

In the present invention, the host material contains at least one selected from the compound represented by the formula (250), the compound represented by the formula (240), and the compound represented by the formula (260).

### <Organic Electroluminescent Element Material>

The organic electroluminescent element material of the present invention is an organic electroluminescent element material containing a luminescent compound; an organometallic compound; and a host material, in which
the organometallic compound has a molecular weight of 1,200 or more,
the host material contains at least one selected from the group consisting of a compound represented by the following formula (240), a compound represented by the following formula (250), and a compound represented by the following formula (260), and
the following relational expression (E-1) and the following relational expression (E-2) are satisfied.

$$T 1 A \geq T 1 B \qquad Expression ( E - 1 )$$

$$Δ EST = S 1 B - T 1 B \leq 0.3 eV \qquad Expression ( E - 2 )$$

(In the expression (E-1) and the expression (E-2),
T1A: a triplet energy level (eV) of the organometallic compound
T1B: a triplet energy level (eV) of the luminescent compound
S1B: a singlet energy level (eV) of the luminescent compound)

In the present invention, the organic electroluminescent element material satisfies the following relational expression (E-1).

$$T 1 A \geq T 1 B \qquad Expression ( E - 1 )$$

When the expression (E-1) is satisfied, the organometallic compound efficiently transfers excited triplet energy generated in the emission layer to the luminescent compound, and the luminescent compound emits light with high efficiency.

The luminescent compound in the present invention satisfies the following relational expression (E-2).

$$Δ EST = S 1 B - T 1 B \leq 0.3 eV \qquad Expression ( E - 2 )$$

When the expression (E-2) is satisfied, the excited triplet energy of the luminescent compound is efficiently internally converted into an excited singlet, and the luminescent compound emits light with high efficiency.
ΔEST in the expression (E-2) is 0.30 eV or less, preferably 0.25 eV or less, and more preferably 0.20 eV or less. A lower limit value of ΔEST is not particularly limited, and is generally 0.01 eV or more, and preferably 0.02 eV or more.

The T1A is preferably 1.90 eV or more, more preferably 2.00 eV or more, and still more preferably 2.10 eV or more, and is preferably 3.00 eV or less, more preferably 2.80 eV or less, and still more preferably 2.70 eV or less. It is considered that, by setting the T1A within the range, decomposition of the organometallic compound can be prevented since the excited state of the organometallic compound is not too high in energy, and the excited state of the organometallic compound is rapidly transferred to the luminescent compound since the excited state of the organometallic compound is not too low in energy, so that an element with higher performance can be obtained. For example, the T1A can be 2.10 eV or more and 2.80 eV or less as a preferred aspect.

The T1A, T1B, and S1B can be obtained by the following method.

The S1B, and T1A and T1B can be determined from peak wavelengths of a fluorescence spectrum and a phosphorescence spectrum, respectively. The fluorescence spectrum and the phosphorescence spectrum can be measured using a spectrophotometer, for example, using a spectrophotometer F-7000 manufactured by Hitachi High-Tech Science Corporation. In the measurement, a solution obtained by dissolving the compound in an appropriate organic solvent at a concentration of about 10⁻⁶ M to 10⁻⁵ M is used as a sample. The fluorescence spectrum is measured at room temperature. The phosphorescence is measured by cooling to 77 K with liquid nitrogen.

### [(Group A), (Group B), and (Group C)]

Here, in the present description, the host material contained in the emission layer is referred to as (group A), (group B), and (group C) as follows for convenience.
(Group A) An electron transport material, preferably a compound represented by the following formula (250)
(Group B) A hole transport material, preferably a compound represented by the following formula (240)
(Group C) A material for adjusting charge transportability, preferably a compound represented by the following formula (260)

In the present invention, the host material that can be contained in the emission layer preferably contains at least one kind of compound selected from at least one of the three groups each represented by (Group A), (Group B) and (Group C),
more preferably contains at least one kind of compound selected from the (Group A) or the (Group B),
still more preferably contains at least two kinds of compound selected from each of at least any two of the three groups each represented by the (Group A), the (Group B), and the (Group C),
even more preferably contains at least two kinds of compound selected from each of the two groups each represented by the (Group A) and the (Group B), and
particularly preferably contains at least three kinds of compound selected from each of the three groups each represented by the (Group A), the (Group B) and the (Group C).

The compounds respectively selected from the two groups may be one kind or two or more kinds.

The host material contained in the organic electroluminescent element material contains at least one kind of compound selected from the group consisting of a compound represented by the formula (250), which is a compound selected from the (Group A), a compound represented by the formula (240), which is a compound selected from the (Group B), and a compound represented by the formula (260), which is a compound selected from the (Group C), and
the host material contained in the organic electroluminescent element material more preferably contains at least two kinds of compound selected from any two of the compound represented by the formula (250), the compound represented by the formula (240), and the compound represented by the formula (260),
still more preferably contains at least two kinds of compound selected from each of the compound represented by the formula (250) and the compound represented by the formula (240), and
particularly preferable contains at least three kinds of compound selected from each of the compound represented by the formula (250), the compound represented by the formula (240), and the compound represented by the formula (260).

It is considered that when the organic electroluminescent element material of the present invention contains, as the host material, the compound represented by the formula (250), which is a compound having a structure in which a nitrogen-containing 6-membered heteroaromatic ring and a benzene ring are linked, the charge transportability in the emission layer can be appropriately adjusted, the voltage can be lowered, the luminescent efficiency can be improved, deterioration of the luminescent compound and the organometallic compound can be prevented, and the operating lifetime becomes longer. In particular, it is considered that when the compound represented by the formula (250) has a triazine structure in which all of W's in the formula (250) are nitrogen atoms, the compound represented by the formula (250) has a relatively deep LUMO, and has a moderate electron trapping property in addition to the electron transportability, and does not supply electrons excessively to the luminescent compound and the organometallic compound, thereby improving the durability of the luminescent compound and the organometallic compound, and as a result, the operating lifetime of the organic electroluminescent element becomes longer. In particular, it is considered that this effect is high when the luminescent compound is the polycyclic heterocyclic compound represented by the formula (1) and the organometallic compound is the compound represented by the formula (201).

Further, in particular, it is considered that when the luminescent compound is the polycyclic heterocyclic compound represented by the formula (1), there is a possibility that electrons enter an empty p-orbital of a boron atom of the polycyclic heterocyclic compound, and deterioration of the polycyclic heterocyclic compound represented by the formula (1) and the organometallic compound represented by the formula (201) is prevented.

The compound represented by the formula (250) has an aromatic 6-membered ring having a nitrogen atom at the center, and thus has high electron transportability. Accordingly, it is considered that when the compound represented by the formula (250) is used as the host material, the voltage is further lowered, the luminescent efficiency is improved, and the operating lifetime becomes longer by using a host material having high hole transportability as another host material.

It is considered that when the organic electroluminescent element material of the present invention contains, as the host material, the compound represented by the formula (240), which is a compound having a structure including two carbazole rings, the charge transportability in the emission layer can be appropriately adjusted, the voltage can be lowered, the luminescent efficiency can be improved, deterioration of the luminescent compound and the organometallic compound can be prevented, and the operating lifetime becomes longer. It is considered that in a case where the luminescent compound or the organometallic compound may be deteriorated when directly receiving holes injected from a layer on an anode side and being in an oxidized state, the compound represented by the formula (240) has hole transportability and easily receives holes from the layer on the anode side, and therefore the luminescent compound or the organometallic compound is less likely to be directly oxidized and deterioration thereof can be prevented. On the other hand, it is considered that in a case where the luminescent compound or the organometallic compound is likely to be deteriorated when directly receiving electrons injected from a cathode side and being in a reduced state, holes are rapidly transported from the compound represented by the formula (240) to the luminescent compound or the organometallic compound, and the luminescent material recombines and emits light to prevent deterioration.

The compound represented by the formula (240) has excellent hole transportability and excellent hole transportability to the organometallic compound. It is considered that since the compound represented by the formula (240) has two highly planar carbazole ring structures, the hole transportability to the luminescent compound is improved. In particular, it is considered that the hole transportability to the luminescent compound which is a highly planar polycyclic heterocyclic compound represented by the formula (1) is improved. At this time, it is considered that since electrons are rapidly supplied to the luminescent compound, recombination light emission is rapidly performed, and deterioration of the luminescent compound is also prevented. Accordingly, it is considered that when the compound represented by the formula (240) is used as a first host material and the material having high electron transportability is used as a second host material, an organic electroluminescent element having a low voltage, improved luminescent efficiency, and a long operating lifetime can be obtained. The host material having high electron transportability is preferably the compound represented by the formula (250).

It is considered that when the organic electroluminescent element material of the present invention contains, as the host material, the compound represented by the formula (260), which is a compound having a structure in which many benzene rings are linked, the charge transportability in the emission layer can be appropriately adjusted, deterioration of the luminescent compound and the organometallic compound can be prevented, and the operating lifetime becomes longer. In particular, the compound represented by the formula (260) has an effect of preventing charge transportability. In particular, it is considered that when the compound represented by the formula (250) having excellent electron transportability is used as the host material, by further adding the compound represented by the formula (260) as the host material, the electron transportability in the emission layer can be prevented so that the luminescent compound or the organometallic compound is not excessively reduced and deteriorated, and the operating lifetime of the element becomes longer.

### <Luminescent Compound>

The luminescent compound of the present invention is a compound satisfying the following relational expression (E-2).

$$Δ EST = S 1 B - T 1 B \leq 0.3 eV \qquad Expression ( E - 2 )$$

(In the expression (E-2),
T1B: a triplet energy level (eV) of the luminescent compound
S1B: a singlet energy level (eV) of the luminescent compound)

### <Polycyclic Heterocyclic Compound>

In the present invention, the luminescent compound is preferably the polycyclic heterocyclic compound represented by the formula (1).

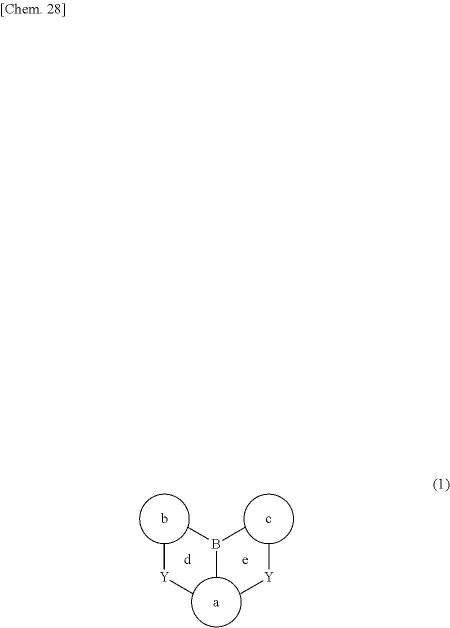

(In the formula (1),
ring a, ring b, and ring c each independently represent an aromatic hydrocarbon ring which may have a substituent or an aromatic heterocyclic ring which may have a substituent,
Y's each independently represent O, N—R, or S,
the R is an aromatic hydrocarbon ring group which may have a substituent, an aromatic heterocyclic group which may have a substituent, or an alkyl group,
the R may be bonded to a carbon atom adjacent to an atom bonded to the Y in at least one ring selected from the group consisting of the ring a, the ring b, and the ring c by —O—, —S—, —C(—R^{a})₂—, or a single bond,
the R^{a}'s each independently represent a hydrogen atom or an alkyl group, and
the adjacent carbon atom is not a carbon atom constituting a central fused bicyclic structure of the formula (1) containing B and the Y.

At least one hydrogen atom in the polycyclic heterocyclic compound represented by the formula (1) may be substituted with a halogen atom or deuterium.
Ring d is a ring constituted by B, Y, and some of atoms constituting ring a and ring b, and ring e is a ring constituted by B, Y, and some of atoms constituting ring a and ring c.)

### (Ring a, Ring b, Ring c, Ring d, and Ring e)

Ring a, ring b, and ring c each independently represent an aromatic hydrocarbon ring which may have a substituent or an aromatic heterocyclic ring which may have a substituent.

Ring d is a ring constituted by B, Y, and some of atoms constituting ring a and ring b, and ring e is a ring constituted by B, Y, and some of atoms constituting ring a and ring c.

The substituent which the aromatic hydrocarbon ring or the aromatic heterocyclic ring of ring a, ring b, and ring c may have is preferably a group selected from the following substituent group α.

### (Central Fused Bicyclic Structure)

In the present invention, the fused bicyclic structure consisting of ring d and ring e may be referred to as a “central fused bicyclic structure” for convenience.

The aromatic hydrocarbon ring or aromatic heterocyclic ring in ring a, ring b, and ring c preferably has a 5- or 6-membered ring that shares a bond with the central fused bicyclic structure of the formula (1) composed of B and Y, and more preferably has a 6-membered ring that shares a bond with the central fused bicyclic structure of the formula (1) composed of B and Y The central fused bicyclic structure is more preferably a fused bicyclic structure in which ring d is a 6-membered ring consisting of B, Y, two atoms constituting ring a, and two atoms constituting ring b, and ring e is a 6-membered ring consisting of B, Y, two atoms constituting ring a, and two atoms constituting ring c.

A case where the “6-membered ring that shares a bond with the central fused bicyclic structure” is present means, for example, a case where ring a is a benzene ring (a 6-membered ring). The expression “the aromatic hydrocarbon ring or aromatic heterocyclic ring (which is ring a) has a 6-membered ring” means that ring a is formed only by the 6-membered ring or that ring a is formed by fusing another ring or the like to the 6-membered ring so as to include the 6-membered ring. The same description applies to “ring b”, “ring c”, and “5-membered ring”.

Examples of the aromatic hydrocarbon ring in ring a, ring b, and ring c of the formula (1) include an aromatic hydrocarbon ring having 6 to 30 carbon atoms, an aromatic hydrocarbon ring having 6 to 16 carbon atoms is preferred, an aromatic hydrocarbon ring having 6 to 12 carbon atoms is more preferred, and an aromatic hydrocarbon ring having 6 to 10 carbon atoms is particularly preferred.

Specific examples of the aromatic hydrocarbon ring preferably include a benzene ring which is a monocyclic ring, a biphenyl ring which is a bicyclic ring, a naphthalene ring which is a fused bicyclic ring, a terphenyl ring which is a tricyclic ring (m-terphenyl, o-terphenyl, and p-terphenyl), an acenaphthylene ring, a fluorene ring, a phenalene ring, and a phenanthrene ring which are a fused tricyclic ring, a triphenylene ring, a pyrene ring, and a naphthacene ring which are a fused tetracyclic ring, and a perylene ring and a pentacene ring which are a fused pentacyclic ring, more preferably include a benzene ring, a biphenyl ring, a naphthalene ring, a terphenyl ring, and a fluorene ring include, and most preferably include a benzene ring.

Examples of the aromatic heterocyclic ring in ring a, ring b, and ring c of the formula (1) include an aromatic heterocyclic ring having 2 to 30 carbon atoms, an aromatic heterocyclic ring having 2 to 25 carbon atoms is preferred, an aromatic heterocyclic ring having 2 to 20 carbon atoms is more preferred, an aromatic heterocyclic ring having 2 to 15 carbon atoms is still more preferred, and an aromatic heterocyclic ring having 2 to 10 carbon atoms is particularly preferred. The “aromatic heterocyclic ring” is preferably a heterocyclic ring containing, as a ring-constituting atom, 1 to 5 heteroatoms selected from oxygen, sulfur, and nitrogen in addition to carbon.

Specific examples of the aromatic heterocyclic ring preferably include a pyrrole ring, an oxazole ring, a thiazole ring, an isothiazole ring, an imidazole ring, a thiadiazole ring, a triazole ring, a pyrazole ring, a pyridine ring, a pyrimidine ring, a pyrazine ring, a triazine ring, an indole ring, an isoindole ring, a benzimidazole ring, a benzoxazole ring, a benzothiazole ring, a quinoline ring, an isoquinoline ring, a quinazoline ring, a quinoxaline ring, a naphthyridine ring, a carbazole ring, an acridine ring, a phenoxazine ring, a phenothiazine ring, a furan ring, a benzofuran ring, a dibenzofuran ring, a thiophene ring, a benzothiophene ring, and a dibenzothiophene ring.

### (Substituent Group α)

The substituent group α is a substituted or unsubstituted aromatic hydrocarbon group, a substituted or unsubstituted aromatic heterocyclic group, a substituted or unsubstituted diarylamino group, a substituted or unsubstituted diheteroarylamino group, a substituted or unsubstituted arylheteroarylamino group (an amino group having an aromatic hydrocarbon group and an aromatic heterocyclic group), a substituted or unsubstituted alkyl group, a substituted or unsubstituted alkoxy group, a substituted or unsubstituted aryloxy group, or a halogen atom.

The substituent which the group selected from the substituent group α other than a halogen atom may have is selected from the following substituent group β.

Examples of the aromatic hydrocarbon group or aryl structure in the substituent group α include a group of an aromatic hydrocarbon ring in ring a, ring b, and ring c. A specific structure and a preferred structure of the aromatic hydrocarbon ring are the same as those of the aromatic hydrocarbon ring in ring a, ring b, and ring c in the formula (1). The aromatic hydrocarbon group in the substituent group α is preferably a benzene ring.

Examples of the aromatic heterocyclic group or heteroaryl structure in the substituent group α include a group of an aromatic heterocyclic ring in ring a, ring b, and ring c. A specific structure of the aromatic heterocyclic ring is the same as that of the aromatic heterocyclic ring in ring a, ring b, and ring c in the formula (1). The aromatic heterocyclic group in the substituent group α is preferably a triazine ring, a benzimidazole ring, a benzothiazole ring, a pyrimido[5,4-d]pyrimidine ring, or a benzo[1,2-d:4,5-d]diimidazole ring.

The alkyl group in the substituent group α may be either linear or branched, and examples thereof include a linear alkyl group having 1 to 24 carbon atoms and a branched alkyl group having 3 to 24 carbon atoms. An alkyl group having 1 to 18 carbon atoms (a branched alkyl group having 3 to 18 carbon atoms) is preferred, an alkyl group having 1 to 12 carbon atoms (a branched alkyl group having 3 to 12 carbon atoms) is more preferred, an alkyl group having 1 to 6 carbon atoms (a branched alkyl group having 3 to 6 carbon atoms) is still more preferred, and an alkyl group having 1 to 4 carbon atoms (a branched alkyl group having 3 to 4 carbon atoms) is particularly preferred.

Specific examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a tert-pentyl group, an n-hexyl group, a 1-methyl-pentyl group, a 4-methyl-2-pentyl group, a 3.3-dimethylbutyl group, a 2-ethylbutyl group, an n-heptyl group, a 1-methyl-hexyl group, an n-octyl group, and a tert-octyl group.

Some of hydrogen atoms of the alkyl group in the substituent group α may be substituted with fluorine atoms.

Examples of the alkoxy group in the substituent group α include a linear alkoxy group having 1 to 24 carbon atoms or a branched alkoxy group having 3 to 24 carbon atoms. An alkoxy group having 1 to 18 carbon atoms (a branched alkoxy group having 3 to 18 carbon atoms) is preferred, an alkoxy group having 1 to 12 carbon atoms (a branched alkoxy group having 3 to 12 carbon atoms) is more preferred, an alkoxy group having 1 to 6 carbon atoms (a branched alkoxy group having 3 to 6 carbon atoms) is still more preferred, and an alkoxy group having 1 to 4 carbon atoms (a branched alkoxy group having 3 to 4 carbon atoms) is particularly preferred.

Specific examples of the alkoxy group include a methoxy group, an ethoxy group, a proxy group, an isopropoxy group, a butoxy group, an isobutoxy group, a sec-butoxy group, a tert-butoxy group, a pentyloxy group, a hexyloxy group, a heptyloxy group, and an octyloxy group.

Examples of the halogen atom in the substituent group α include a fluorine atom, a chlorine atom, and a bromine atom. A fluorine atom and a chlorine atom are preferred, and among them, a fluorine atom is more preferred.

### (Substituent Group β)

The substituent group β is an aromatic hydrocarbon group which may be substituted with an aralkyl group, an aromatic heterocyclic group which may be substituted with an aralkyl group, an alkyl group, or a halogen atom. Examples of the aromatic hydrocarbon group, aromatic heterocyclic group, alkyl group, aralkyl group, and halogen atom in the substituent group β include those same as those in the substituent group α, and preferred structures thereof are also the same as those in the substituent group α.

The substituent group β is preferably an alkyl group, or an aralkyl group, an aromatic hydrocarbon group which may be substituted with an aralkyl group, an aromatic heterocyclic group which may be substituted with an aralkyl group, from the viewpoint of improving stability and solubility.

In the substituent group β, the aralkyl group, the aralkyl group which may substitute an aromatic hydrocarbon group, and the aralkyl group which may substitute an aromatic heterocyclic group are preferably an aralkyl group having 7 to 30 carbon atoms, and preferably have a structure in which a benzene ring is bonded to an alkyl group.

The halogen atom in the substituent group β is preferably a fluorine atom.

### (Y)

Y's in the formula (1) each independently represent O, N—R, or S.

### (R)

R represents an aromatic hydrocarbon ring group which may have a substituent, an aromatic heterocyclic group which may have a substituent, or an alkyl group.

Two Y's in the formula (1) may be the same as or different from each other, and are preferably the same. The two Y's are preferably N—R.

When R in the formula (1) is an aromatic hydrocarbon ring group which may have a substituent or an aromatic heterocyclic group which may have a substituent, R is a group same as the aromatic hydrocarbon ring group which may have a substituent or the aromatic heterocyclic group which may have a substituent in ring a, ring b, and ring c in the formula (1). A specific structure and a preferred structure thereof are also the same as those of the aromatic hydrocarbon ring group which may have a substituent or the aromatic heterocyclic group which may have a substituent in ring a, ring b, and ring c in the formula (1). When R in the formula (1) is an aromatic hydrocarbon ring group which may have a substituent or an aromatic heterocyclic group which may have a substituent, the formula (1) is represented by the following formula (21).

The polycyclic heterocyclic compound represented by the formula (1) is preferably represented by the following formula (21).

Examples of the alkyl group in R in the formula (1) include an alkyl group in the substituent group α. As the alkyl group, an alkyl group having 1 to 4 carbon atoms (for example, a methyl group or an ethyl group) is particularly preferred.

R may be bonded to a carbon atom adjacent to an atom bonded to the Y in at least one ring selected from the group consisting of the ring a, the ring b, and the ring c by —O—, —S—, —C(—R^{a})₂, or a single bond.

R^{a}'s each independently represent a hydrogen atom or an alkyl group.

Examples of the alkyl group in R^{a} include an alkyl group in the substituent group α. As the alkyl group, an alkyl group having 1 to 4 carbon atoms is particularly preferred, such as a methyl group or an ethyl group.

The adjacent carbon atom is not a carbon atom constituting the central fused bicyclic structure of the formula (1) containing B and the Y.

At least one hydrogen atom in the polycyclic heterocyclic compound represented by the formula (1) may be substituted with a halogen atom or deuterium.

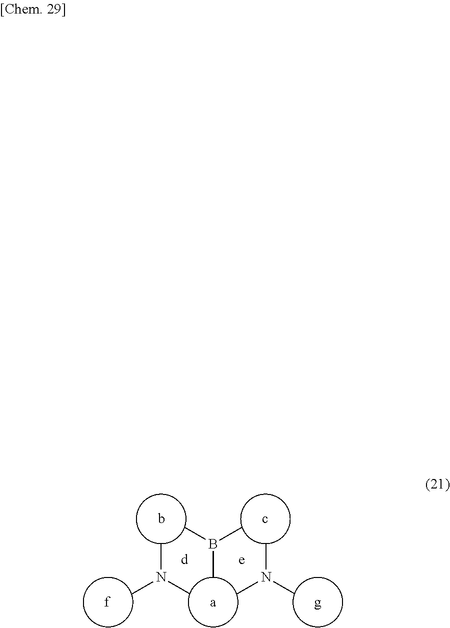

(In the formula (21),
ring a, ring b, and ring c are the same as those defined in the formula (1),
ring d is a ring constituted by B, N, and some of atoms constituting ring a and ring b, and ring e is a ring constituted by B, N, and some of atoms constituting ring a and ring c,
ring f and ring g each independently represent an aromatic hydrocarbon ring which may have a substituent or an aromatic heterocyclic ring which may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group,
the adjacent carbon atom is not a carbon atom constituting ring d and ring e each containing B and N, and
at least one hydrogen atom in the polycyclic heterocyclic compound represented by the formula (21) may be substituted with a halogen atom or deuterium.)

The aromatic hydrocarbon ring group and the aromatic heterocyclic group in ring f and ring g can be selected from the same ranges as the aromatic hydrocarbon ring group and the aromatic heterocyclic group in ring a, ring b, and ring c.

As the aromatic hydrocarbon ring group and aromatic heterocyclic group in ring f and ring g, an aromatic hydrocarbon ring group having 6 to 10 carbon atoms (for example, a phenyl group and a naphthyl group) and an aromatic heterocyclic group having 2 to 15 carbon atoms (for example, a carbazolyl group) are particularly preferred.

The substituents which ring f and ring g, which are an aromatic hydrocarbon ring or an aromatic heterocyclic ring, may have are the same as that of ring a, ring b, and ring c, and are preferably a group selected from the substituent group α.

### (Formula (22))

The formula (21) is preferably a structure represented by the following formula (22). That is, the polycyclic heterocyclic compound represented by the formula (1) is preferably represented by the following formula (22).

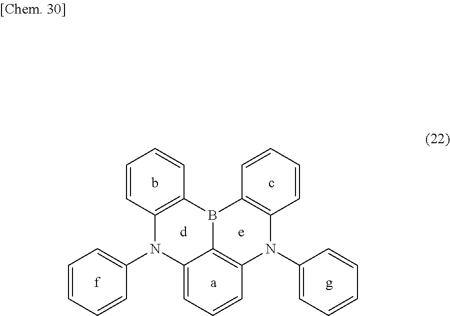 [SMILES: c1ccc(N2c3ccccc3B3c4ccccc4N(c4ccccc4)c4cccc2c43)cc1]

(In the formula (22),
ring a, ring b, ring c, ring f, and ring g in the formula (21) are all benzene ring structures,
ring d is a ring constituted by B, N, and some of atoms constituting ring a and ring b, and ring e is a ring constituted by B, N, and some of atoms constituting ring a and ring c,
ring a, ring b, ring c, ring f, and ring g may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group, and
at least one hydrogen atom in the polycyclic heterocyclic compound represented by the formula (22) may be substituted with a halogen atom or deuterium.

The substituents which ring a, ring b, ring c, ring f, and ring g may have are the same as the substituents which ring a, ring b, ring c, ring f, and ring g in the formula (21) may have, and a specific structure and a preferred structure thereof are also the same.

An aromatic compound represented by the formula (22) is preferably a polycyclic heterocyclic compound represented by the following formula (71).

An aromatic compound represented by the formula (1) is preferably a polycyclic heterocyclic compound represented by the following formula (71).

### (Specific Examples of Polycyclic Heterocyclic Compound Represented by Formula (1))

A structure of the polycyclic heterocyclic compound represented by the formula (1) is not particularly limited, and examples thereof include the following structures.

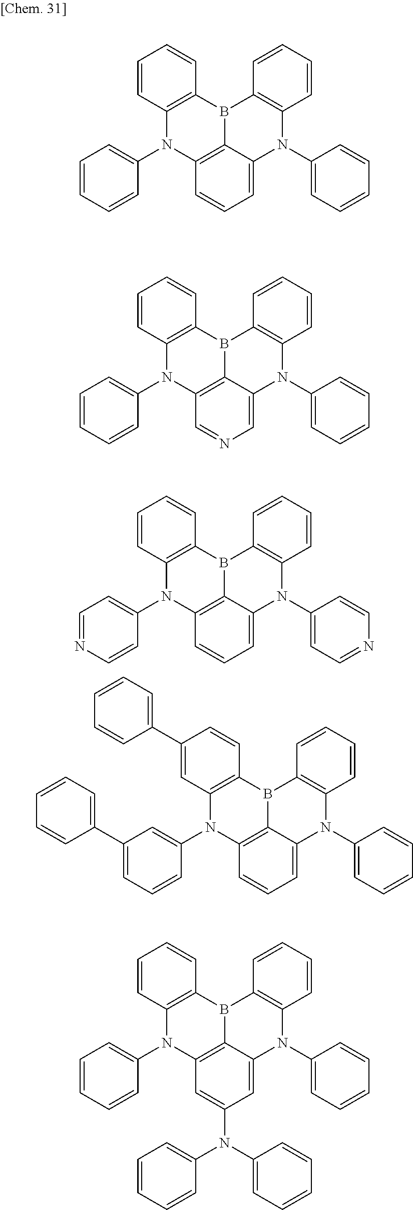

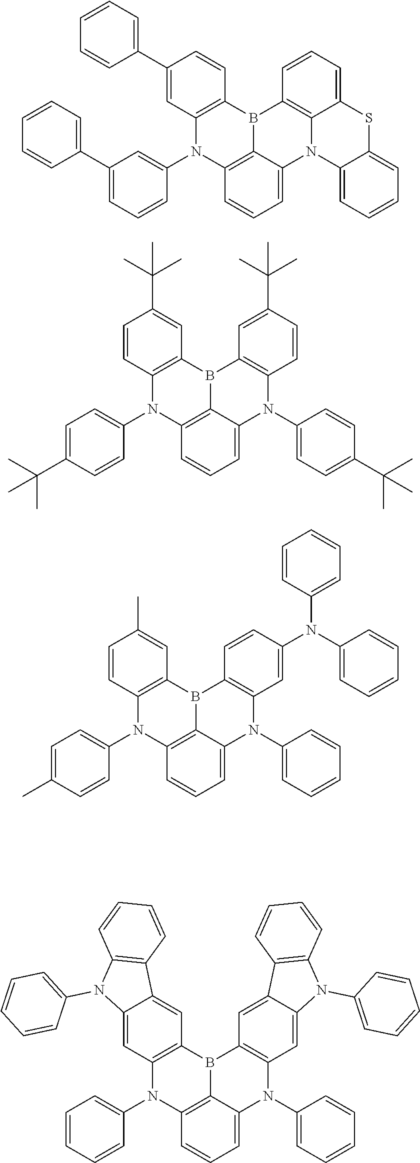

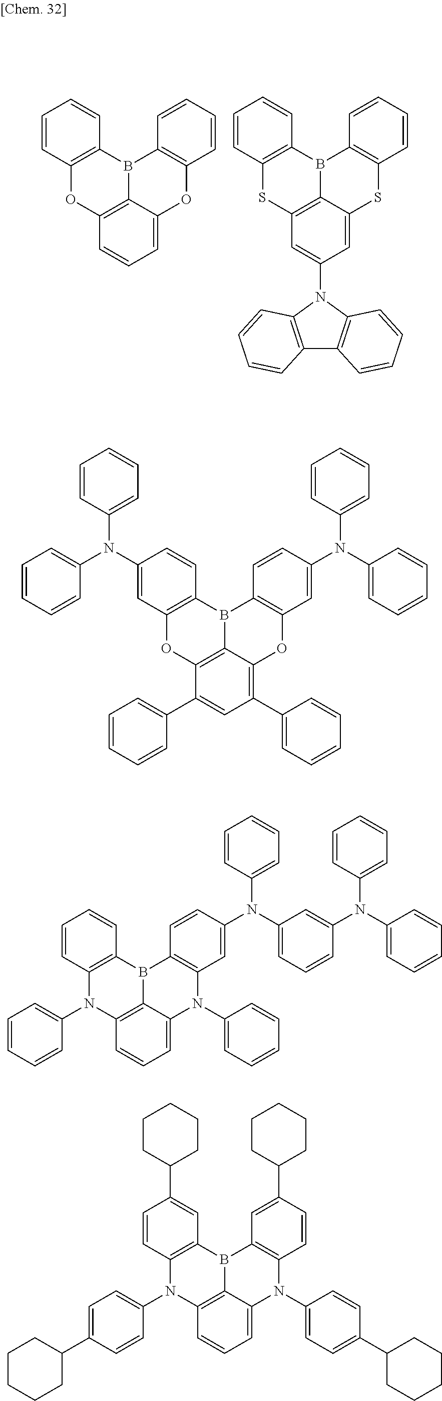

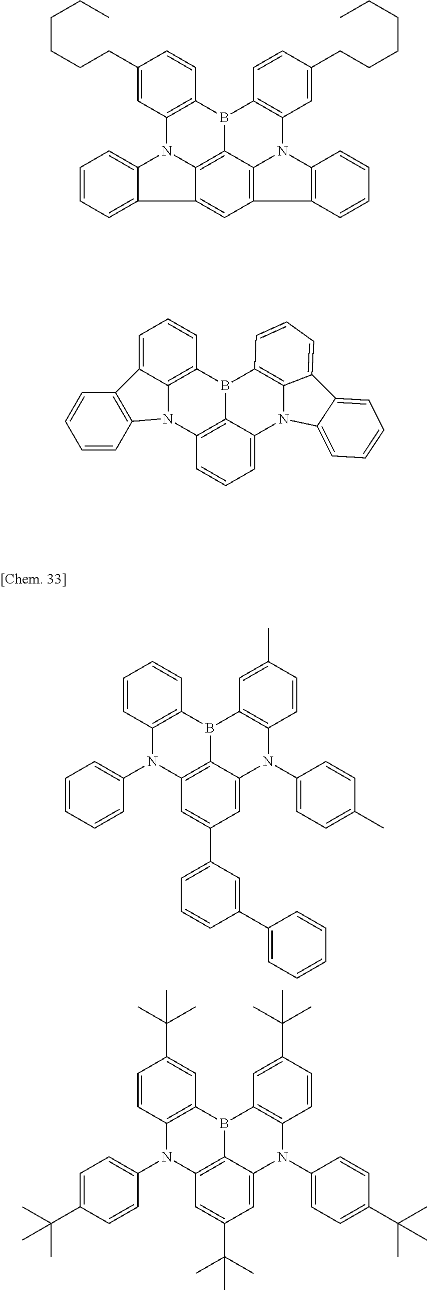

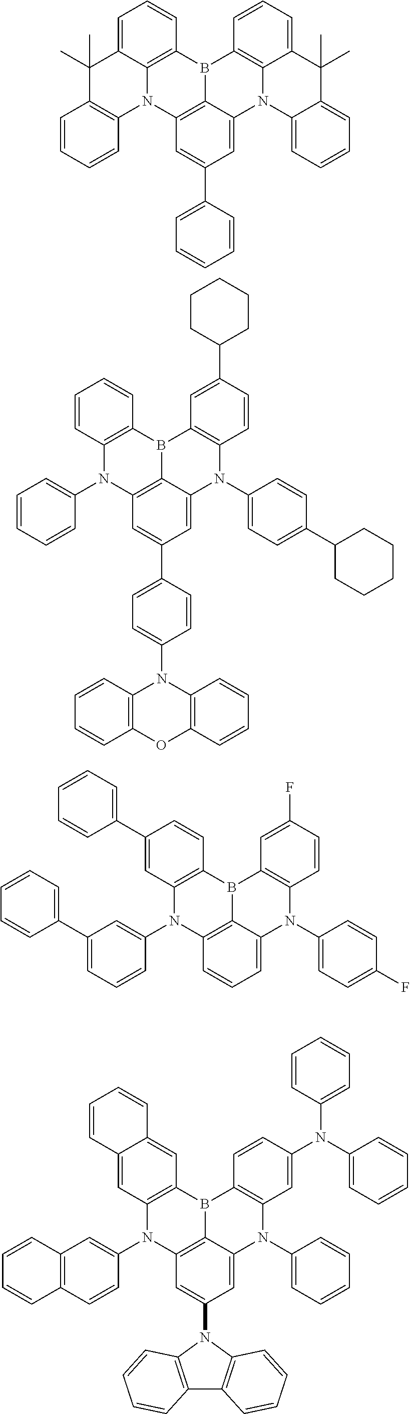

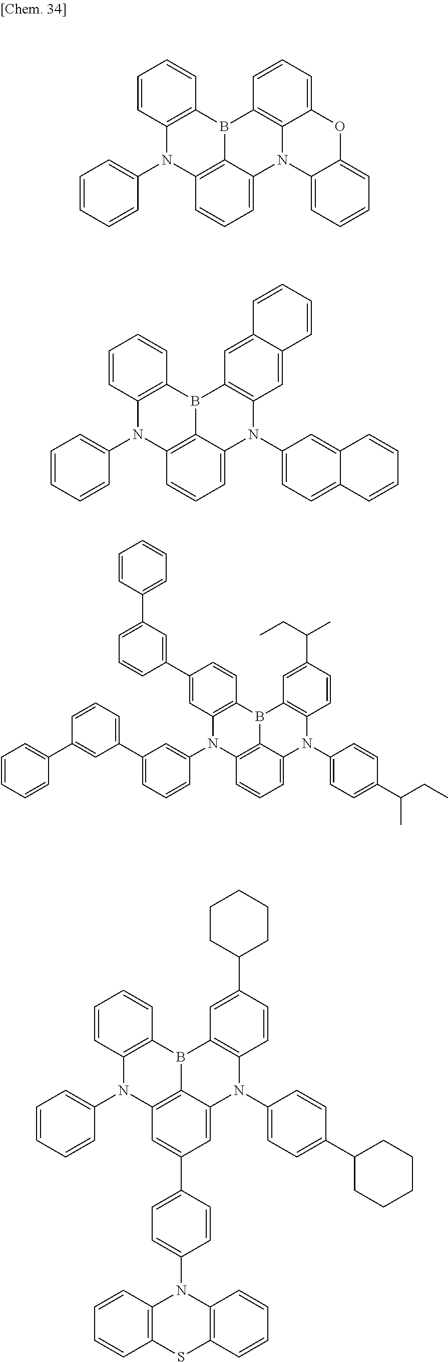 [SMILES: c1ccc(N2c3ccccc3B3c4cccc5c4N(c4ccccc4O5)c4cccc2c43)cc1 ; c1ccc(N2c3ccccc3B3c4cc5ccccc5cc4N(c4ccc5ccccc5c4)c4cccc2c43)cc1 ; CCC(C)c1ccc(N2c3ccc(C(C)CC)cc3B3c4ccc(-c5cccc(-c6ccccc6)c5)cc4N(c4cccc(-c5cccc(-c6ccccc6)c5)c4)c4cccc2c43)cc1 ; c1ccc(N2c3ccccc3B3c4cc(C5CCCCC5)ccc4N(c4ccc(C5CCCCC5)cc4)c4cc(-c5ccc(N6c7ccccc7Sc7ccccc76)cc5)cc2c43)cc1]

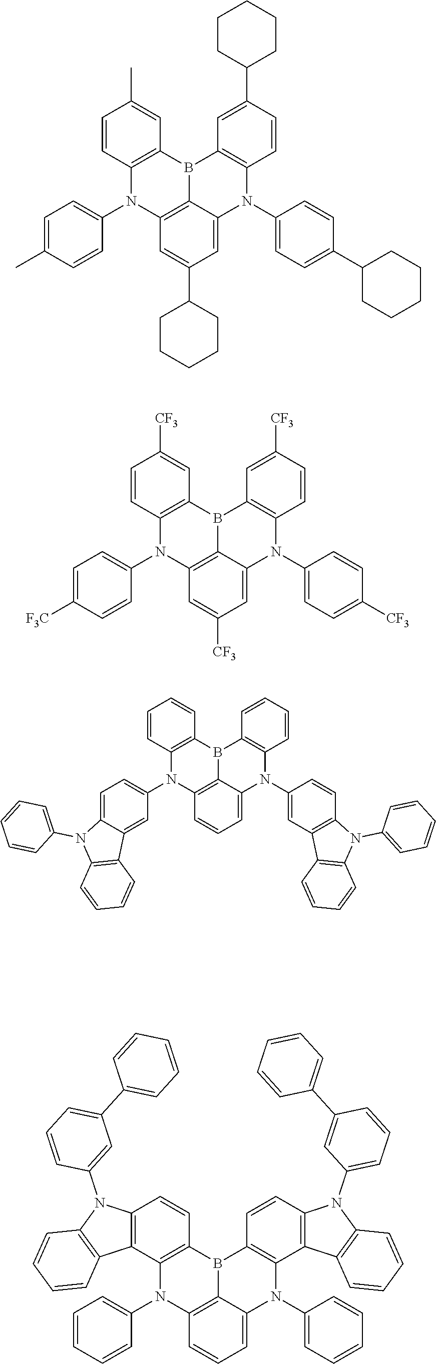 [SMILES: Cc1ccc(N2c3ccc(C)cc3B3c4cc(C5CCCCC5)ccc4N(c4ccc(C5CCCCC5)cc4)c4cc(C5CCCCC5)cc2c43)cc1 ; FC(F)(F)c1ccc(N2c3ccc(C(F)(F)F)cc3B3c4cc(C(F)(F)F)ccc4N(c4ccc(C(F)(F)F)cc4)c4cc(C(F)(F)F)cc2c43)cc1 ; c1ccc(-n2c3ccccc3c3cc(N4c5ccccc5B5c6ccccc6N(c6ccc7c(c6)c6ccccc6n7-c6ccccc6)c6cccc4c65)ccc32)cc1 ; c1ccc(-c2cccc(-n3c4ccccc4c4c5c(ccc43)B3c4ccc6c(c4N(c4ccccc4)c4cccc(c43)N5c3ccccc3)c3ccccc3n6-c3cccc(-c4ccccc4)c3)c2)cc1]

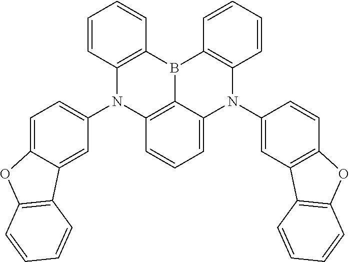 [SMILES: c1ccc2c(c1)B1c3ccccc3N(c3ccc4oc5ccccc5c4c3)c3cccc(c31)N2c1ccc2oc3ccccc3c2c1]

### <Polycyclic Heterocyclic Compound TD1>

The polycyclic heterocyclic compound represented by the formula (1) is preferably a polycyclic heterocyclic compound represented by the following formula (71). In the present invention, the polycyclic heterocyclic compound represented by the following formula (71) may be referred to as a polycyclic heterocyclic compound TD1.

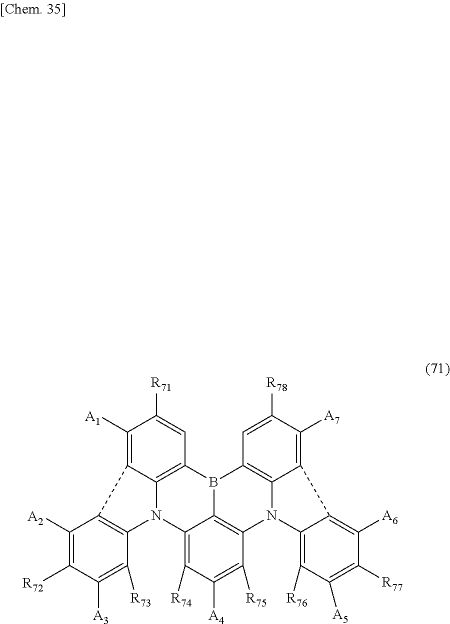

(In the formula (71),
A₁ to A₇ each independently represent a hydrogen atom; a fluorine atom; an alkyl group which may have a substituent; an electron-accepting heteroaryl group; a nitro group; a cyano group; or an aromatic hydrocarbon group or aromatic heterocyclic group which has an electron-accepting heteroaryl group, a nitro group, or a cyano group as a substituent,
R₇₁ to R₇₈ each independently represent a hydrogen atom, an alkyl group which may have a substituent, an aromatic hydrocarbon group which may have a substituent, an aromatic heterocyclic group which may have a substituent, an electron-donating substituent, or a combination thereof,
at least one hydrogen atom in the polycyclic heterocyclic compound represented by the formula (71) may be substituted with a halogen atom or deuterium, and
a dotted line represents a single bond or no bond.)

In the polycyclic heterocyclic compound represented by the formula (71), an LUMO electron cloud is localized and gathered at positions where A₁ to A₇ are bonded to a phenyl group. Therefore, when at least one selected from A₁ to A₇ is an electron-accepting substituent to be described later, an electron cloud spreads, an energy level of LUMO is stabilized, and an energy difference between HOMO and LUMO is reduced. As a result, by using the polycyclic heterocyclic compound represented by the formula (71), a luminescence spectrum having a longer wavelength can be obtained.

In the polycyclic heterocyclic compound represented by the formula (71), a HOMO electron cloud is localized and gathered at R₇₁ to R₇₈. Therefore, when at least one selected from R₇₁ to R₇₈ is an electron-donating substituent to be described later, the HOMO electron cloud easily spreads outward, an energy level of the HOMO becomes unstable, and an energy difference between HOMO and LUMO is reduced. As a result, by using the polycyclic heterocyclic compound represented by the formula (71), a luminescence spectrum having a longer wavelength can be obtained.

In the present invention, in order to satisfy the expression (E-1), a luminescent wavelength of the luminescent compound is preferably a long wavelength. Therefore, in the polycyclic heterocyclic compound represented by the formula (71), it is preferable that at least one selected from A₁ to A₇ is an electron-accepting substituent, at least one selected from R₇₁ to R₇₈ is an electron-donating substituent, or at least one selected from A₁ to A₇ is an electron-accepting substituent and at least one selected from R₇₁ to R₇₈ is an electron-donating substituent, since a luminescence spectrum having a longer wavelength can be obtained, and it is more preferable that at least one selected from A₁ to A₇ is an electron-accepting substituent.

### (Substituent)

The polycyclic heterocyclic compound of the formula (71) will be described in detail below. In the following description, when the substituent is selected from a substituent group Z, any substituent included in the substituent group Z may be used as the substituent. Among the substituent group Z, an alkyl group, an alkoxy group, an aryloxy group, an aromatic hydrocarbon group, or an aralkyl group is preferred.

(A₁ to A₇)

A₁ to A₇ each independently represent a hydrogen atom; a fluorine atom; an alkyl group which may have a substituent; an electron-accepting heteroaryl group; a nitro group; a cyano group; or an aromatic hydrocarbon group or aromatic heterocyclic group having an electron-accepting heteroaryl group, a nitro group, or a cyano group as a substituent.

Preferably, at least one selected from A₁ to A₇ is an electron-accepting substituent, and A₁ to A₇ other than the electron-accepting substituent each independently represent a hydrogen atom, a fluorine atom, or an alkyl group which may have a substituent.

At least one selected from A₁ to A₇ is preferably an electron-accepting substituent, since the luminescent wavelength can be adjusted by the number and type of A₁ to A₇.

### (Electron-Accepting Substituent)

In the present invention, the electron-accepting substituent is a substituent with a chemical structure that tends to become electron-excessive by withdrawing electrons from an adjacent chemical structure through a chemical bond.

Examples of the electron-accepting substituent include a substituent such as an electron-accepting heteroaryl group, a nitro group, or a cyano group, and an aromatic hydrocarbon group or aromatic heterocyclic group having any of these substituents. Among them, an electron-accepting heteroaryl group is preferred from the viewpoint of longer wavelength.

The heteroaryl group is an aryl group having at least one atom selected from a nitrogen atom, an oxygen atom, and a sulfur atom. Examples of the heteroaryl group include a group having a polycyclic aromatic heteroaryl having 1 to 4 rings and containing a carbon atom, a nitrogen atom, an oxygen atom, or a sulfur atom.

The electron-accepting heteroaryl group is a heteroaryl group that is likely to become electron-excessive by withdrawing electrons from an adjacent chemical structure through a chemical bond, and is preferably a heteroaryl group having an “absolute value α” described below of 3 eV or more.

The electron-accepting substituent is preferably a group having an absolute value of 3 eV or more, the absolute value being obtained by summing the HOMO energy level and the LUMO energy level and dividing the sum by 2 (hereinafter, may be referred to as “absolute value α”). When the absolute value α is 3 eV or more, the electron accepting property of the substituent is empirically improved.

The absolute value α of the electron-accepting substituent is preferably 3.1 eV or more, more preferably 3.5 eV or more, and still more preferably 4.0 eV or more. An upper limit of the absolute value α of the electron-accepting substituent is not particularly limited, and is generally 7.0 eV or less.

The HOMO energy level and the LUMO energy level of the electron-accepting substituent refer to an energy level of a HOMO molecular orbital and an energy level of a LUMO molecular orbital obtained as follows. That is, a single bond between the electron-accepting substituent and an adjacent phenyl group in the formula (1) is deleted and a hydrogen atom is added. A molecular structure of the obtained electron-accepting substituent may then be subjected to a structural optimization calculation using density functionals in the molecular orbital calculation software Gaussian 16, with the functional: B3LYP and the basis function: 6-31G(d).

The electron-accepting substituents are each independently preferably a group represented by the following formula (71-5), a group represented by the following formula (71-6), a group represented by the following formula (71-7), or a group represented by the following formula (71-8).

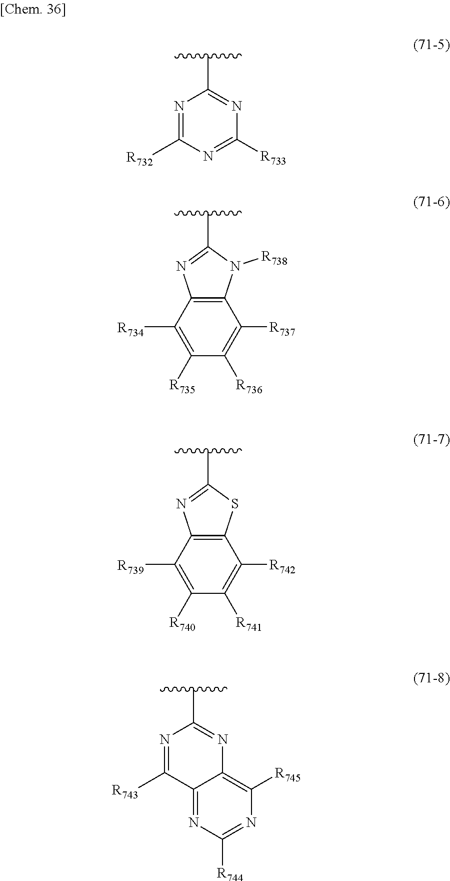

In the formulae (71-5) to (71-8),
R₇₃₂ to R₇₄₅ each independently represent a hydrogen atom, an alkyl group which may have a substituent, or an aromatic hydrocarbon group which may have a substituent.

Examples of the alkyl group include a linear, branched, or cyclic alkyl group having 1 or more and 24 or less carbon atoms, such as a methyl group, an ethyl group, an n-propyl group, an i-propyl group, an n-butyl group, an i-butyl group, a sec-butyl group, a tert-butyl group, an n-hexyl group, an n-octyl group, a cyclohexyl group, and a dodecyl group.

Examples of the aromatic hydrocarbon group include an aromatic hydrocarbon group having 6 or more and 60 or less carbon atoms. Specific examples thereof include a 6-membered monocyclic or 2- to 5-fused monovalent group, such as a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, and a fluorene ring.

The substituent which R₇₃₂ to R₇₄₅ may have can be selected from the substituent group Z to be described later.

Specific examples of the formulae (71-5) to (71-8) include the following formulae (71-2-1) to (71-2-7).

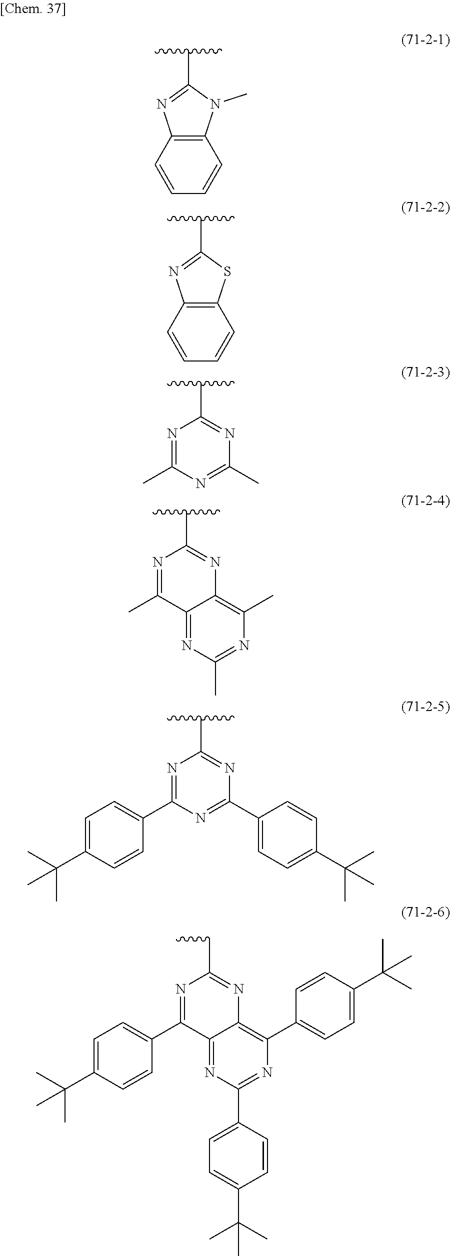

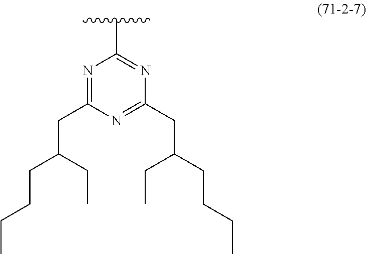 [SMILES: *c1nc(CC(CC)CCCC)nc(CC(CC)CCCC)n1]

In the formulae (71-2-1) to (71-2-7), the absolute value α obtained by calculation is as follows.
Group represented by formula (71-2-4): 4.35 eV
Group represented by formula (71-2-6): 4.18 eV
Group represented by formula (71-2-3): 4.17 eV
Group represented by formula (71-2-7): 4.12 eV
Group represented by formula (71-2-5): 4.10 eV
Group represented by formula (71-2-2): 3.73 eV
Group represented by formula (71-2-1): 3.13 eV

That is, when the same number of groups represented by the formula (71-2-4), groups represented by the formula (71-2-6), groups represented by the formula (71-2-3), groups represented by the formula (71-2-7), groups represented by the formula (71-2-5), groups represented by the formula (71-2-2), or groups represented by the formula (71-2-1) are introduced into the same positions of A₁ to A₇ in the formula (1), an effect of obtaining a longer luminescent wavelength can be obtained in the order of the formula (71-2-4)>the formula (71-2-6)>the formula (71-2-3)>the formula (71-2-7)>the formula (71-2-5)>the formula (71-2-2)>the formula (71-2-1).

Among them, the electron-accepting substituent is preferably a group represented by the formula (71-5) from the viewpoint of longer wavelength and ease of production by organic synthesis.

The group represented by the formula (71-5) has a relatively large absolute value α and has less steric hindrance with the adjacent phenyl group in the formula (71). Therefore, the adjacent phenyl group and the group represented by the formula (71-5) are less twisted in the π-plane, and the effect of obtaining a longer luminescent wavelength is obtained. The group represented by the formula (71-5) can be produced relatively easily by organic synthesis, and even when it is desired to improve solubility in a solvent, a long-chain alkyl group (for example, having 4 or more carbon atoms) can be relatively easily introduced into R₇₃₂ and R₇₃₃.

R₇₃₂ and R₇₃₃ each preferably represent an alkyl group which may have a substituent since a longer luminescent wavelength can be easily obtained by increasing the absolute value α, and also from the viewpoint of solubility in a solvent. It is more preferable that at least one selected from R₇₃₂ and R₇₃₃ is a phenyl group having a tert-butyl group.

From the viewpoint of solubility in a solvent and narrowing a half-value width of the luminescent wavelength, it is preferable that one selected from R₇₃₂ and R₇₃₃ is an alkyl group which may have a substituent, and the other one is an aromatic hydrocarbon group which may have a substituent. The substituent which the aromatic hydrocarbon group may have can be selected from the substituent group Z.

A₁ to A₇ other than the electron-accepting substituent each independently represent a hydrogen atom, a fluorine atom, or an alkyl group which may have a substituent.

Examples of the alkyl group include a linear, branched, or cyclic alkyl group having 1 or more and 24 or less carbon atoms, such as a methyl group, an ethyl group, an n-propyl group, an i-propyl group, an n-butyl group, an i-butyl group, a sec-butyl group, a tert-butyl group, an n-hexyl group, an n-octyl group, a cyclohexyl group, and a dodecyl group.

The substituent which A₁ to A₇ may have can be selected from the substituent group Z to be described later.

When A₁ to A₇ each independently represent a fluorine atom or an alkyl group which may have a substituent, the luminescent wavelength becomes slightly shorter or longer than when A₁ to A₇ each represent a hydrogen atom due to electron-accepting properties thereof. Therefore, it is preferable to select the substituent according to a desired wavelength.

When a wet-process film formation method is used, A₁ to A₇ preferably each independently represent a long-chain alkyl group for the purpose of improving solubility in a solvent.

Among A₁ to A₇, a degree of localization of the LUMO electron cloud is not uniform, and varies depending on the position. Therefore, among A₁ to A₇, the positions where the effect of obtaining a longer wavelength by the electron-accepting substituent is strongly obtained are in the order of A₄>A₁=A₇>A₃=A₅>A₂=A₆.

That is, in A₄, the effect of obtaining a longer wavelength by the electron-accepting substituent appears most strongly.

Therefore, at least one selected from A₁, A₄, and A₇ is preferably an electron-accepting substituent, and more preferably a group represented by the formula (71-5).

When both A₁ and A₇ represent an electron-accepting substituent, the effect of obtaining a longer wavelength is approximately the same as when only A₄ is the same electron-accepting substituent.

It is preferable that two or more selected from A₁ to A₇ represent an electron-accepting substituent since the wavelength becomes further longer, and it is preferable that two or more selected from A₁ to A₇ represent an electron-accepting substituent and A₄ represent an electron-accepting substituent since the wavelength becomes more further longer.

In the formula (71), it is preferable that single bonds each connecting A₁ to A₇ to adjacent phenyl groups are twisted and the π plane of the adjacent phenyl group and the main aromatic hydrocarbon group of the electron-accepting substituent is not twisted. This is because exchange of charges between the adjacent phenyl group and the electron-accepting substituent is difficult to smoothly occur due to the twist, and the luminescent wavelength of the formula (71) is difficult to become longer.

(R₇₁ to R₇₈)

R₇₁ to R₇₈ each independently represent a hydrogen atom, an alkyl group which may have a substituent, an aromatic hydrocarbon group which may have a substituent, an aromatic heterocyclic group which may have a substituent, an electron-donating substituent, or a combination thereof.

Examples of the alkyl group include a linear, branched, or cyclic alkyl group having 1 or more and 24 or less carbon atoms, such as a methyl group, an ethyl group, an n-propyl group, an i-propyl group, an n-butyl group, an i-butyl group, a sec-butyl group, a tert-butyl group, an n-hexyl group, an n-octyl group, a cyclohexyl group, and a dodecyl group.

Examples of the aromatic hydrocarbon group include an aromatic hydrocarbon group having 6 or more and 60 or less carbon atoms. Specific examples thereof include a 6-membered monocyclic or 2- to 5-fused monovalent group, such as a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, and a fluorene ring.

The aromatic heterocyclic group is preferably an aromatic heterocyclic group having 3 or more and 60 or less carbon atoms. Specific examples thereof include a 5- or 6-membered monocyclic or 2- to 4-fused monovalent group, such as a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a benzimidazole ring, a perimidine ring, a quinazoline ring, a quinazolinone ring, or an azulene ring.

The substituent which R₇₁ to R₇₈ may have can be selected from the substituent group Z to be described later.

At least one selected from R₇₁ to R₇₈ is preferably an electron-donating substituent from the viewpoint of longer wavelength.

### (Electron-Donating Substituent)

In the present invention, the electron-donating substituent is a substituent with a chemical structure that tends to become electron-deficient by donating electrons from an adjacent chemical structure through a chemical bond.

In the polycyclic heterocyclic compound represented by the formula (71), a HOMO electron cloud is localized and gathered at R₇₁ to R₇₈. Therefore, when at least one selected from R₇₁ to R₇₈ is an electron-donating substituent, the HOMO electron cloud easily spreads outward, an energy level of the HOMO becomes unstable, and an energy difference between HOMO and LUMO is reduced. As a result, using the polycyclic heterocyclic compound represented by the formula (71), a luminescence spectrum having a longer wavelength can be obtained.

The electron-donating substituent is preferably a group having an absolute value α of less than 3 eV When the absolute value α is less than 3 eV, the electron donor property of the substituent is empirically improved.

The absolute value α of the electron-donating substituent is more preferably less than 2.97 eV, still more preferably less than 2.8 eV, and particularly preferably less than 2.6 eV, from the viewpoint of longer wavelength. A lower limit of the absolute value α of the electron-donating substituent is not particularly limited, and is generally 1 eV or more.

The HOMO energy level and the LUMO energy level of the electron-donating substituent refer to an energy level of a HOMO molecular orbital and an energy level of an LUMO molecular orbital obtained as follows. That is, a single bond between the electron-donating substituent and the adjacent phenyl group in the formula (1) is deleted and a hydrogen atom is added. A molecular structure of the obtained electron-donating substituent may then be subjected to a structural optimization calculation using density functionals in the molecular orbital calculation software Gaussian 16, with the functional: B3LYP and the basis function: 6-31G(d).

The electron-donating substituents preferably each independently represent a group represented by the following formula (71-2), a group represented by the following formula (71-3), or a group represented by the following formula (71-4).

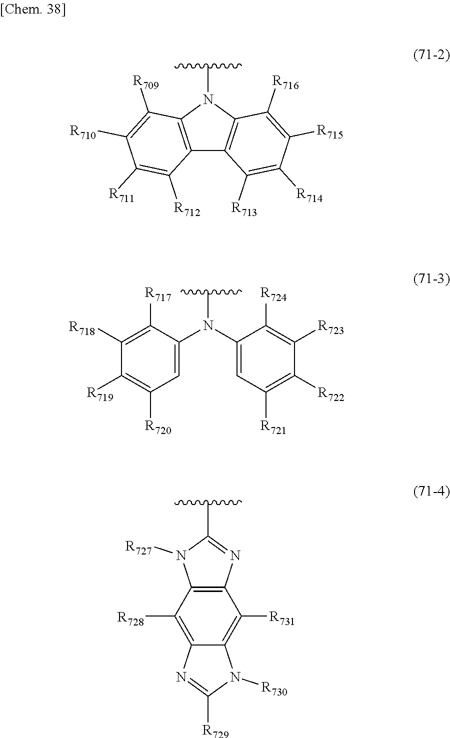

In the formulae (71-2) to (71-4),
R₇₀₉ to R₇₂₄ and R₇₂₇ to R₇₃₁ each independently represent an alkyl group which may have a substituent, an aromatic hydrocarbon group which may have a substituent, or a hydrogen atom.

Examples of the alkyl group include a linear, branched, or cyclic alkyl group having 1 or more and 24 or less carbon atoms, such as a methyl group, an ethyl group, an n-propyl group, an i-propyl group, an n-butyl group, an i-butyl group, a sec-butyl group, a tert-butyl group, an n-hexyl group, an n-octyl group, a cyclohexyl group, and a dodecyl group.

Examples of the aromatic hydrocarbon group include an aromatic hydrocarbon group having 6 or more and 60 or less carbon atoms. Specific examples thereof include a 6-membered monocyclic or 2- to 5-fused monovalent group, such as a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, and a fluorene ring.

The substituent which R₇₀₉ to R₇₂₄ and R₇₂₇ to R₇₃₁ may have can be selected from the substituent group Z to be described later.

Specific examples of the formulae (71-2) to (71-4) include the following formulae (71-4-1) to (71-4-3).

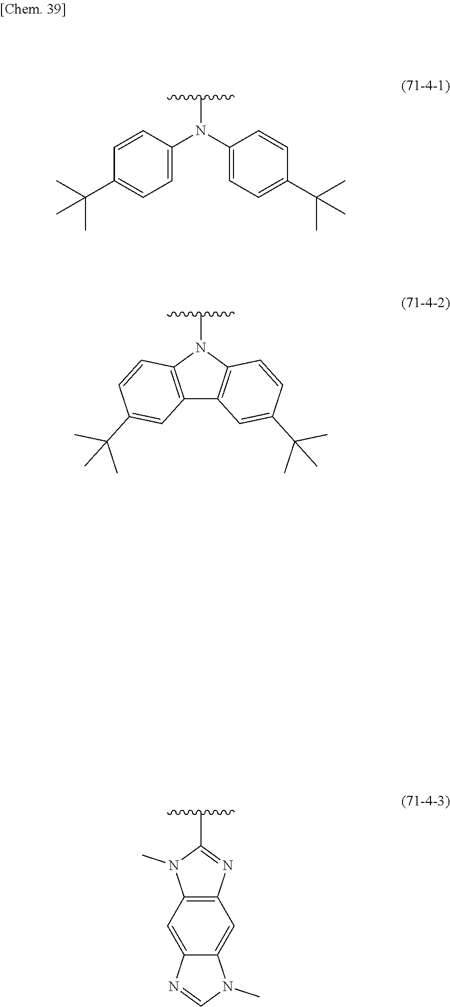

In the formulae (71-4-1) to (71-4-3), the absolute value α obtained by calculation is as follows.
Group represented by formula (71-4-3): 2.96 eV
Group represented by formula (71-4-2): 2.91 eV
Group represented by formula (71-4-1): 2.46 eV

That is, when the same number of groups represented by the formula (71-4-3), groups represented by the formula (71-4-2), or groups represented by the formula (71-4-1) are introduced into the same positions of R₇₁ to R₇₈ in the formula (71), the effect of obtaining a longer luminescent wavelength is obtained in the order of the formula (71-4-1)>the formula (71-4-2)>the formula (71-4-3).

It is preferable that two or more selected from R₇₁ to R₇₈ represent an electron-donating substituent since the wavelength becomes further longer.

Among them, the electron-donating substituent preferably represents a group represented by the formula (71-2), from the viewpoint of a balance between longer wavelength, ease of production by organic synthesis, and structural stability.

The absolute value α of the group represented by the formula (71-2) is relatively small, and the effect of obtaining a longer luminescent wavelength is obtained. The group represented by the above formula (71-2) can be produced relatively easily by organic synthesis, and even when it is desired to improve solubility in a solvent, a long-chain alkyl group can be introduced relatively easily into R₇₀₉ to R₇₁₆.

At least one selected from R₇₀₉ to R₇₁₆ preferably represents a tert-butyl group from the viewpoint of solubility in a solvent and ease of synthesis.

When R₇₁ to R₇₈ each independently represent an alkyl group which may have a substituent, an aromatic hydrocarbon group which may have a substituent, an aromatic heterocyclic group which may have a substituent, or a combination thereof, the luminescent wavelength becomes slightly shorter or longer than when R₇₁ to R₇₈ represent a hydrogen atom due to electron accepting properties thereof. Therefore, it is preferable to select the substituent in accordance with a desired wavelength.

When a wet-process film formation method is used, it is preferable that R₇₁ to R₇₈ each independently represent a long-chain alkyl group for the purpose of improving solubility in a solvent.

Among R₇₁ to R₇₈, a degree of localization of the HOMO electron cloud is not uniform, and varies depending on the position. Therefore, among R₇₁ to R₇₈, the positions where the effect of obtaining a longer wavelength by the electron donor substituent is strongly obtained are in the order of R₇₄=R₇₅>R₇₁=R₇₈>R₇₃=R₇₆>R₇₂=R₇₇. That is, in R₇₄ and R₇₅, the effect of making the wavelength longer by the electron donor substituent appears most strongly.

### (Dotted Line)

In the formula (71), the dotted line may represent a single bond or no bond.

The dotted line preferably represents a single bond. When the dotted line represents a single bond, the electron cloud spreads and the luminescent wavelength becomes slightly longer. When the dotted line represents a single bond, it is easy to introduce an electron-accepting substituent in A₁ to A₇ and an electron-donating substituent in R₇₁ to Res.

### (Symmetry of Polycyclic Heterocyclic Compound)

The polycyclic heterocyclic compound of the formula (71) is preferably asymmetric since it has an effect of narrowing a half width of the luminescent wavelength. It is considered that, due to reduced symmetry in an asymmetric type, the polycyclic heterocyclic compounds are less likely to be associated with each other, and the interaction between the polycyclic heterocyclic compounds is reduced, so that the half width of the luminescence spectrum is narrowed.

The polycyclic heterocyclic compound being asymmetric means that when a line connecting B and a bond axis of A₄ in the formula (71) is taken as a rotation axis, the compound does not have the same structure when rotated 1800 about the rotation axis, or that the compound does not have mirror symmetry with respect to a plane perpendicular to a plane formed by the polycyclic heterocyclic ring of the compound of the formula (71) including the bond axis.

Specifically, a structure that satisfies at least one of the following (i) or (ii) is preferred.
(i) A structure in which A₁ to A₇ and R₇₁ to R₇₈ do not have the same structure when rotated by 180° with respect to the bond axis.
(ii) A structure in which A₁ and A₇ are different, A₂ and A₆ are different, A₃ and A₅ are different, R₇₁ and R₇₈ are different, R₇₂ and R₇₇ are different, R₇₃ and R₇₆ are different, and R₇₄ and R₇₅ are different.

### (Specific Examples of Polycyclic Heterocyclic Compound TD1)

A structure of the polycyclic heterocyclic compound TD1 represented by the formula (71) is not particularly limited, and examples thereof include the following structures.

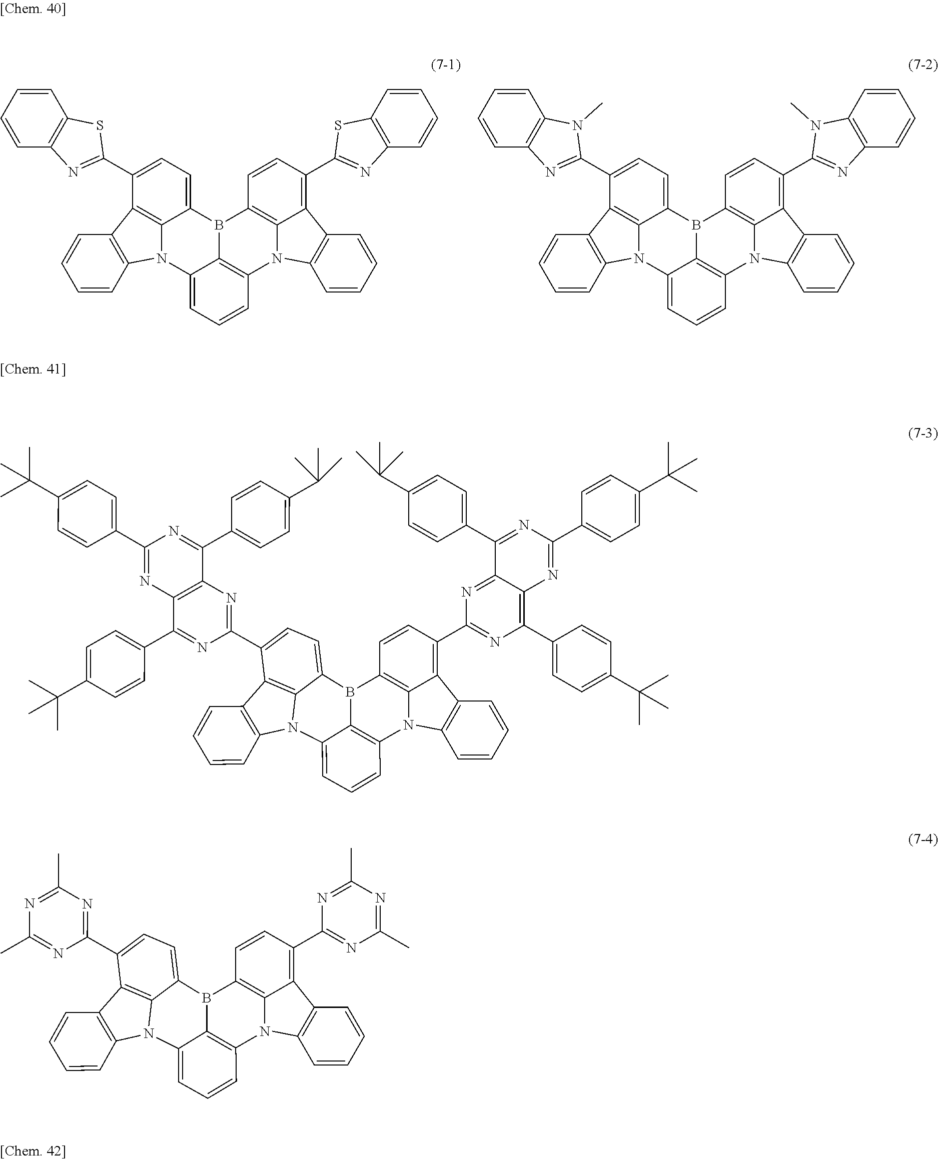

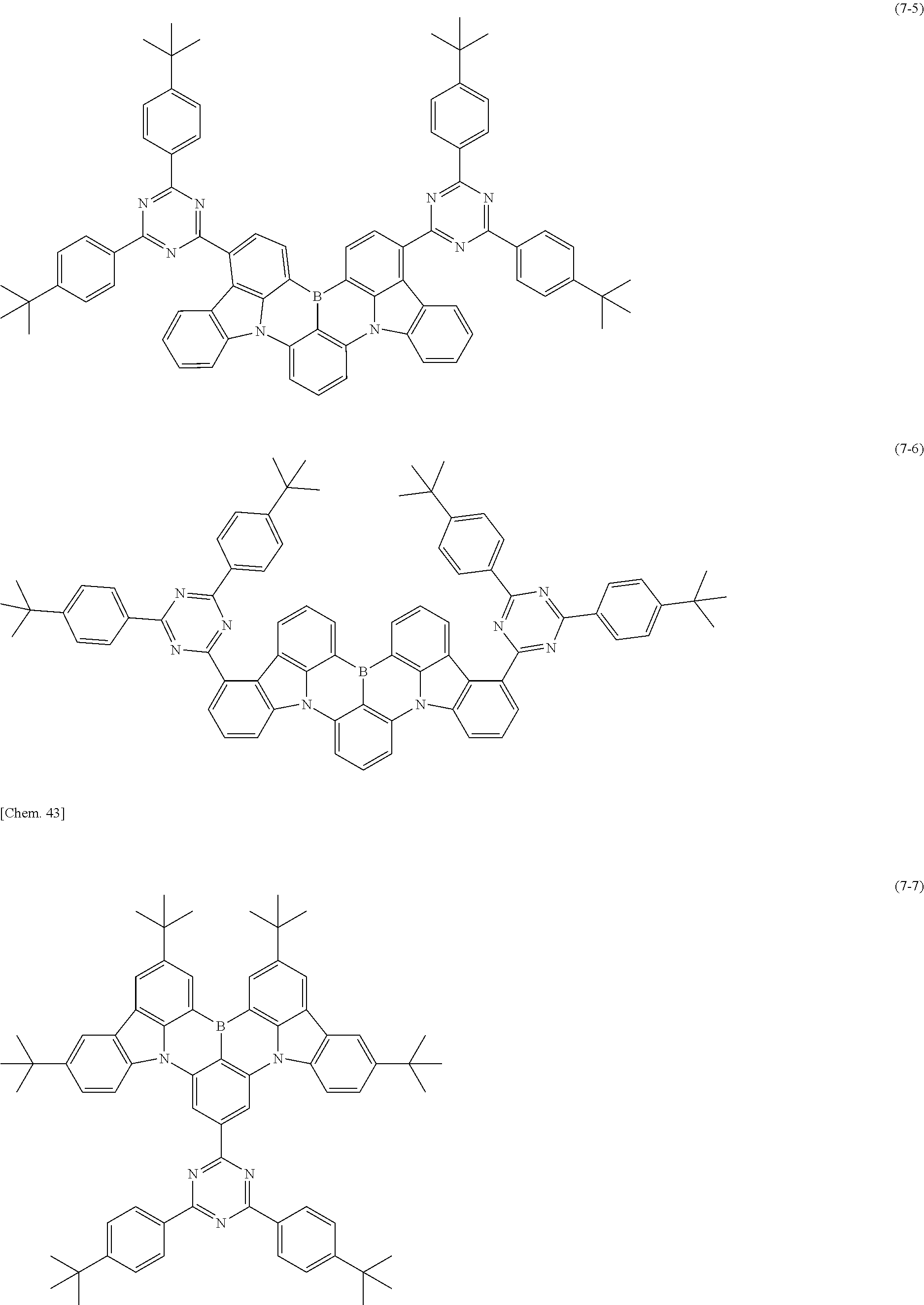

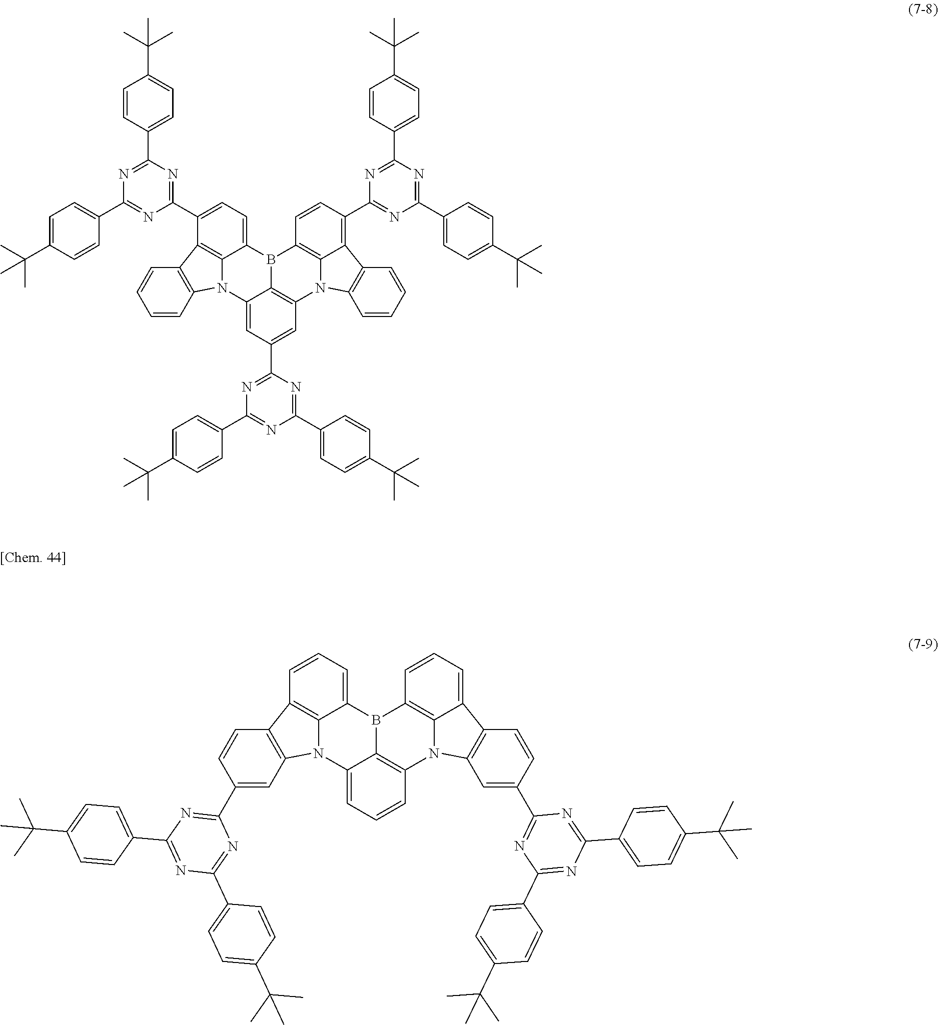

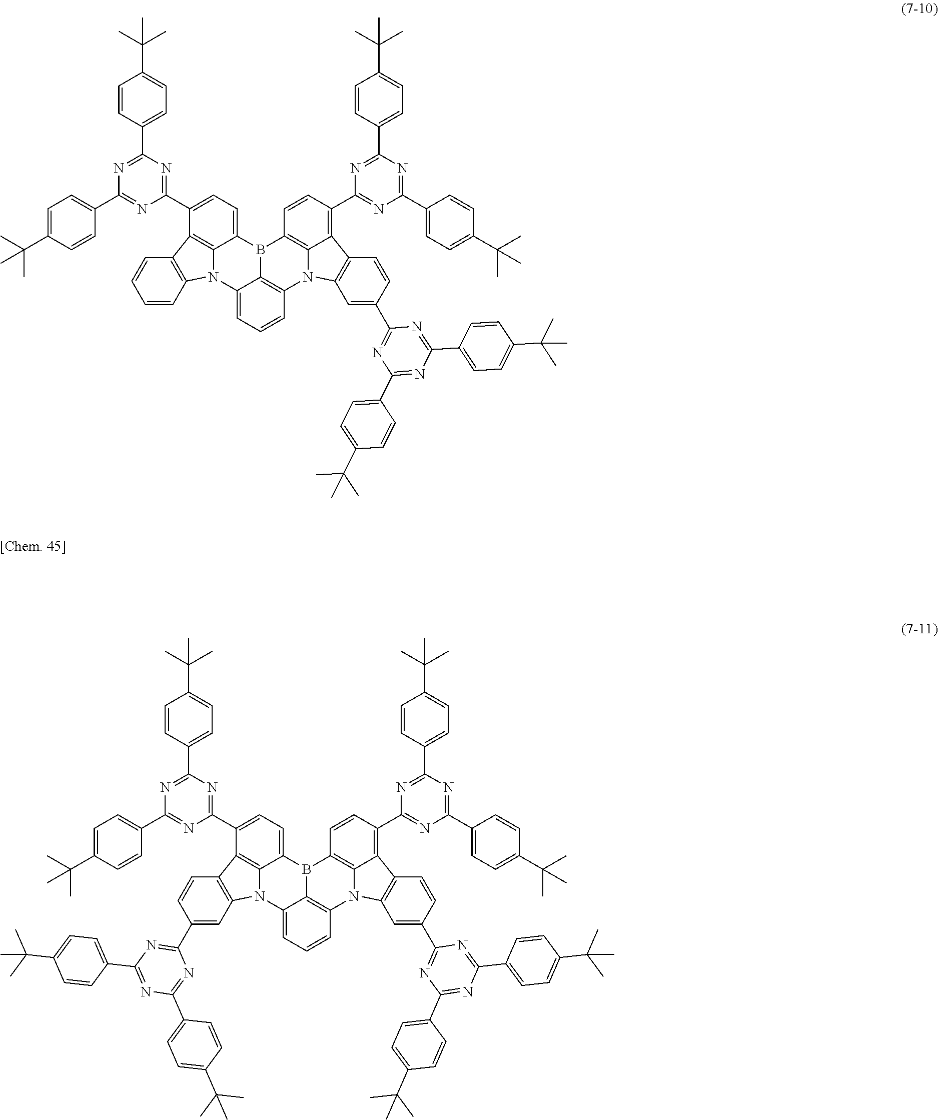

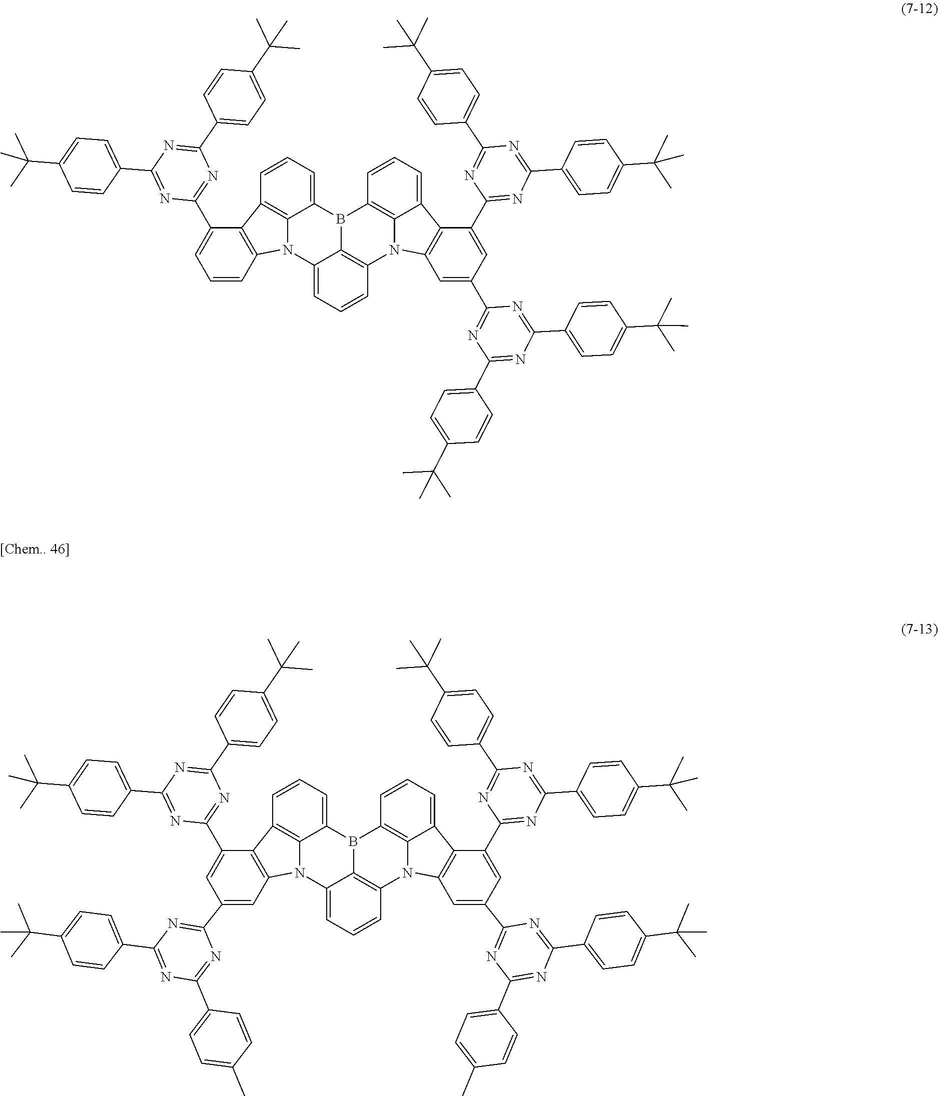

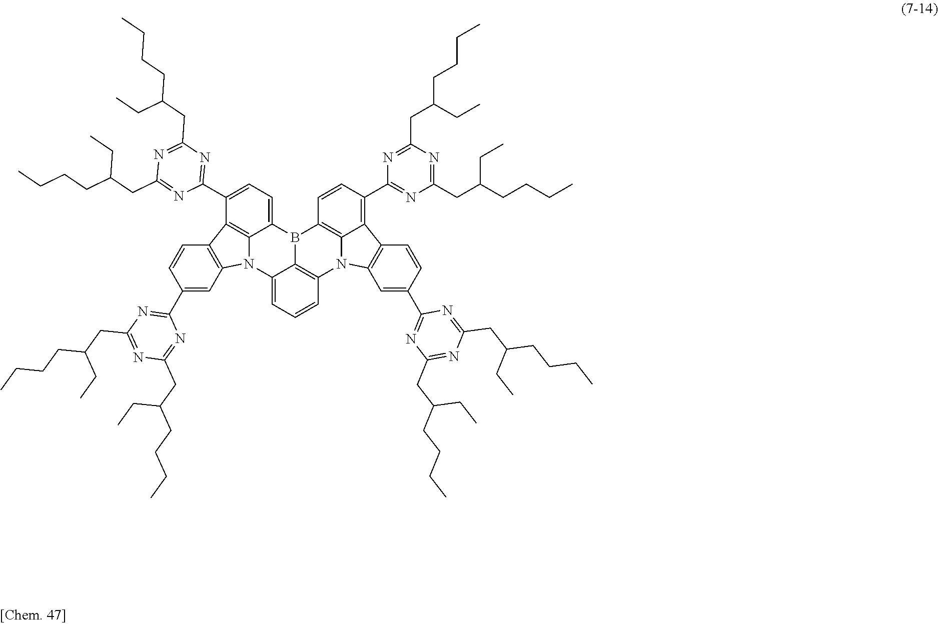 [SMILES: CCCCC(CC)Cc1nc(CC(CC)CCCC)nc(-c2ccc3c4c(-c5nc(CC(CC)CCCC)nc(CC(CC)CCCC)n5)ccc5c4n(c3c2)-c2cccc3c2B5c2ccc(-c4nc(CC(CC)CCCC)nc(CC(CC)CCCC)n4)c4c5ccc(-c6nc(CC(CC)CCCC)nc(CC(CC)CCCC)n6)cc5n-3c24)n1]

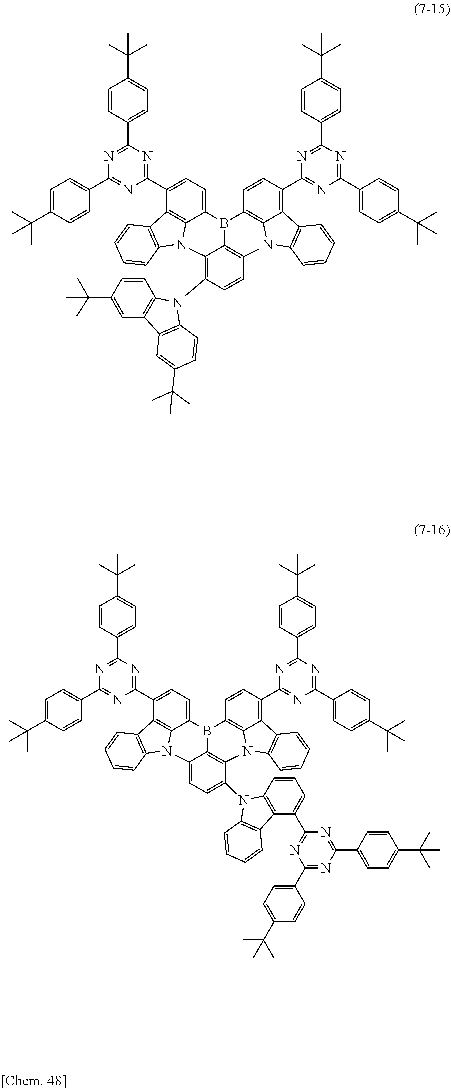

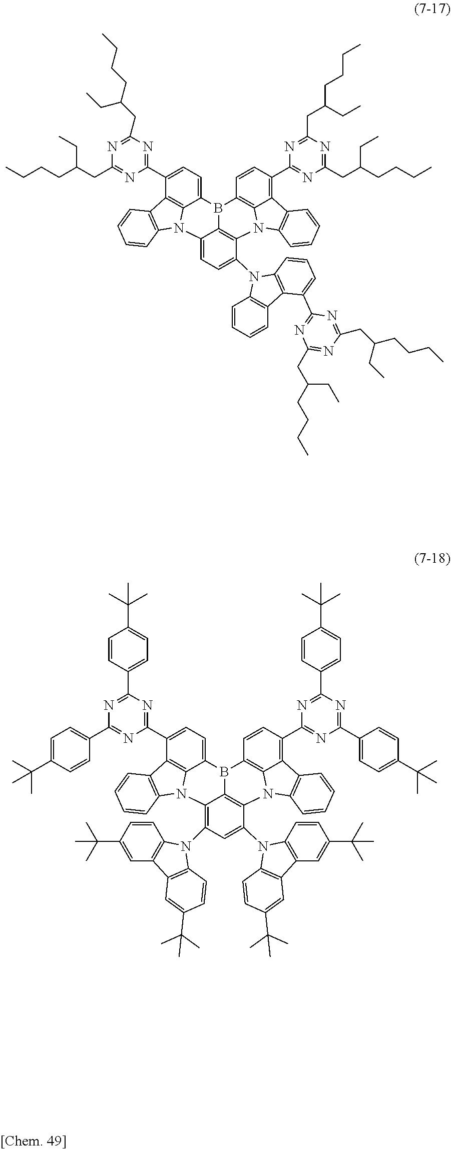

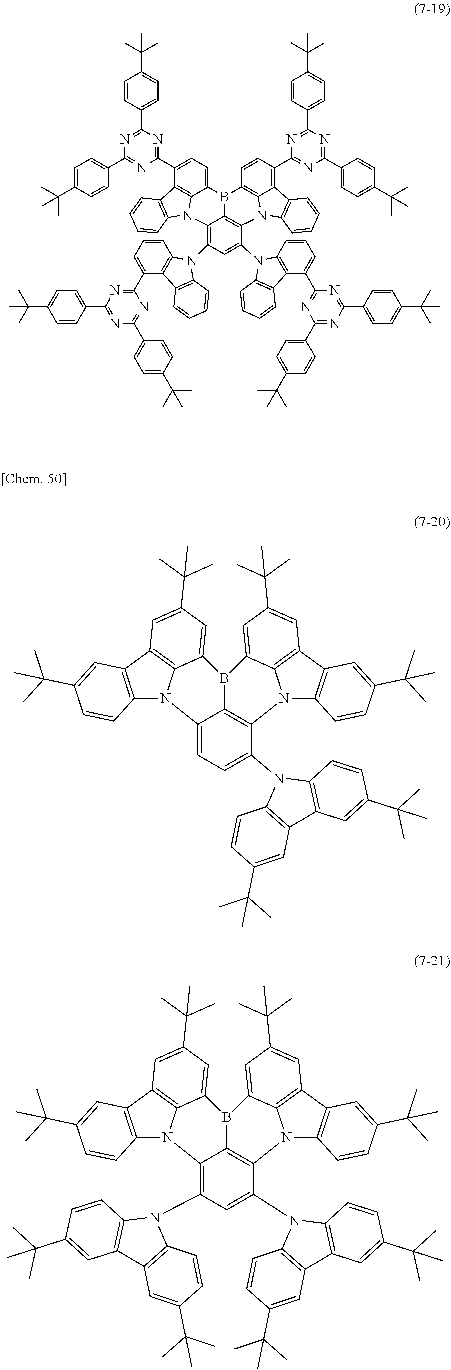

### <Substituent Group Z>

Examples of the substituent group Z include the following structures.

The substituent group Z is a group consisting of an alkyl group, an alkenyl group, an alkynyl group, an alkoxy group, an aryloxy group, a heteroaryloxy group, an alkoxycarbonyl group, a dialkylamino group, a diarylamino group, an arylalkylamino group, an acyl group, a halogen atom, a haloalkyl group, an alkylthio group, an arylthio group, a silyl group, a siloxy group, a cyano group, an aromatic hydrocarbon group, an aromatic heterocyclic group, an aralkyl group, and a heteroaralkyl group.

Preferred structures and specific examples of these substituents are as follows.

As the alkyl group, a linear, branched, or cyclic alkyl group having generally 1 or more, preferably 4 or more, and generally 24 or less, preferably 12 or less carbon atoms; for example, a methyl group, an ethyl group, an n-propyl group, an i-propyl group, an n-butyl group, an i-butyl group, a sec-butyl group, a tert-butyl group, an n-hexyl group, a cyclohexyl group, a dodecyl group, and a cyclohexyl group

As the alkenyl group, an alkenyl group having generally 2 or more, and generally 24 or less, preferably 12 or less carbon atoms; for example, a vinyl group

As the alkynyl group, an alkynyl group having generally 2 or more, and generally 24 or less, preferably 12 or less carbon atoms; for example, an ethynyl group

As the alkoxy group, an alkoxy group having generally 1 or more, and generally 24 or less, preferably 12 or less carbon atoms; for example, a methoxy group, and an ethoxy group

As the (hetero)aryloxy group, an aryloxy group or heteroaryloxy group having generally 4 or more, preferably 5 or more, and generally 36 or less, preferably 24 or less carbon atoms; for example, a phenoxy group, a naphthoxy group, and a pyridyloxy group

As the alkoxycarbonyl group, an alkoxycarbonyl group having generally 2 or more, and generally 24 or less, preferably 12 or less carbon atoms; for example, a methoxycarbonyl group, and an ethoxycarbonyl group

As the dialkylamino group, a dialkylamino group having generally 2 or more, and generally 24 or less, preferably 12 or less carbon atoms; for example, a dimethylamino group, and a diethylamino group

As the diarylamino group, a diarylamino group having generally 10 or more, preferably 12 or more, and generally 36 or less, preferably 24 or less carbon atoms; for example, a diphenylamino group, and a ditolylamino group

As the arylalkylamino group, an arylalkylamino group having generally 7 or more, and generally 36 or less, preferably 24 or less carbon atoms; for example, a phenylmethylamino group

As the acyl group, an acyl group having generally 2 or more, and generally 24 or less, preferably 12 or less carbon atoms; for example, an acetyl group, and a benzoyl group

As the halogen atom, a halogen atom; for example, a fluorine atom and a chlorine atom

As the haloalkyl group, a haloalkyl group having generally 1 or more, and generally 12 or less, and preferably 6 or less carbon atoms; for example, a trifluoromethyl group

As the alkylthio group, an alkylthio group having generally 1 or more, and generally 24 or less, preferably 12 or less carbon atoms; for example, a methylthio group and an ethylthio group

As the arylthio group, an arylthio group having generally 4 or more, preferably 5 or more, and generally 36 or less, preferably 24 or less carbon atoms; for example, a phenylthio group, a naphthylthio group, and a pyridylthio group

As the silyl group, a silyl group having generally 2 or more, preferably 3 or more, and generally 36 or less, preferably 24 or less carbon atoms; for example, a trimethylsilyl group, and a triphenylsilyl group

As the siloxy group, a siloxy group having generally 2 or more, preferably 3 or more, and generally 36 or less, preferably 24 or less carbon atoms; for example, a trimethylsiloxy group, and a triphenylsiloxy group A cyano group

As the aromatic hydrocarbon group, an aromatic hydrocarbon group having generally 6 or more, and generally 36 or less, preferably 24 or less carbon atoms; for example, a phenyl group, a biphenyl group, a terphenyl group, a quaterphenyl group, a naphthyl group, a phenanthrenyl group, a triphenylene group, and a naphthylphenyl group

As the aromatic heterocyclic group, an aromatic heterocyclic group having generally 3 or more, preferably 4 or more, and generally 36 or less, preferably 24 or less carbon atoms; for example, a thienyl group and a pyridyl group

As the aralkyl group, an aralkyl group having 7 or more, preferably 8 or more, and 40 or less, preferably 30 or less, and more preferably 20 or less carbon atoms; for example, a 1,1-dimethyl-1-phenylmethyl group, a 1,1-di(n-butyl)-1-phenylmethyl group, a 1,1-di(n-hexyl)-1-phenylmethyl group, a 1,1-di(n-octyl)-1-phenylmethyl group, a phenylmethyl group, a phenylethyl group, a 3-phenyl-1-propyl group, a 4-phenyl-1-n-butyl group, a 1-methyl-1-phenylethyl group, a 5-phenyl-1-n-propyl group, a 6-phenyl-1-n-hexyl group, a 6-naphthyl-1-n-hexyl group, a 7-phenyl-1-n-heptyl group, an 8-phenyl-1-n-octyl group, and a 4-phenylcyclohexyl group

As the heteroaralkyl group, a heteroaralkyl group having 2 or more, preferably 4 or more, and 40 or less, preferably 30 or less, more preferably 20 or less carbon atoms; a 1,1-dimethyl-1-(2-pyridyl)methyl group, a 1,1-di(n-hexyl)-1-(2-pyridyl)methyl group, a (2-pyridyl)methyl group, a (2-pyridyl)ethyl group, a 3-(2-pyridyl)-1-propyl group, a 4-(2-pyridyl)-1-n-butyl group, a 1-methyl-1-(2-pyridyl)ethyl group, a 5-(2-pyridyl)-1-n-propyl group, a 6-(2-pyridyl)-1-n-hexyl group, a 6-(2-pyrimidyl)-1-n-hexyl group, a 6-(2,6-diphenyl-1,3,5-triazin-4-yl)-1-n-hexyl group, a 7-(2-pyridyl)-1-n-heptyl group, an 8-(2-pyridyl)-1-n-octyl group, and a 4-(2-pyridyl)cyclohexyl group

### [Organometallic Compound]

In the present invention, the organometallic compound contains a metal selected from Groups 7 to 11 of the long-period periodic table (hereinafter, the term “periodic table” refers to a long-period periodic table unless otherwise specified). Preferred examples of the metal selected from Groups 7 to 11 of the periodic table include ruthenium, rhodium, palladium, silver, rhenium, osmium, iridium, platinum, and gold, and among them, iridium or platinum is more preferred.

The organometallic compound is preferably a Werner type complex or an organometallic complex. A ligand of the complex is preferably a ligand in which a (hetero)aryl group is linked to pyridine, pyrazole, phenanthroline, or the like, such as a (hetero)arylpyridine ligand, or a (hetero)arylpyrazole ligand, and particularly preferably a phenylpyridine ligand or a phenylpyrazole ligand. Here, (hetero)aryl represents an aryl group or a heteroaryl group.

Due to a heavy atom effect of the metal, in the organometallic compound containing the metal, intersystem crossing from excited singlet to excited triplet occurs, and a relaxation time from the excited triplet to the ground state is shortened to a certain extent. Further, it is presumed that, by satisfying the above relational expression (E-1), the excited state generated by application of a voltage to the organic electroluminescent element can be transferred to the luminescent compound by either electron exchange interaction or dipole-dipole interaction, and the luminescent compound can be made to emit light efficiently.

The organometallic compound is particularly preferably an organometallic complex containing iridium. The organometallic complex containing iridium is preferably a metal compound represented by the formula (201).

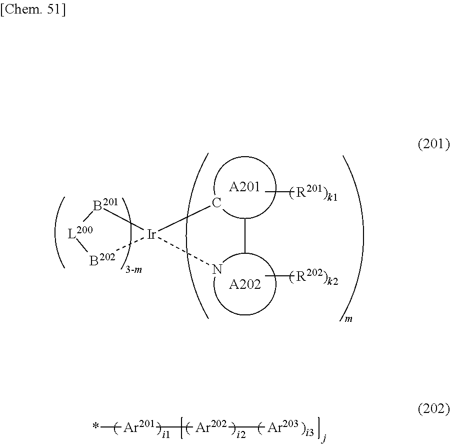

[Ring A201 represents an aromatic hydrocarbon ring structure which may have a substituent or an aromatic heterocyclic structure which may have a substituent.
Ring A202 represents an aromatic heterocyclic structure which may have a substituent.
R₂₀₁ and R₂₀₂ each independently represent a structure represented by the formula (202).

When a plurality of R₂₀₁'s and a plurality of R₂₀₂'s are present, they may be the same as or different from each other.
Ar²⁰¹ and Ar²⁰³ each independently represent an aromatic hydrocarbon ring structure which may have a substituent or an aromatic heterocyclic structure which may have a substituent.
Ar²⁰² represents an aromatic hydrocarbon ring structure which may have a substituent, an aromatic heterocyclic structure which may have a substituent, or an aliphatic hydrocarbon structure which may have a substituent.

When a plurality of Ar²⁰¹'s, a plurality of Ar²⁰²'s, and a plurality of Ar²⁰³'s are present, they may be the same as or different from each other.
* represents bonding to ring A201 or ring A202.
B²⁰¹-L²⁰⁰-B²⁰² represents an anionic bidentate ligand. B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure. L²⁰⁰ represents a single bond or an atomic group constituting a bidentate ligand together with B²⁰¹ and B²⁰².

When a plurality of B²⁰¹-L²⁰⁰-B²⁰²'s are present, they may be the same as or different from each other.
i1 and i2 each independently represent an integer of 0 or more and 12 or less.
i3 is an integer of 0 or more, an upper limit of which is the number that can be substituted for Ar²⁰².
j is an integer of 0 or more, an upper limit of which is the number that can be substituted for Ar²⁰¹.
K1 and k2 each independently represent an integer of 0 or more, an upper limit of which is the number that can be substituted for ring A201 and ring A202.
m represents an integer of 1 to 3.]

### (Ring A201 and Ring A202)

The aromatic hydrocarbon ring in ring A201 is preferably an aromatic hydrocarbon ring having 6 to 30 carbon atoms, and specifically, a benzene ring, a naphthalene ring, an anthracene ring, a triphenylyl ring, an acenaphthene ring, a fluoranthene ring, or a fluorene ring is preferred.

The aromatic heterocyclic ring in ring A201 is preferably an aromatic heterocyclic ring having 3 to 30 carbon atoms and containing a nitrogen atom, oxygen atom, or sulfur atom as a heteroatom, and more preferably a furan ring, a benzofuran ring, a thiophene ring, or a benzothiophene ring.

Ring A201 is more preferably a benzene ring, a naphthalene ring, or a fluorene ring, particularly preferably a benzene ring or a fluorene ring, and most preferably a benzene ring.

The aromatic heterocyclic ring in ring A202 is preferably an aromatic heterocyclic ring having 3 to 30 carbon atoms and containing a nitrogen atom, oxygen atom, or sulfur atom as a heteroatom, specifically, is a pyridine ring, a pyrazine ring, a pyrimidine ring, an imidazole ring, an oxazole ring, or a thiazole ring, and most preferably a pyridine ring.

When m is 2 or 3, a plurality of rings A201 and a plurality of rings A202 may be the same as or different from each other.

Preferred combinations of ring A201 and ring A202, expressed as (ring A201-ring A202), include (benzene ring-pyridine ring), (benzene ring-quinoline ring), (benzene ring-quinoxaline ring), (benzene ring-quinazoline ring), (benzene ring-imidazole ring), and (benzene ring-benzothiazole ring), and most preferably (benzene ring-pyridine ring).

The substituent which ring A201 and ring A202 may have can be optionally selected, and is preferably one or more kinds of substituents selected from a substituent group S to be described later.

The substituents bonded to ring A201, the substituents bonded to ring A202, or the substituents bonded to ring A201 and the substituents bonded to ring A202 may be bonded to each other to form a ring.

(R²⁰¹ and R²⁰²)
R²⁰¹ and R²⁰² each independently represent a structure represented by the formula (202), and “*” represents bonding to ring A201 or ring A202. R²⁰¹ and R²⁰² may be the same as or different from each other. When a plurality of R²⁰¹'s and a plurality of R²⁰²'s are present, they may be the same as or different from each other. That is, when a plurality of R²⁰¹'s are present, they may be the same as or different from each other, and when a plurality of R²⁰²'s are present, they may be the same as or different from each other.
(Ar²⁰¹, Ar²⁰², and Ar²⁰³)

Ar²⁰¹ and Ar²⁰³ each independently represent an aromatic hydrocarbon ring structure which may have a substituent or an aromatic heterocyclic structure which may have a substituent.

Ar²⁰² represents an aromatic hydrocarbon ring structure which may have a substituent, an aromatic heterocyclic structure which may have a substituent, or an aliphatic hydrocarbon structure which may have a substituent.

When a plurality of Ar²⁰¹'s, a plurality of Ar²⁰²'s, and a plurality of Ar²⁰³'s are present, they may be the same as or different from each other. That is, when a plurality of Ar²⁰¹'s are present, they may be the same as or different from each other, when a plurality of Ar²⁰²'s are present, they may be the same as or different from each other, and when a plurality of Ar²⁰³'s are present, they may be the same as or different from each other.

When any of Ar²⁰¹, Ar²⁰², and Ar²⁰³ is an aromatic hydrocarbon ring structure which may have a substituent, the aromatic hydrocarbon ring structure is preferably an aromatic hydrocarbon ring having 6 to 30 carbon atoms, and specifically, a benzene ring, a naphthalene ring, an anthracene ring, a triphenylyl ring, an acenaphthene ring, a fluoranthene ring, or a fluorene ring is preferred, a benzene ring, a naphthalene ring, or a fluorene ring is more preferred, and a benzene ring is most preferred.

When any of Ar²⁰¹, Ar²⁰², and Ar²⁰³ is a fluorene ring which may have a substituent, it is preferable that a 9-position and a 9′-position of the fluorene ring have a substituent or are bonded to an adjacent structure.

When any of Ar²⁰¹, Ar²⁰², and Ar²⁰³ is a benzene ring which may have a substituent, it is preferable that at least one benzene ring is bonded to an adjacent structure at a meta position or a para position, and it is more preferable that at least one benzene ring is bonded to an adjacent structure at a meta position.

When any of Ar²⁰¹, Ar²⁰², and Ar²⁰³ is an aromatic heterocyclic structure which may have a substituent, the aromatic heterocyclic structure is preferably an aromatic heterocyclic ring having 3 to 30 carbon atoms and containing any of a nitrogen atom, an oxygen atom, and a sulfur atom as a heteroatom, and specific examples thereof include a pyridine ring, a pyrimidine ring, a pyrazine ring, a triazine ring, an imidazole ring, an oxazole ring, a thiazole ring, a benzothiazole ring, a benzoxazole ring, a benzoimidazole ring, a quinoline ring, an isoquinoline ring, a quinoxaline ring, a quinazoline ring, a naphthyridine ring, a phenanthridine ring, a carbazole ring, a dibenzofuran ring, and a dibenzothiophene ring, and preferably a pyridine ring, a pyrimidine ring, a triazine ring, a carbazole ring, a dibenzofuran ring, and a dibenzothiophene ring.

When any of Ar²⁰¹, Ar²⁰², and Ar²⁰³ is a carbazole ring which may have a substituent, it is preferable that an N-position of the carbazole ring has a substituent or is bonded to an adjacent structure.

When Ar²⁰² is an aliphatic hydrocarbon structure which may have a substituent, the aliphatic hydrocarbon structure is an aliphatic hydrocarbon structure having a linear, branched, or cyclic structure, preferably an aliphatic hydrocarbon having 1 to 24 carbon atoms, more preferably an aliphatic hydrocarbon having 1 to 12 carbon atoms, and still more preferably an aliphatic hydrocarbon having 1 to 8 carbon atoms.

(i1, i2, i3, j, k1, k2)

i1 and i2 each independently represent preferably an integer of 1 to 12, more preferably an integer of 1 to 8, and still more preferably an integer of 1 to 6. Within the range, improvement in solubility and improvement in charge transportability are expected.
i3 represents preferably an integer of 0 to 5, more preferably an integer of 0 to 2, and still more preferably 0 or 1.
j represents preferably an integer of 0 to 2, and more preferably 0 or 1.
k1 and k2 each represent preferably an integer of 0 to 3, more preferably an integer of 1 to 3, still more preferably 1 or 2, and particularly preferably 1.

The substituent which Ar²⁰¹, Ar²⁰², and Ar²⁰³ may have can be optionally selected, and preferably represents one or more substituents selected from the substituent group S to be described later, more preferably represents a hydrogen atom, an alkyl group, or an aryl group, particularly preferably represents a hydrogen atom or an alkyl group, and most preferably unsubstituted (represents a hydrogen atom).

Unless otherwise specified, the substituent preferably represents a group selected from the following substituent group S.

### (Substituent Group S)

An alkyl group, preferably an alkyl group having 1 to 20 carbon atoms, more preferably an alkyl group having 1 to 12 carbon atoms, still more preferably an alkyl group having 1 to 8 carbon atoms, particularly preferably an alkyl group having 1 to 6 carbon atoms. The alkyl group may be linear or branched.
An alkoxy group, preferably an alkoxy group having 1 to 20 carbon atoms, more preferably an alkoxy group having 1 to 12 carbon atoms, and still more preferably an alkoxy group having 1 to 6 carbon atoms.
An aryloxy group, preferably an aryloxy group having 6 to 20 carbon atoms, more preferably an aryloxy group having 6 to 14 carbon atoms, still more preferably an aryloxy group having 6 to 12 carbon atoms, and particularly preferably an aryloxy group having 6 carbon atoms.
A heteroaryloxy group, preferably a heteroaryloxy group having 3 to 20 carbon atoms, and more preferably a heteroaryloxy group having 3 to 12 carbon atoms.
An alkylamino group, preferably an alkylamino group having 1 to 20 carbon atoms, and more preferably an alkylamino group having 1 to 12 carbon atoms.
An arylamino group, preferably an arylamino group having 6 to 36 carbon atoms, more preferably an arylamino group having 6 to 24 carbon atoms.
An aralkyl group, preferably an aralkyl group having 7 to 40 carbon atoms, more preferably an aralkyl group having 7 to 18 carbon atoms, and still more preferably an aralkyl group having 7 to 12 carbon atoms.
A heteroaralkyl group, preferably a heteroaralkyl group having 7 to 40 carbon atoms, and more preferably a heteroaralkyl group having 7 to 18 carbon atoms.
An alkenyl group, preferably an alkenyl group having 2 to 20 carbon atoms, more preferably an alkenyl group having 2 to 12 carbon atoms, still more preferably an alkenyl group having 2 to 8 carbon atoms, and particularly preferably an alkenyl group having 2 to 6 carbon atoms.
An alkynyl group, preferably an alkynyl group having 2 to 20 carbon atoms, and more preferably an alkynyl group having 2 to 12 carbon atoms.
An aryl group, preferably an aryl group having 6 to 30 carbon atoms, more preferably an aryl group having 6 to 24 carbon atoms, still more preferably an aryl group having 6 to 18 carbon atoms, and particularly preferably an aryl group having 6 to 14 carbon atoms.
A heteroaryl group, preferably a heteroaryl group having 3 to 30 carbon atoms, more preferably a heteroaryl group having 3 to 24 carbon atoms, still more preferably a heteroaryl group having 3 to 18 carbon atoms, and particularly preferably a heteroaryl group having 3 to 14 carbon atoms.
An alkylsilyl group, preferably an alkylsilyl group having an alkyl group with 1 to 20 carbon atoms, and more preferably an alkylsilyl group having an alkyl group with 1 to 12 carbon atoms.
An arylsilyl group, preferably an arylsilyl group having an aryl group with 6 to 20 carbon atoms, and more preferably an arylsilyl group having an aryl group with 6 to 14 carbon atoms.
An alkylcarbonyl group, preferably an alkylcarbonyl group having 2 to 20 carbon atoms.
An arylcarbonyl group, preferably an arylcarbonyl group having 7 to 20 carbon atoms.
A hydrogen atom, a deuterium atom, a fluorine atom, a cyano group, or —SF₅.

In the above groups, one or more hydrogen atoms may be substituted with fluorine atoms, or one or more hydrogen atoms may be substituted with deuterium atoms.

Unless otherwise specified, aryl is an aromatic hydrocarbon, and heteroaryl is an aromatic heterocyclic ring.

### (Preferred Group in Substituent Group S)

Among the above substituent group S, preferred are an alkyl group, an alkoxy group, an aryloxy group, an arylamino group, an aralkyl group, an alkenyl group, an aryl group, a heteroaryl group, an alkylsilyl group, an arylsilyl group, a group in which one or more hydrogen atoms of these groups are substituted with fluorine atoms, a fluorine atom, a cyano group, or —SF₅, more preferred are an alkyl group, an arylamino group, an aralkyl group, an alkenyl group, an aryl group, a heteroaryl group, a group in which one or more hydrogen atoms of these groups are substituted with fluorine atoms, a fluorine atom, a cyano group, or —SF₅, still more preferred are an alkyl group, an alkoxy group, an aryloxy group, an arylamino group, an aralkyl group, an alkenyl group, an aryl group, a heteroaryl group, an alkylsilyl group, or an arylsilyl group, particularly preferred are an alkyl group, an arylamino group, an aralkyl group, an alkenyl group, an aryl group, or a heteroaryl group, and most preferred are an alkyl group, an arylamino group, an aralkyl group, an aryl group, or a heteroaryl group.

These substituents in the substituent group S may further have a substituent selected from the substituent group S as a substituent. A preferred group, a more preferred group, a still more preferred group, a particularly preferred group, and a most preferred group of the substituent which these substituents may have are the same as the preferred group in the substituent group S.

### (Preferred Structure of Formula (201))

Among the structure represented by the formula (202) of the formula (201), a structure having a group to which a benzene ring is linked, a structure having an aromatic hydrocarbon group or an aromatic heterocyclic group in which an alkyl group or an aralkyl group is bonded to ring A201 or ring A202, and a structure in which a dendron is bonded to ring A201 or ring A202 are preferred.

In the structure having a group to which a benzene ring is linked, Ar²⁰¹ represents a benzene ring structure, i1 represents 1 to 6, and at least one of the benzene rings is bonded to a structure adjacent at an ortho position or a meta position.

With the structure, it is expected to improve the solubility and improve the charge transportability.

In the structure having an aromatic hydrocarbon group or an aromatic heterocyclic group in which an alkyl group or an aralkyl group is bonded to ring A201 or ring A202, and
Ar²⁰¹ is an aromatic hydrocarbon structure or aromatic heterocyclic structure, i1 represents 1 to 6, Ar²⁰² represents an aliphatic hydrocarbon structure, i2 is 1 to 12, and preferably 3 to 8, Ar²⁰³ represents a benzene ring structure, and i3 represents 0 or 1.

In the case of the structure, Ar²⁰¹ preferably represents the aromatic hydrocarbon structure, more preferably represents a structure in which 1 to 5 benzene rings are linked, and still more preferably represents one benzene ring.

With the structure, it is expected to improve the solubility and improve the charge transportability.

In the structure in which a dendron is bonded to ring A201 or ring A202, Ar²⁰¹ and Ar²⁰² each represent a benzene ring structure, Ar²⁰³ represents a biphenyl or terphenyl structure, i1 and i2 each represent 1 to 6, i3 represents 2, and j represents 2.

With the structure, it is expected to improve the solubility and improve the charge transportability.

(Structure Represented by B²⁰¹-L²⁰⁰-B²⁰²)

When a plurality of B²⁰¹-L²⁰⁰-B²⁰²'s are present, they may be the same as or different from each other.

The structure represented by B²⁰¹-L²⁰⁰-B²⁰² is preferably a structure represented by the following formula (203) or (204).

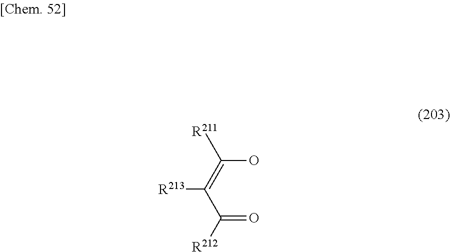

R²¹¹, R²¹², and R²¹³ each represent a substituent.

The substituent is not particularly limited, and is preferably a group selected from the substituent group S.

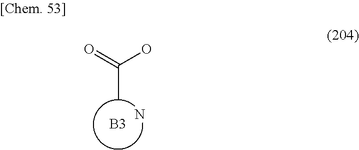

Ring B3 represents an aromatic heterocyclic structure containing a nitrogen atom which may have a substituent.

Ring B3 preferably represents a pyridine ring.

The substituent which ring B3 may have is not particularly limited, and is preferably a group selected from the substituent group S.

### (Molecular Weight)

An upper limit of the molecular weight of the organometallic compound is not particularly limited, and is preferably 10000 or less, more preferably 5000 or less, still more preferably 4000 or less, and particularly preferably 3000 or less. The molecular weight of the organometallic compound is 1200 or more, preferably 1300 or more, and more preferably 1700 or more. It is considered that when the molecular weight is within the range, the organometallic compound is uniformly mixed with the aromatic compound of the present invention and/or another charge transport material without being aggregated, and an emission layer having high luminescent efficiency can be obtained.

The molecular weight of the organometallic compound is preferably large since Tg or a melting point, a decomposition temperature, and the like are high, the organometallic compound and the formed emission layer are excellent in heat resistance, and deterioration in film quality due to gas generation, recrystallization, migration of molecules, and the like, an increase in impurity concentration due to thermal decomposition of the material, and the like hardly occur. On the other hand, the molecular weight of the organometallic compound is preferably small since purification of an organic compound is easy.

MwA/MwB is preferably 1.0 or more, more preferably 1.5 or more, and still more preferably 2.0 or more, where MwA is the molecular weight of the organometallic compound and MwB is the molecular weight of the luminescent compound. It is considered that when MwA/MwB is within the range, energy is appropriately transferred from the organometallic compound to the luminescent compound, and an emission layer having high luminescent efficiency can be obtained.

### (Specific Examples of Organometallic Compound)

The organometallic compound represented by the formula (201) is not particularly limited, and specific examples thereof include the following structures.

Me means a methyl group, and Ph means a phenyl group.

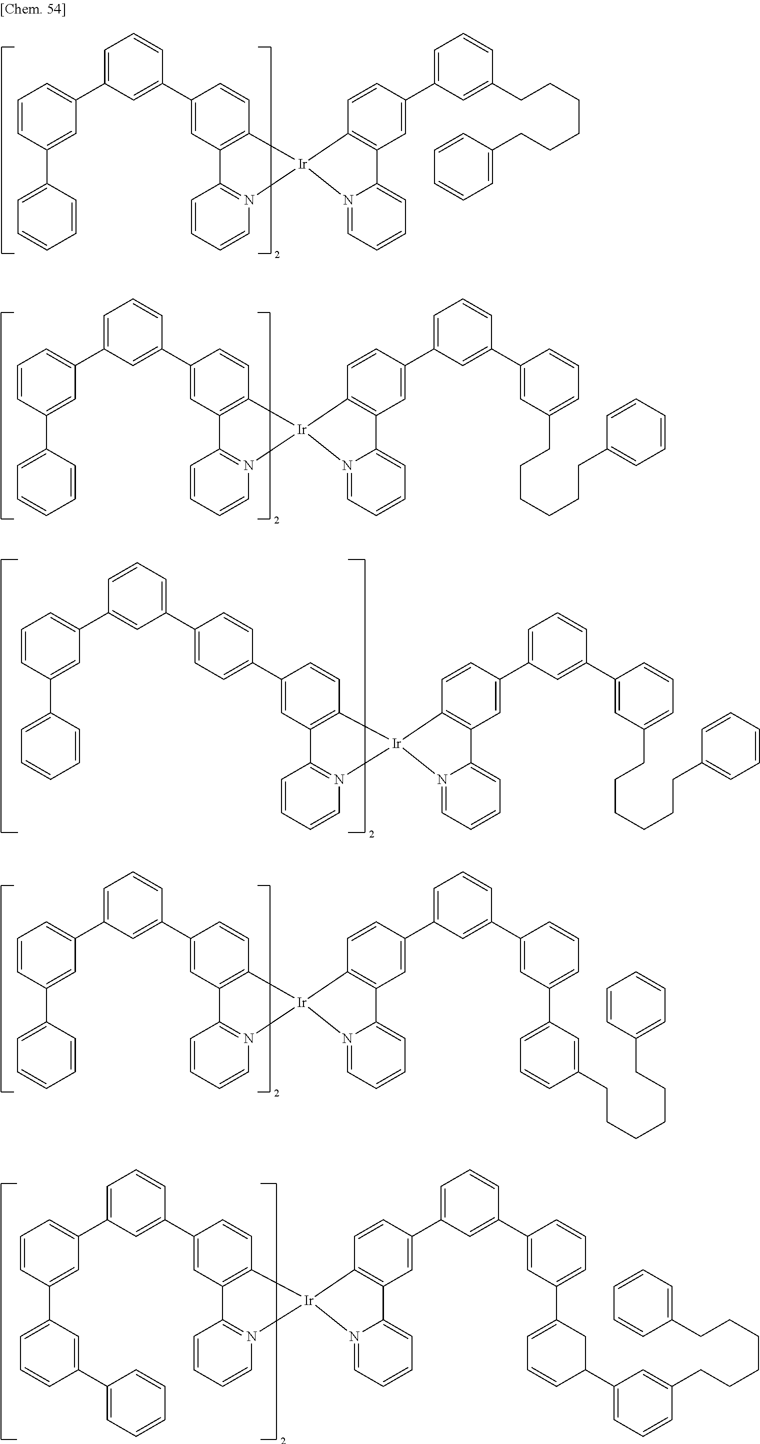

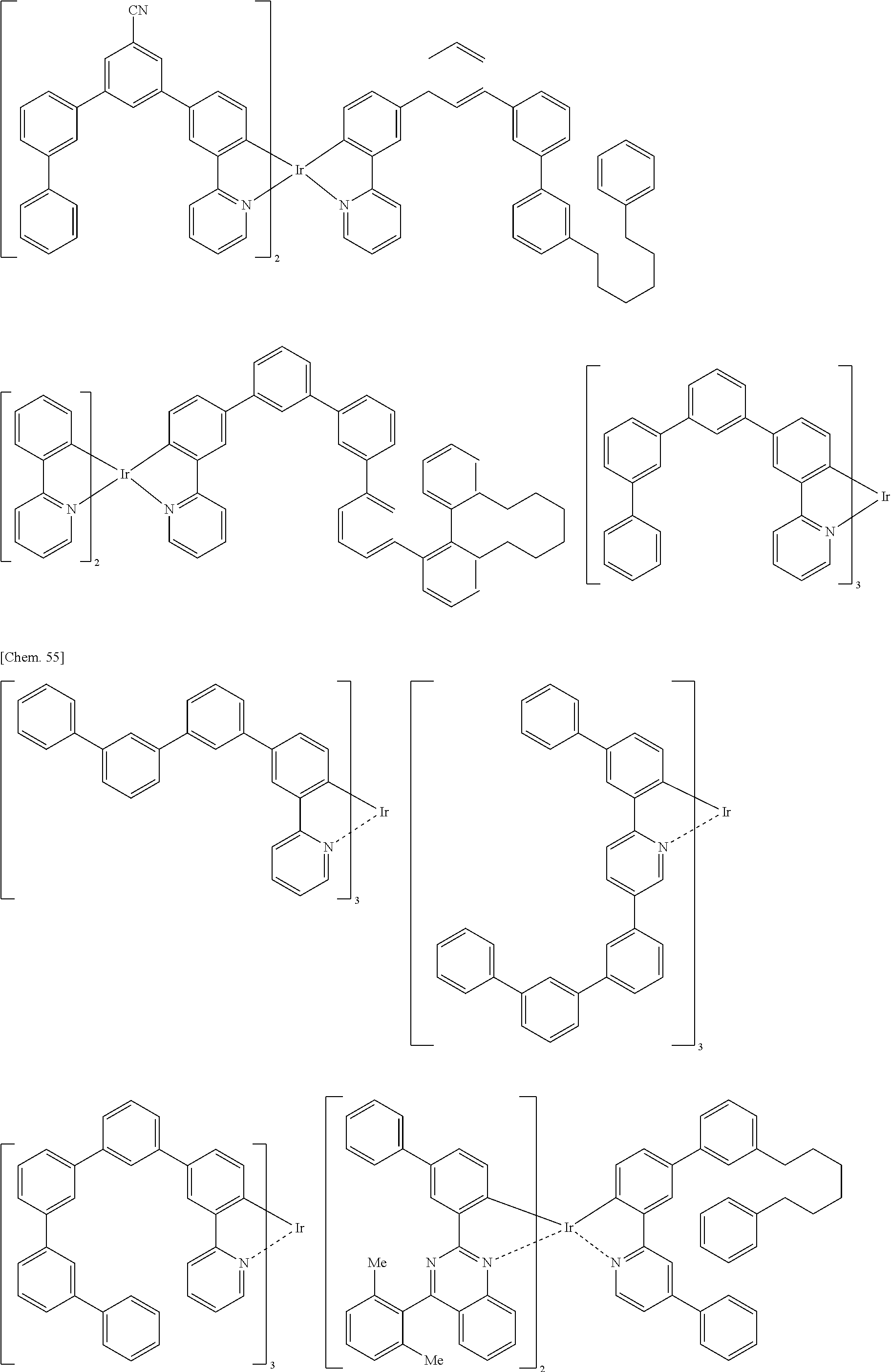

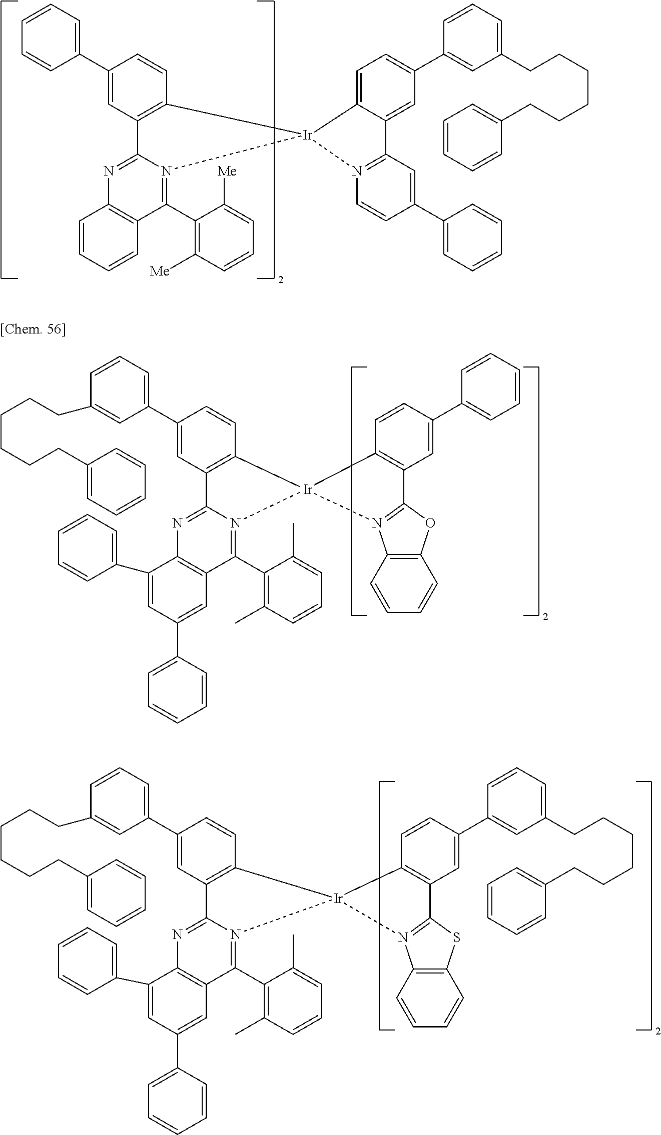

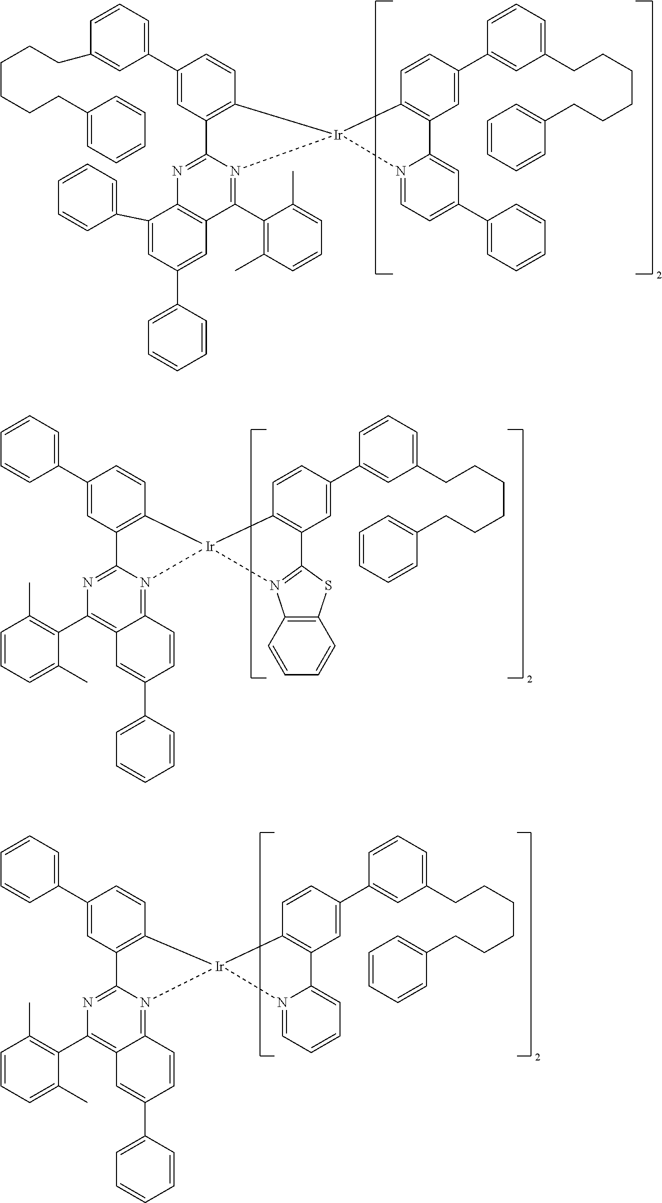

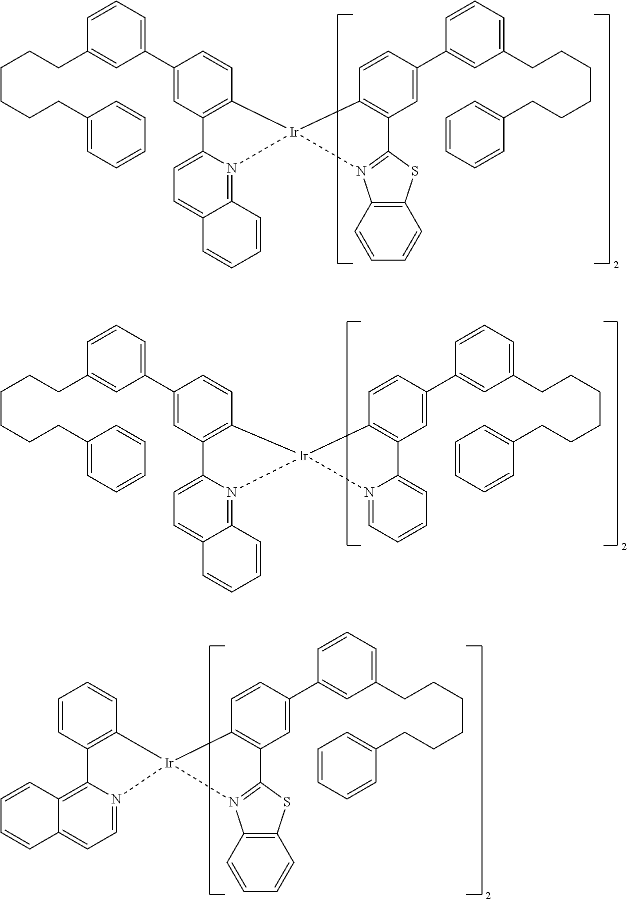

### (Preferred Combination)

In the organic electroluminescent element material, the organometallic compound is preferably represented by the formula (201), and the luminescent compound is preferably a polycyclic heterocyclic compound represented by the formula (1).

### [Host Material]

The organic electroluminescent element material preferably contains a host material. The host material is preferably a charge transport material, and any of related-art materials used for an organic electroluminescent element material can be used. The charge transport material used as the host material for an organic electroluminescent element material is a material having a skeleton excellent in charge transportability, and is preferably selected from an electron transport material, a hole transport material, and a bipolar material capable of transporting both electrons and holes. Further, in the present invention, the charge transport material includes a material for adjusting the charge transportability.

Specific examples of the skeleton excellent in charge transportability include pyridine, pyrimidine, triazine, carbazole, naphthalene, perylene, pyrene, anthracene, chrysene, naphthacene, phenanthrene, coronene, fluoranthene, benzophenanthrene, fluorene, acetonaphthofluoranthene, coumarin, p-bis(2-phenylethenyl)benzene and derivatives thereof, quinacridone derivatives, 4-(dicyanomethylene)-2-methyl-6-(p-dimethylaminostyryl)-4H-pyran-based (DCM-based) compounds, benzopyran derivatives, rhodamine derivatives, benzothioxanthene derivatives, azabenzothioxanthene, fused aromatic ring compounds substituted with an arylamino group, and styryl derivatives substituted with an arylamino group.

One of these solvents may be used alone, or any desired two or more thereof may be used in combination in any desired proportion.

Among them, preferred are pyridine, pyrimidine, triazine, carbazole, naphthalene, perylene, pyrene, anthracene, chrysene, naphthacene, phenanthrene, coronene, fluoranthene, benzophenanthrene, fluorene, acetonaphthofluoranthene, and derivatives thereof, and more preferred are anthracene derivatives.

Specific examples of the skeleton excellent in charge transportability include an aromatic structure, an aromatic amine structure, a triarylamine structure, a dibenzofuran structure, a naphthalene structure, a phenanthrene structure, a phthalocyanine structure, a porphyrin structure, a thiophene structure, a benzylphenyl structure, a fluorene structure, a quinacridone structure, a triphenylene structure, a carbazole structure, a pyrene structure, an anthracene structure, a phenanthroline structure, a quinoline structure, a pyridine structure, a pyrimidine structure, a triazine structure, an oxadiazole structure, and an imidazole structure.

As the electron transport material, a compound having a pyridine structure, a pyrimidine structure, or a triazine structure, which is a skeleton excellent in electron transportability and is relatively stable, is more preferred, and a compound having a pyrimidine structure or a triazine structure is still more preferred. The electron transport material is particularly preferably a compound represented by the formula (250) to be described later.

The hole transport material is a compound having a structure excellent in hole transportability, and among the skeleton excellent in charge transportability, a carbazole structure, a dibenzofuran structure, a triarylamine structure, a naphthalene structure, a phenanthrene structure, or a pyrene structure is preferred as the structure excellent in hole transportability, and a carbazole structure, a dibenzofuran structure, or a triarylamine structure is more preferred. The hole transport material is particularly preferably a compound represented by the formula (240) to be described later.

As the bipolar material capable of transporting both electrons and holes, a material having both a skeleton excellent in electron transportability and a skeleton excellent in hole transportability is preferred.

As the material for adjusting the charge transportability, a compound represented by the formula (260) to be described later, which is a compound having a structure in which many benzene rings are linked, is preferred. It is considered that when the compound is contained as the host material, excitons generated in the emission layer are efficiently recombined to increase the luminescent efficiency, and the charge transportability in the emission layer is appropriately adjusted to prevent deterioration of the luminescent material and the operating lifetime becomes longer.

The charge transport material used as the host material of the organic electroluminescent element material is preferably a compound having a 3 or more-fused ring structure, and more preferably a compound having two or more 3 or more-fused ring structures or a compound having at least one 5 or more-fused ring. By using these compounds, the rigidity of the molecule increases, and the effect of preventing the degree of molecular motion responsive to heat is easily obtained. Further, it is preferable that the 3 or more-fused ring and the 5 or more-fused ring have an aromatic hydrocarbon ring or an aromatic heterocyclic ring in terms of charge transportability and material durability.

Specific examples of the 3 or more-fused ring structure include an anthracene structure, a phenanthrene structure, a pyrene structure, a chrysene structure, a naphthacene structure, a triphenylene structure, a fluorene structure, a benzofluorene structure, an indenofluorene structure, an indolofluorene structure, a carbazole structure, an indenocarbazole structure, an indolocarbazole structure, a dibenzofuran structure, and a dibenzothiophene structure.

Among the 3 or more-fused ring structure, from the viewpoint of charge transportability and solubility, at least one selected from the group consisting of a phenanthrene structure, a fluorene structure, an indenofluorene structure, a carbazole structure, an indenocarbazole structure, an indolocarbazole structure, a dibenzofuran structure, and a dibenzothiophene structure is preferred, and from the viewpoint of durability to charge, a carbazole structure or an indolocarbazole structure is more preferred.

### <Definition of Substituent>

The substituent which the host material may have is selected from the substituent group Z2.

### <Substituent Group Z2>

The substituent group Z2 is a group consisting of an alkyl group, an alkoxy group, an aryloxy group, a heteroaryloxy group, an alkoxycarbonyl group, a dialkylamino group, a diarylamino group, an arylalkylamino group, an acyl group, a halogen atom, a haloalkyl group, an alkylthio group, an arylthio group, a silyl group, a siloxy group, a cyano group, an aromatic hydrocarbon group, and an aromatic heterocyclic group. These substituents may have any of linear, branched, and cyclic structures.

More specific examples of the substituent group Z2 include the following structures.
For example, a linear, branched, or cyclic alkyl group having generally 1 or more, preferably 4 or more, and generally 24 or less, preferably 12 or less, more preferably 8 or less, still more preferably 6 or less carbon atoms, such as a methyl group, an ethyl group, an n-propyl group, an i-propyl group, an n-butyl group, an i-butyl group, a sec-butyl group, a tert-butyl group, an n-hexyl group, a cyclohexyl group, or a dodecyl group;
For example, an alkoxy group having generally 1 or more, and generally 24 or less, preferably 12 or less carbon atoms, such as a methoxy group, or an ethoxy group;
For example, an aryloxy group or a heteroaryloxy group having generally 4 or more, preferably 5 or more, and generally 36 or less, preferably 24 or less carbon atoms, such as a phenoxy group, a naphthoxy group, or a pyridyloxy group;
For example, an alkoxycarbonyl group having generally 2 or more, and generally 24 or less, preferably 12 or less carbon atoms, such as a methoxycarbonyl group, or an ethoxycarbonyl group;
For example, a dialkylamino group having generally 2 or more, and generally 24 or less, preferably 12 or less carbon atoms, such as a dimethylamino group, or a diethylamino group;
For example, a diarylamino group having generally 10 or more, preferably 12 or more, and generally 36 or less, preferably 24 or less carbon atoms, such as a diphenylamino group, or a ditolylamino group;
For example, an arylalkylamino group having generally 7 or more, and generally 36 or less, preferably 24 or less carbon atoms, such as a phenylmethylamino group;
For example, an acyl group having generally 2 or more, and generally 24 or less, preferably 12 or less carbon atoms, such as an acetyl group, or a benzoyl group;
For example, a halogen atom, such as a fluorine atom or a chlorine atom;
For example, a haloalkyl group having generally 1 or more, and generally 12 or less, preferably 6 or less carbon atoms, such as a trifluoromethyl group;
For example, an alkylthio group having generally 1 or more, and generally 24 or less, preferably 12 or less carbon atoms, such as a methylthio group, or an ethylthio group;
For example, an arylthio group having generally 4 or more, preferably 5 or more, and generally 36 or less, preferably 24 or less, such as a phenylthio group, a naphthylthio group, or a pyridylthio group;
For example, a silyl group having generally 2 or more, preferably 3 or more, and generally 36 or less, preferably 24 or less carbon atoms, such as a trimethylsilyl group, or a triphenylsilyl group;
For example, a siloxy group having generally 2 or more, preferably 3 or more, and generally 36 or less, preferably 24 or less carbon atoms, such as a trimethylsiloxy group, or a triphenylsiloxy group; A cyano group;
For example, an aromatic hydrocarbon group having generally 6 or more, and generally 36 or less, preferably 24 or less carbon atoms, such as a phenyl group, or a naphthyl group;
For example, an aromatic heterocyclic group having generally 3 or more, preferably 4 or more, and generally 36 or less, preferably 24 or less carbon atoms, such as a thienyl group, or a pyridyl group.

Among the substituent group Z2, an alkyl group, an alkoxy group, a diarylamino group, an aromatic hydrocarbon group, or an aromatic heterocyclic group is preferred. From the viewpoint of charge transportability, the substituent is preferably an aromatic hydrocarbon group or an aromatic heterocyclic group, more preferably an aromatic hydrocarbon group, and still more preferably has no substituent. From the viewpoint of improving solubility, the substituent is preferably an alkyl group or an alkoxy group.

Each substituent in the above substituent group Z2 may further have a substituent. Examples of the substituent are the same as those of the above substituent (the substituent group Z2). Each substituent that may be contained in the substituent group Z2 is preferably an alkyl group having 8 or less carbon atoms, an alkoxy group having 8 or less carbon atoms, or a phenyl group, and more preferably an alkyl group having 6 or less carbon atoms, an alkoxy group having 6 or less carbon atoms, or a phenyl group. It is more preferable that each substituent in the substituent group Z2 does not have any further substituent from the viewpoint of charge transportability.

### <Compound Represented by Formula (250)>

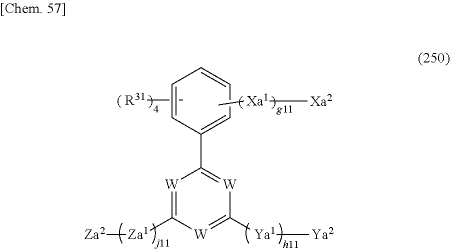

(In the formula (250),
W's each independently represent CH or N, and at least one W represents N,
Xa¹, Ya¹, and Za¹ each independently represent a divalent aromatic hydrocarbon group having 6 to 30 carbon atoms which may have a substituent, or a divalent aromatic heterocyclic group having 3 to 30 carbon atoms which may have a substituent,
Xa², Ya², and Za² each independently represent a hydrogen atom, a monovalent aromatic hydrocarbon group having 6 to 30 carbon atoms which may have a substituent, or a monovalent aromatic heterocyclic group having 3 to 30 carbon atoms which may have a substituent,
g11, h11, and j11 each independently represent an integer of 0 to 6,
at least one of g11, h11, and j11 represents an integer of 1 or more,
when g11 is 2 or more, a plurality of Xa¹'s may be the same as or different from each other,
when h11 is 2 or more, a plurality of Ya¹'s may be the same as or different from each other,
when j11 is 2 or more, a plurality of Za¹'s may be the same as or different from each other,
R³¹ represents a hydrogen atom or a substituent, and four R³¹'s may be the same as or different from each other, and
when g11, h11, or j11 is 0, the respective corresponding Xa², Ya², and Za² are not a hydrogen atom.

In Xa¹, Ya¹, Za¹, Xa², Ya², and Za², the substituent which the aromatic hydrocarbon group having 6 to 30 carbon atoms may have, and the substituent which the aromatic heterocyclic group having 3 to 30 carbon atoms may have are each independently selected from the following substituent group Z2, and the substituent selected from the following substituent group Z2 does not have any further substituent.

### <Substituent Group Z2>

Alkyl group, alkoxy group, aryloxy group, heteroaryloxy group, alkoxycarbonyl group, dialkylamino group, diarylamino group, arylalkylamino group, acyl group, halogen atom, haloalkyl group, alkylthio group, arylthio group, silyl group, siloxy group, cyano group, aromatic hydrocarbon group, and aromatic heterocyclic group

The compound represented by the formula (250) is preferably a charge transport compound, that is, a charge transport host material.

### <W>

W's in the formula (250) each represent CH or N, and at least one W represents N, and it is preferable that at least two W's represent N, and it is more preferable that all W's represent N, from the viewpoint of electron transportability and electron durability.

<Xa¹, Ya¹, Za¹, Xa², Ya², Za²>

In the formula (250), when Xa¹, Ya¹, and Za¹ each represent a divalent aromatic hydrocarbon group having 6 to 30 carbon atoms which may have a substituent, and when Xa², Ya², and Za² each represent an aromatic hydrocarbon group having 6 to 30 carbon atoms which may have a substituent, the aromatic hydrocarbon ring of the aromatic hydrocarbon group having 6 to 30 carbon atoms is preferably a 6-membered monocyclic ring or a 2- to 5-fused ring. Specific examples thereof include a benzene ring, a naphthalene ring, an anthracene ring, a phenanthrene ring, a fluorene ring, a perylene ring, a tetracene ring, a pyrene ring, a benzpyrene ring, a chrysene ring, a triphenylene ring, a fluoranthene ring, and an indenofluorene ring. Among them, a benzene ring, a naphthalene ring, an anthracene ring, a phenanthrene ring, or a fluorene ring is preferred, a benzene ring, a naphthalene ring, a phenanthrene ring, or a fluorene ring is more preferred, and a benzene ring, a naphthalene ring, or a fluorene ring is still more preferred. -Xa¹-Xa², which is a terminal partial structure when g11 is 2 or more, -Ya¹-Ya², which is a terminal partial structure when h11 is 2 or more, and -Za¹-Za², which is a terminal partial structure when j11 is 2 or more, may be a spirofluorene structure. In the compound represented by the formula (250), it is preferable that at least one of -Xa¹-Xa², which is a terminal partial structure when g11 is 2 or more, -Ya¹-Ya², which is a terminal partial structure when h11 is 2 or more, and -Za¹-Za², which is a terminal partial structure when j11 is 2 or more, is a spirofluorene structure.

In the formula (250), when Xa¹, Ya¹, and Za¹ each represent a divalent aromatic heterocyclic group having 3 to 30 carbon atoms which may have a substituent, and when Xa², Ya², and Za² each represent an aromatic heterocyclic group having 3 to 30 carbon atoms which may have a substituent, the aromatic heterocyclic ring of the aromatic heterocyclic group having 3 to 30 carbon atoms is preferably a 5- or 6-membered monocyclic ring or a 2- to 5-membered fused ring. Specific examples thereof include a furan ring, a benzofuran ring, a dibenzofuran ring, a thiophene ring, a benzothiophene ring, a dibenzothiophene ring, a pyrrole ring, a pyrazole ring, an imidazole ring, an oxadiazole ring, an indole ring, a carbazole ring, an indolocarbazole ring, an indenocarbazole ring, a pyrroloimidazole ring, a pyrrolopyrazole ring, a pyrrolopyrrole ring, a thienopyrrole ring, a thienothiophene ring, a phropyrrole ring, a furofuran ring, a thienofuran ring, a benzisooxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinoline ring, a quinoxaline ring, a perimidine ring, a quinazoline ring, and a quinazolinone ring. Among them, preferred are a thiophene ring, a pyrrole ring, an imidazole ring, a pyridine ring, a pyrimidine ring, a triazine ring, a quinoline ring, a quinazoline ring, a carbazole ring, a dibenzofuran ring, a dibenzothiophene ring, an indolocarbazole ring, a phenanthroline ring, or an indenocarbazole ring, more preferred are a pyridine ring, a pyrimidine ring, a triazine ring, a quinoline ring, a quinazoline ring, a carbazole ring, an indolocarbazole ring, an indenocarbazole ring, a dibenzofuran ring, or a dibenzothiophene ring, and still more preferred are a carbazole ring, an indolocarbazole ring, a dibenzofuran ring, or a dibenzothiophene ring.

In Xa¹, Ya¹, Za¹, Xa², Ya², and Za² in the formula (250), the aromatic hydrocarbon ring is particularly preferably a benzene ring, a naphthalene ring, or a phenanthrene ring, and the aromatic heterocyclic ring is particularly preferably a carbazole ring, a dibenzofuran ring, or a dibenzothiophene ring.

In the formula (250), in Xa¹, Ya¹, Za¹, Xa², Ya² and Za², the substituent which the aromatic hydrocarbon group having 6 to 30 carbon atoms may have, and the substituent which the aromatic heterocyclic group having 3 to 30 carbon atoms may have are each independently selected from the substituent group Z2, and the substituent selected from the substituent group Z2 does not have any further substituent. It is considered that when the substituent selected from the substituent group Z2 does not have any further substituent, high charge transportability and durability can be maintained.

Among the substituent group Z2, from the viewpoint of charge transportability and durability, an aromatic hydrocarbon group and an aromatic heterocyclic group are preferred, and an aromatic hydrocarbon group is particularly preferred.

### <Substituent Group Z2>

Alkyl group, alkoxy group, aryloxy group, heteroaryloxy group, alkoxycarbonyl group, dialkylamino group, diarylamino group, arylalkylamino group, acyl group, halogen atom, haloalkyl group, alkylthio group, arylthio group, silyl group, siloxy group, cyano group, aromatic hydrocarbon group, and aromatic heterocyclic group

<g11, h11, j11>

g11, h11, and j11 each independently represent an integer of 0 to 6, and at least one of g11, h11, and j11 is an integer of 1 or more. From the viewpoint of charge transportability and durability, g11 is preferably 2 or more, or at least one of h11 and j11 is preferably 3 or more.

The compound represented by the formula (250) preferably has a total of 8 to 18 of these rings, including rings having three W's at the center, from the viewpoint of charge transportability, durability, and solubility in an organic solvent.

<(Xa¹)_{g11}, (Ya¹)ₕ₁₁, (Za¹)ⱼ₁₁>

From the viewpoint of the solubility and durability of the compound, it is preferable that at least one group selected from (Xa¹)_{g11}, (Ya¹)ₕ₁₁, and (Za¹)ⱼ₁₁ has a partial structure selected from a partial structure represented by the following formula (11), a partial structure represented by the following formula (12), and a partial structure represented by the following formula (13), and it is more preferable that (Xa¹)_{g11} when g11 is 1 or more, (Ya¹)ₕ₁₁ when h11 is 1 or more, and (Za¹)ⱼ₁₁ when j11 is 1 or more each independently have a partial structure selected from a partial structure represented by the following formula (11), a partial structure represented by the following formula (12), and a partial structure represented by the following formula (13).

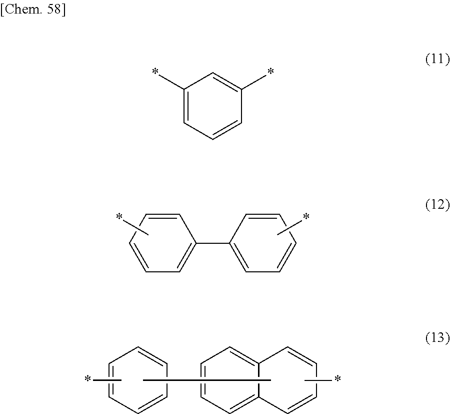

In each of the formulae (11) to (13), * represents a bond with an adjacent structure, or when Xa², Ya², or Za² in the formula (250) represents a hydrogen atom, * represents the hydrogen atom. At least one of two present *'s represents a bonding site with an adjacent structure. In the following description, the definition of * is the same unless otherwise specified.

More preferably, (Xa¹)_{g11} when g11 is 1 or more, (Ya¹)ₕ₁₁ when h11 is 1 or more, and (Za¹)ⱼ₁₁ when j11 is 1 or more each independently have a partial structure represented by the formula (11) or a partial structure represented by the formula (12).

Still more preferably, (Xa¹)_{g11} when g11 is 1 or more, (Ya¹)ₕ₁₁ when h11 is 1 or more, and (Za¹)ⱼ₁₁ when j11 is 1 or more each independently have a partial structure represented by the formula (11) and a partial structure represented by the formula (12).

The partial structure represented by the formula (12) is preferably a partial structure represented by the following formula (12-2).

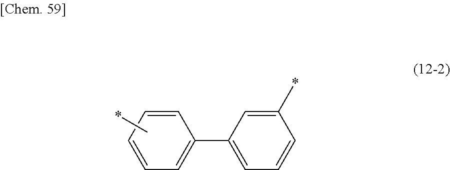

The partial structure represented by the formula (12) is more preferably a partial structure represented by the following formula (12-3).

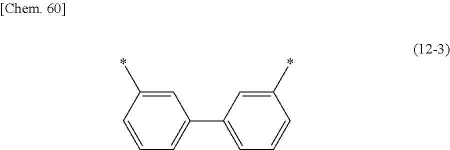 [SMILES: *c1cccc(-c2cccc(*)c2)c1]

As the partial structure having the partial structure represented by the formula (11) and the partial structure represented by the formula (12), from the viewpoint of solubility, a partial structure selected from the following formulae (14) to (17), which is a structure containing a plurality of structures selected from the partial structure represented by the formula (11) and the partial structure represented by the formula (12), is preferred. That is, (Xa¹)_{g11} when g11 is 1 or more, (Ya¹)ₕ₁₁ when h11 is 1 or more, and (Za¹)ⱼ₁₁ when j11 is 1 or more each independently have a partial structure selected from the formulae (11) to (13) and the following formulae (14) to (17). In other words, from the viewpoint of solubility, it is preferable that (Xa¹)_{g11} when g11 is 1 or more, (Ya¹)ₕ₁₁ when h11 is 1 or more, and (Za¹)ⱼ₁₁ when j11 is 1 or more each independently have a partial structure selected from the formulae (11) to (17).

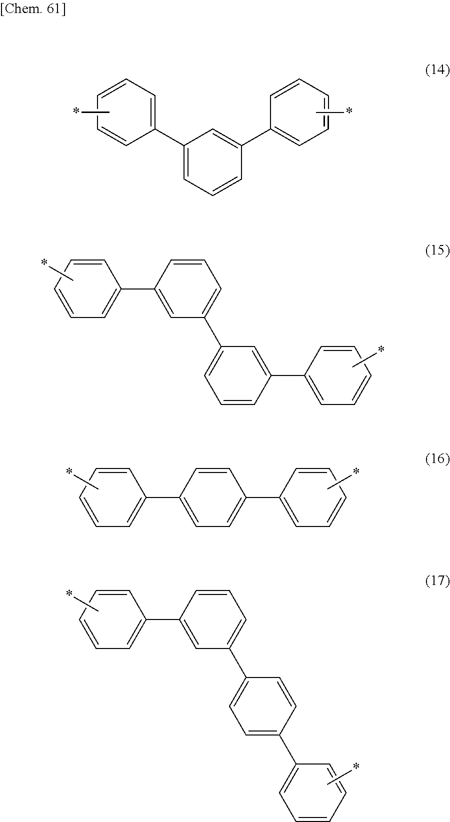

The structure containing a plurality of structures selected from the partial structure represented by the formula (11) and the partial structure represented by the formula (12) is, for example, a partial structure represented by the formula (14) which can be regarded as having one partial structure represented by the formula (11) and two partial structures represented by the formula (12) as in the following formula (14a).

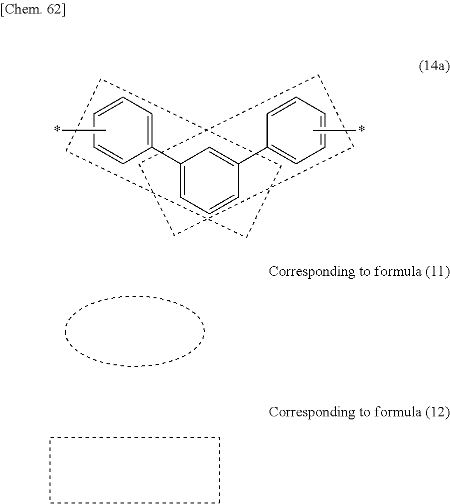

More preferably, at least one of (Xa¹)_{g11}, (Ya¹)ₕ₁₁, and (Za¹)ⱼ₁₁ has at least the partial structure represented by the formula (14) or the partial structure represented by the formula (15). Still more preferably, (Xa¹)_{g11} when g11 is 1 or more, (Ya¹)ₕ₁₁ when h11 is 1 or more, and (Za¹)ⱼ₁₁ when j11 is 1 or more each have the partial structure represented by the formula (14) or the partial structure represented by formula (15).

The partial structure represented by the formula (14) is preferably a partial structure represented by the following formula (14-2).

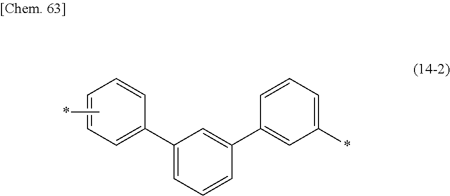

The partial structure represented by the formula (14) is more preferably a partial structure represented by the following formula (14-3).

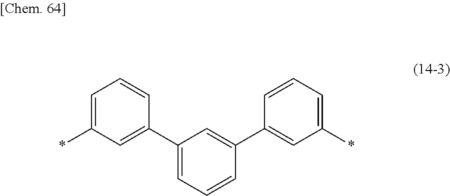 [SMILES: *c1cccc(-c2cccc(-c3cccc(*)c3)c2)c1]

The partial structure represented by the formula (15) is preferably a partial structure represented by the following formula (15-2).

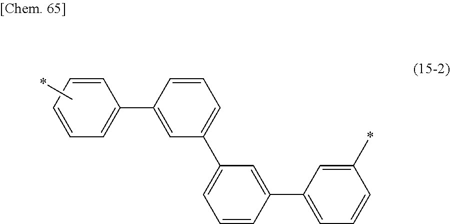

The partial structure represented by the formula (15) is more preferably a partial structure represented by the following formula (15-3).

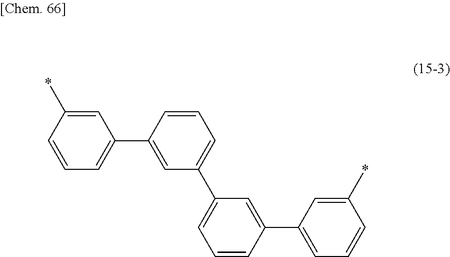 [SMILES: *c1cccc(-c2cccc(-c3cccc(-c4cccc(*)c4)c3)c2)c1]

The partial structure represented by the formula (17) is preferably a partial structure represented by the following formula (17-2).

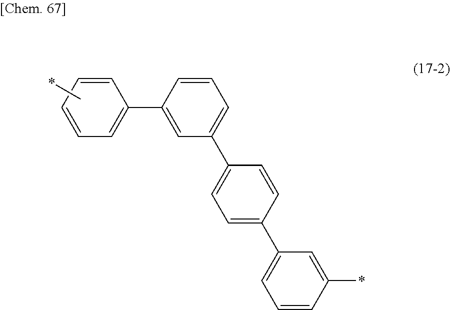

It is more preferable that at least one of (Xa¹)_{g11}, (Ya¹)ₕ₁₁, and (Za¹)ⱼ₁₁ has a partial structure represented by the following formula (19) or a partial structure represented by the following formula (20) as the partial structure containing the partial structure represented by the formula (13).

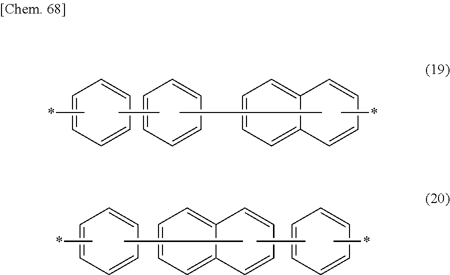

In each of the formulae (14) to (20), * represents a bond with an adjacent structure, or when Xa², Ya², or Za² represents a hydrogen atom, * represents the hydrogen atom. At least one of two present *'s represents a bonding site with an adjacent structure.

Among the partial structures each represented by the formulae (14) to (20), the partial structure represented by the formula (14-3) and the partial structure represented by the formula (15-3) are preferred, and the partial structure represented by the formula (14-3) is more preferred.

It is preferable that -(Xa¹)_{g11}-(Xa²), -(Ya¹)ₕ₁₁-(Ya²), and -(Za¹)ⱼ₁₁-(Za²) each independently have the partial structure represented by the formula (11), the partial structure represented by the formula (12-3), the partial structure represented by the formula (14-3), or the partial structure represented by the formula (15-3).

It is more preferable that at least one of -(Xa¹)_{g11}-(Xa²), -(Ya¹)ₕ₁₁-(Ya²), and -(Za¹)ⱼ₁₁-(Za²) has any one of partial structures or terminal structures each represented by the following formulae (250-1) to (250-10).

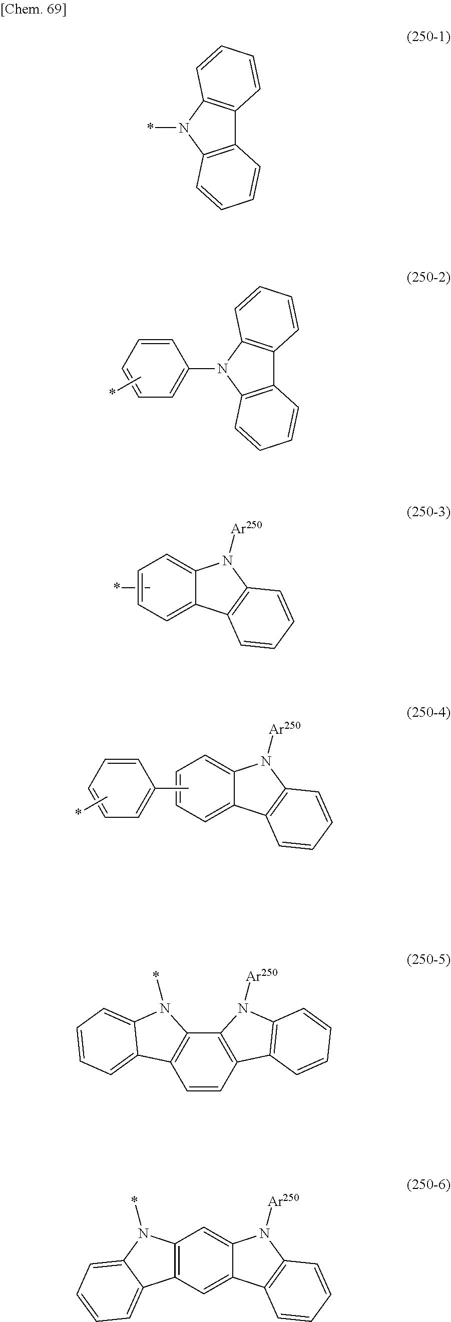

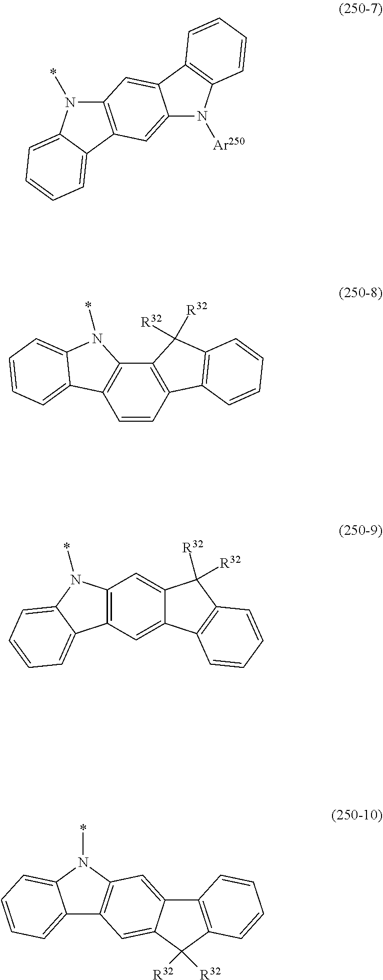

[In the formula (250-1) to formula (250-10), * represents a bonding site. Ar²⁵⁰ represents an aromatic hydrocarbon group having 6 to 20 carbon atoms. R³² represents a substituent, and the structures each represented by the formula (250-1) to formula (250-10) may further have a substituent.]

The substituents which these structures may have are the same as those of R³².

Ar²⁵⁰ preferably represents an aromatic hydrocarbon group having 6 to 20 carbon atoms, more preferably represents a phenyl group or a biphenyl group, and still more preferably represents a phenyl group.

In a structure having two R³²'s, the two R³²'s may be the same as or different from each other.

R³² preferably represents an alkyl group having 1 to 20 carbon atoms, an aralkyl group having 7 to 40 carbon atoms, an alkoxy group having 1 to 20 carbon atoms, an aryloxy group having 6 to 20 carbon atoms, an alkylsilyl group having 1 to 20 carbon atoms, an arylsilyl group having 6 to 20 carbon atoms, an aryl group having 6 to 30 carbon atoms which may be substituted with an alkyl group having 1 to 8 carbon atoms, or a heteroaryl group having 3 to 30 carbon atoms which may be substituted with an alkyl group having 1 to 8 carbon atoms, more preferably represents an alkyl group having 1 to 20 carbon atoms groups, an aralkyl group having 7 to 40 carbon atoms, an alkoxy group having 1 to 20 carbon atoms, an aryloxy group having 6 to 20 carbon atoms, and an aryl group having 6 to 30 carbon atoms which may be substituted with an alkyl group having 1 to 8 carbon atoms, and still more preferably represents an alkyl group having 1 to 8 carbon atoms, an aralkyl group having 7 to 20 carbon atoms, an alkoxy group having 1 to 8 carbon atoms, an aryloxy group having 6 to 14 carbon atoms, and an aryl group having 6 to 14 carbon atoms which may be substituted with an alkyl group having 1 to 8 carbon atoms.

### <R³¹>

R³¹ in the case of a substituent preferably represents an aromatic hydrocarbon group having 6 to 30 carbon atoms which may have a substituent, or an aromatic heterocyclic group having 3 to 30 carbon atoms which may have a substituent. From the viewpoint of improvement in durability and charge transportability, R³¹ more preferably represents an aromatic hydrocarbon group which may have a substituent. When a plurality of R³¹'s are present in the case of a substituent, R³¹'s may be different from each other.

The substituent which the aromatic hydrocarbon group having 6 to 30 carbon atoms may have, the substituent which the aromatic heterocyclic group having 3 to 30 carbon atoms may have, and the substituent which R³¹ as a substituent may have can be selected from the above substituent group Z2.

From the viewpoint of charge transportability, R³¹ preferably represents a hydrogen atom.

From the viewpoint of solubility, it is preferable that -(Ya¹)ₕ₁₁-(Ya²) and -(Za¹)ⱼ₁₁-(Za²) do not simultaneously represent an unsubstituted phenyl group.

### <Molecular Weight>

The compound represented by the formula (250) is a low molecular weight material, and has a molecular weight of preferably 3,000 or less, more preferably 2,500 or less, particularly preferably 2,000 or less, and most preferably 1,500 or less. A lower limit of the molecular weight of the compound is generally 400 or more, preferably 500 or more, and more preferably 600 or more.

### <Specific Examples of Compound Represented by Formula (250)>

The compound represented by the formula (250) is not particularly limited, and examples thereof include the following compounds.

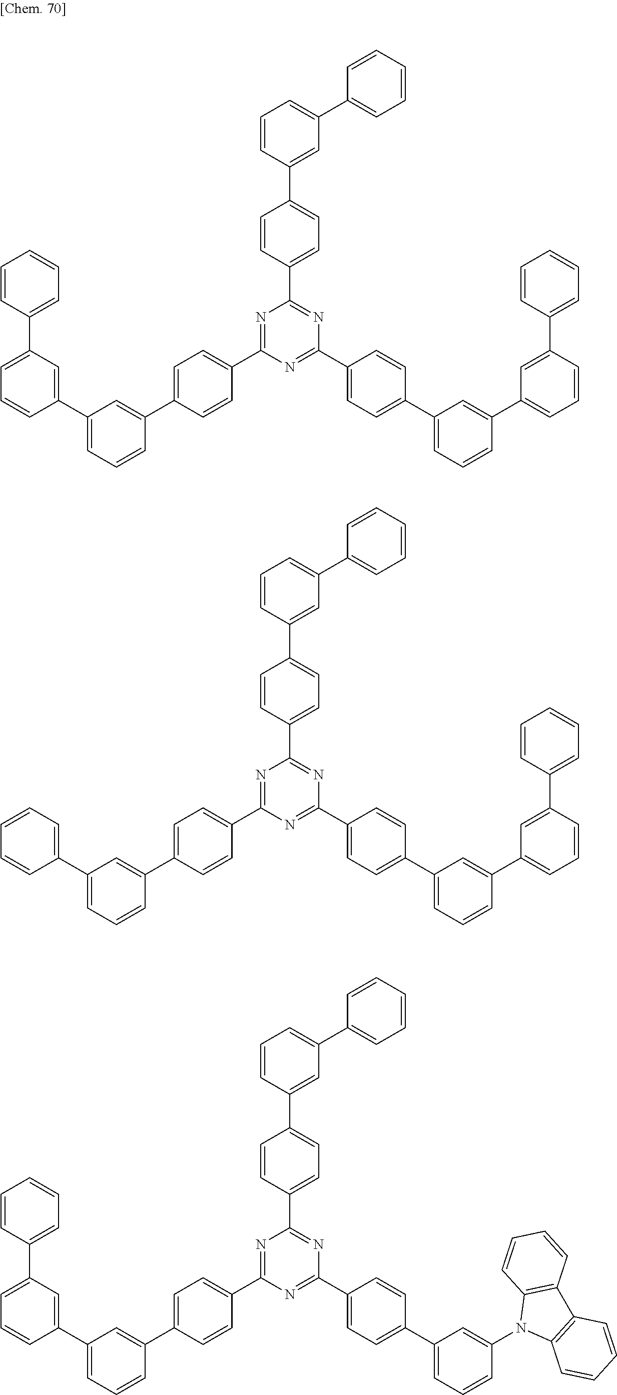 [SMILES: c1ccc(-c2cccc(-c3ccc(-c4nc(-c5ccc(-c6cccc(-c7cccc(-c8ccccc8)c7)c6)cc5)nc(-c5ccc(-c6cccc(-c7cccc(-c8ccccc8)c7)c6)cc5)n4)cc3)c2)cc1 ; c1ccc(-c2cccc(-c3ccc(-c4nc(-c5ccc(-c6cccc(-c7ccccc7)c6)cc5)nc(-c5ccc(-c6cccc(-c7cccc(-c8ccccc8)c7)c6)cc5)n4)cc3)c2)cc1 ; c1ccc(-c2cccc(-c3ccc(-c4nc(-c5ccc(-c6cccc(-c7cccc(-c8ccccc8)c7)c6)cc5)nc(-c5ccc(-c6cccc(-n7c8ccccc8c8ccccc87)c6)cc5)n4)cc3)c2)cc1]

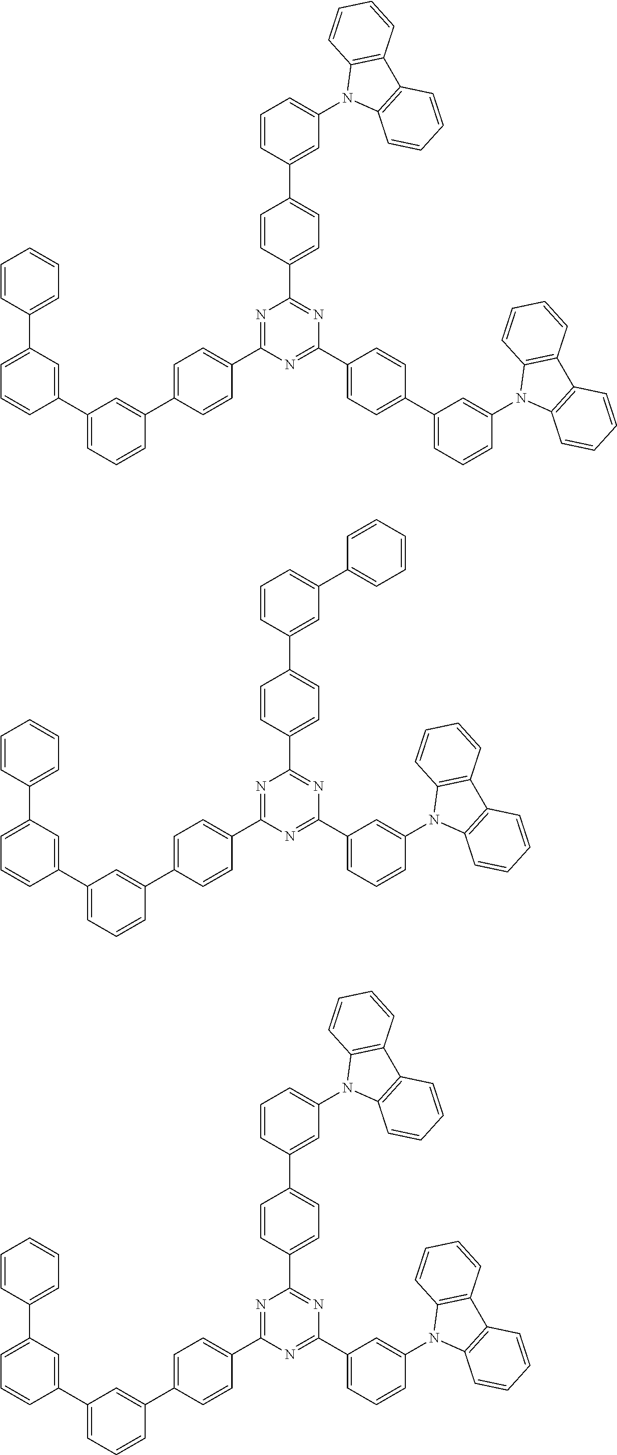 [SMILES: c1ccc(-c2cccc(-c3cccc(-c4ccc(-c5nc(-c6ccc(-c7cccc(-n8c9ccccc9c9ccccc98)c7)cc6)nc(-c6ccc(-c7cccc(-n8c9ccccc9c9ccccc98)c7)cc6)n5)cc4)c3)c2)cc1 ; c1ccc(-c2cccc(-c3ccc(-c4nc(-c5ccc(-c6cccc(-c7cccc(-c8ccccc8)c7)c6)cc5)nc(-c5cccc(-n6c7ccccc7c7ccccc76)c5)n4)cc3)c2)cc1 ; c1ccc(-c2cccc(-c3cccc(-c4ccc(-c5nc(-c6ccc(-c7cccc(-n8c9ccccc9c9ccccc98)c7)cc6)nc(-c6cccc(-n7c8ccccc8c8ccccc87)c6)n5)cc4)c3)c2)cc1]

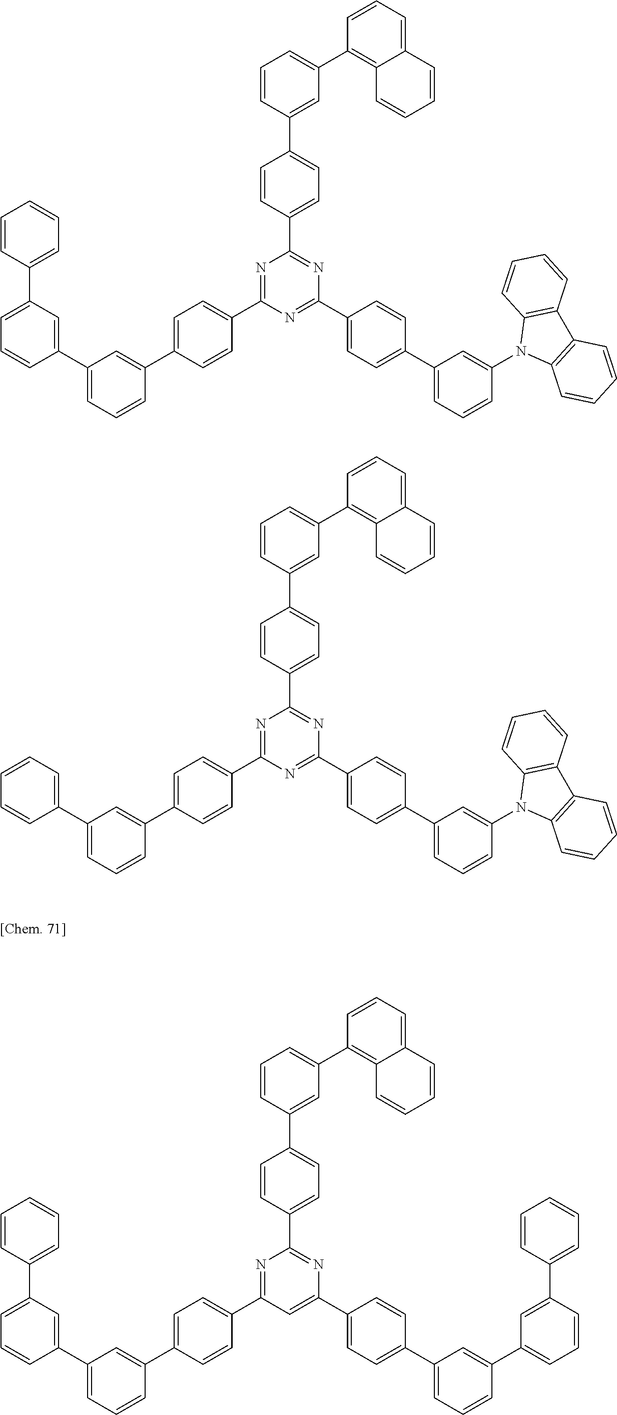 [SMILES: c1ccc(-c2cccc(-c3cccc(-c4ccc(-c5nc(-c6ccc(-c7cccc(-c8cccc9ccccc89)c7)cc6)nc(-c6ccc(-c7cccc(-n8c9ccccc9c9ccccc98)c7)cc6)n5)cc4)c3)c2)cc1 ; c1ccc(-c2cccc(-c3ccc(-c4nc(-c5ccc(-c6cccc(-c7cccc8ccccc78)c6)cc5)nc(-c5ccc(-c6cccc(-n7c8ccccc8c8ccccc87)c6)cc5)n4)cc3)c2)cc1 ; c1ccc(-c2cccc(-c3cccc(-c4ccc(-c5cc(-c6ccc(-c7cccc(-c8cccc(-c9ccccc9)c8)c7)cc6)nc(-c6ccc(-c7cccc(-c8cccc9ccccc89)c7)cc6)n5)cc4)c3)c2)cc1]

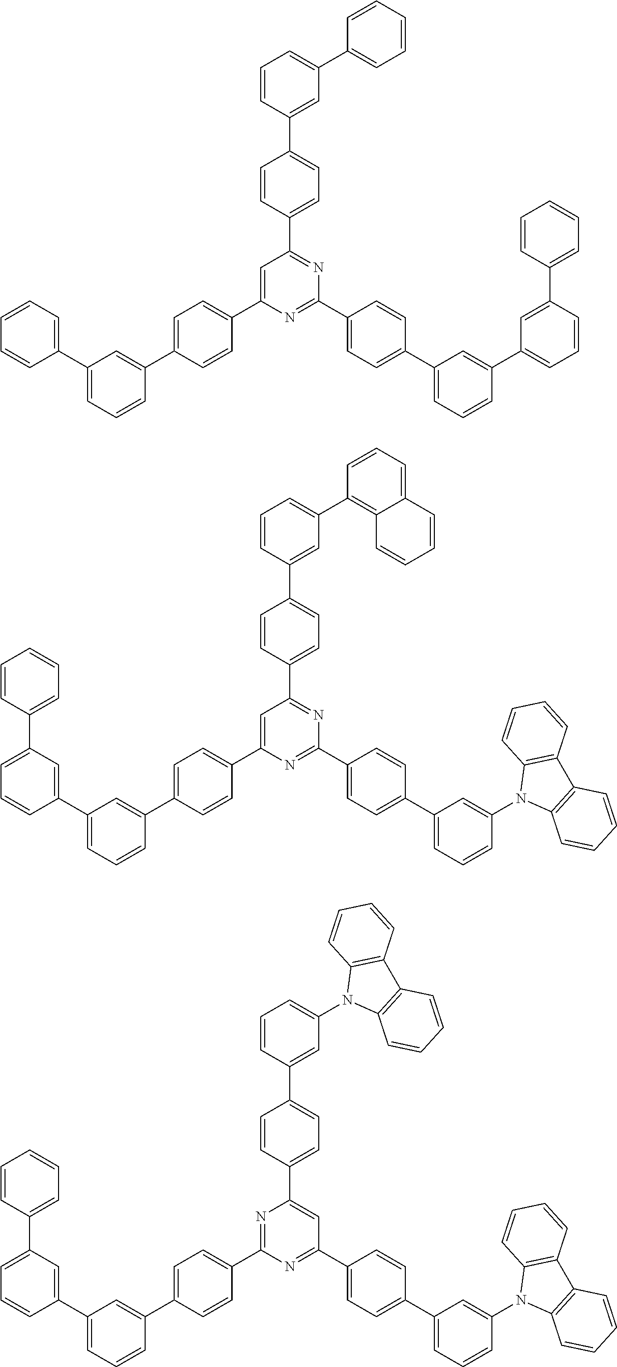 [SMILES: c1ccc(-c2cccc(-c3ccc(-c4cc(-c5ccc(-c6cccc(-c7ccccc7)c6)cc5)nc(-c5ccc(-c6cccc(-c7cccc(-c8ccccc8)c7)c6)cc5)n4)cc3)c2)cc1 ; c1ccc(-c2cccc(-c3cccc(-c4ccc(-c5cc(-c6ccc(-c7cccc(-c8cccc9ccccc89)c7)cc6)nc(-c6ccc(-c7cccc(-n8c9ccccc9c9ccccc98)c7)cc6)n5)cc4)c3)c2)cc1 ; c1ccc(-c2cccc(-c3cccc(-c4ccc(-c5nc(-c6ccc(-c7cccc(-n8c9ccccc9c9ccccc98)c7)cc6)cc(-c6ccc(-c7cccc(-n8c9ccccc9c9ccccc98)c7)cc6)n5)cc4)c3)c2)cc1]

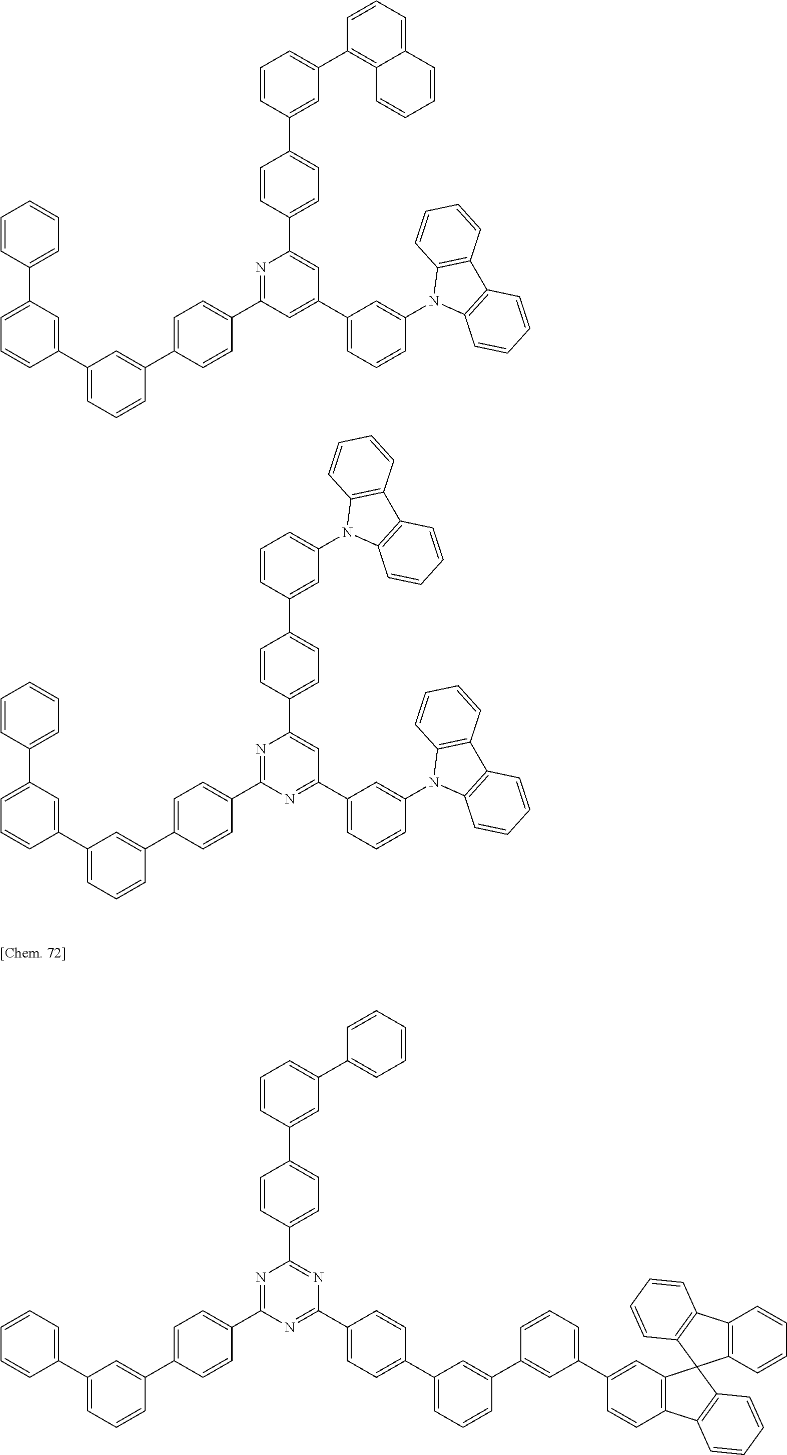 [SMILES: c1ccc(-c2cccc(-c3cccc(-c4ccc(-c5cc(-c6cccc(-n7c8ccccc8c8ccccc87)c6)cc(-c6ccc(-c7cccc(-c8cccc9ccccc89)c7)cc6)n5)cc4)c3)c2)cc1 ; c1ccc(-c2cccc(-c3cccc(-c4ccc(-c5nc(-c6ccc(-c7cccc(-n8c9ccccc9c9ccccc98)c7)cc6)cc(-c6cccc(-n7c8ccccc8c8ccccc87)c6)n5)cc4)c3)c2)cc1 ; c1ccc(-c2cccc(-c3ccc(-c4nc(-c5ccc(-c6cccc(-c7ccccc7)c6)cc5)nc(-c5ccc(-c6cccc(-c7cccc(-c8ccc9c(c8)C8(c%10ccccc%10-c%10ccccc%108)c8ccccc8-9)c7)c6)cc5)n4)cc3)c2)cc1]

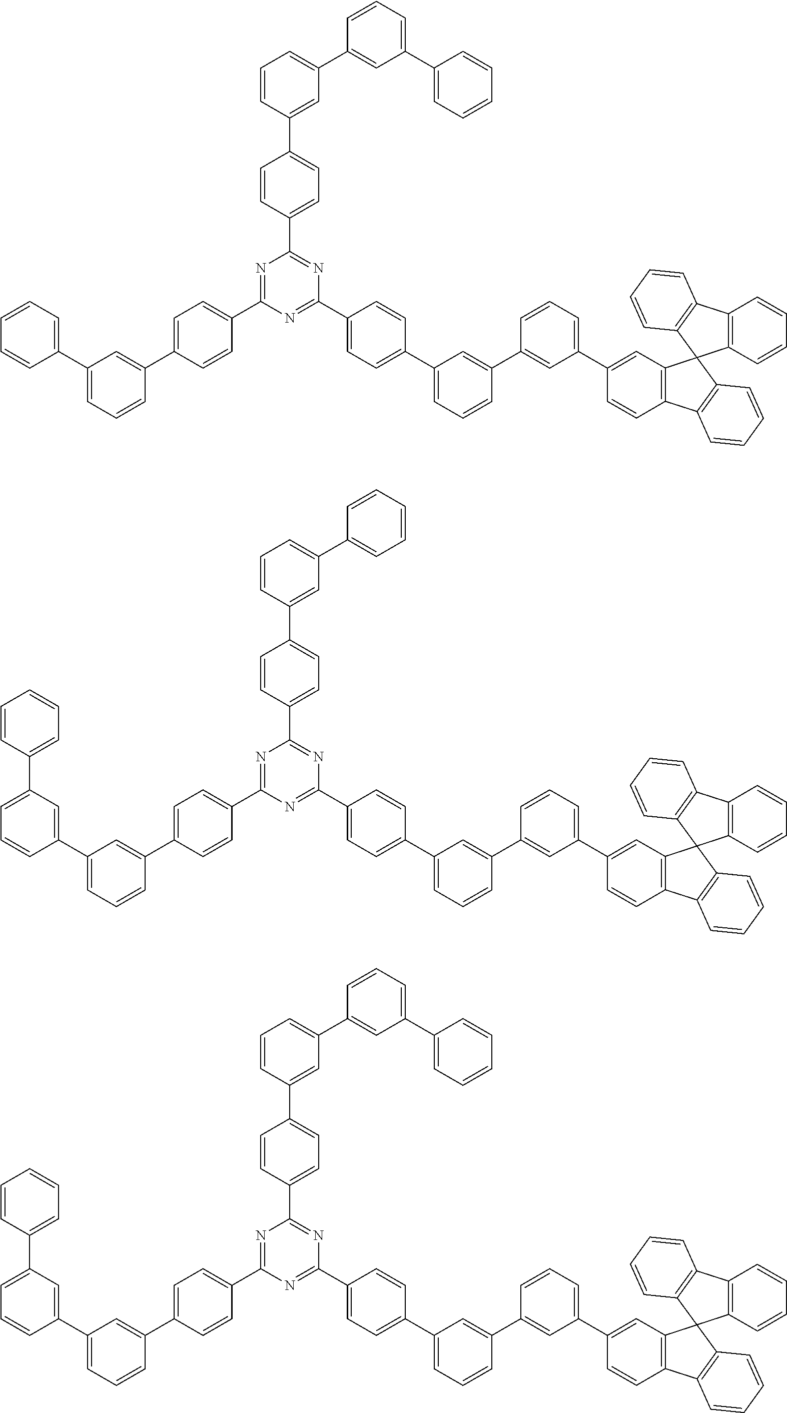

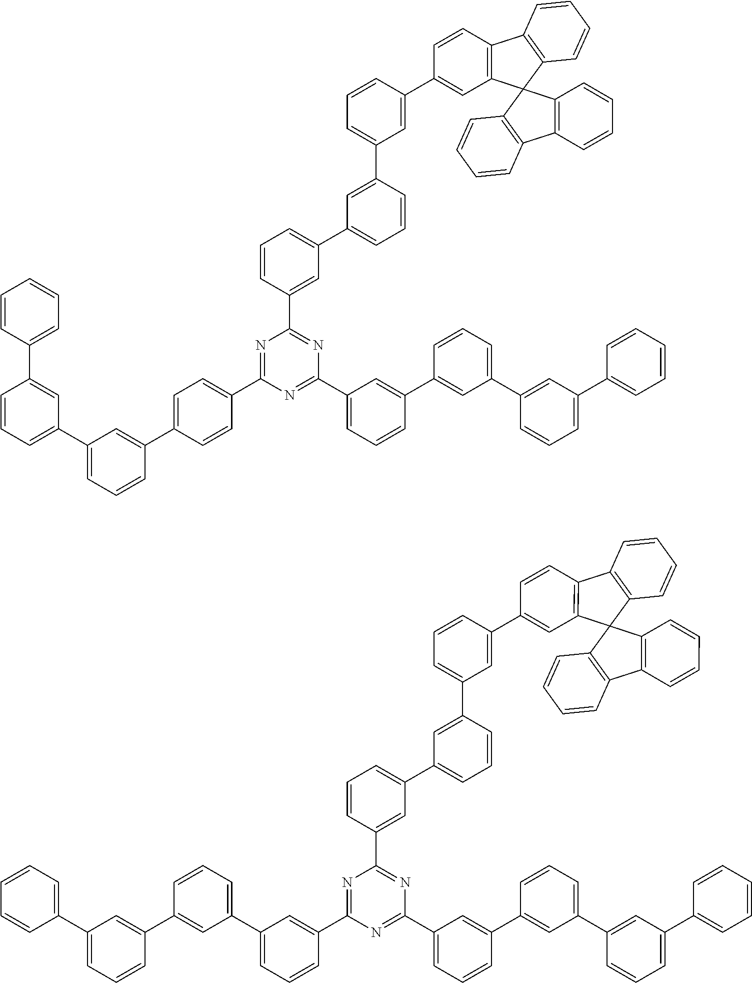 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-c7cccc(-c8cccc(-c9ccc%10c(c9)C9(c%11ccccc%11-c%11ccccc%119)c9ccccc9-%10)c8)c7)c6)n5)cc4)c3)c2)cc1 ; c1ccc(-c2cccc(-c3cccc(-c4cccc(-c5nc(-c6cccc(-c7cccc(-c8cccc(-c9ccccc9)c8)c7)c6)nc(-c6cccc(-c7cccc(-c8cccc(-c9ccc%10c(c9)C9(c%11ccccc%11-c%11ccccc%119)c9ccccc9-%10)c8)c7)c6)n5)c4)c3)c2)cc1]

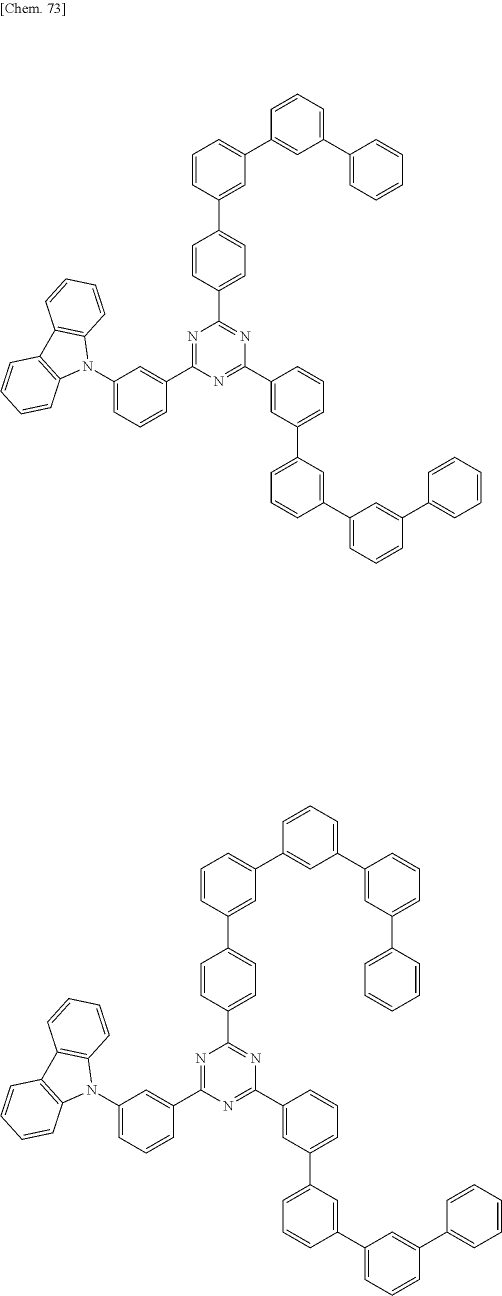 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-n7c8ccccc8c8ccccc87)c6)n5)cc4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-n8c9ccccc9c9ccccc98)c7)n6)cc5)c4)c3)c2)cc1]

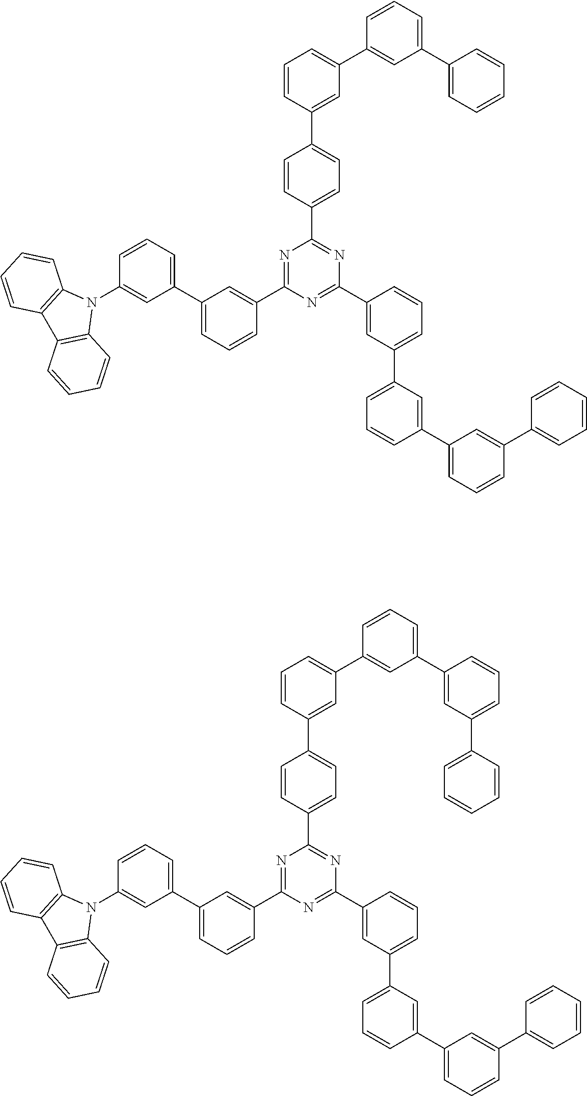 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-c7cccc(-n8c9ccccc9c9ccccc98)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-c8cccc(-n9c%10ccccc%10c%10ccccc%109)c8)c7)n6)cc5)c4)c3)c2)cc1]

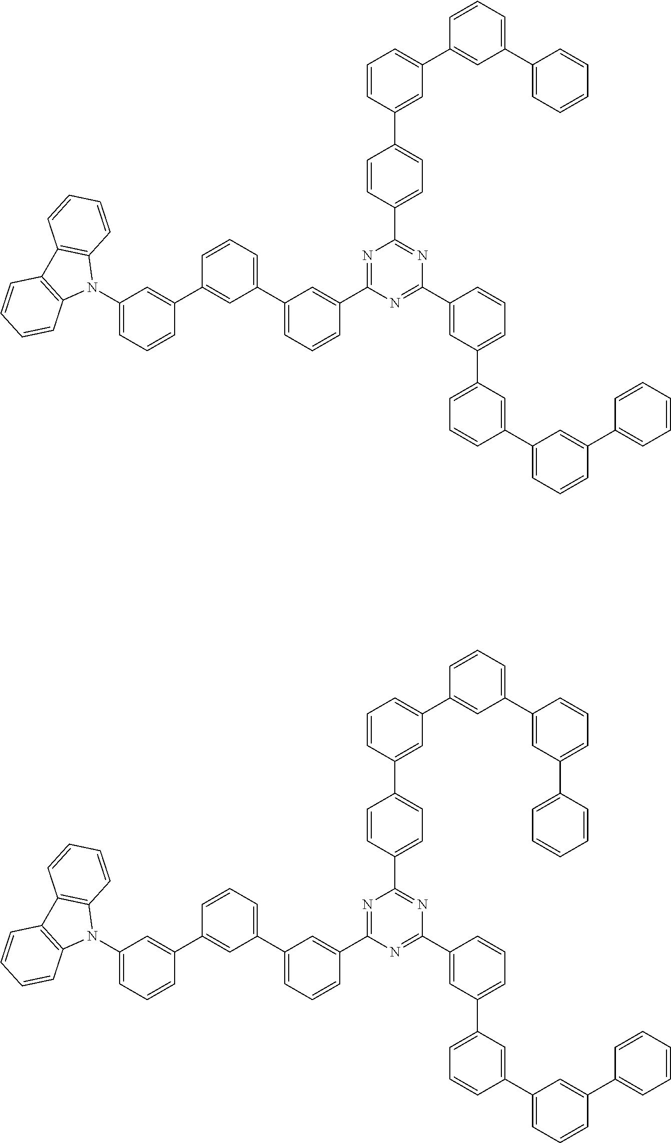 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-c8cccc(-c9cccc(-n%10c%11ccccc%11c%11ccccc%11%10)c9)c8)c7)n6)cc5)c4)c3)c2)cc1]

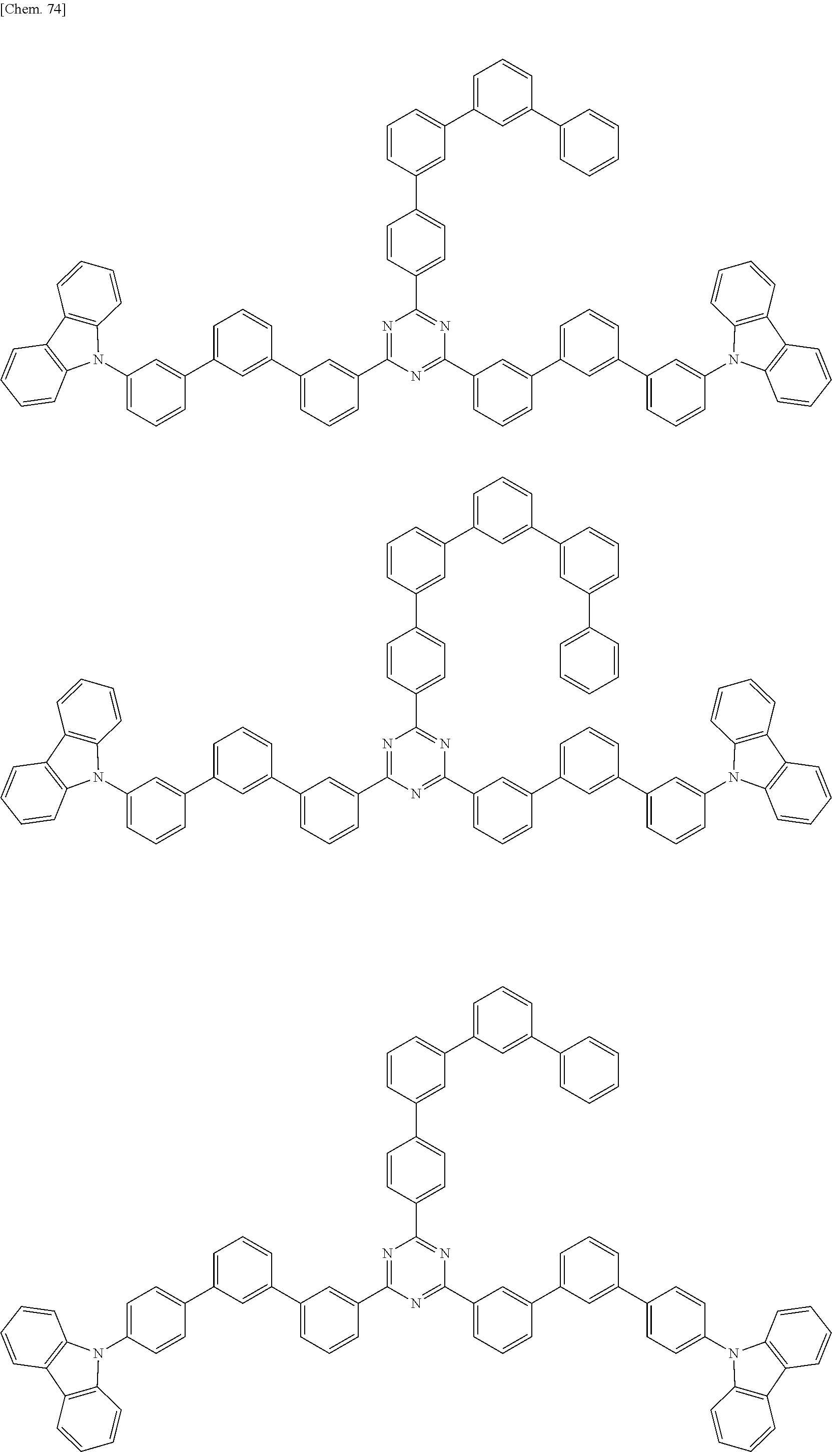

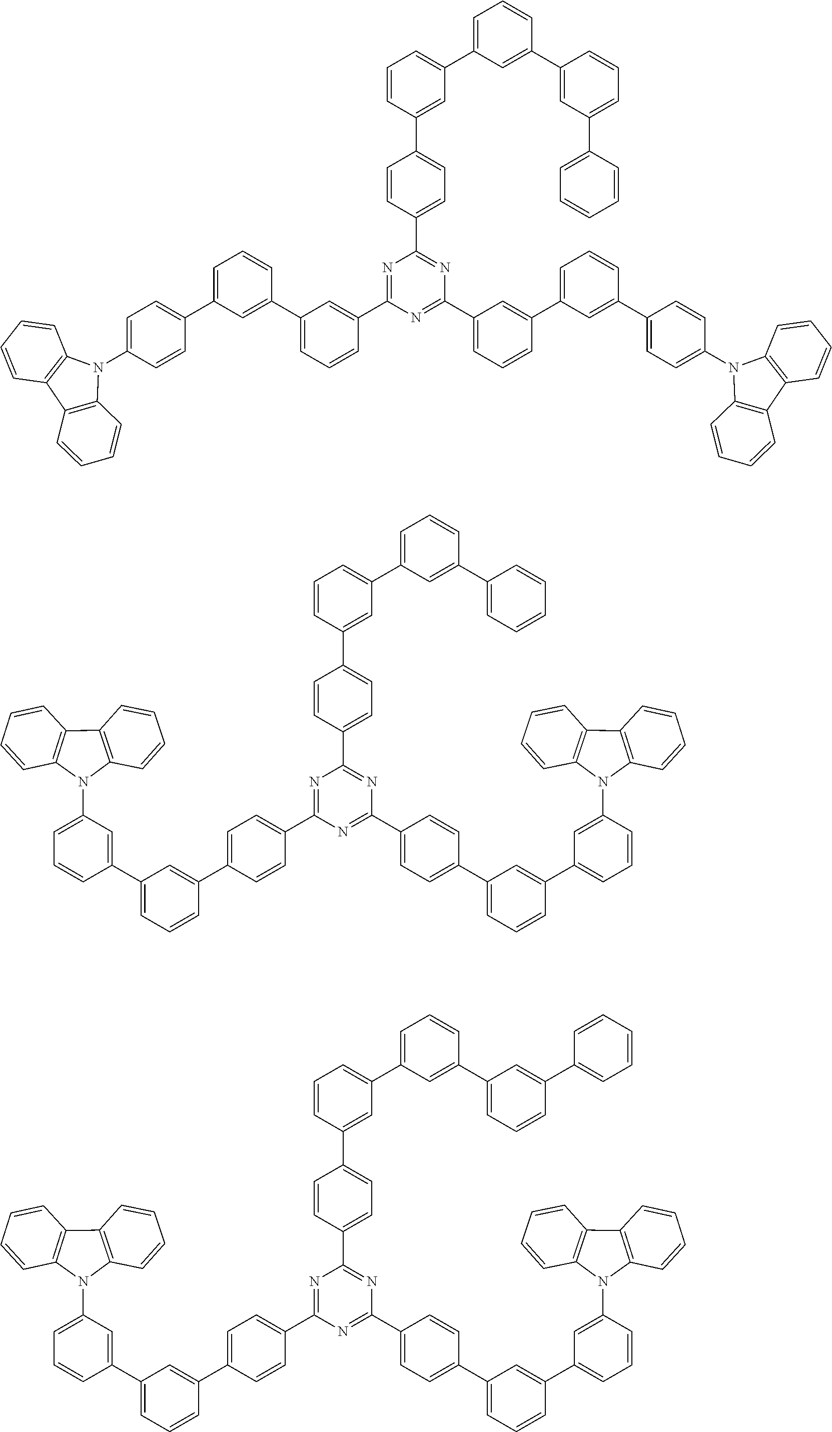

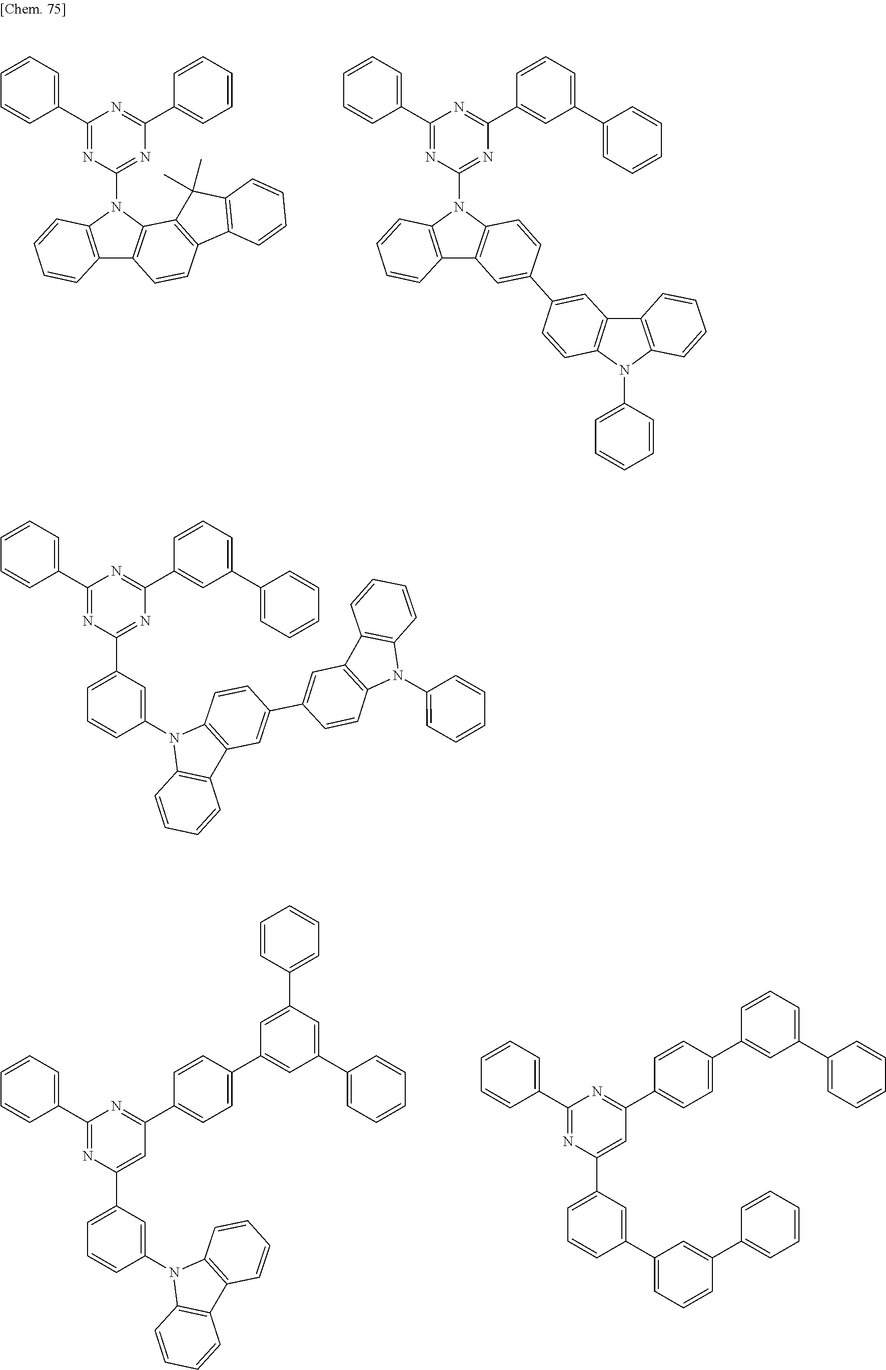 [SMILES: CC1(C)c2ccccc2-c2ccc3c4ccccc4n(-c4nc(-c5ccccc5)nc(-c5ccccc5)n4)c3c21 ; c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-c2cccc(-c3nc(-c4ccccc4)nc(-c4cccc(-n5c6ccccc6c6cc(-c7ccc8c(c7)c7ccccc7n8-c7ccccc7)ccc65)c4)n3)c2)cc1 ; c1ccc(-c2cc(-c3ccccc3)cc(-c3ccc(-c4cc(-c5cccc(-n6c7ccccc7c7ccccc76)c5)nc(-c5ccccc5)n4)cc3)c2)cc1 ; c1ccc(-c2cccc(-c3ccc(-c4cc(-c5cccc(-c6cccc(-c7ccccc7)c6)c5)nc(-c5ccccc5)n4)cc3)c2)cc1]

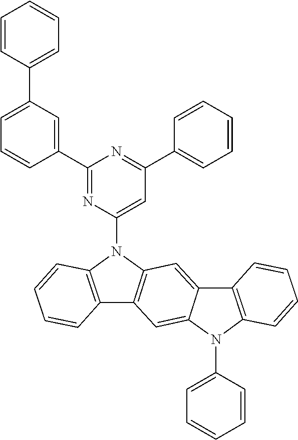 [SMILES: c1ccc(-c2cccc(-c3nc(-c4ccccc4)cc(-n4c5ccccc5c5cc6c(cc54)c4ccccc4n6-c4ccccc4)n3)c2)cc1]

The organic electroluminescent element material of the present invention may contain only one type of compound represented by the formula (250), or may contain two or more types thereof.

### <Compound Represented by Formula (240)>

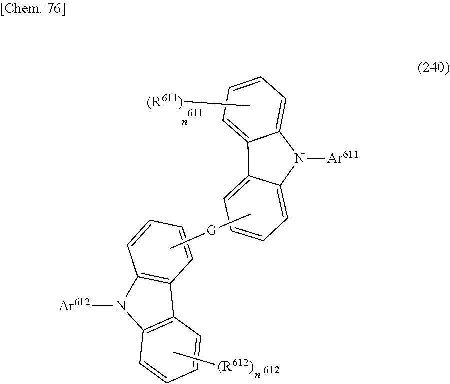

(In the formula (240),
Ar⁶¹¹ and Ar⁶¹² each independently represent a monovalent aromatic hydrocarbon group having 6 to 50 carbon atoms which may have a substituent,
R⁶¹¹ and R⁶¹² each independently represent a deuterium atom, a halogen atom, or a monovalent aromatic hydrocarbon group having 6 to 50 carbon atoms which may have a substituent,
G represents a single bond, or a divalent aromatic hydrocarbon group having 6 to 50 carbon atoms which may have a substituent, and
n⁶¹¹ and n⁶¹² each independently represent an integer of 0 to 4.)
   <Ar⁶¹¹ and Ar⁶¹²>

Ar⁶¹¹ and Ar⁶¹² each independently represent a monovalent aromatic hydrocarbon group having 6 to 50 carbon atoms which may have a substituent.

The number of carbon atoms of the aromatic hydrocarbon group is preferably 6 to 50, more preferably 6 to 30, and still more preferably 6 to 18. Specific examples of the aromatic hydrocarbon group include a monovalent group having an aromatic hydrocarbon structure having generally 6 or more, and generally 30 or less, preferably 18 or less, and more preferably 14 or less carbon atoms, such as a benzene ring, a naphthalene ring, an anthracene ring, a tetraphenylene ring, a phenanthrene ring, a chrysene ring, a pyrene ring, a benzoanthracene ring, or a perylene ring, or a monovalent group having a structure in which a plurality of structures selected from these structures are bonded in a chain or branched manner. When a plurality of aromatic hydrocarbon rings are linked, generally, examples thereof include a structure in which 2 to 8 aromatic hydrocarbon rings are linked, and a structure in which 2 to 5 aromatic hydrocarbon rings are linked is preferred. When a plurality of aromatic hydrocarbon rings are linked, the same structure may be linked or different structures may be linked.

Ar⁶¹¹ and Ar⁶¹² preferably each independently represent
a phenyl group,
a monovalent group in which a plurality of benzene rings are bonded in a chain or branched manner,
a monovalent group in which one or more benzene rings and at least one naphthalene ring are bonded in a chain or branched manner,
a monovalent group in which one or more benzene rings and at least one phenanthrene ring are bonded in a chain or branched manner, or
a monovalent group in which one or more benzene rings and at least one tetraphenylene ring are bonded in a chain or branched manner, and
more preferably each independently represent a monovalent group in which a plurality of benzene rings are bonded in a chain or branched manner, and in either case, the order of bonding does not matter.

It is particularly preferable that Ar⁶¹¹ and Ar⁶¹² each independently represent a monovalent group in which a plurality of benzene rings which may have a substituent are bonded in a chain or branched manner, and it is most preferable that Ar⁶¹¹ and Ar⁶¹² each independently represent a monovalent group in which a plurality of benzene rings which may have a substituent are bonded in a chain or branched manner.

The number of benzene rings, naphthalene rings, phenanthrene rings, and tetraphenylene rings to be bonded is generally 2 to 8, and preferably 2 to 5, as described above. Among them, a monovalent structure in which 1 to 4 benzene rings are linked, a monovalent structure in which 1 to 4 benzene rings and a naphthalene ring are linked, a monovalent structure in which 1 to 4 benzene rings and a phenanthrene ring are linked, or a monovalent structure in which 1 to 4 benzene rings and a tetraphenylene ring are linked is preferred.

The aromatic hydrocarbon group may have a substituent. The substituent which the aromatic hydrocarbon group may have is as described above, and specifically, can be selected from the substituent group Z2. Preferred substituents are the preferred substituents in the above substituent group Z2.

From the viewpoint of the solubility and durability of the compound, it is preferable that at least one of Ar⁶¹¹ and Ar⁶¹² has a partial structure selected from the following formulae (11) to (13) and (21) to (24), and it is more preferable that Ar⁶¹¹ and Ar⁶¹² each independently have a partial structure selected from the following formulae (11) to (13) and (21) to (24).

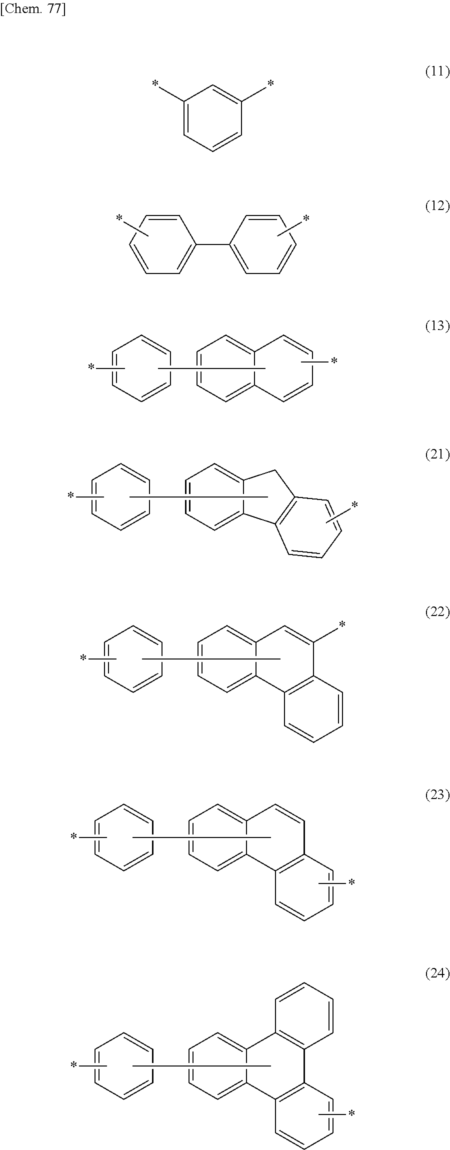

In each of the formulae (11) to (13) and (21) to (24), * represents a bond with an adjacent structure or a hydrogen atom, and at least one of two present *'s represents a bonding site with an adjacent structure. In the following description, the definition of * is the same unless otherwise specified.

More preferably, Ar⁶¹¹ and Ar⁶¹² each independently have the partial structure represented by the formula (11) or the partial structure represented by the formula (12).

Still more preferably, Ar⁶¹¹ and Ar⁶¹² each independently have the partial structure represented by the formula (11) and the partial structure represented by the formula (12).

The partial structure represented by the formula (12) is preferably a partial structure represented by the following formula (12-2).

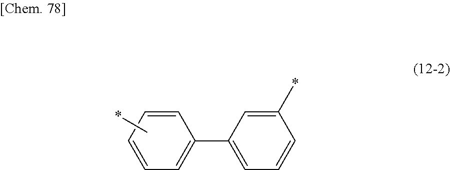

The partial structure represented by the formula (12) is more preferably a partial structure represented by the following formula (12-3).

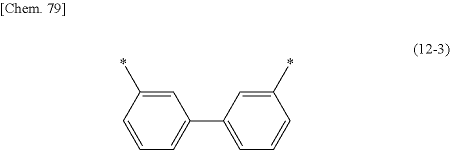 [SMILES: *c1cccc(-c2cccc(*)c2)c1]

As the partial structure having the partial structure represented by the formula (11) and the partial structure represented by the formula (12), a partial structure selected from the following formulae (14) to (17), which is a structure containing a plurality of structures selected from the partial structure represented by the formula (11) and the partial structure represented by the formula (12), is preferred. That is, it is preferable that Ar⁶¹¹ and Ar⁶¹² each independently have a partial structure selected from the formulae (11) to (13) and the following formulae (14) to (17).

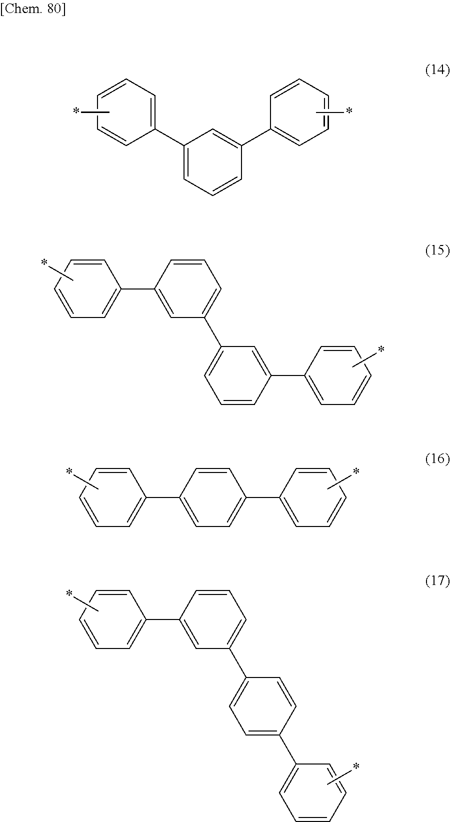

The structure containing a plurality of structures selected from the partial structure represented by the formula (11) and the partial structure represented by the formula (12) is, for example, a partial structure represented by the formula (14) which can be regarded as having one partial structure represented by the formula (11) and two partial structures represented by the formula (12) as in the following formula (14a).

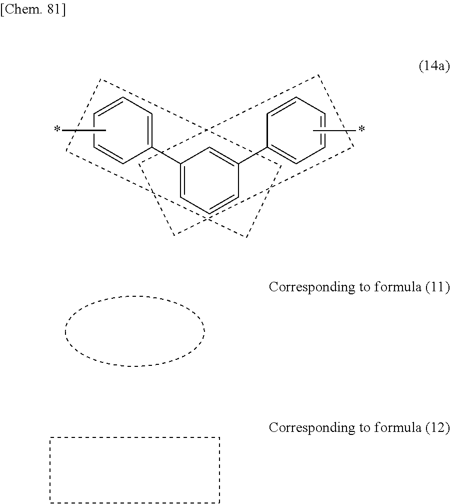

More preferably, at least one of Ar⁶¹¹ and Ar⁶¹² has the partial structure represented by the formula (14) or the partial structure represented by the formula (15). Still more preferably, Ar⁶¹¹ and Ar⁶¹² each have the partial structure represented by the formula (14) or the partial structure represented by the formula (15).

The partial structure represented by the formula (14) is preferably a partial structure represented by the following formula (14-2).

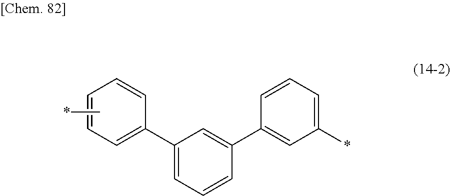

The partial structure represented by the formula (14) is more preferably a partial structure represented by the following formula (14-3).

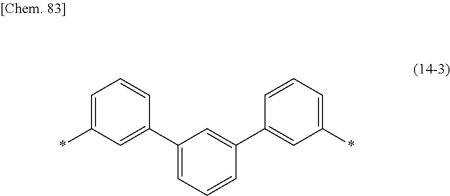 [SMILES: *c1cccc(-c2cccc(-c3cccc(*)c3)c2)c1]

The partial structure represented by the formula (15) is preferably a partial structure represented by the following formula (15-2).

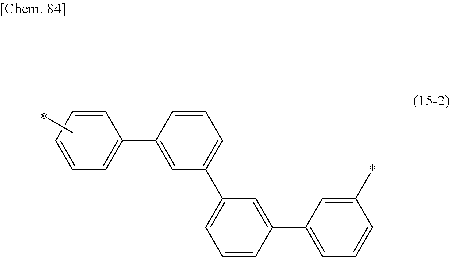

The partial structure represented by the formula (15) is more preferably a partial structure represented by the following formula (15-3).

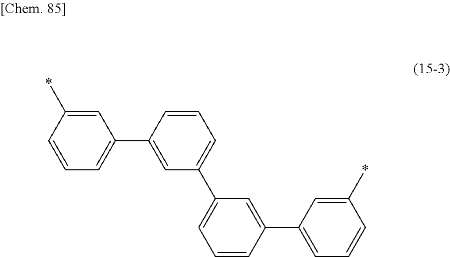 [SMILES: *c1cccc(-c2cccc(-c3cccc(-c4cccc(*)c4)c3)c2)c1]

The partial structure represented by the formula (17) is preferably a partial structure represented by the following formula (17-2).

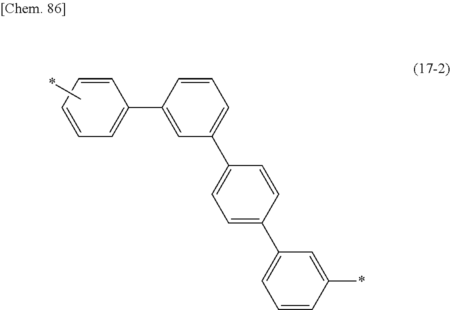

It is more preferable that at least one of Ar⁶¹¹ and Ar⁶¹² has a partial structure represented by the following formula (19) or a partial structure represented by the following formula (20) as the partial structure containing the partial structure represented by the formula (13).

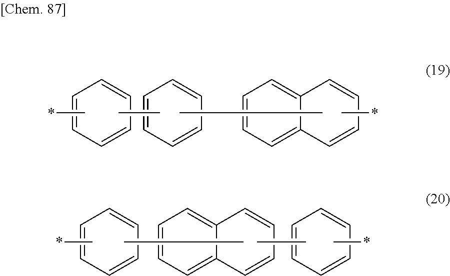

In each of the formulae (14) to (20), * represents a bond with an adjacent structure or a hydrogen atom. At least one of two present *'s represents a bonding site with an adjacent structure.

Among the partial structures each represented by the formulae (14) to (20), the partial structure represented by the formula (14-3) and the partial structure represented by the formula (15-3) are preferred, and the partial structure represented by the formula (14-3) is more preferred.

It is preferable that Ar⁶¹¹ and Ar⁶¹² each independently have the partial structure represented by the formula (11), the partial structure represented by the formula (12-3), the partial structure represented by the formula (14-3), or the partial structure represented by the formula (15-3).

<R⁶¹¹ and R⁶¹²>

R⁶¹¹ and R⁶¹² each independently represent a deuterium atom, a halogen atom such as a fluorine atom, or a monovalent aromatic hydrocarbon having 6 to 50 carbon atoms which may have a substituent.

A monovalent aromatic hydrocarbon group having 6 to 50 carbon atoms which may have a substituent is preferred.

Examples of the aromatic hydrocarbon group include a monovalent group having an aromatic hydrocarbon structure having more preferably 6 to 30, still more preferably 6 to 18, and particularly preferably 6 to 10 carbon atoms.

Specific examples of the monovalent aromatic hydrocarbon group are the same as those of Ar⁶¹¹, a preferred aromatic hydrocarbon group is also the same, and a phenyl group is particularly preferred.

The aromatic hydrocarbon group may have a substituent. The substituent which the aromatic hydrocarbon group may have is as described above, and specifically, can be selected from the substituent group Z2. Preferred substituents are the preferred substituents in the above substituent group Z2.

<n⁶¹¹ and n⁶¹²>

n⁶¹¹ and n⁶¹² each independently represent an integer of 0 to 4. It is preferable that n⁶¹¹ and n⁶¹² each independently represent 0 to 2, and it is more preferable that n⁶¹¹ and n⁶¹² each independently represent 0 or 1.

When Ar⁶¹¹ is an unsubstituted phenyl group, n⁶¹¹ is an integer of 1 to 4, and when Ar⁶¹² is an unsubstituted phenyl group, n⁶¹² is preferably an integer of 1 to 4, from the viewpoint of having high solubility in an organic solvent.

### <Substituent>

When Ar⁶¹¹, Ar⁶¹², R⁶¹¹, and R⁶¹² each represent a monovalent aromatic hydrocarbon group, the substituent which they may have is preferably a substituent selected from the substituent group Z2.

### <G>

G represents a single bond or a divalent aromatic hydrocarbon group having 6 to 50 carbon atoms which may have a substituent.

The number of carbon atoms of the aromatic hydrocarbon group of G is preferably 6 to 50, more preferably 6 to 30, and still more preferably 6 to 18. Specific examples of the aromatic hydrocarbon group include a divalent group having an aromatic hydrocarbon structure having generally 6 or more and generally 30 or less, preferably 18 or less, and more preferably 14 or less carbon atoms, such as a benzene ring, a naphthalene ring, an anthracene ring, a tetraphenylene ring, a phenanthrene ring, a chrysene ring, a pyrene ring, a benzoanthracene ring, or a perylene ring, or a divalent group having a structure in which a plurality of structures selected from these structures are bonded in a chain or branched manner. When a plurality of aromatic hydrocarbon rings are linked, generally, examples thereof include a structure in which 2 to 8 aromatic hydrocarbon rings are linked, and a structure in which 2 to 5 aromatic hydrocarbon rings are linked is preferred. When a plurality of aromatic hydrocarbon rings are linked, the same structure may be linked or different structures may be linked.

G is preferably a single bond, a phenylene group, a divalent group in which a plurality of benzene rings are bonded in a chain or branched manner, a divalent group in which one or more benzene rings and at least one naphthalene ring are bonded in a chain or branched manner, a divalent group in which one or more benzene rings and at least one phenanthrene ring are bonded in a chain or branched manner, or
a divalent group in which one or more benzene rings and at least one tetraphenylene ring are bonded in a chain or branched manner, and more preferably each independently represent a divalent group in which a plurality of benzene rings are bonded in a chain or branched manner, and in either case, the order of bonding does not matter.

The number of benzene rings, naphthalene rings, phenanthrene rings and tetraphenylene rings to be bonded is generally 2 to 8, and preferably 2 to 5, as described above. Among them, a divalent structure in which 1 to 4 benzene rings are linked, a divalent structure in which 1 to 4 benzene rings and a naphthalene ring are linked, a divalent structure in which 1 to 4 benzene rings and a phenanthrene ring are linked, or a divalent structure in which 1 to 4 benzene rings and a tetraphenylene ring are linked is more preferred.

The aromatic hydrocarbon group may have a substituent. The substituent which the aromatic hydrocarbon group may have is as described above, and specifically, can be selected from the substituent group Z2. Preferred substituents are the preferred substituents in the above substituent group Z2.

### <Molecular Weight>

The compound represented by the formula (240) is a low molecular weight material, and has a molecular weight of preferably 3,000 or less, more preferably 2,500 or less, still more preferably 2,000 or less, particularly preferably 1,500 or less, and generally 400 or more, preferably 500 or more, and more preferably 600 or more.

### <Specific Examples of Compound IV Represented by the Formula (240)>

Preferred specific examples of a compound IV represented by the formula (240) are shown below, and the present invention is not limited thereto.

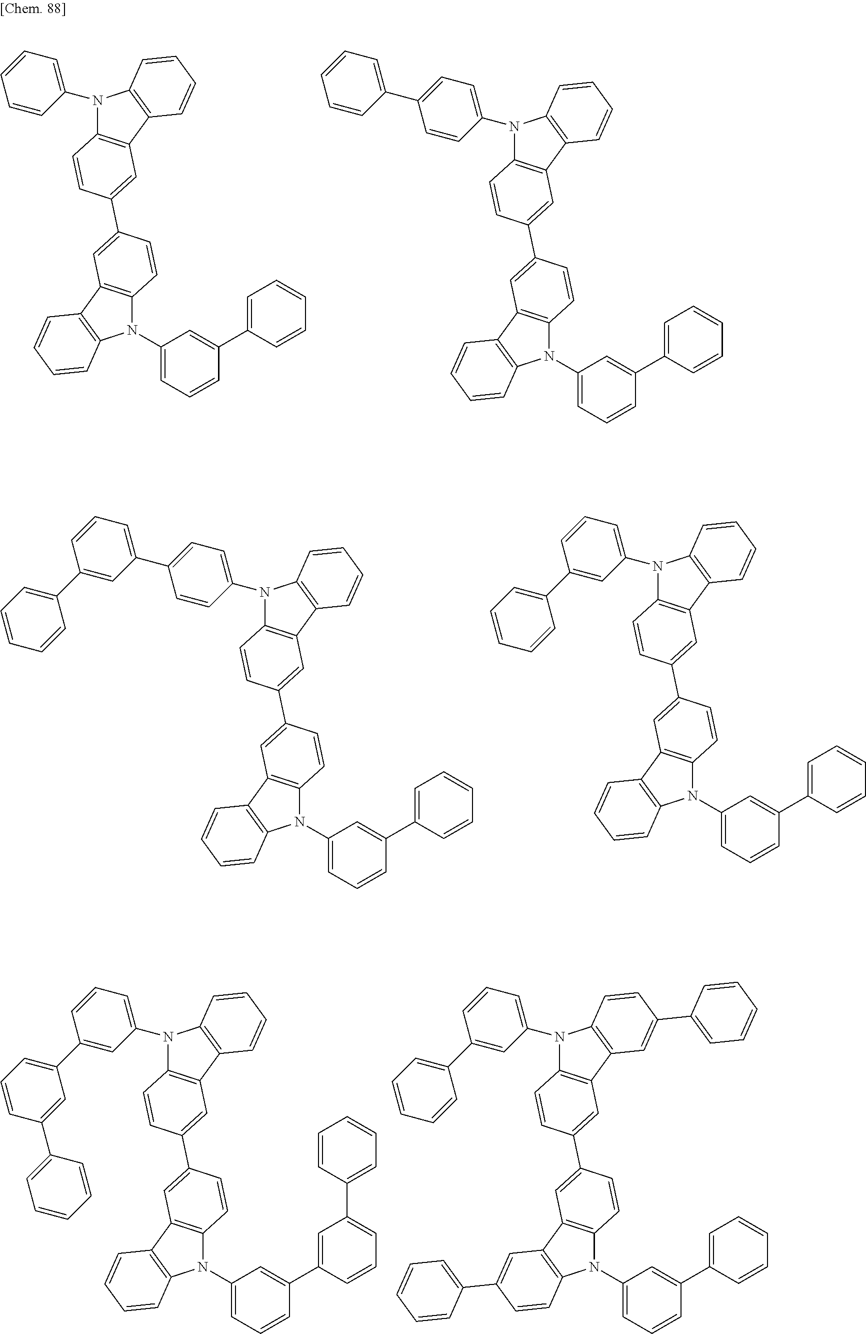

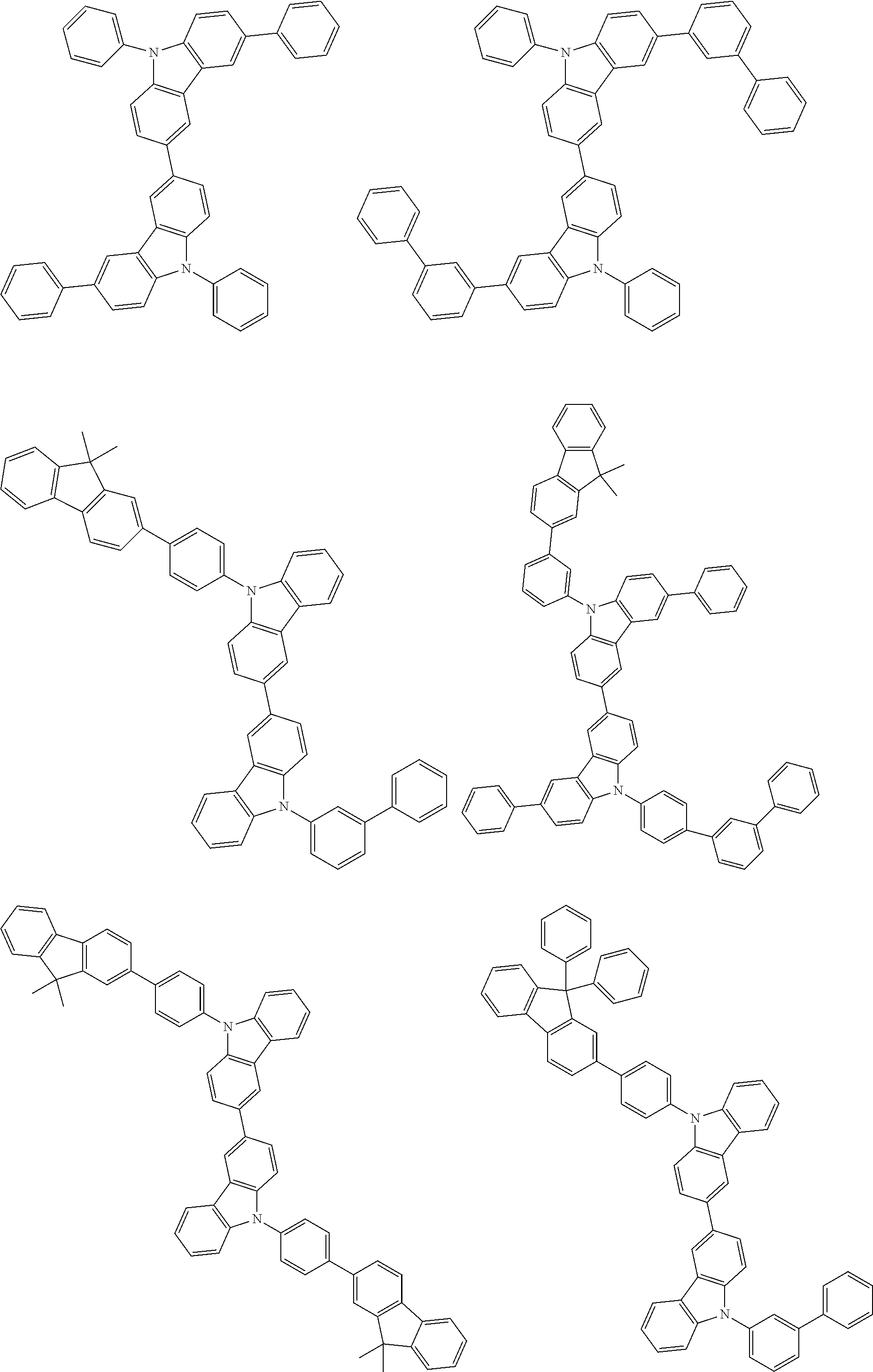

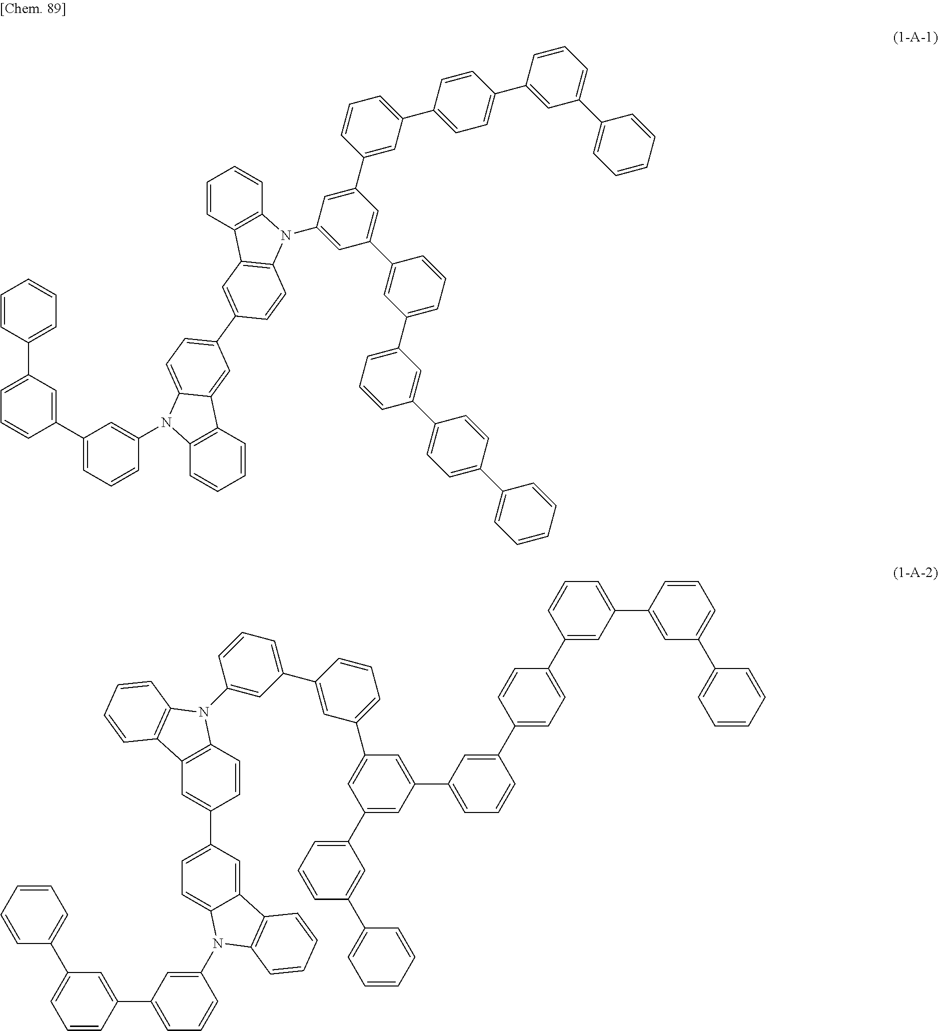 [SMILES: c1ccc(-c2ccc(-c3cccc(-c4cccc(-c5cc(-c6cccc(-c7ccc(-c8cccc(-c9ccccc9)c8)cc7)c6)cc(-n6c7ccccc7c7cc(-c8ccc9c(c8)c8ccccc8n9-c8cccc(-c9cccc(-c%10ccccc%10)c9)c8)ccc76)c5)c4)c3)cc2)cc1 ; c1ccc(-c2cccc(-c3cccc(-c4ccc(-c5cccc(-c6cc(-c7cccc(-c8ccccc8)c7)cc(-c7cccc(-c8cccc(-n9c%10ccccc%10c%10cc(-c%11ccc%12c(c%11)c%11ccccc%11n%12-c%11cccc(-c%12cccc(-c%13ccccc%13)c%12)c%11)ccc%109)c8)c7)c6)c5)cc4)c3)c2)cc1]

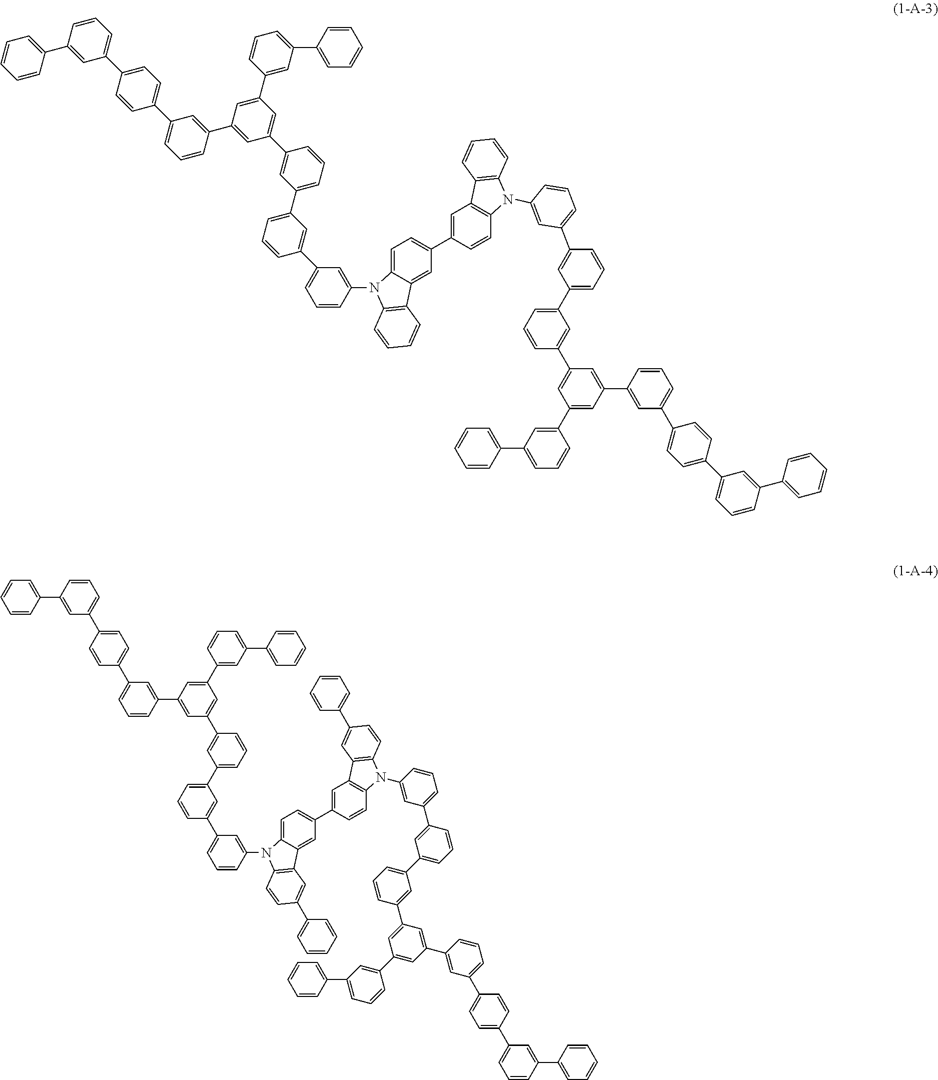

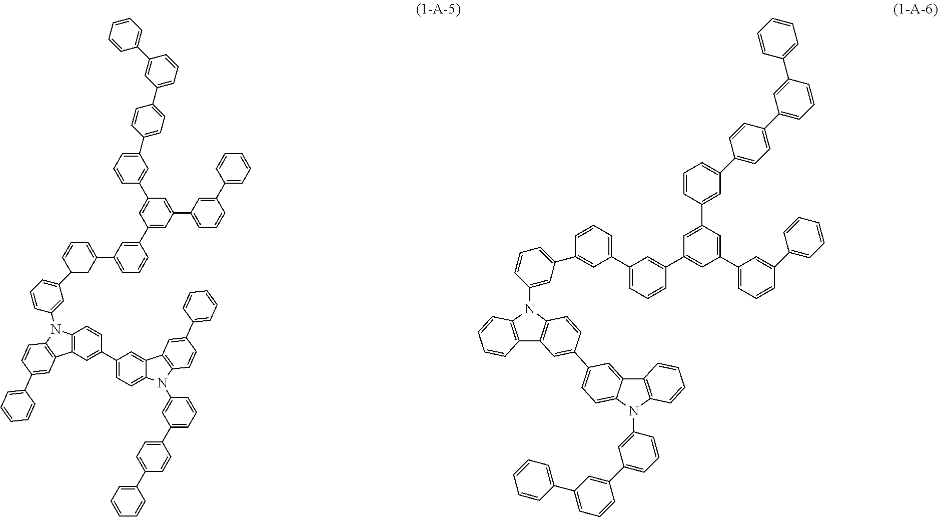 [SMILES: C1=CC(c2cccc(-n3c4ccc(-c5ccccc5)cc4c4cc(-c5ccc6c(c5)c5cc(-c7ccccc7)ccc5n6-c5cccc(-c6ccc(-c7ccccc7)cc6)c5)ccc43)c2)CC(c2cccc(-c3cc(-c4cccc(-c5ccccc5)c4)cc(-c4cccc(-c5ccc(-c6cccc(-c7ccccc7)c6)cc5)c4)c3)c2)=C1 ; c1ccc(-c2cccc(-c3ccc(-c4cccc(-c5cc(-c6cccc(-c7ccccc7)c6)cc(-c6cccc(-c7cccc(-c8cccc(-n9c%10ccccc%10c%10cc(-c%11ccc%12c(c%11)c%11ccccc%11n%12-c%11cccc(-c%12cccc(-c%13ccccc%13)c%12)c%11)ccc%109)c8)c7)c6)c5)c4)cc3)c2)cc1]

The organic electroluminescent element material of the present invention may contain only one type of compound represented by the formula (240), or may contain two or more types thereof.

### <Compound Represented by Formula (260)>

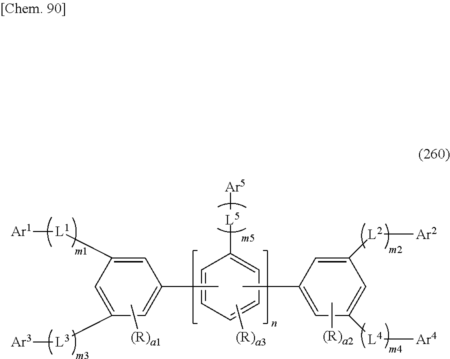

(In the formula (260),
Ar¹ to Ar⁵ each independently represent a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent,
R's each independently represent a substituent,
m1 to m5 each independently represent an integer of 0 to 5,
n represents an integer of 0 to 10,
a1 to a3 each independently represent an integer of 0 to 3, and
at least one of Ar¹, Ar², Ar³, Ar⁴, and at least one Ar⁵ when n is 1 or more is not a hydrogen atom.)
   (Ar¹, Ar², and Ar⁵)

In the formula (260), Ar¹, Ar², and Ar⁵ each independently represent a hydrogen atom, or a monovalent aromatic hydrocarbon group having 6 or more and 60 or less carbon atoms which may have a substituent.

From the viewpoint of solubility and durability of the compound, Ar¹, Ar², and Ar⁵ in the formula (260) each preferably represent a hydrogen atom, a monovalent group of a benzene ring, a monovalent group of a naphthalene ring, or a structure represented by the formula (4) or the formula (5), more preferably represent a hydrogen atom, a monovalent group of a benzene ring, or a structure represented by the formula (4) or the formula (5), still more preferably represent a hydrogen atom, a monovalent group of a benzene ring, or a structure represented by the formula (5), and particularly preferably represent a structure represented by the formula (5).

From the viewpoint of durability and charge transportability, it is more preferable that one or more and three or less of Ar¹, Ar², and at least one Ar⁵ are represented by the following formula (4) or the following formula (5), and it is more preferable that one or more and three or less of Ar¹, Ar², and at least one Ar⁵ are represented by the following formula (5).

From the viewpoint of charge transportability and solubility, it is preferable that one of Ar¹, Ar², and at least one Ar⁵ is represented by the following formula (5).

From the viewpoint of durability, it is preferable that two or more of Ar¹, Ar², and at least one Ar⁵ are represented by the following formula (5), and it is more preferable that three of them are represented by the following formula (5).

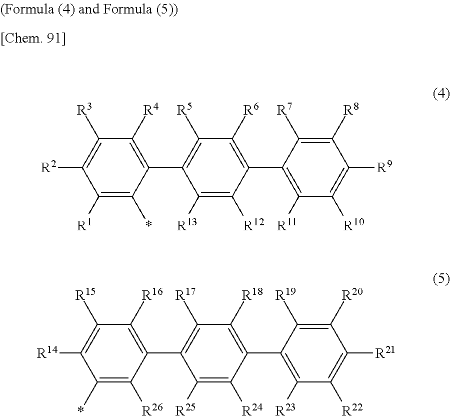

(In the formula (4) or the formula (5),
asterisk (*) represents a bonding site with the formula (260), and
R¹ to R²⁶ each independently represent a hydrogen atom or a substituent.)

When Ar¹ represents the formula (4) or the formula (5), m1 preferably represents 0 or 1, and more preferably represents 0. When Ar² represents the formula (4) or the formula (5), m2 preferably represents 0 or 1, and more preferably represents 0. When Ar⁵ represents the formula (4) or the formula (5), m5 preferably represents 0 or 1, and more preferably represents 0.

(Ar³ and Ar⁴)

In the formula (260), Ar³ and Ar⁴ each independently represent a hydrogen atom, or a monovalent aromatic hydrocarbon group having 6 or more and 60 or less carbon atoms which may have a substituent.

Examples of the monovalent aromatic hydrocarbon group having 6 or more and 60 or less carbon atoms include a monovalent group of a benzene ring, a naphthalene ring, an anthracene ring, a phenanthrene ring, a tetraphenylene ring, a chrysene ring, a pyrene ring, a benzanthracene ring, a perylene ring, a biphenyl ring, or a terphenyl ring.

From the viewpoint of solubility and durability of the compound, in the formula (260), Ar³ and Ar⁴ each independently preferably represent a hydrogen atom, a monovalent group of a benzene ring, or a monovalent group of a naphthalene ring, and more preferably represent a hydrogen atom or a monovalent group of a benzene ring.

(L¹ to L⁵)

In the formula (260), L¹ to L⁵ each independently represent a divalent aromatic hydrocarbon group having 6 or more and 60 or less carbon atoms which may have a substituent.

Examples of the divalent aromatic hydrocarbon group having 6 or more and 60 or less carbon atoms include a divalent group of a benzene ring, a naphthalene ring, an anthracene ring, a tetraphenylene ring, a phenanthrene ring, a chrysene ring, a pyrene ring, a benzanthracene ring, or a perylene ring.

L¹ to L⁵ each independently preferably represent a phenylene group, or a divalent group in which two or more, for example, 2 to 5 phenylene groups are linked via direct bonds, which may have a substituent, and more preferably represent a 1,3-phenylene group which may have a substituent, from the viewpoint of solubility.

### (R)

In the formula (260), R's each independently represent a substituent. As the substituent, those selected from the substituent group Z can be used. Among them, an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, an aralkyl group, or an aromatic hydrocarbon group is preferred. From the viewpoint of heat resistance and durability, preferred are an alkyl group, an alkenyl group, an alkoxy group, an aryloxy group, an alkoxycarbonyl group, an acyl group, a halogen atom, a haloalkyl group, a silyl group, a siloxy group, an aralkyl group, or an aromatic hydrocarbon group, more preferred are an alkyl group, an alkoxy group, an aralkyl group, or an aromatic hydrocarbon group, still more preferred are an alkyl group having 10 or less carbon atoms, an aralkyl group having 30 or less carbon atoms, or an aromatic hydrocarbon group having 30 or less carbon atoms, and particularly preferred are a benzene ring or a group in which 2 to 5 benzene rings are linked.

(m1 to m5)

In the formula (260), m1, m2, and m5 each independently represent an integer of 0 to 5, and
m3 and m4 each independently represent an integer of 1 to 5.

From the viewpoint of solubility and durability of the compound, in the formula (260), m1, m2, and m5 are preferably 4 or less, more preferably 3 or less, still more preferably 2 or less, particularly preferably 1 or less, and most preferably 0.

m1 when Ar¹ is the formula (4) or the formula (5), m2 when Ar² is the formula (4) or the formula (5), and m5 when Ar⁵ is the formula (4) or the formula (5) are preferably 0.

From the viewpoint of solubility and durability of the compound, in the formula (260), m3 and m4 are preferably 1 or more, and preferably 4 or less, more preferably 3 or less, and particularly preferably 2 or less.

In the formula (260), when m1 is 2 or more, a plurality of L¹'s may be the same as or different from each other. In the formula (260), when m2 is 2 or more, a plurality of L²'s may be the same as or different from each other. In the formula (260), when m3 is 2 or more, a plurality of L³'s may be the same as or different from each other. In the formula (260), when m4 is 2 or more, a plurality of L⁴'s may be the same as or different from each other. In the formula (260), when m5 is 2 or more, a plurality of L⁵'s may be the same as or different from each other.

((L¹)ₘ₁, (L²)ₘ₂, (L³)ₘ₃, (L⁴)ₘ₄, and (L⁵)ₘ₅)

From the viewpoint of the solubility and durability of the compound, in the formula (260), it is preferable that at least one group of (L¹)ₘ₁, (L²)ₘ₂, (L³)ₘ₃, (L⁴)ₘ₄, and at least one (L⁵)ₘ₅ has a partial structure selected from a partial structure represented by the following formula (11), a partial structure represented by the following formula (12), and a partial structure represented by the following formula (13), and it is more preferable that (L¹)ₘ₁ when m1 is 1 or more, (L²)ₘ₂ when m2 is 1 or more, (L⁵)ₘ₅ when n is 1 or more and m5 is 1 or more, and (L³)ₘ₃ when m3 is 1 or more, and (L⁴)ₘ₄ when m4 is 1 or more each have a partial structure selected from the partial structure represented by the following formula (11), the partial structure represented by the following formula (12), and the partial structure represented by the following formula (13). As a preferred aspect, for example, in the formula (260), (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more may each independently have a partial structure selected from partial structures each represented by the following formulae (11) to (17).

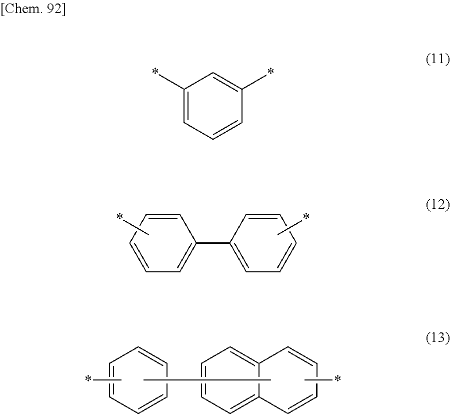

In each of the formula (11) to formula (13), * represents a bond with an adjacent structure, or when Ar¹, Ar², Ar³, Ar⁴, or Ar⁵ represents a hydrogen atom, * represents the hydrogen atom, and at least one of two present *'s represents a bonding site with an adjacent structure. In the following description, the definition of * is the same unless otherwise specified.

More preferably, in the formula (260), at least one of (L¹)ₘ₁, (L²)ₘ₂, (L³)ₘ₃, (L⁴)ₘ₄, and at least one (L⁵)ₘ₅ has the partial structure represented by the formula (11) or the partial structure represented by the formula (12).

More preferably, in the formula (260), (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more each have the partial structure represented by the formula (11) or the partial structure represented by the formula (12).

Particularly preferably, in the formula (260), (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more each have the partial structure represented by the formula (11) and the partial structure represented by the formula (12).

In the formula (260), the formula (12) is preferably the following formula (12-2).

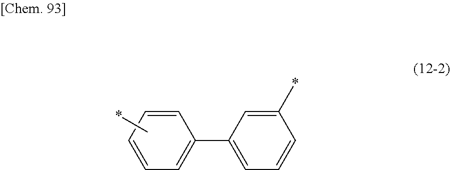

In the formula (260), the formula (12) is more preferably the following formula (12-3).

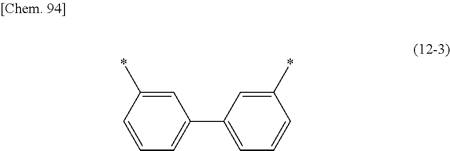 [SMILES: *c1cccc(-c2cccc(*)c2)c1]

From the viewpoint of the solubility and durability of the compound, the partial structure that at least one of (L¹)ₘ₁, (L²)ₘ₂, (L³)ₘ₃, (L⁴)ₘ₄, and at least one (L⁵)ₘ₅ in the formula (260) preferably has is a partial structure having the partial structure represented by the formula (11) and the partial structure represented by the formula (12).

In the formula (260), as the partial structure having the partial structure represented by the formula (11) and the partial structure represented by the formula (12), a partial structure selected from the following formulae (14) to (17), which is a structure containing a plurality of structures selected from the partial structure represented by the formula (11) and the partial structure represented by the formula (12), is preferred. That is, it is preferable that (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more each independently has a partial structure selected from the formulae (11) to (13) and the following formulae (14) to (17).

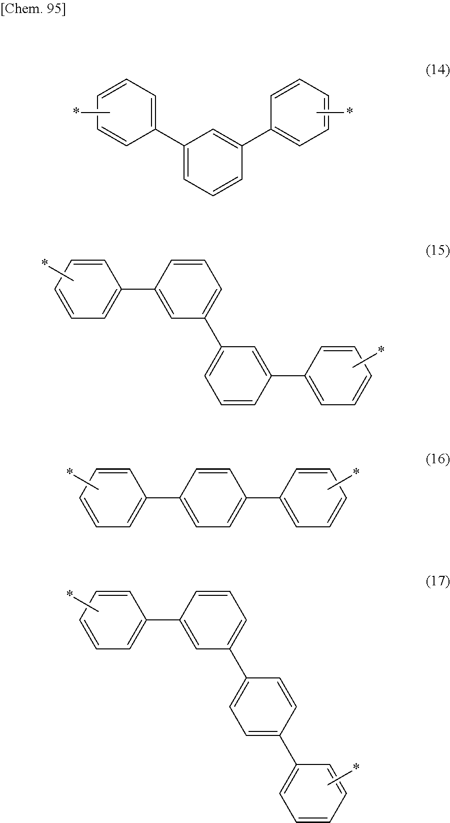

In the formula (260), the structure containing a plurality of structures selected from the substructure represented by the formula (11) and the substructure represented by the formula (12) is, for example, a partial structure in the formula (14) that can be regarded as having one partial structure represented by the formula (11) and two partial structures represented by the formula (12), as in the following formula (14a).

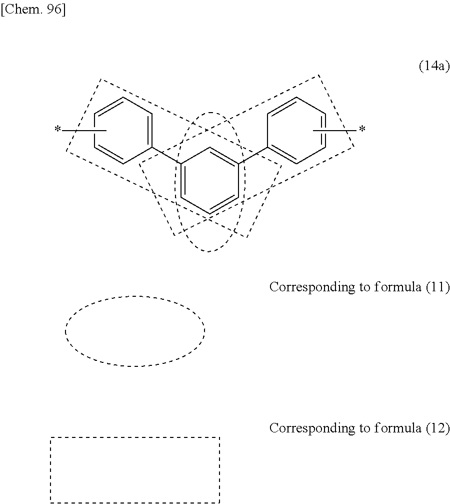

More preferably, in the formula (260), at least one of (L¹)ₘ₁, (L²)ₘ₂, (L³)ₘ₃, (L⁴)ₘ₄, and at least one (L⁵)ₘ₅ has the partial structure represented by the formula (14) or the partial structure represented by the formula (15). Still more preferably, (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more each have the partial structure represented by the formula (14) or the partial structure represented by the formula (15).

In the formula (260), the formula (14) is preferably the following formula (14-2).

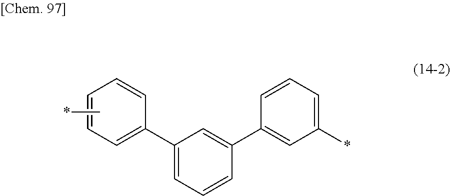

In the formula (260), the formula (14) is more preferably the following formula (14-_3).

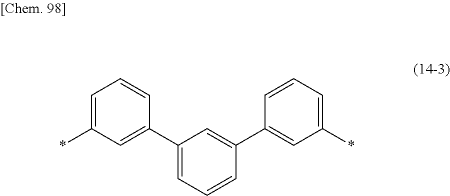 [SMILES: *c1cccc(-c2cccc(-c3cccc(*)c3)c2)c1]

In the formula (260), the formula (15) is preferably the following formula (15-2).

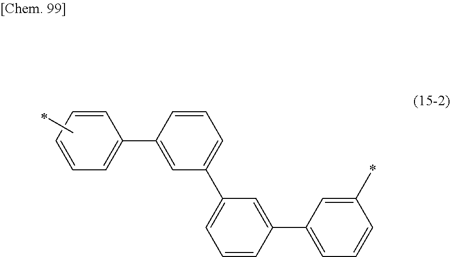

In the formula (260), the formula (15) is more preferably the following formula (15-3).

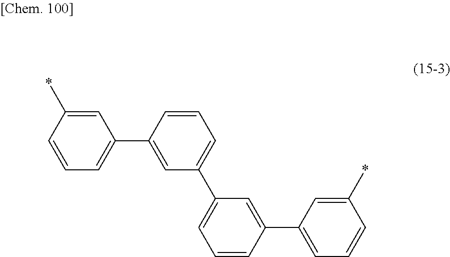 [SMILES: *c1cccc(-c2cccc(-c3cccc(-c4cccc(*)c4)c3)c2)c1]

In the formula (260), the formula (17) is preferably the following formula (17-2).

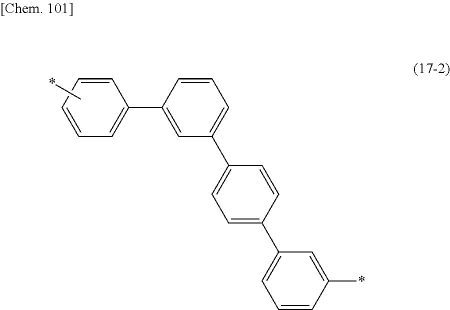

It is more preferable that at least one of (L¹)ₘ₁, (L²)ₘ₂, (L³)ₘ₃, (L⁴)ₘ₄, and at least one (L⁵)ₘ₅ in the formula (260) has, as the partial structure containing the partial structure represented by the formula (13), a partial structure represented by the following formula (19) or a partial structure represented by the following formula (20).

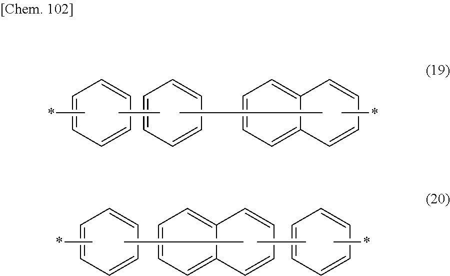

In each of the formulae (14) to (20), * represents a bond with an adjacent structure or a hydrogen atom, and at least one of two present *'s represents a bonding site with an adjacent structure.

In the formula (260), among the formulae (14) to (20), the formula (14-3) and the formula (15-3) are preferred, and the formula (14-3) is more preferred.

(Preferred Partial Structures of L¹ to L⁵)

It is preferable that L¹ to L⁵ in the formula (260) each have the partial structure represented by the formula (11), the partial structure represented by the formula (12-3), the partial structure represented by the formula (14-3), or the a partial structure represented by the formula (15-3).

(n)

In the formula (260), n represents an integer of 0 to 10.

From the viewpoint of solubility and durability of the compound, n in the formula (260) is preferably 1 or more, and more preferably 2 or more, and is preferably 6 or less, more preferably 5 or less, and particularly preferably 4 or less.

(a1 to a3)

a1 to a3 each independently represent an integer of 0 to 3.

From the viewpoint of solubility and durability of the compound,
it is preferable that a1 to a3 each independently represent 0 or 1, and
it is most preferably that a1=a2=a3=0.
   (R¹ to R²⁶)

In the formula (260), R¹ to R²⁶ each independently represent a hydrogen atom or a substituent. As the substituent, those selected from the substituent group Z can be used. Among them, an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, an aralkyl group, or an aromatic hydrocarbon group is preferred. From the viewpoint of durability, an alkyl group, an alkenyl group, an alkoxy group, an aryloxy group, an alkoxycarbonyl group, an acyl group, a halogen atom, a haloalkyl group, a silyl group, a siloxy group, an aralkyl group, or an aromatic hydrocarbon group is preferred, a hydrogen atom or an aromatic hydrocarbon group is more preferred, and a hydrogen atom is particularly preferred.

### (Substituent)

In the formula (260), the substituents which a monovalent aromatic hydrocarbon group having 6 or more and 60 or less carbon atoms in Ar¹ to Ar⁵ and a divalent aromatic hydrocarbon group having 6 or more and 60 or less carbon atoms in L¹ to L⁵ may have may each independently be selected from the substituent group Z. Among them, an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, an aralkyl group, or an aromatic hydrocarbon group is preferred, an alkyl group, an alkenyl group, an alkoxy group, an aryloxy group, an alkoxycarbonyl group, an acyl group, a halogen atom, a haloalkyl group, a silyl group, a siloxy group, an aralkyl group, or an aromatic hydrocarbon group is more preferred.

### (Molecular Weight)

A molecular weight of the compound represented by the formula (260) is preferably 3,000 or less, more preferably 2,500 or less, still more preferably 2,000 or less, and particularly preferably 1,500 or less, and is generally 400 or more, preferably 500 or more, and more preferably 600 or more.

### Specific Example

Specific examples of the compound represented by the formula (260) are shown below, and the present invention is not limited thereto.

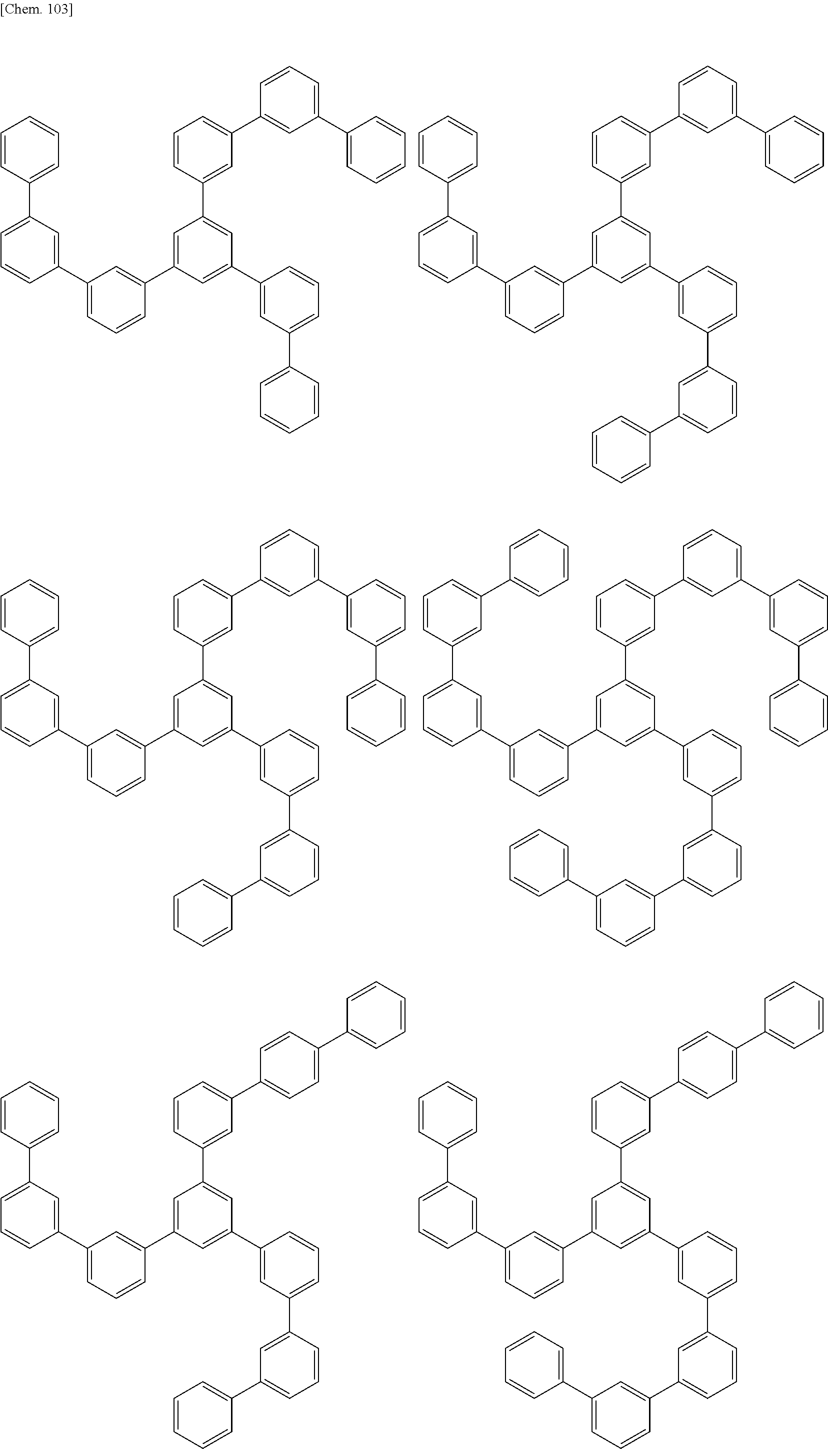

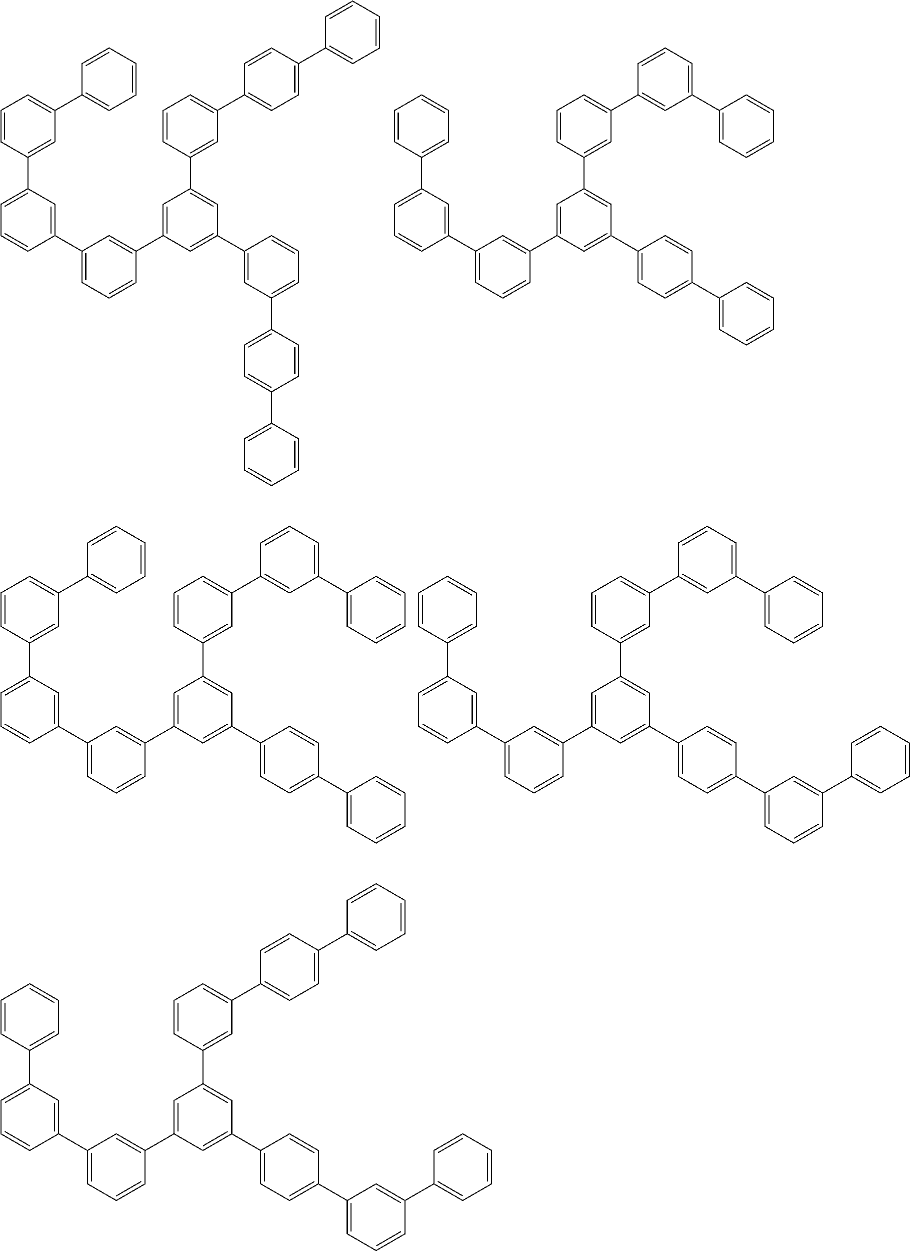

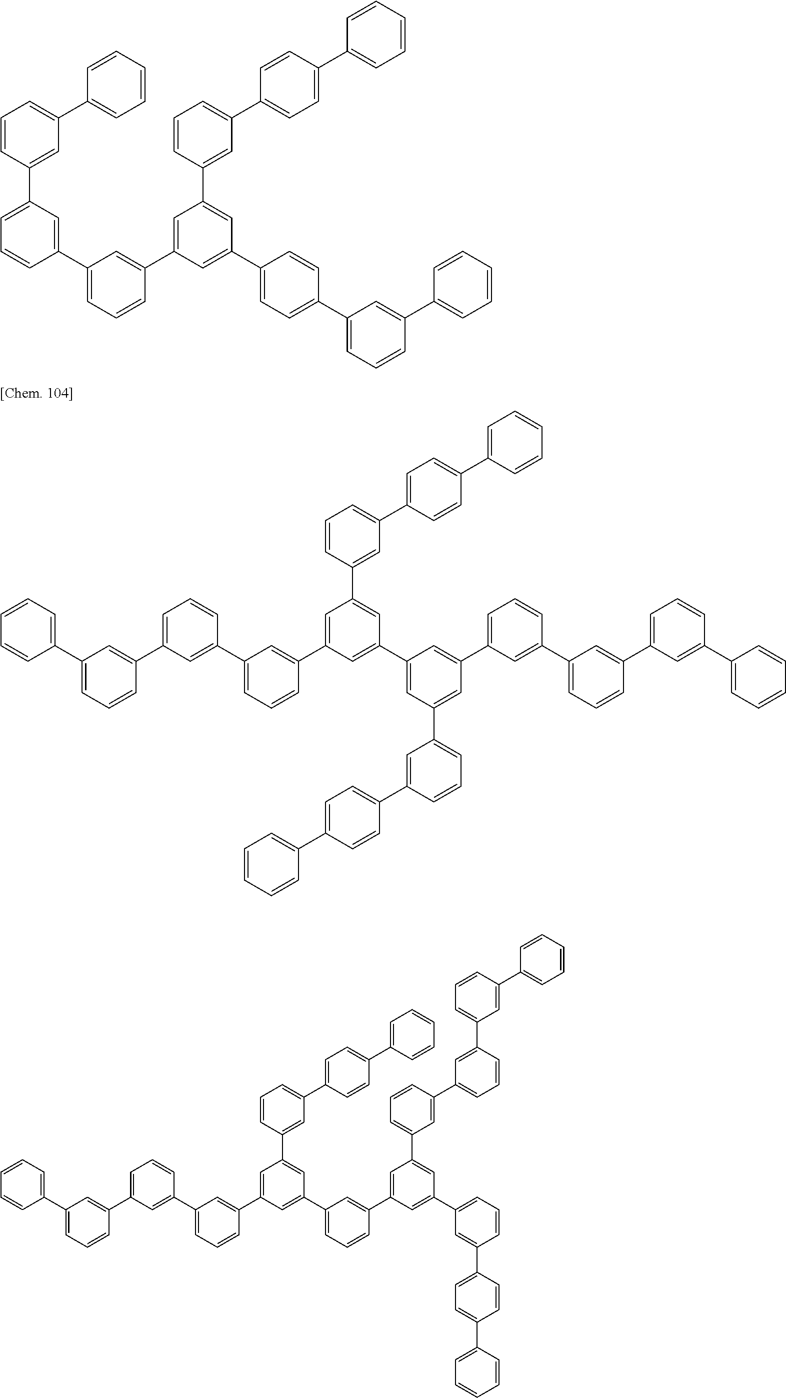

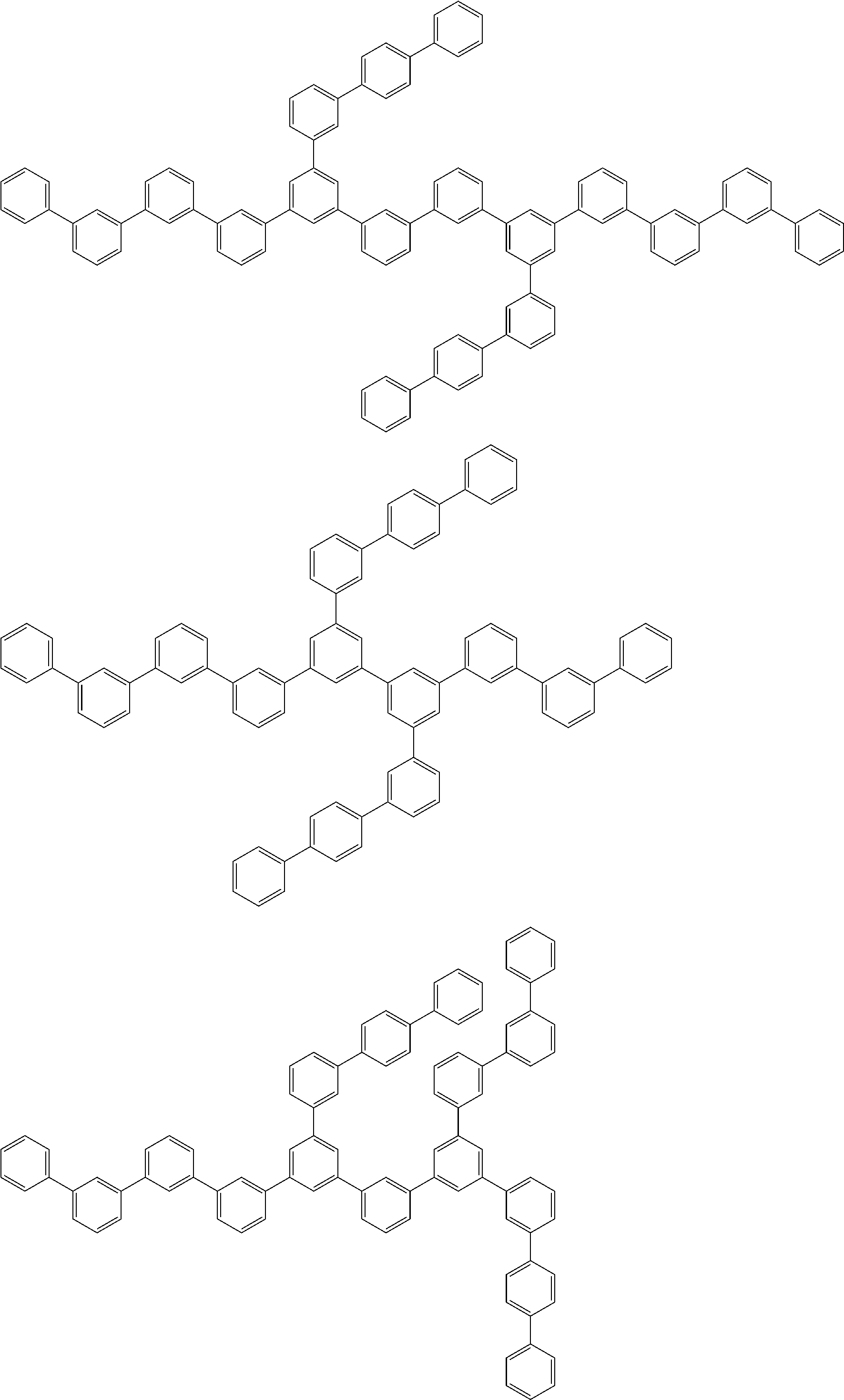

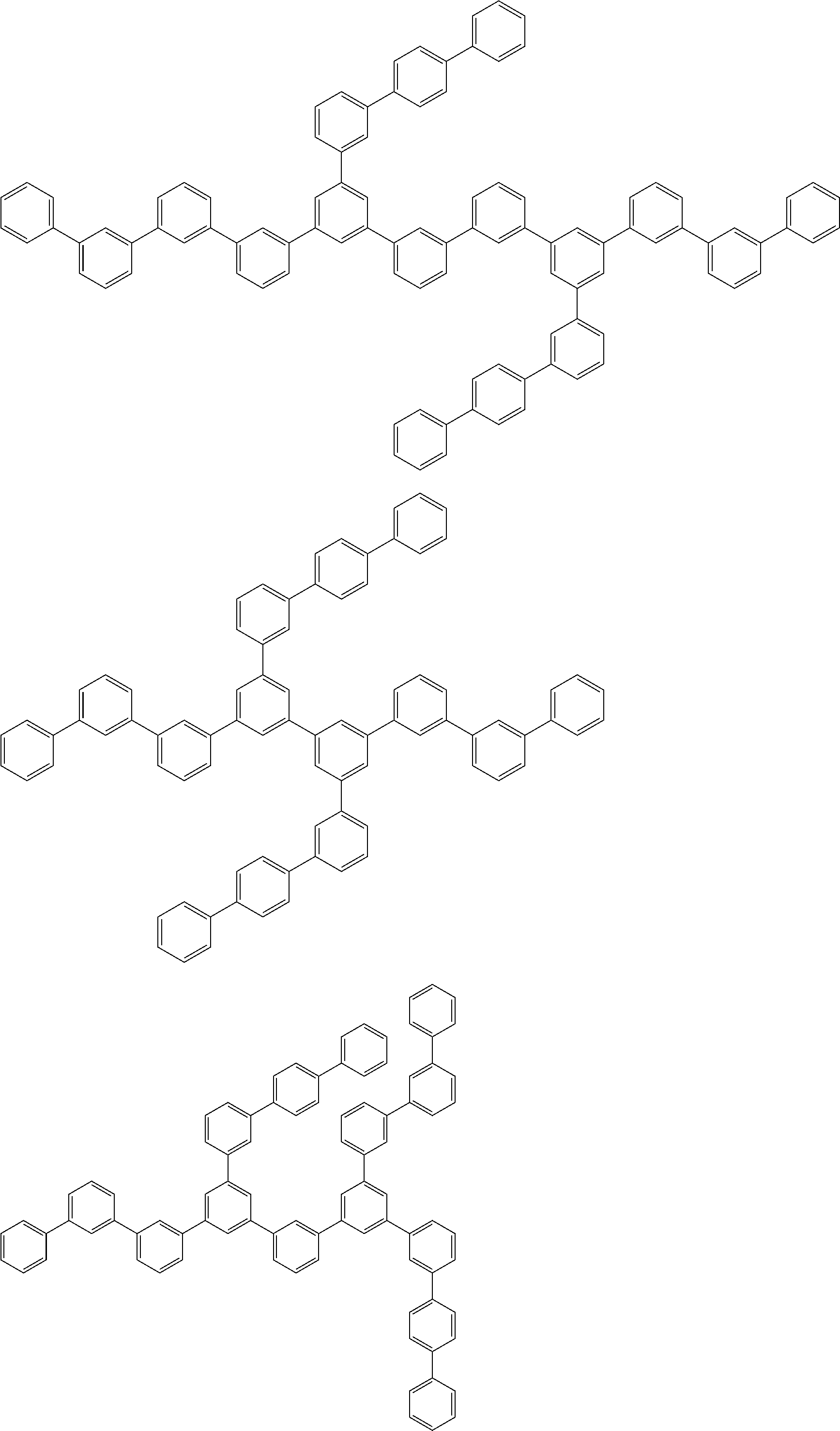

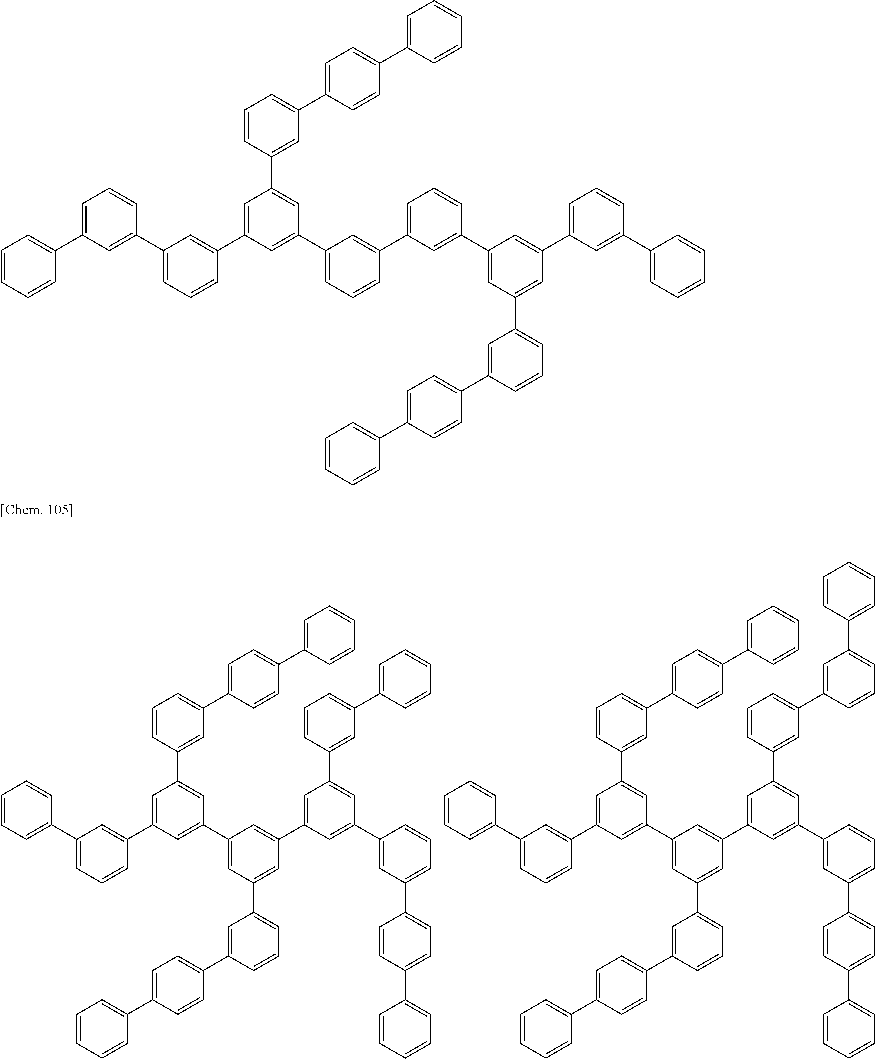

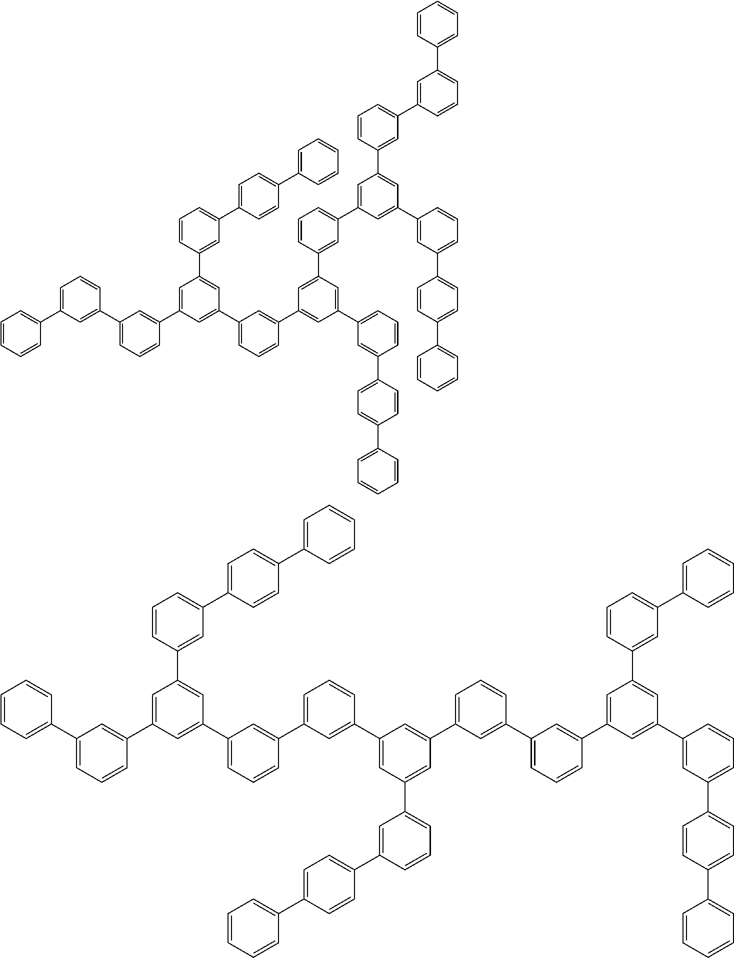

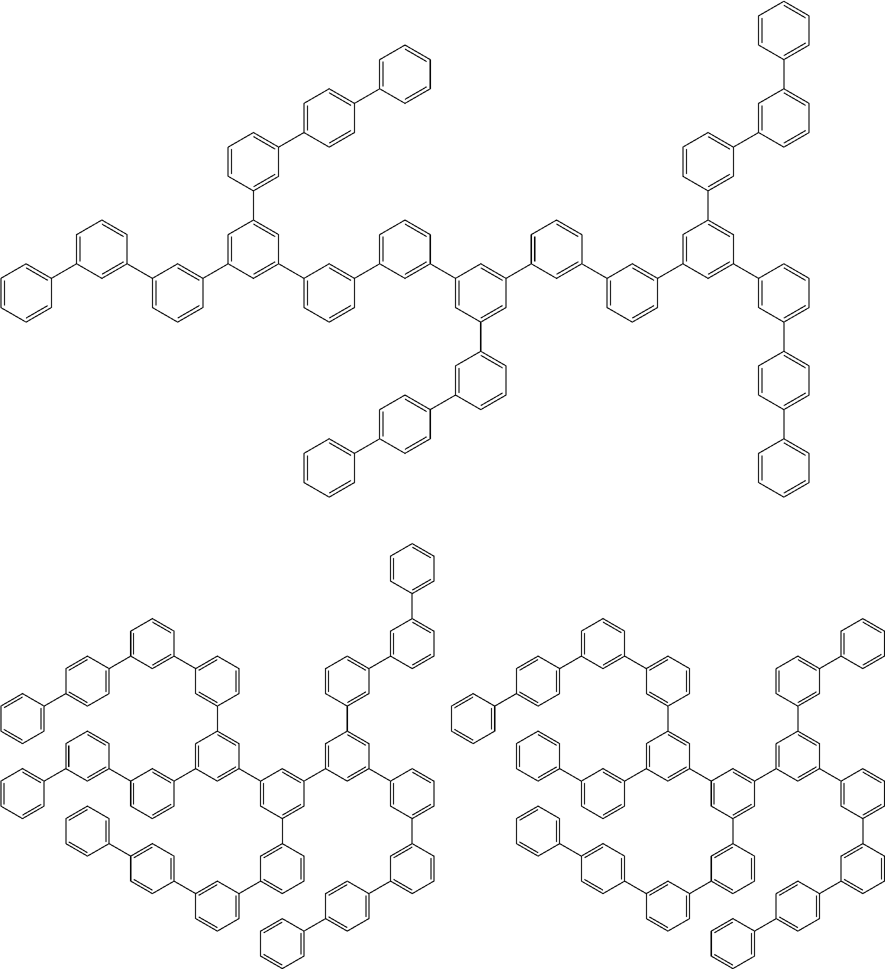

The organic electroluminescent element material of the present invention may contain only one type of compound represented by the formula (260), or may contain two or more types thereof.

### [Organic Electroluminescent Element]

The present invention relates to an organic electroluminescent element including: an anode; a cathode; an emission layer; and a hole injection layer, in which the emission layer is provided between the anode and the cathode, the hole injection layer is provided between the anode and the emission layer, and the emission layer contains the above-described organic electroluminescent element material.

A preferred range of the organic electroluminescent element material is as described above.

Preferred ranges of layers contained in the organic electroluminescent element are as described below.

### [Composition]

A composition of the present invention is a composition containing a luminescent compound, an organometallic compound, a host material, and an organic solvent,
the organometallic compound has a molecular weight of 1,200 or more,
the host material contains at least one selected from the group consisting of a compound represented by the formula (240), a compound represented by the formula (250), and a compound represented by the formula (260), and
the following relational expression (E-1) and the following relational expression (E-2) are satisfied.

$$T 1 A \geq T 1 B \qquad Expression ( E - 1 )$$

$$Δ EST = S 1 B - T 1 B \leq 0.3 eV \qquad Expression ( E - 2 )$$

(In the expression (E-1) and the expression (E-2),
T1A: a triplet energy level (eV) of the organometallic compound
T1B: a triplet energy level (eV) of the luminescent compound
S1B: a singlet energy level (eV) of the luminescent compound)

The luminescent compound contained in the composition of the present invention is preferably a polycyclic heterocyclic compound represented by the formula (1). The organometallic compound contained in the composition of the present invention is preferably an organometallic compound represented by the formula (201). That is, in the composition of the present invention, it is preferable that the organometallic compound is represented by the formula (201) and the luminescent compound is a polycyclic heterocyclic compound represented by the formula (1).

Preferred aspects of the polycyclic heterocyclic compound represented by the formula (1) and the organometallic compound represented by the formula (201), which are preferably contained in the composition of the present invention, and the relational expression (E-1) and the relational expression (E-2) are as described above. The composition of the present invention is preferably an organic electroluminescent element formation composition, and more preferably an emission layer formation composition. That is, the composition of the present invention is preferably an organic electroluminescent element formation composition containing the above-described organic electroluminescent element material and an organic solvent, and more preferably an emission layer formation composition.

A method for forming an emission layer may be either a vacuum deposition method or a wet-process film formation method, and is preferably a wet-process film formation method. In the case of the wet-process film formation method, the emission layer is formed by coating and drying an emission layer formation composition containing an organic solvent.

The composition is a composition in which a luminescent compound, an organometallic compound, and a host material are dissolved or dispersed in an organic solvent. The composition may be a composition in which the polycyclic heterocyclic compound represented by the formula (1), the organometallic compound represented by the formula (201), and the host material are dissolved or dispersed in an organic solvent.

### (Organic Solvent)

The organic solvent contained in the composition is a volatile liquid component used for forming a layer containing a luminescent compound, an organometallic compound, and a host material by wet-process film formation.

The organic solvent is not particularly limited as long as it is an organic solvent in which the luminescent compound, the organometallic compound, and the host material as solutes are satisfactorily dissolved.

Preferred examples of the organic solvent include alkanes such as n-decane, cyclohexane, ethylcyclohexane, decalin, and bicyclohexane; aromatic hydrocarbons such as toluene, xylene, mesitylene, phenylcyclohexane, tetralin, and methylnaphthalene; halogenated aromatic hydrocarbons such as chlorobenzene, dichlorobenzene, and trichlorobenzene; aromatic ethers such as 1,2-dimethoxybenzene, 1,3-dimethoxybenzene, anisole, phenetole, 2-methoxytoluene, 3-methoxytoluene, 4-methoxytoluene, 2,3-dimethylanisole, 2,4-dimethylanisole, and diphenylether; aromatic esters such as phenyl acetate, phenyl propionate, methyl benzoate, ethyl benzoate, propyl benzoate, and n-butyl benzoate; alicyclic ketones such as cyclohexanone, cyclooctanone, and fenchone; alicyclic alcohols such as cyclohexanol and cyclooctanol; aliphatic ketones such as methyl ethyl ketone and dibutyl ketone; aliphatic alcohols such as butanol and hexanol; and aliphatic ethers such as ethylene glycol dimethyl ether, ethylene glycol diethyl ether, and propylene glycol-1-monomethyl ether acetate (PGMEA).

Among them, alkanes, aromatic hydrocarbons, and aromatic esters are preferred, and aromatic hydrocarbons and aromatic esters are particularly preferred, from the viewpoint of the viscosity and the boiling point.

One kind of these organic solvents may be used alone, or two or more kinds thereof may be used in any combination and ratio.

A boiling point of the solvent to be used is generally 80° C. or higher, preferably 100° C. or higher, more preferably 120° C. or higher, and generally 350° C. or lower, preferably 330° C. or lower, more preferably 300° C. or lower. When the boiling point of the organic solvent falls below this range, there is a possibility that film formation stability is reduced due to solvent evaporation from the composition during wet-process film formation. When the boiling point of the organic solvent exceeds this range, there is a possibility that the film formation stability is reduced due to residual solvent after film formation during wet-process film formation.

In particular, it is preferable to combine two or more of the above organic solvents having a boiling point of 150° C. or higher, since it is considered that a more uniform coating film can be easily formed.

### (Content)

A content of the luminescent compound in the organic electroluminescent element material is generally 0.001 mass % or more, and preferably 0.01 mass % or more, and is generally 30.0 mass % or less, and preferably 20.0 mass % or less. A content of the organometallic compound in the composition is generally 0.001 mass % or more, and preferably 0.01 mass % or more, and is generally 30.0 mass % or less, and preferably 20.0 mass % or less. When the content is within the range, holes and electrons are efficiently injected into the emission layer from adjoining layers (for example, a hole transport layer and a hole blocking layer), and an operating voltage can be reduced. The composition may contain only one type of luminescent compound and organometallic compound, or may contain a combination of two or more types.

A content of the organometallic compound contained in the organic electroluminescent element material is generally 100 parts by mass or less, preferably 10 parts by mass or less, and more preferably 5 parts by mass or less, and is generally 0.01 parts by mass or more, preferably 0.1 parts by mass or more, and more preferably 0.2 parts by mass or more, with respect to 1 part by mass of the luminescent compound.

A content of the host material in the composition is generally 0.01 mass % or more, and preferably 0.1 mass % or more, and is generally 30.0 mass % or less, and preferably 20.0 mass % or less.

The content of the host material contained in the organic electroluminescent element material or the composition is generally 1000 parts by mass or less, preferably 100 parts by mass or less, and more preferably 50 parts by mass or less, and is generally 0.01 parts by mass or more, preferably 0.1 parts by mass or more, and more preferably 1 part by mass or more, with respect to 1 part by mass of the organometallic compound.

A content of the organic solvent contained in the composition is generally 10 mass % or more, preferably 50 mass % or more, and particularly preferably 80 mass % or more, and is generally 99.95 mass % or less, preferably 99.9 mass % or less, and particularly preferably 99.8 mass % or less. When the content of the organic solvent is equal to or more than the above lower limit, the composition has a suitable viscosity and the coatability is improved, whereas when the content of the organic solvent is equal to or less than the above upper limit, a uniform film is easily obtained and the film formability is good.

### (Other Components)

The composition may further contain other compounds in addition to the above compounds as necessary. Preferred examples of the other compounds include phenols such as dibutylhydroxytoluene and dibutylphenol, which are known as antioxidants.

### (Film Formation Method)

A method for forming the emission layer is preferably a wet-process film formation method. The wet-process film formation method is a method in which a composition is applied to form a liquid film, and then the liquid film is dried to remove an organic solvent, thereby forming a film of the emission layer. As the coating method, for example, a wet film forming method such as a spin coating method, a dip coating method, a die coating method, a bar coating method, a blade coating method, a roll coating method, a spray coating method, a capillary coating method, an ink jet method, a nozzle printing method, a screen printing method, a gravure printing method, or a flexographic printing method is adopted, and the coating film is dried to form a film. Among the coating method, a spin coating method, a spray coating method, an ink jet method, and a nozzle printing method are preferred. When producing an organic EL display device including the organic electroluminescent element, the ink jet method or nozzle printing method is preferred, and the ink jet method is particularly preferred.

The drying method is not particularly limited, and natural drying, drying under reduced pressure, drying with heating, or drying under reduced pressure while heating can be appropriately used. The heating and drying may be performed to further remove the remaining organic solvent after natural drying or vacuum drying.

The drying under reduced pressure is preferably performed under a reduced pressure equal to or lower than a vapor pressure of the organic solvent contained in the composition.

In the case of heating, the heating method is not particularly limited, and heating with a hot plate, heating in an oven, red radiation heating, or the like can be used. A heating temperature is generally 80° C. or higher, preferably 100° C. or higher, more preferably 110° C. or higher, and is preferably 200° C. or lower, and more preferably 150° C. or lower.

A heating time is generally 1 minute or more and preferably 2 minutes or more, and is generally 60 minutes or less, preferably 30 minutes or less, and more preferably 20 minutes or less.

### [Hole Injection Layer]

The hole injection layer needs to have a function of transporting holes, and therefore contains a hole transport material. Further, the hole injection layer preferably contains tetraarylborate ions. The hole injection layer also preferably contains a crosslinking substance of an electron-accepting compound having a crosslinking group.

In order to improve the hole injection property from the anode to the hole injection layer and improve the hole transportability in the hole injection layer, the hole transport material contained in the hole injection layer preferably contains a cation radical site. In order to convert the hole transport material into a cation radical, an electron-accepting compound is used when forming the hole injection layer. As a core skeleton of the electron-accepting compound, an ionic compound consisting of a counter cation and a tetraarylborate ion, which is an anion having an ionic valence of 1 to be described later, is preferred because of high stability.

The hole transport material is converted into a cation radical as follows. For example, in a case where a compound having a triarylamine structure is used as the hole transport material, when a tetraarylborate having diaryliodonium as a counter cation is used as the electron-accepting compound, the counter cation can change from diaryliodonium to triarylamine as shown in the following formula when forming the hole injection layer.

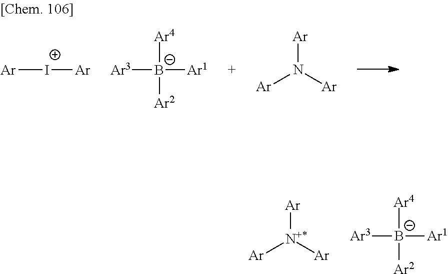

(For example, Ar and Ar¹ to Ar⁴ each independently represent an aromatic hydrocarbon group which may have a substituent, an aromatic heterocyclic group which may have a substituent, or a monovalent group in which a plurality of structures selected from an aromatic hydrocarbon ring group which may have a substituent and an aromatic heterocyclic group which may have a substituent are linked.)

The triarylamine produced in the above reaction has a singly-occupied molecular orbital (SOMO) capable of accepting electrons, and therefore a tetraarylborate having a triarylamine as a counter cation is an electron-accepting compound.

In the present invention, the compound composed of a cation of the hole transport material and an anion, i.e., a tetraarylborate ion, is referred to as a charge-transporting ionic compound. Details will be described later.

### [Electron-Accepting Compound Having Crosslinking Group]

Examples of the electron-accepting compound include a compound having, as a core skeleton, an ionic compound composed of a tetraarylborate ion and a counter cation, as described above.

### (Crosslinking Group)

The crosslinking group of the electron-accepting compound which forms a crosslinking substance of the electron-accepting compound having a crosslinking group and which may be contained in the hole injection layer of the organic electroluminescent element according to the present invention means a group which reacts with another group located in the vicinity of the crosslinking group by irradiation with heat and/or active energy rays to form a new chemical bond. In this case, the group to be reacted may be the same as or different from the crosslinking group.

It is considered that, when the electron-accepting compound contains a crosslinking group, a crosslinking reaction proceeds during formation of the hole injection layer, the electron-accepting compound can be fixed to the hole injection layer, and the electron-accepting compound does not diffuse into the layer above the hole injection layer when a layer above the hole injection layer is formed by the wet-process film formation method. Therefore, it is presumed that a deterioration reaction during driving can be prevented by using the electron-accepting compound having a crosslinking group.

The crosslinking group is preferably a crosslinking group represented by any one of the following formulae (X1) to (X18).

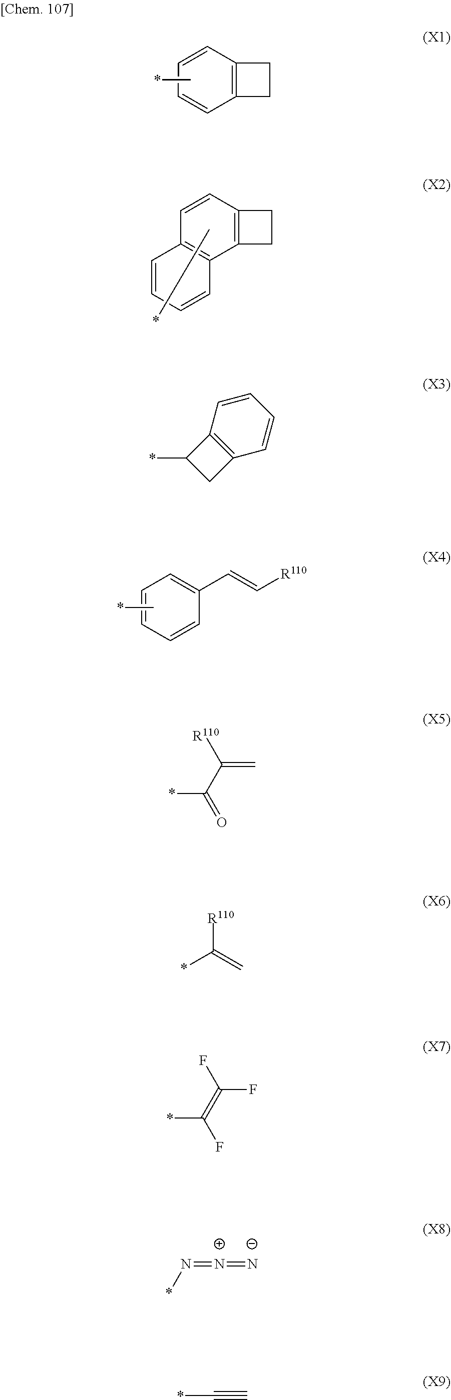

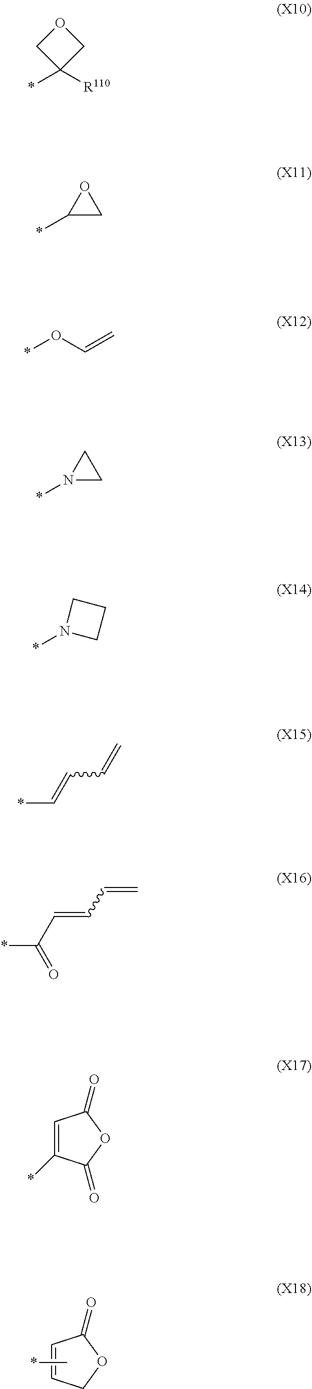

(In the formulae (X1) to (X4), a benzene ring and a naphthalene ring may have a substituent. The substituents may be bonded to each other to form a ring.

In the formula (X4), the formula (X5), the formula (X6), and the formula (X10), R¹¹⁰'s each independently represent an alkyl group which may have a substituent.

In the formulae (X1) to (X18), * represents a bonding site.)

The alkyl group represented by R¹¹⁰ has a linear, branched, or cyclic structure and has 1 or more, and preferably 24 or less, more preferably 12 or less, still more preferably 8 or less carbon atoms.

The substituent which the benzene ring and naphthalene ring in the formulae (X1) to (X4) and R¹¹⁰ in the formulae (X4) to (X6) and (X10) may have is preferably an alkyl group, an aromatic hydrocarbon group, an alkyloxy group, or an aralkyl group.

The alkyl group as the substituent has a linear, branched, or cyclic structure and has preferably 24 or less, more preferably 12 or less, still more preferably 8 or less, and preferably 1 or more carbon atoms.

The number of carbon atoms of the aromatic hydrocarbon group as the substituent is preferably 24 or less, more preferably 18 or less, still more preferably 12 or less, and is preferably 6 or more. The aromatic hydrocarbon group may further have the alkyl group as the substituent.

The number of carbon atoms of the alkyloxy group as the substituent is preferably 24 or less, more preferably 12 or less, still more preferably 8 or less, and is preferably 1 or more.

The number of carbon atoms of the aralkyl group as the substituent is preferably 30 or less, more preferably 24 or less, still more preferably 14 or less, and is preferably 7 or more. The alkylene group contained in the aralkyl group preferably has a linear or branched structure. The aryl group contained in the aralkyl group may further have the alkyl group as the substituent.

As the crosslinking group, a crosslinking group represented by any one of the formulae (X1) to (X4) is preferred in that it has a small polarity and has a little effect on charge transport. Further, a crosslinking group represented by any one of the formulae (X1) to (X3) is more preferred in that the crosslinking reaction proceeds only by heat.

In the crosslinking group represented by the formula (X1), as shown in the following formula, a cyclobutene ring is opened by heat, and the ring-opened groups are bonded to each other to form a crosslinked structure.

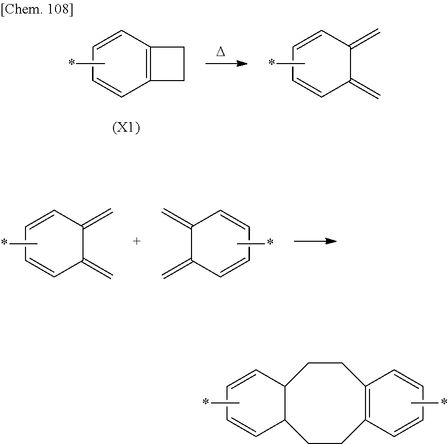

In the crosslinking group represented by the formula (X2), as shown in the following formula, a cyclobutene ring is opened by heat, and the ring-opened groups are bonded to each other to form a crosslinked structure.

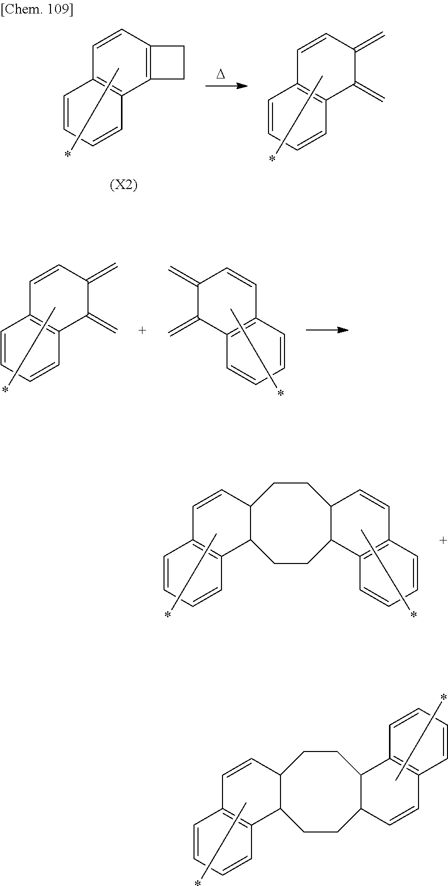

In the crosslinking group represented by the formula (X3), as shown in the following formula, a cyclobutene ring is opened by heat, and the ring-opened groups are bonded to each other to form a crosslinked structure.

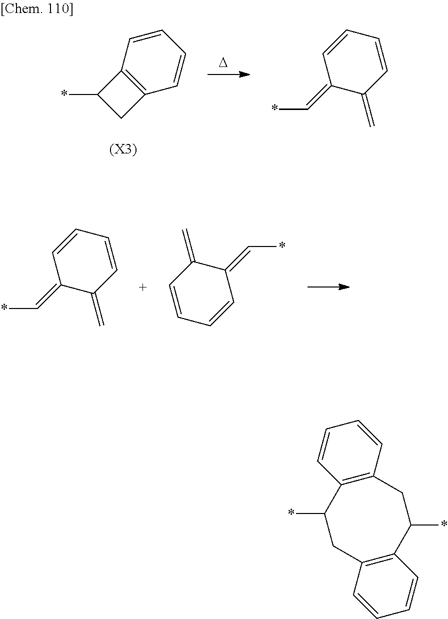

In the crosslinking group represented by any of the formulae (X1) to (X3), the cyclobutene ring is opened by heat, and when a double bond exists in the vicinity thereof, the opened group reacts with the double bond to form a crosslinked structure. An example in which a crosslinked structure is formed by a ring-opened group of the crosslinking group represented by the formula (X1) and a crosslinking group having a double-bond site and represented by the formula (X4) is shown below. (R¹¹⁰ in the formula (X4) is not shown.)

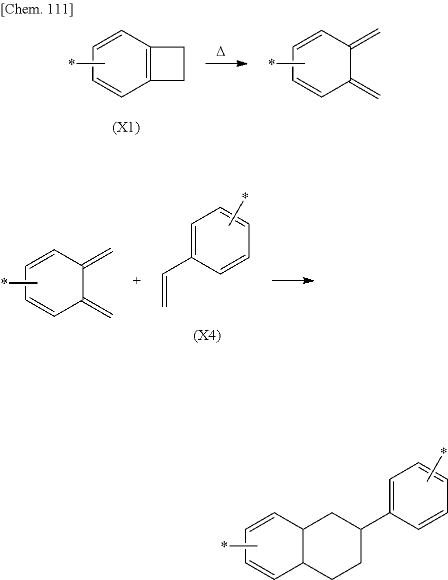

Examples of the group containing a double bond capable of reacting with the crosslinking group represented by any one of the formulae (X1) to (X3) include, in addition to the crosslinking group represented by the formula (X4), a crosslinking group represented by any one of formulae (X5), (X6), (X12), (X15), (X16), (X17), and (X18). When such a group containing a double bond is used as the crosslinking group in the electron-accepting compound, it is preferable to contain the crosslinking group represented by any one of the formulae (X1) to (X3) in another component forming the hole injection layer such as a hole-transporting compound since a possibility of forming a crosslinked structure increases.

As the crosslinking group, a radically polymerizable crosslinking group represented by any one of the formulae (X4), (X5), and (X6) is preferred since it has a small polarity and is unlikely to interfere with charge transport.

As the crosslinking group, a crosslinking group represented by a formula (X7) is preferred in terms of enhancing electron acceptability. When the crosslinking group represented by the formula (X7) is used, the following crosslinking reaction proceeds.

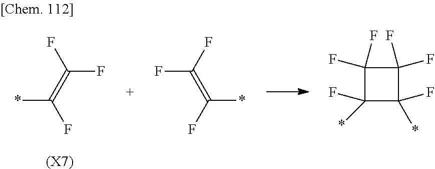

A crosslinking group represented by any one of formulae (X8) and (X9) is preferred in terms of high reactivity. When the crosslinking group represented by the formula (X8) and the crosslinking group represented by the formula (X9) are used, the following crosslinking reaction proceeds.

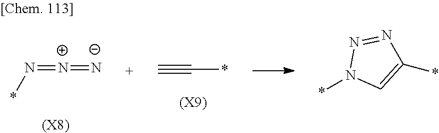

As the crosslinking group, a cationic polymerizable crosslinking group represented by any one of formulae (X10), (X11), and (X12) is preferred in terms of high reactivity.

### (Crosslinking Substance of Electron-Accepting Compound)

As described later, the hole injection layer of the organic electroluminescent element of the present invention is preferably obtained by wet-process film formation of a hole injection layer formation composition, and the hole injection layer formation composition is preferably a composition obtained through a step of dissolving or dispersing a first ionic compound having a tetraarylborate ion structure to be described later and a hole transport material to be described later in an organic solvent. The hole transport layer of the organic electroluminescent element of the present invention preferably contains a charge-transporting ionic compound having a tetraarylborate ion structure of the present invention to be described later as an anion and a cation of the hole transport material as a counter cation.

Accordingly, as the electron-accepting compound in the electron-accepting compound having a crosslinking group, an electron-accepting compound which is an ionic compound is preferred, and the ionic compound as the electron-accepting compound is preferably an ionic compound having a tetraarylborate ion structure as the anion. When the electron-accepting compound is an ionic compound having a tetraarylborate ion structure as the anion, it is preferable that the tetraarylborate ion has a crosslinking group. The tetraarylborate ion structure will be described later.

When the electron-accepting compound having a crosslinking group is used, a crosslinking substance of the electron-accepting compound having a crosslinking group is formed. The crosslinking substance of the electron-accepting compound having a crosslinking group includes the following crosslinking substance.
A compound in which electron-accepting compounds are crosslinked with each other.
A compound in which an electron-accepting compound and a hole transport material are crosslinked.
A compound in which an electron-accepting compound and the tetraarylborate ion in the present invention are crosslinked.
A compound in which the tetraarylborate ions in the present invention are crosslinked with each other.
A compound in which the tetraarylborate ion in the present invention and a hole transport material are crosslinked.

Here, the term “tetraarylborate ion in the present invention” includes a case where the tetraarylborate ion exists as an electron-accepting compound, which is an ionic compound consisting of a tetraarylborate ion to be described later and a counter cation, and a case where the tetraarylborate ion exists as a charge-transporting ionic compound consisting of a tetraarylborate ion to be described later and a cation of a hole transport material.

In the present invention, the crosslinking substance of the tetraarylborate ion having a crosslinking group may be the following crosslinking substance.
A compound in which an electron-accepting compound and the tetraarylborate ion in the present invention are crosslinked.
A compound in which the tetraarylborate ions in the present invention are crosslinked with each other.
A compound in which the tetraarylborate ion in the present invention and a hole transport material are crosslinked.

The two crosslinking groups to be subjected to a crosslinking reaction may be the same as or different from each other, as long as they are capable of crosslinking.

### [Tetraarylborate Ion]

The tetraarylborate ion is an anion having an ionic value of 1, in which boron atoms are substituted with four aromatic hydrocarbon rings which may have a substituent and/or a crosslinking group or aromatic heterocyclic rings which may have a substituent and/or a crosslinking group.

A boron-containing polycyclic heterocyclic compound has an empty p-orbital on boron and is particularly susceptible to reaction with an electron-donating substance. As a result of the reaction, an oxide of an electron-donating substance is generated, and the oxide may further cause a deterioration reaction during driving. On the other hand, a tetraarylborate ion having a stable structure satisfying the octet law without an empty p-orbital on boron has an effect of stabilizing a cation obtained by oxidizing an electron-donating substance. Therefore, it is presumed that the use of the tetraarylborate ion can prevent the deterioration reaction during driving, improves durability, and prolongs the operating lifetime of the element.

The tetraarylborate ion that can be contained in the organic electroluminescent element of the present invention preferably has a fluorine atom or a fluorine-substituted alkyl group as a substituent of the aryl group, in terms of further improving stability. That is, the tetraarylborate ion is preferably represented by the following formula (2).

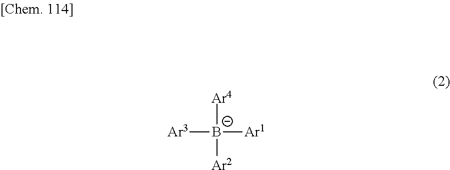

(In the formula (2),
Ar¹, Ar², Ar³, and Ar⁴ each independently represent an aromatic hydrocarbon ring group which may have a substituent and/or a crosslinking group, an aromatic heterocyclic group which may have a substituent and/or a crosslinking group, or a monovalent group in which a plurality of structures selected from an aromatic hydrocarbon ring group which may have a substituent and/or a crosslinking group and an aromatic heterocyclic group which may have a substituent and/or a crosslinking group are linked, and
at least one of Ar¹, Ar², Ar³, and Ar⁴ has a fluorine atom or a fluorine-substituted alkyl group as a substituent.)

It is preferable that at least one of Ar¹, Ar², Ar³, and Ar⁴ has a crosslinking group.

The aromatic hydrocarbon ring group used for Ar¹, Ar², Ar³, and Ar⁴ is preferably of monocyclic or 2- to 6-fused. Specific examples thereof include a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, a fluorene ring, a biphenyl structure, a terphenyl structure, and a quaterphenyl structure.

The aromatic heterocyclic group used for Ar¹, Ar², Ar³, and Ar⁴ is preferably of monocyclic or 2- to 6-fused. Specific examples thereof include a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a perimidine ring, a quinazoline ring, a quinazolinone ring, and an azulene ring.

Among them, a monovalent group derived from a benzene ring, a naphthalene ring, a fluorene ring, a pyridine ring, or a carbazole ring, or a biphenyl group is more preferred because of excellent stability and heat resistance. Particularly preferred is a monovalent group derived from a benzene ring, that is, a phenyl group or a biphenyl group.

The total number of monocyclic or 2- to 6-fused aromatic hydrocarbon ring groups and monocyclic or 2- to 6-fused aromatic heterocyclic groups contained in a monovalent group in which a plurality of structures selected from an aromatic hydrocarbon ring groups which may have a substituent and/or a crosslinking group and an aromatic heterocyclic groups which may have a substituent and/or a crosslinking group are linked is 2 or more and is preferably 8 or less, more preferably 4 or less, and still more preferably 3 or less.

Examples of the substituent which Ar¹, Ar², Ar³, and Ar⁴ may have include a group described in a substituent group W to be described later.

The substituent of Ar¹, Ar², Ar³, and Ar⁴ is preferably a fluorine atom or a fluorine-substituted alkyl group, from the viewpoint of increasing the stability of the anion and improving the effect of stabilizing the cation. The fluorine atom or the fluorine-substituted alkyl group preferably substitutes two or more of Ar¹, Ar², Ar³, and Ar⁴, more preferably substitutes three or more thereof, and most preferably substitutes four thereof.

The fluorine-substituted alkyl group as the substituent of Ar¹, Ar², Ar³, and Ar⁴ is preferably a linear or branched alkyl group having 1 to 12 carbon atoms and substituted with a fluorine atom, more preferably a perfluoroalkyl group, still more preferably a linear or branched perfluoroalkyl group having 1 to 5 carbon atoms, particularly preferably a linear or branched perfluoroalkyl group having 1 to 3 carbon atoms, and most preferably a perfluoromethyl group. The reason for this is that the hole injection layer containing the crosslinking substance of the electron-accepting compound having a tetraarylborate ion or a crosslinking group, and the coating film laminated thereon, become stable.

The crosslinking group which Ar¹, Ar², Ar³, and Ar⁴ may have is the same as the crosslinking group described above.

In terms of further increasing the stability of the anion and further improving the effect of stabilizing the cation, in the tetraarylborate ion that the organic electroluminescent element of the present invention can contain, it is preferable that at least one of Ar¹, Ar², Ar³, and Ar⁴ in the formula (2) represents a group represented by a formula (3), it is more preferable that at least two of Ar¹, Ar², Ar³, and Ar⁴ each independently represent the group represented by the formula (3), it is still more preferable that at least three of Ar¹, Ar², Ar³, and Ar⁴ each independently represent the group represented by the formula (3), and it is most preferable that all of Ar¹, Ar², Ar³, and Ar⁴ each independently represent the group represented by the formula (3).

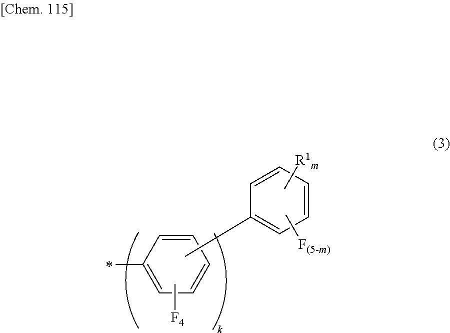

(In the formula (3),
R¹'s each independently represent an aromatic hydrocarbon ring group which may have a substituent and/or a crosslinking group, an aromatic heterocyclic group which may have a substituent and/or a crosslinking group, a monovalent group in which a plurality of structures selected from an aromatic hydrocarbon ring group which may have a substituent and/or a crosslinking group and an aromatic heterocyclic group which may have a substituent and/or a crosslinking group are linked, a fluorine-substituted alkyl group, a substituent, or a crosslinking group,
F₄ represents four fluorine atoms being substituted,
F₍₅₋ₘ₎'s each independently represent 5-m fluorine atoms being substituted,
k's each independently represent an integer of 0 to 5, and
m's each independently represent an integer of 0 to 5.
* represents a bonding site.)

K is preferably 1 or more, and more preferably 2 or more, in terms of further improving the stability of the anion. K is preferably 0 or 1, and more preferably 0, in terms of easy dispersion without deviation.

m is preferably 0 in terms of more excellent durability, is preferably 1 or more and preferably 3 or less in terms of enabling various functions to be introduced into the tetraarylborate ion, and is more preferably 1 or 2 in terms of compatibility with durability.

It is preferable that k+m≥1 since the stability of the anion is improved and the durability is excellent.

As the aromatic hydrocarbon ring group or the aromatic heterocyclic group of R¹, a preferred structure thereof and a substituent which R¹ may have are the same as the structures and the substituents of Ar¹, Ar², Ar³, and Ar⁴.

Examples of the substituent of R¹ and the substituent when R¹ is a substituent include a group described in the substituent group W to be described later.

In the formula (3), in terms of further increasing the stability of the anion and further improving the effect of stabilizing the cation, at least one R¹ is preferably the fluorine-substituted alkyl group, more preferably a perfluoroalkyl group, and still more preferably a trifluoromethyl group.

The crosslinking group of R¹ and the crosslinking group when R¹ is a crosslinking group are as described above.

In the formula (3), it is preferable that at least one R¹ contains the crosslinking group, in terms of achieving both crosslinkability and electron acceptability. In this case, R¹ is preferably the above crosslinking group or a structure in which one or more of the above crosslinking groups are bonded to an aromatic hydrocarbon group.

Further, it is also preferable that R¹ is a group containing a group represented by the following formula (4) or a group represented by the following formula (5).

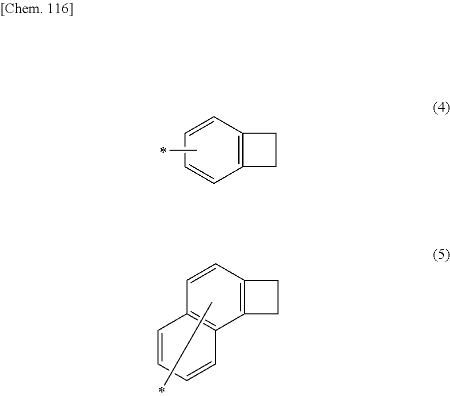

The group represented by the formula (4) and the group represented by the formula (5) may have a substituent, and examples of the substituent are the same as the substituent which R¹ may have.

R¹ is preferably the group represented by the formula (4) or the group represented by the formula (5), or a structure in which one or more groups represented by the formula (4) or groups represented by the formula (5) are bonded to an aromatic hydrocarbon group.

When R¹ has a structure in which one or more of the crosslinking groups are bonded to an aromatic hydrocarbon group, the aromatic hydrocarbon group preferably has a structure in which two or more rings selected from a benzene ring, a naphthalene ring, or a benzene ring and a naphthalene ring are linked, and the number of links is preferably 4 or less. In this case, R¹ more preferably has a structure in which the crosslinking group is bonded to a monocyclic benzene ring or a monocyclic naphthalene ring, still more preferably has a structure in which the crosslinking group is bonded to a benzene ring, and particularly preferably has a structure in which one or two crosslinking groups are bonded.

When R¹ is a group containing the group represented by the formula (4) or the group represented by the following formula (5), R¹ more preferably has a structure in which the group represented by the formula (4) or the group represented by the formula (5) is bonded to a monocyclic benzene ring or a monocyclic naphthalene ring, still more preferably has a structure in which the group represented by the formula (4) or the group represented by the formula (5) is bonded to a benzene ring, and particularly preferably has a structure in which one or two groups represented by the formula (4) or groups represented by the formula (5) are bonded.

The group represented by the formula (4) and the group represented by the formula (5) are preferred since they have crosslinkability and it is considered that the tetraarylborate ion and the counter cation do not diffuse into other layers.

### (Substituent Group W)

The substituent group W is a hydrogen atom, a halogen atom, a cyano group, an aromatic hydrocarbon ring group composed of 1 to 5 aromatic hydrocarbon rings, an aliphatic hydrocarbon ring group, an alkyl group, an alkenyl group, an alkynyl group, an aralkyl group, an alkoxy group, an aryloxy group, an alkylthio group, an arylthio group, an alkyl ketone group, or an aryl ketone group.

Examples of the halogen atom include a fluorine atom, a chlorine atom, a bromine atom, and an iodine atom, and a fluorine atom is preferred in terms of the stability of the compound.

Examples of the aromatic hydrocarbon ring group consisting of 1 to 5 aromatic hydrocarbon rings include a phenyl group, a biphenyl group, a terphenyl group, a quaterphenyl group, a naphthyl group, a phenanthrenyl group, a triphenylene group, and a naphthylphenyl group. From the viewpoint of the stability of the compound, a phenyl group, a naphthyl group, a biphenyl group, a terphenyl group, or a quaterphenyl group is preferred.

Examples of the aliphatic hydrocarbon ring group include a cyclopropyl group, a cyclobutyl group, a cyclopentyl group, and a cyclohexyl group.

The number of carbon atoms of the alkyl group is generally 1 or more, and preferably 4 or more, and is generally 24 or less, preferably 12 or less, more preferably 8 or less, and still more preferably 6 or less. Specific examples thereof include a methyl group, an ethyl group, an n-propyl group, an i-propyl group, an n-butyl group, an i-butyl group, a sec-butyl group, a tert-butyl group, an n-hexyl group, a cyclohexyl group, an octyl group, a 2-ethylhexyl group, and a dodecyl group.

The number of carbon atoms of the alkenyl group is generally 2 or more, and is generally 24 or less, and preferably 12 or less. Specific examples thereof include a vinyl group, a propenyl group, and a butenyl group.

The number of carbon atoms of the alkynyl group is generally 2 or more, and is generally 24 or less, and preferably 12 or less. Specific examples thereof include an ethynyl group, a propynyl group, and a butynyl group.

Examples of the aralkyl group include a benzyl group, a phenylethyl group, and a phenylhexyl group.

The number of carbon atoms of the alkoxy group is generally 1 or more, and is generally 24 or less, preferably 12 or less, and more preferably 6 or less. Specific examples thereof include a methoxy group, an ethoxy group, a butyloxy group, a hexyloxy group, and an octyloxy group.

The number of carbon atoms of the aryloxy group is generally 4 or more, preferably 5 or more, and more preferably 6 or more, and is generally 36 or less, preferably 24 or less, and more preferably 12 or less. Specific examples thereof include a phenoxy group and a naphthyloxy group.

The number of carbon atoms of the alkylthio group is generally 1 or more, and is generally 24 or less, and preferably 12 or less. Specific examples thereof include a methylthio group, an ethylthio group, a butylthio group, and a hexylthio group.

The number of carbon atoms of the arylthio group is generally 4 or more, preferably 5 or more, and is generally 36 or less, and preferably 24 or less. Specific examples thereof include a phenylthio group and a naphthylthio group.

The number of carbon atoms of the alkyl ketone group is generally 1 or more, and is generally 24 or less, preferably 12 or less, and more preferably 6 or less. Specific examples thereof include an acetyl group, an ethylcarbonyl group, a butylcarbonyl group, and an octylcarbonyl group.

The number of carbon atoms of the aryl ketone group is generally 5 or more, preferably 7 or more, and is generally 25 or less, and preferably 13 or less. Specific examples thereof include a benzoyl group and a naphthylcarbonyl group.

Adjacent substituents may be bonded to each other to form a ring.

Examples of the ring include a cyclobutene ring and a cyclopentene ring.

The substituent may be further substituted with a substituent, and examples of the substituent include a halogen atom, an alkyl group, an aryl group, and the above crosslinking group.

Among these substituents, a halogen atom or an aryl group is preferred in terms of stability of the compound. A halogen atom is most preferred, and among the halogen atom, a fluorine atom is preferred.

### [Specific Examples of Tetraarylborate Ion]

Specific examples of the tetraarylborate ion used in the organic electroluminescent element of the present invention are listed below, and the invention is not limited thereto.

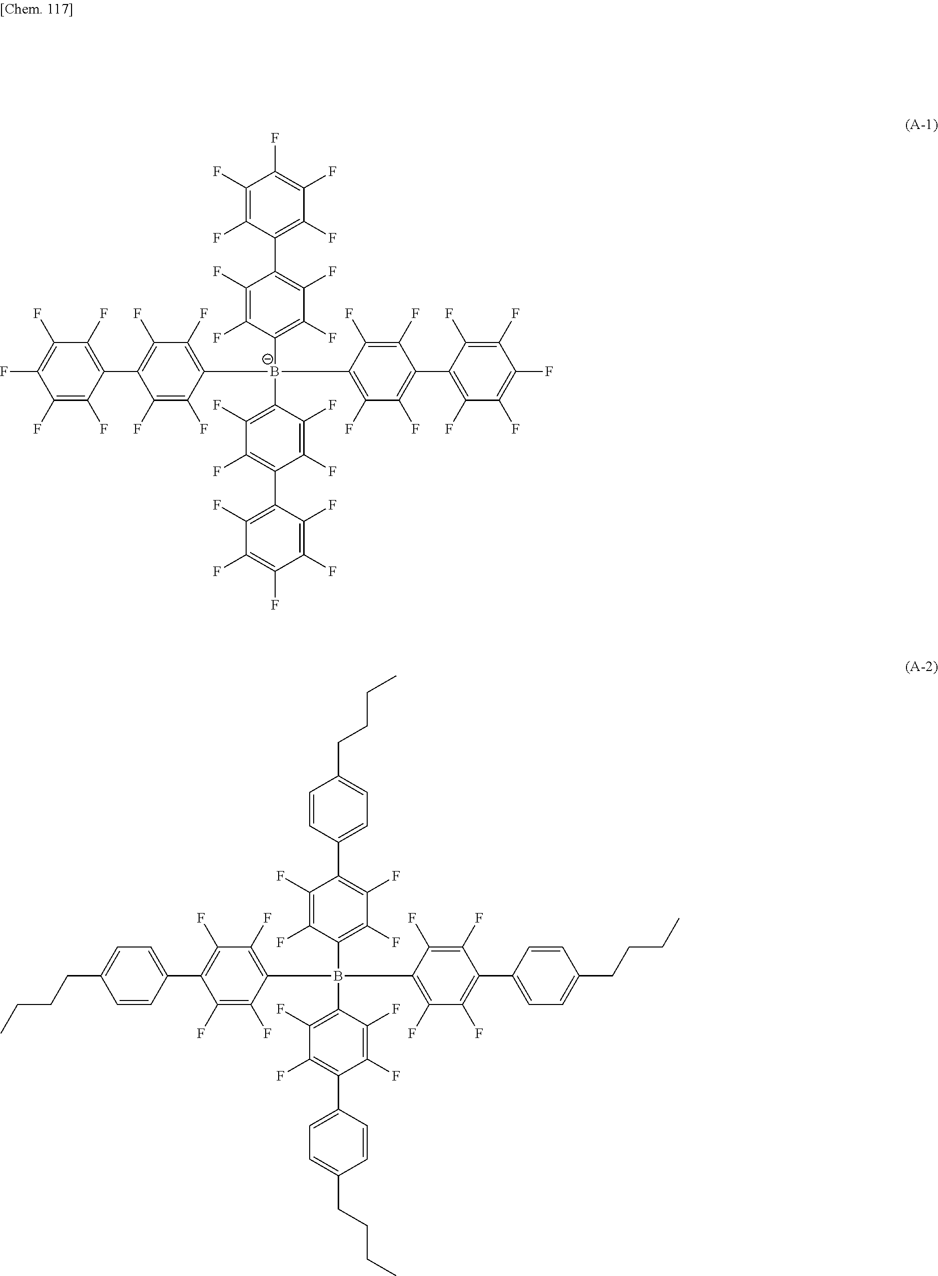

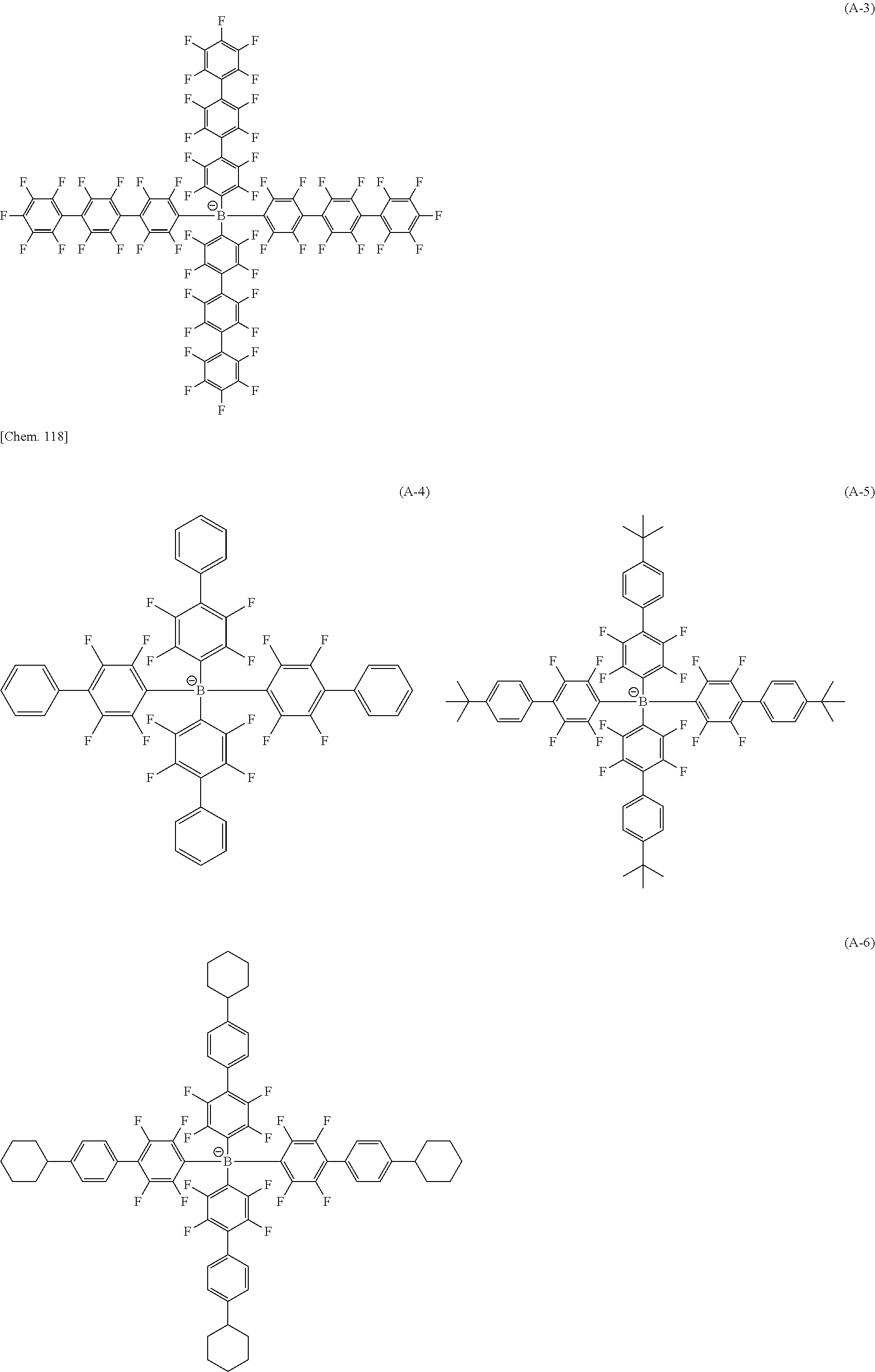

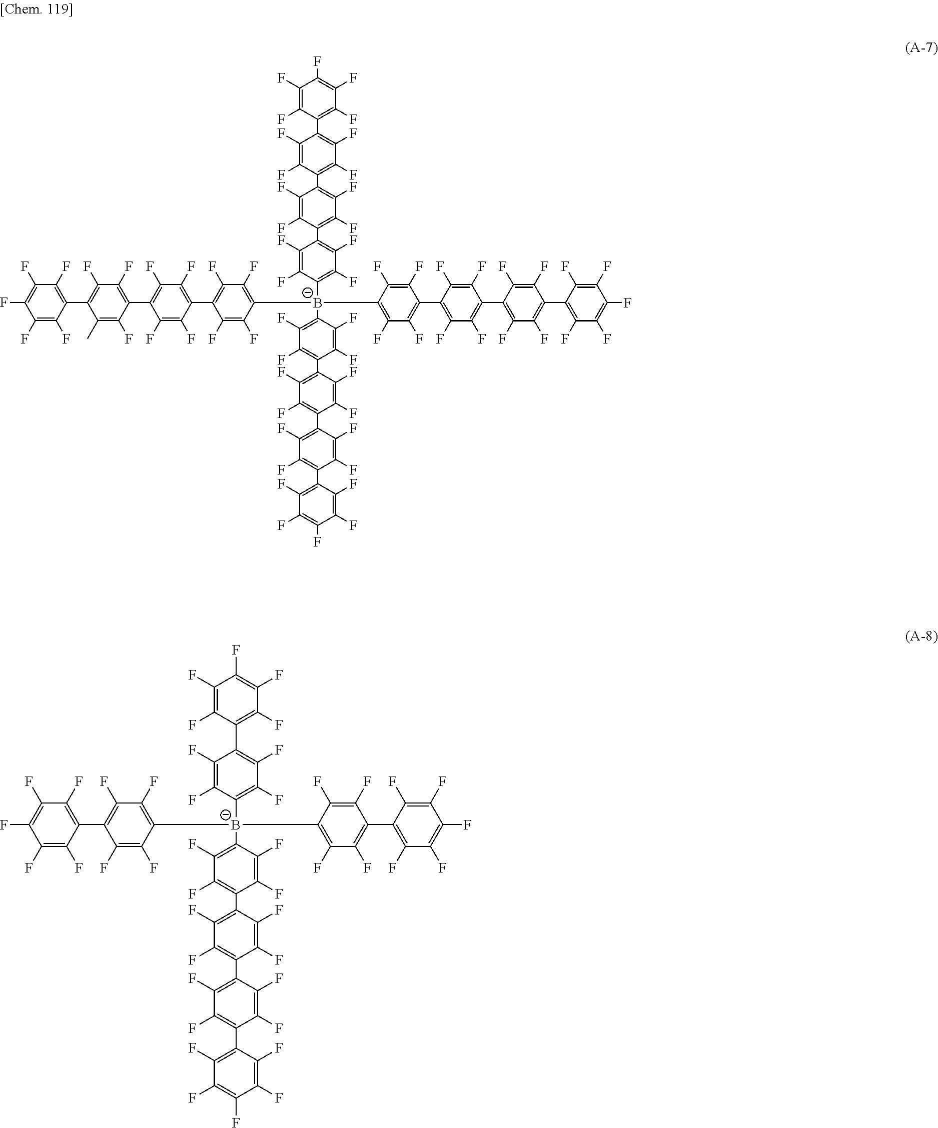

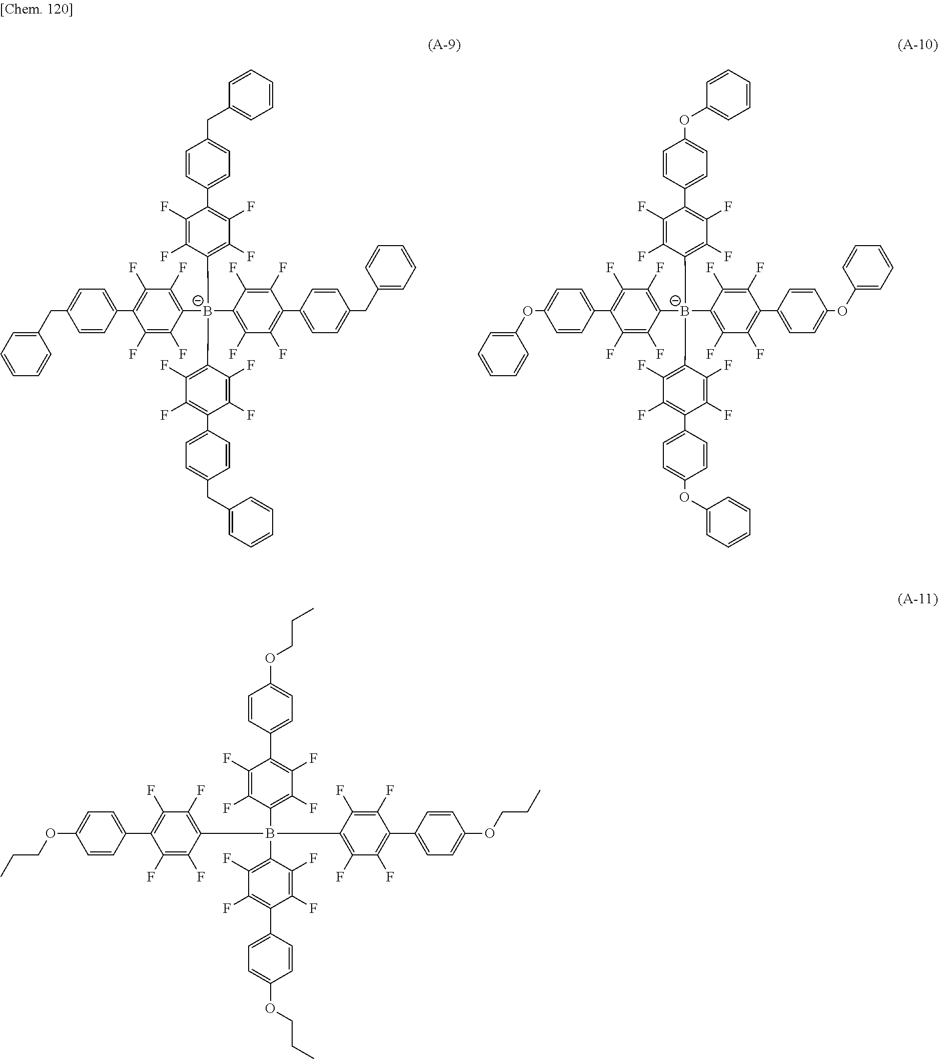

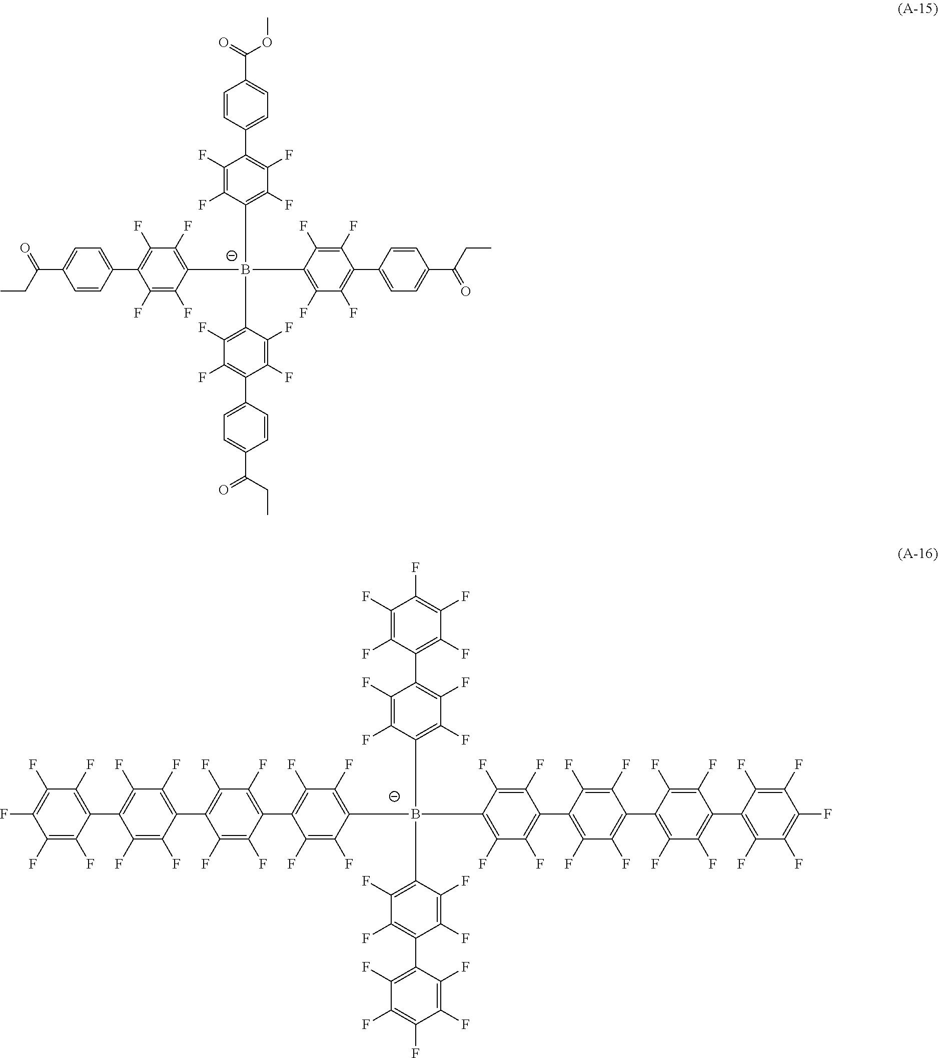

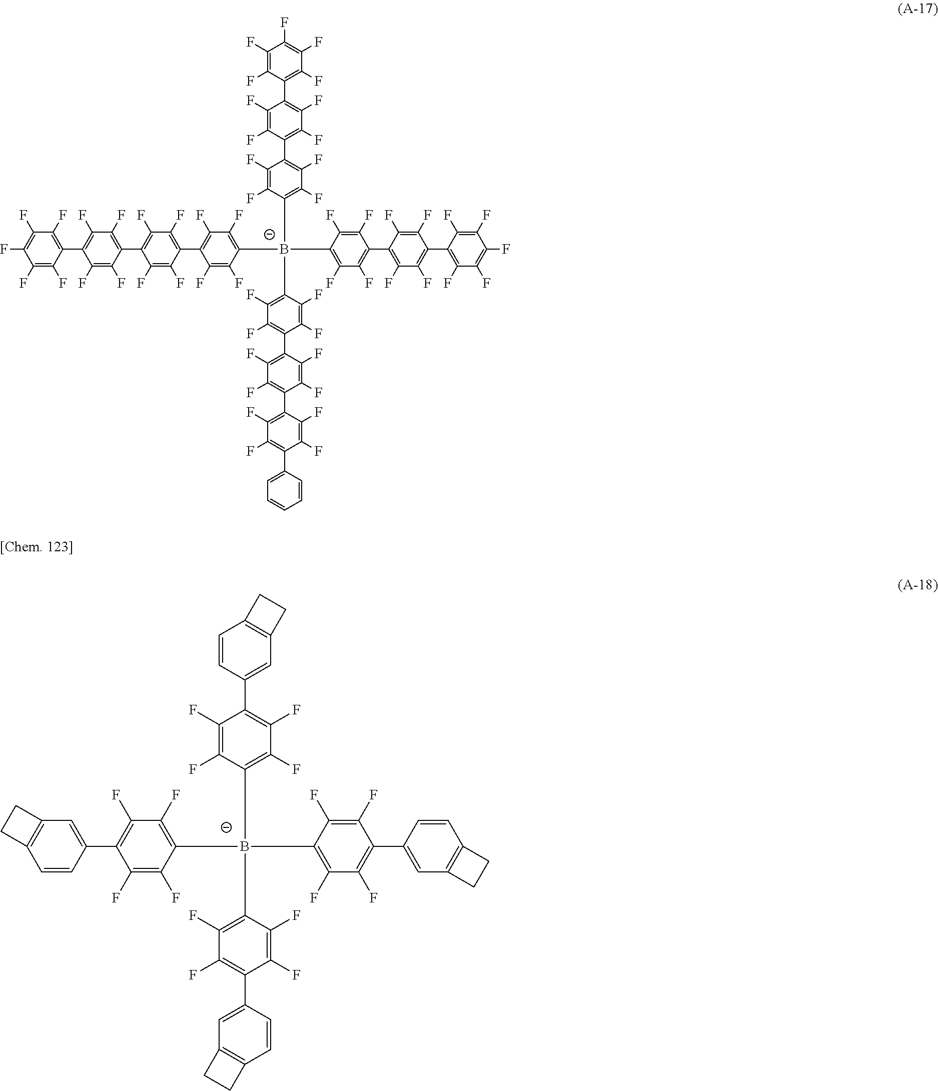

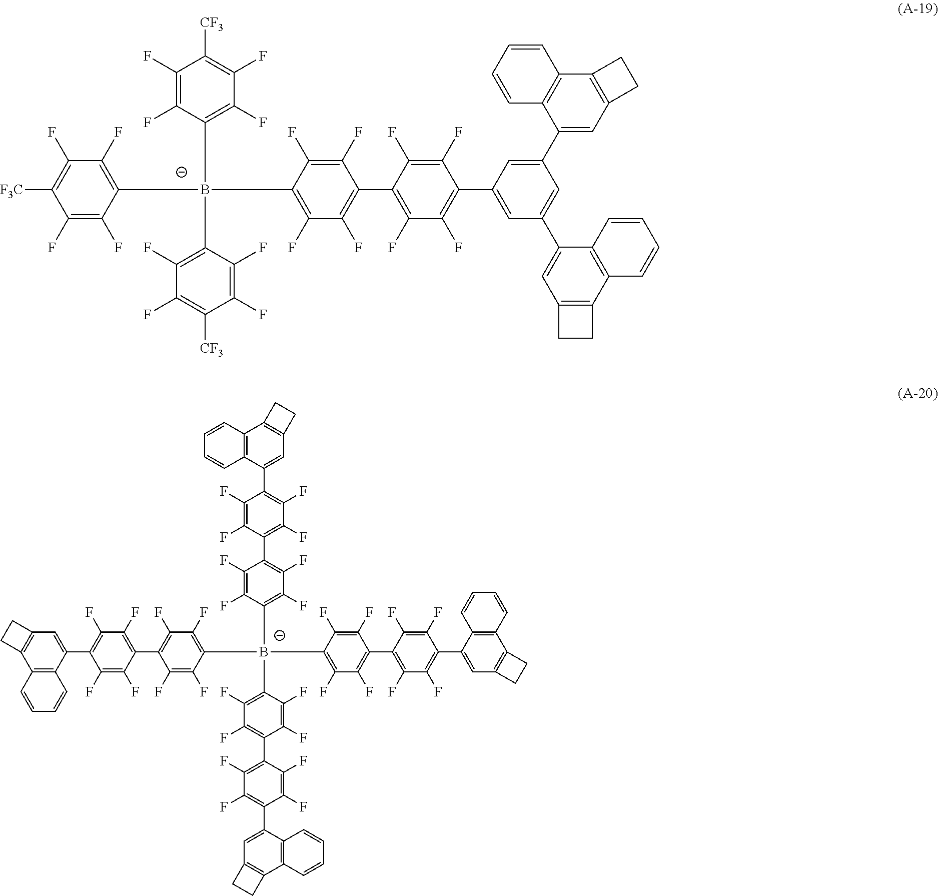

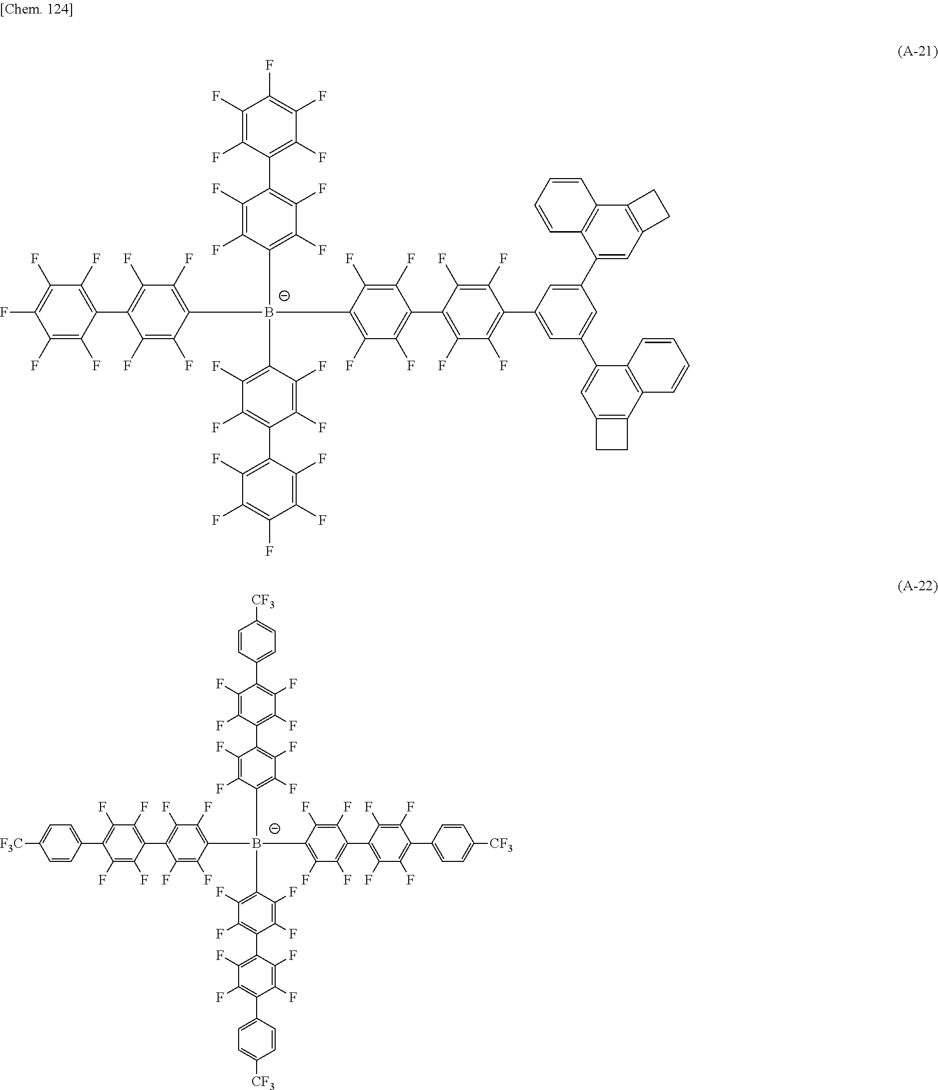 [SMILES: Fc1c(F)c(F)c(-c2c(F)c(F)c([B-](c3c(F)c(F)c(-c4c(F)c(F)c(F)c(F)c4F)c(F)c3F)(c3c(F)c(F)c(-c4c(F)c(F)c(F)c(F)c4F)c(F)c3F)c3c(F)c(F)c(-c4c(F)c(F)c(-c5cc(-c6cc7c(c8ccccc68)CC7)cc(-c6cc7c(c8ccccc68)CC7)c5)c(F)c4F)c(F)c3F)c(F)c2F)c(F)c1F ; Fc1c(F)c(-c2c(F)c(F)c([B-](c3c(F)c(F)c(-c4c(F)c(F)c(-c5ccc(C(F)(F)F)cc5)c(F)c4F)c(F)c3F)(c3c(F)c(F)c(-c4c(F)c(F)c(-c5ccc(C(F)(F)F)cc5)c(F)c4F)c(F)c3F)c3c(F)c(F)c(-c4c(F)c(F)c(-c5ccc(C(F)(F)F)cc5)c(F)c4F)c(F)c3F)c(F)c2F)c(F)c(F)c1-c1ccc(C(F)(F)F)cc1]

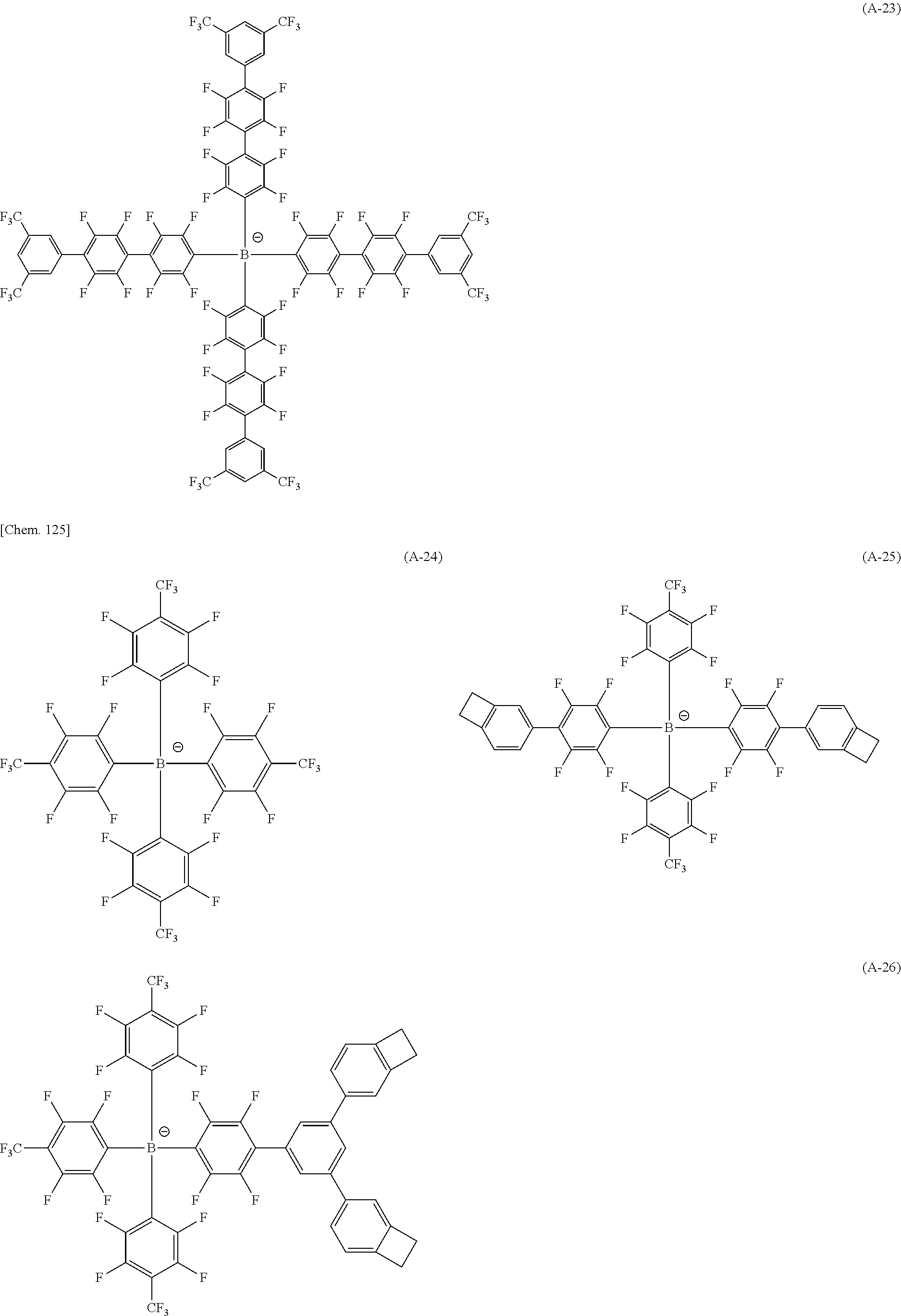

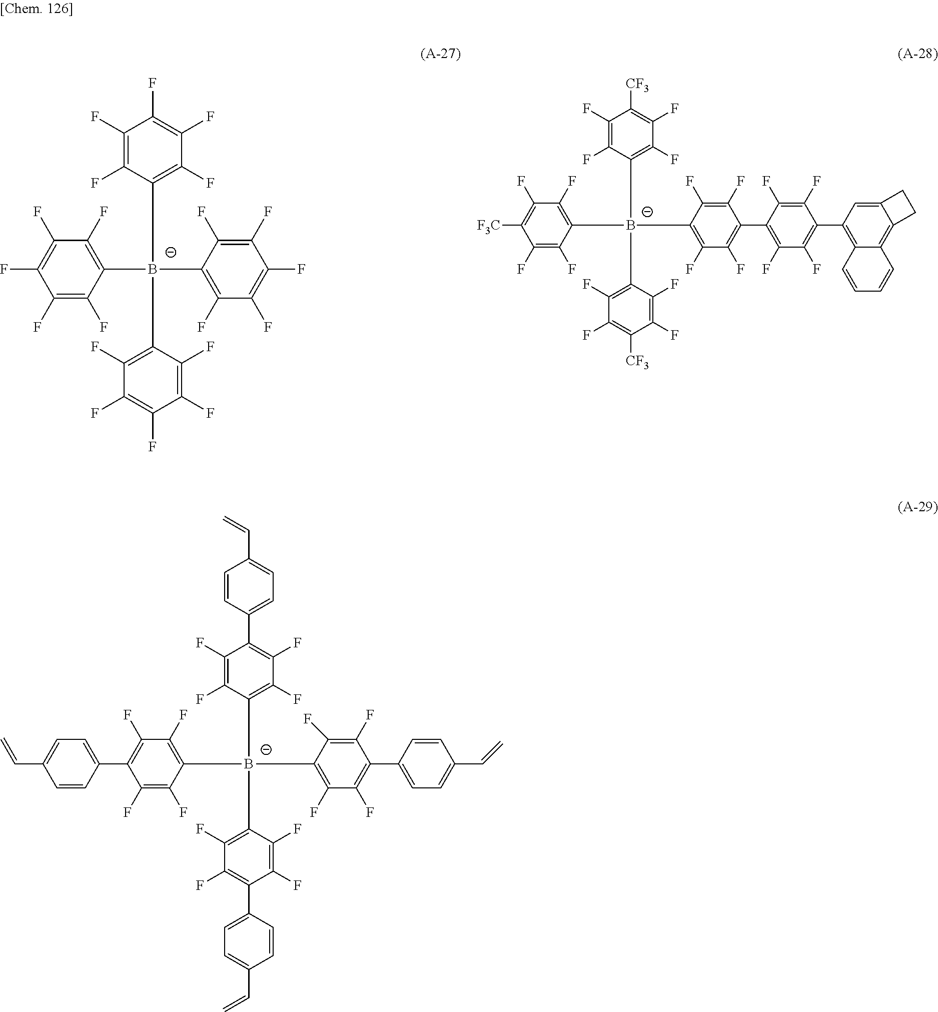

Among the specific examples, compounds (A-1) and (A-2) are preferred in terms of electron acceptability, heat resistance, and solubility. Further, (A-18), (A-19), (A-20), (A-21), (A-25), (A-26), and (A-28) are more preferred from the viewpoint of high stability as a charge transport film composition, and (A-19), (A-21), (A-25), (A-26), and (A-28) are particularly preferred from the viewpoint of stability of the organic electroluminescent element.

The tetraarylborate ions of (A-18), (A-19), (A-20), (A-21), (A-25), (A-26), (A-28), and (A-29) have a crosslinking group and can therefore form a “crosslinking substance of an electron-accepting compound.”

### [Electron-Accepting Ionic Compound Containing Tetraarylborate Ion]

The tetraarylborate ion is also preferably used as an electron-accepting ionic compound containing a tetraarylborate ion. The electron-accepting ionic compound containing a tetraarylborate ion is referred to as the first ionic compound. The first ionic compound is composed of the tetraarylborate ion, which is an anion, and a counter cation. The first ionic compound is used as the electron-accepting compound.

The counter cation is preferably an iodonium cation, a sulfonium cation, a carbocation, an oxonium cation, an ammonium cation, a phosphonium cation, a cycloheptyltrienyl cation, or a ferrocenium cation having a transition metal, more preferably an iodonium cation, a sulfonium cation, a carbocation, or an ammonium cation, and particularly preferably an iodonium cation.

The iodonium cation preferably has a structure represented by a general formula (6) to be described later, and a more preferred structure thereof is also the same.

Specific preferred examples of the iodonium cation include a diphenyliodonium cation, a bis(4-tert-butylphenyl)iodonium cation, a 4-tert-butoxyphenylphenyliodonium cation, a 4-methoxyphenylphenyliodonium cation, and a 4-isopropylphenyl-4-methylphenyliodonium cation.

Specific preferred examples of the sulfonium cation include a triphenylsulfonium cation, a 4-hydroxyphenyldiphenylsulfonium cation, a 4-cyclohexylphenyldiphenylsulfonium cation, a 4-methanephenyldiphenylsulfonium cation, a (4-tert-butoxyphenyl)diphenylsulfonium cation, a bis(4-tert-butoxyphenyl)phenylsulfonium cation, and a 4-cyclohexylphenyldiphenylsulfonium cation.

Specific preferred examples of the carbocation include a trisubstituted carbocation such as a triphenyl carbocation, a tri(methylphenyl) carbocation, and a tri(dimethylphenyl) carbocation.

Specific preferred examples of the ammonium cation include a trialkylammonium cation such as a trimethylammonium cation, a triethylammonium cation, a tripropylammonium cation, a tributylammonium cation, and a tri(n-butyl)ammonium cation; an N,N-dialkylanilinium cation such as an N,N-diethylanilinium cation and an N,N-2,4,6-pentamethylanilinium cation; and a dialkylammonium cation such as a di(isopropyl)ammonium cation and a dicyclohexylammonium cation.

Specific preferred examples of the phosphonium cation include a tetraarylphosphonium cation such as a tetraphenylphosphonium cation, a tetrakis(methylphenyl)phosphonium cation, and a tetrakis(dimethylphenyl)phosphonium cation; and a tetraalkylphosphonium cation such as a tetrabutylphosphonium cation and a tetrapropylphosphonium cation.

Among them, in terms of the film stability of the compound, an iodonium cation, a carbocation, and a sulfonium cation are preferred, and an iodonium cation is more preferred.

The iodonium cation as the counter cation of the first ionic compound preferably has a structure represented by the following formula (6).

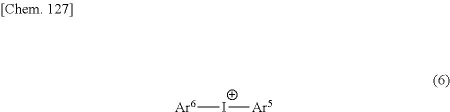

In the formula (6), Ar⁵ and Ar⁶ each independently represent an aromatic hydrocarbon ring group which may have a substituent, or an aromatic heterocyclic group which may have a substituent. The aromatic hydrocarbon ring group or aromatic heterocyclic group as Ar⁵ and Ar⁶ can be selected from structures same as those of Ar¹, Ar², Ar³, and Ar⁴, and preferred structures thereof can also be selected from structures same as those of Ar¹, Ar², Ar³, and Ar⁴.

The counter cation represented by the formula (6) is preferably represented by the following formula (7).

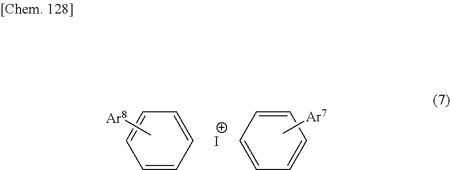

In the formula (7), Ar⁷ and Ar⁸ are the same as the substituents which Ar⁵ and Ar⁶ in the formula (6) may have.

A molecular weight of the first ionic compound used in the present invention is generally 900 or more, preferably 1000 or more, and more preferably 1200 or more, and is generally 10000 or less, preferably 5000 or less, and more preferably 3000 or less. When the molecular weight is too small, delocalization of positive and negative charges may be insufficient, resulting in a decrease in electron-accepting ability. When the molecular weight is too large, charge transport may be hindered.

### Specific Example

Specific examples of the ionic compound with an iodonium cation are given below as the first ionic compound in the present invention, but the first ionic compound is not limited thereto.

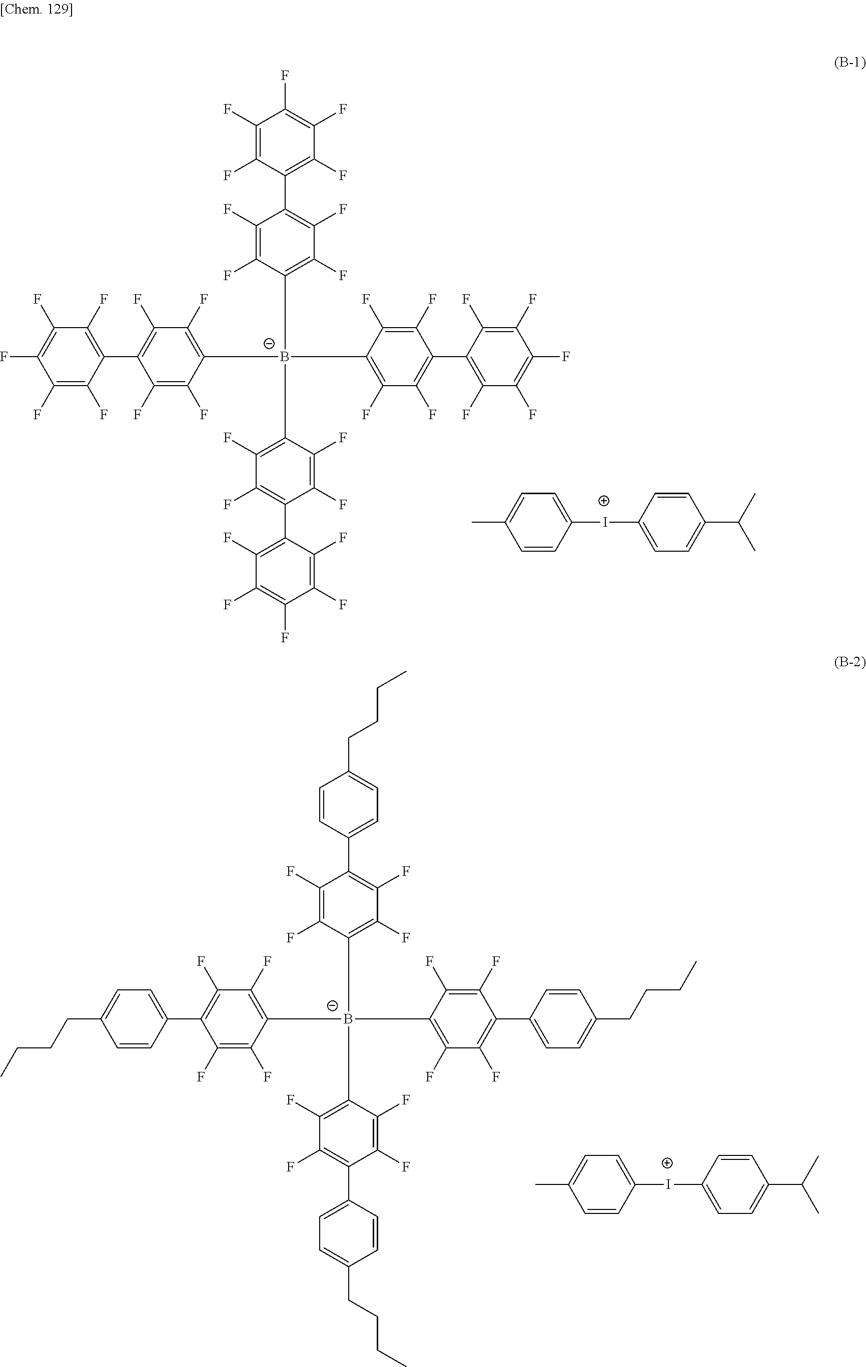 [SMILES: Fc1c(F)c(F)c(-c2c(F)c(F)c([B-](c3c(F)c(F)c(-c4c(F)c(F)c(F)c(F)c4F)c(F)c3F)(c3c(F)c(F)c(-c4c(F)c(F)c(F)c(F)c4F)c(F)c3F)c3c(F)c(F)c(-c4c(F)c(F)c(F)c(F)c4F)c(F)c3F)c(F)c2F)c(F)c1F ; Cc1ccc([I+]c2ccc(C(C)C)cc2)cc1 ; CCCCc1ccc(-c2c(F)c(F)c([B-](c3c(F)c(F)c(-c4ccc(CCCC)cc4)c(F)c3F)(c3c(F)c(F)c(-c4ccc(CCCC)cc4)c(F)c3F)c3c(F)c(F)c(-c4ccc(CCCC)cc4)c(F)c3F)c(F)c2F)cc1 ; Cc1ccc([I+]c2ccc(C(C)C)cc2)cc1]

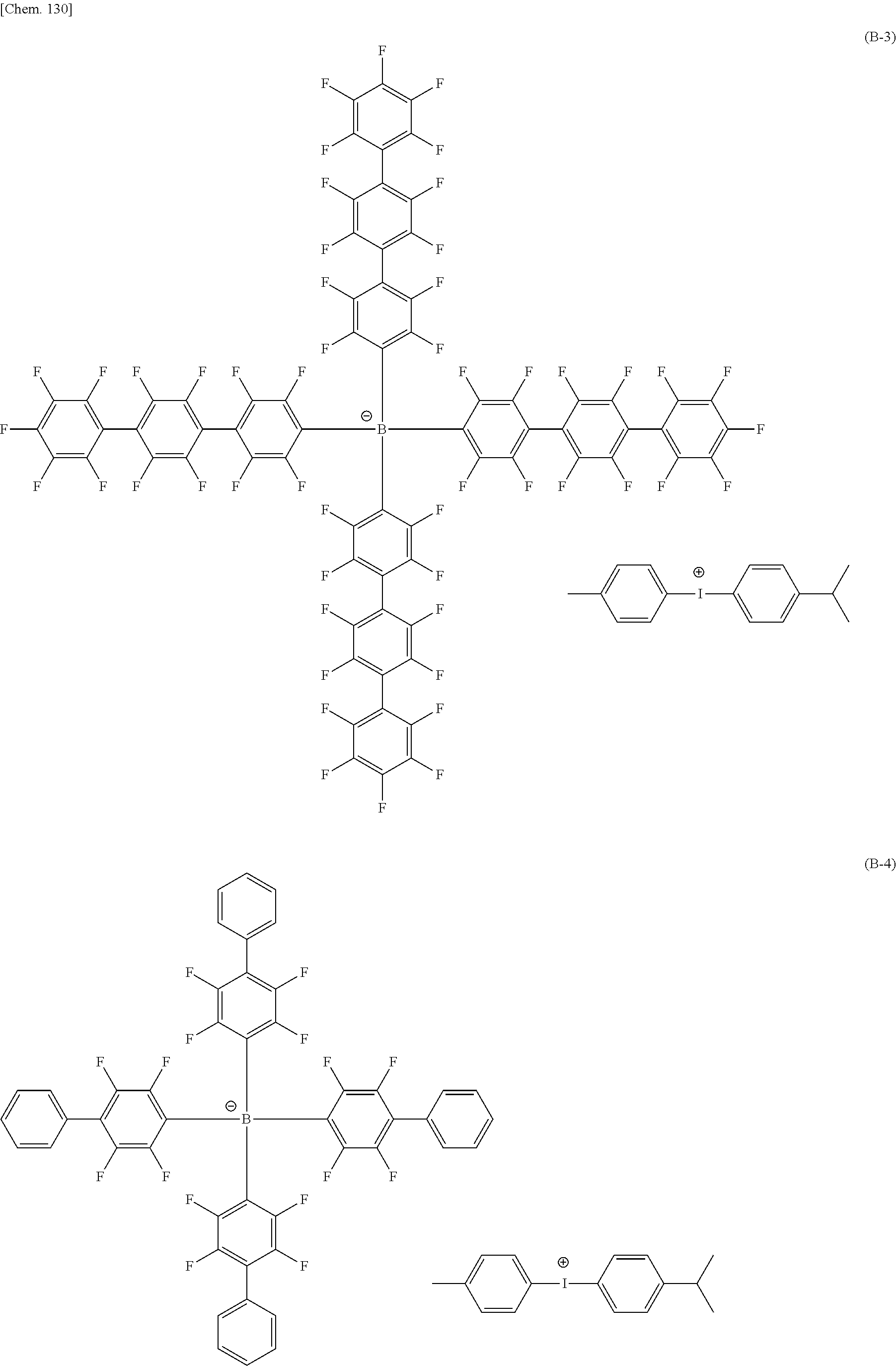

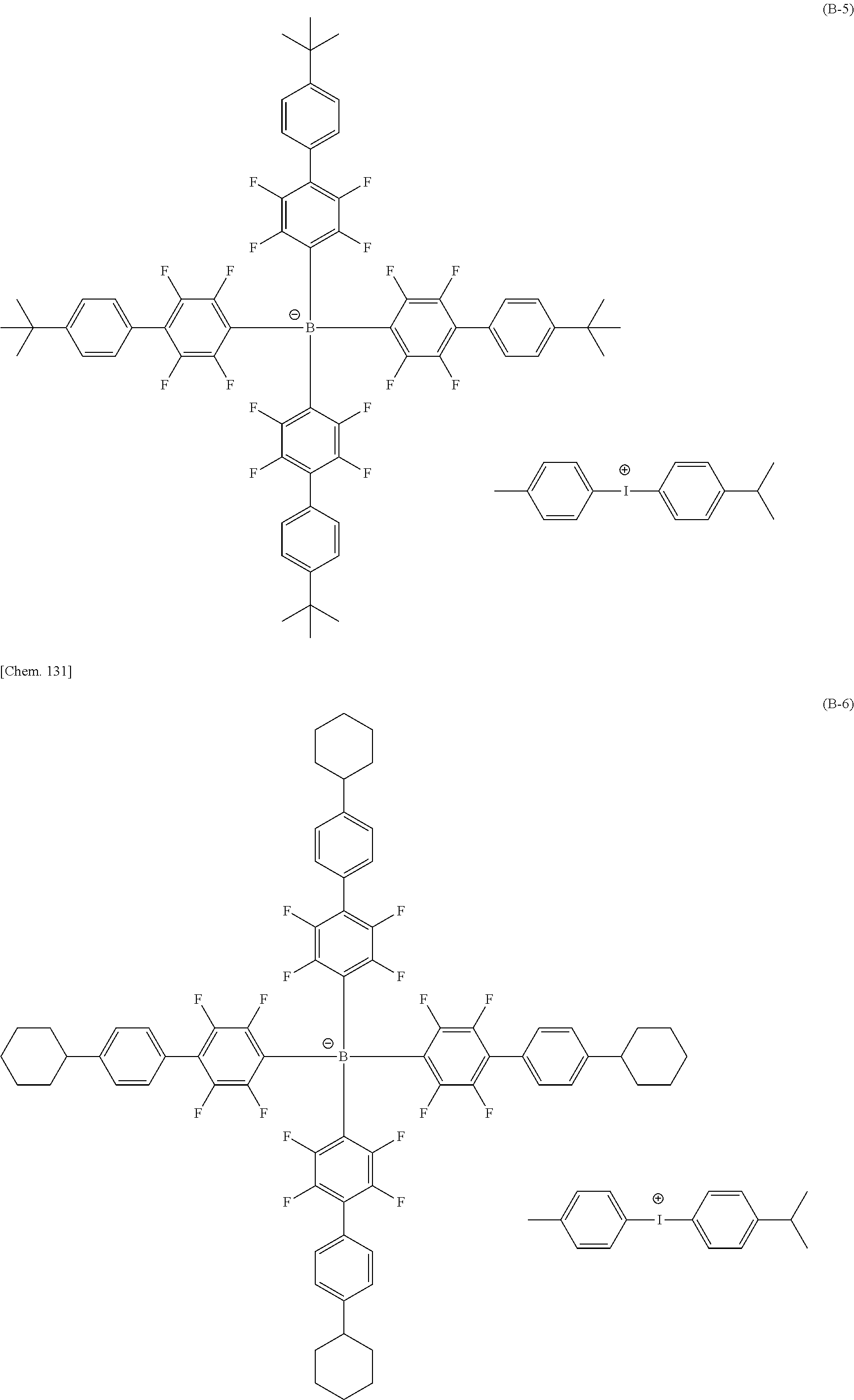

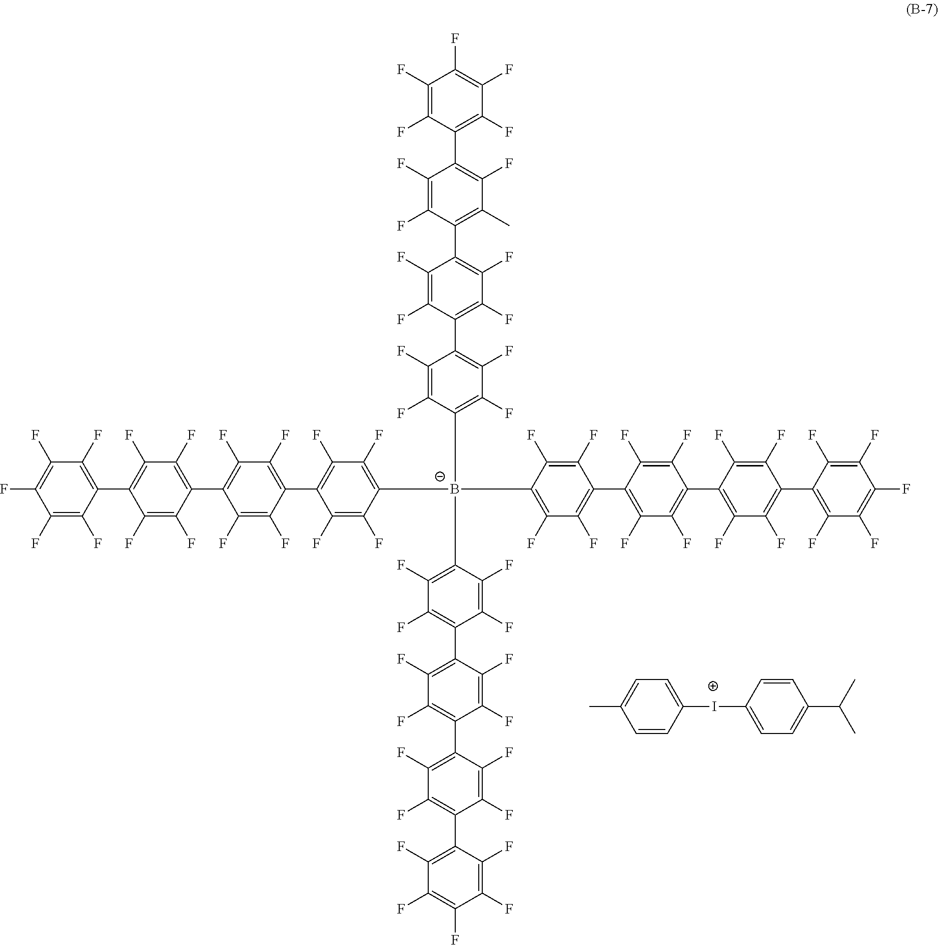 [SMILES: Cc1c(F)c(-c2c(F)c(F)c(F)c(F)c2F)c(F)c(F)c1-c1c(F)c(F)c(-c2c(F)c(F)c([B-](c3c(F)c(F)c(-c4c(F)c(F)c(-c5c(F)c(F)c(-c6c(F)c(F)c(F)c(F)c6F)c(F)c5F)c(F)c4F)c(F)c3F)(c3c(F)c(F)c(-c4c(F)c(F)c(-c5c(F)c(F)c(-c6c(F)c(F)c(F)c(F)c6F)c(F)c5F)c(F)c4F)c(F)c3F)c3c(F)c(F)c(-c4c(F)c(F)c(-c5c(F)c(F)c(-c6c(F)c(F)c(F)c(F)c6F)c(F)c5F)c(F)c4F)c(F)c3F)c(F)c2F)c(F)c1F ; Cc1ccc([I+]c2ccc(C(C)C)cc2)cc1]

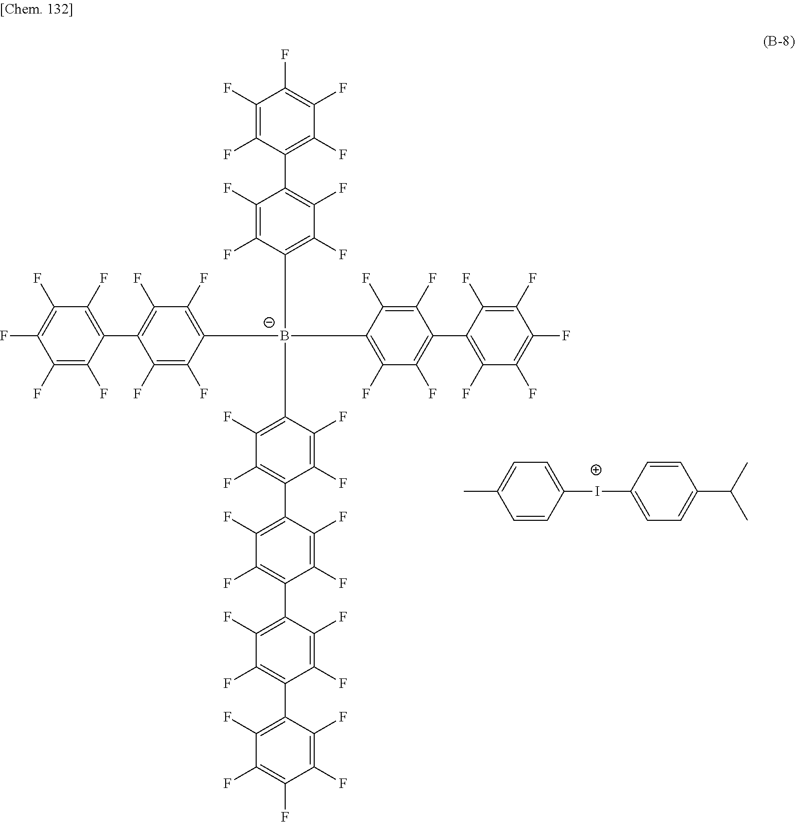 [SMILES: Fc1c(F)c(F)c(-c2c(F)c(F)c(-c3c(F)c(F)c(-c4c(F)c(F)c([B-](c5c(F)c(F)c(-c6c(F)c(F)c(F)c(F)c6F)c(F)c5F)(c5c(F)c(F)c(-c6c(F)c(F)c(F)c(F)c6F)c(F)c5F)c5c(F)c(F)c(-c6c(F)c(F)c(F)c(F)c6F)c(F)c5F)c(F)c4F)c(F)c3F)c(F)c2F)c(F)c1F ; Cc1ccc([I+]c2ccc(C(C)C)cc2)cc1]

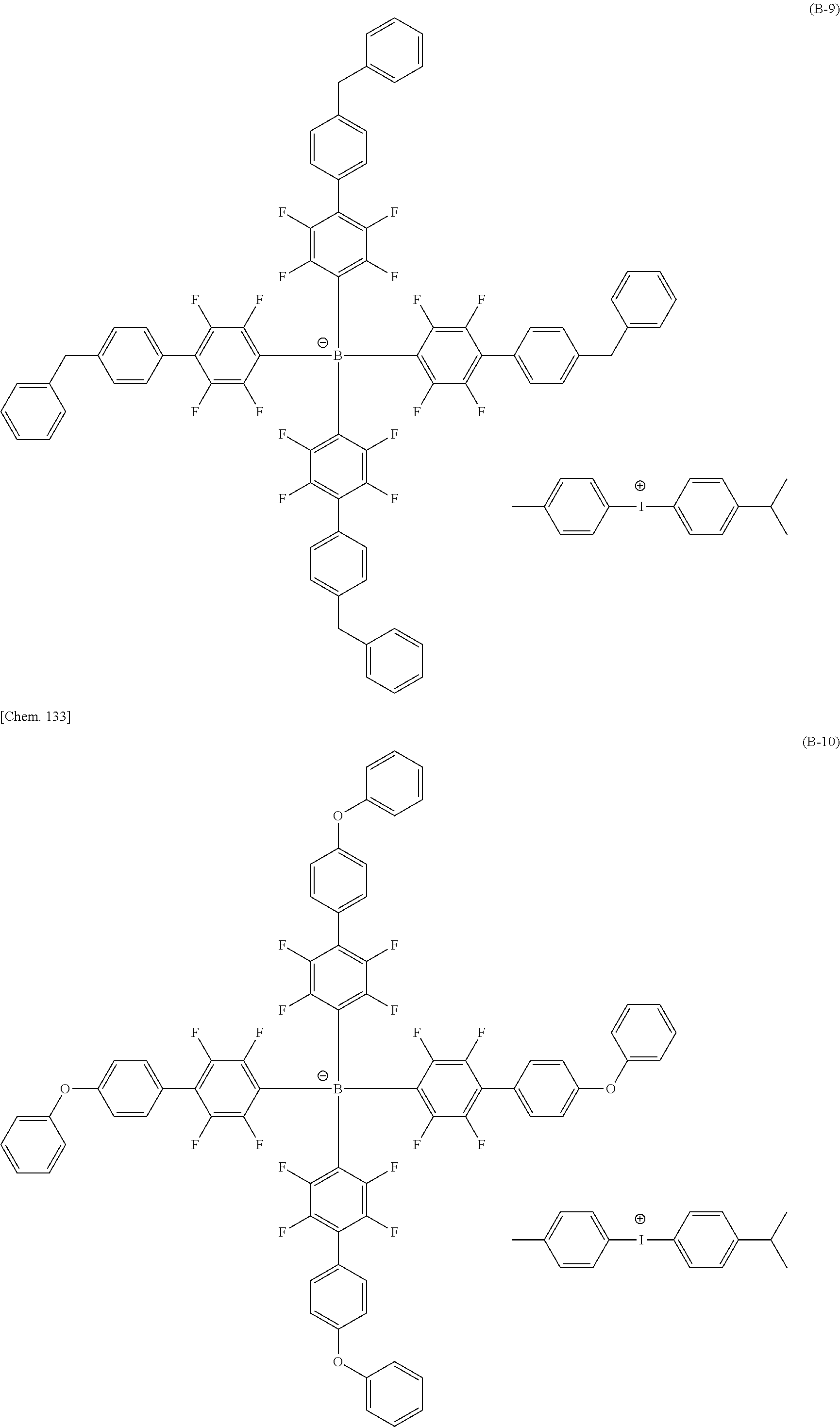 [SMILES: Fc1c(F)c([B-](c2c(F)c(F)c(-c3ccc(Cc4ccccc4)cc3)c(F)c2F)(c2c(F)c(F)c(-c3ccc(Cc4ccccc4)cc3)c(F)c2F)c2c(F)c(F)c(-c3ccc(Cc4ccccc4)cc3)c(F)c2F)c(F)c(F)c1-c1ccc(Cc2ccccc2)cc1 ; Cc1ccc([I+]c2ccc(C(C)C)cc2)cc1 ; Fc1c(F)c([B-](c2c(F)c(F)c(-c3ccc(Oc4ccccc4)cc3)c(F)c2F)(c2c(F)c(F)c(-c3ccc(Oc4ccccc4)cc3)c(F)c2F)c2c(F)c(F)c(-c3ccc(Oc4ccccc4)cc3)c(F)c2F)c(F)c(F)c1-c1ccc(Oc2ccccc2)cc1 ; Cc1ccc([I+]c2ccc(C(C)C)cc2)cc1]

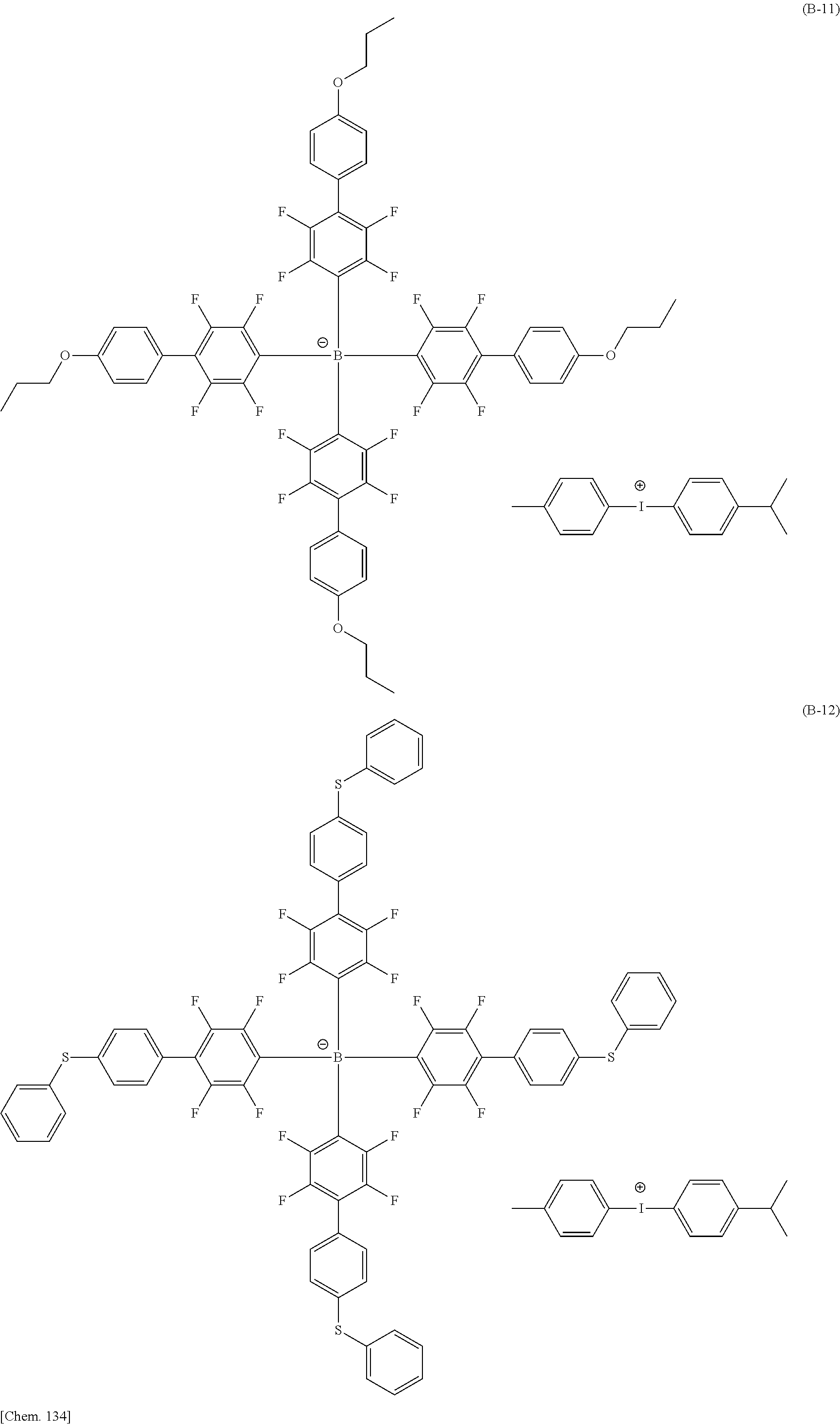

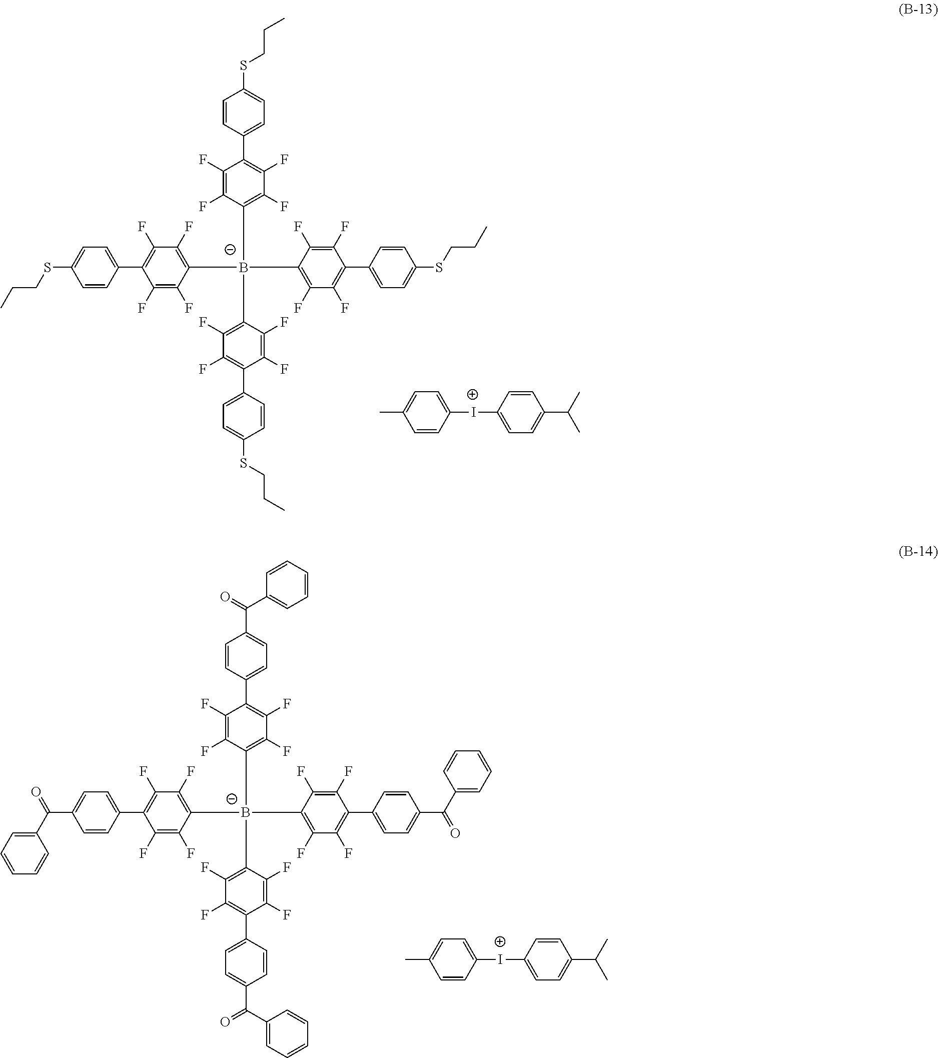

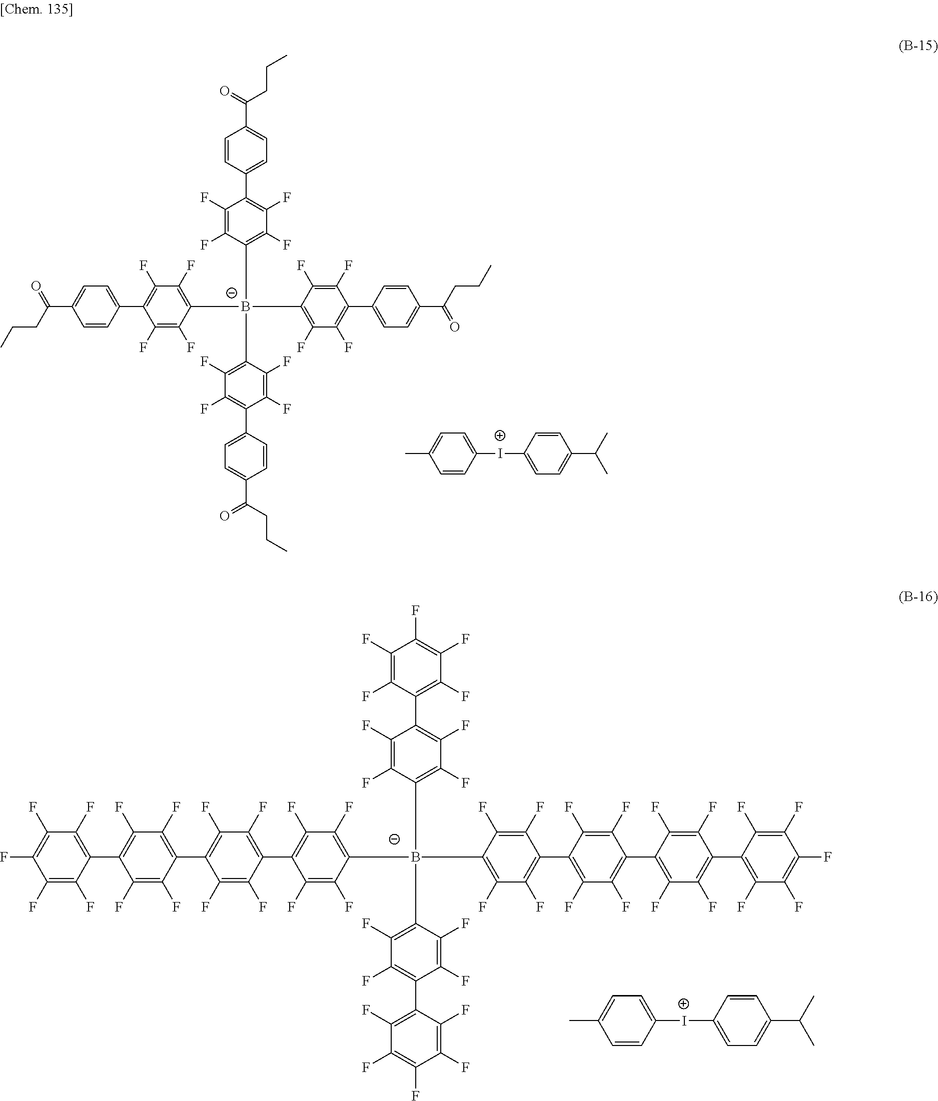

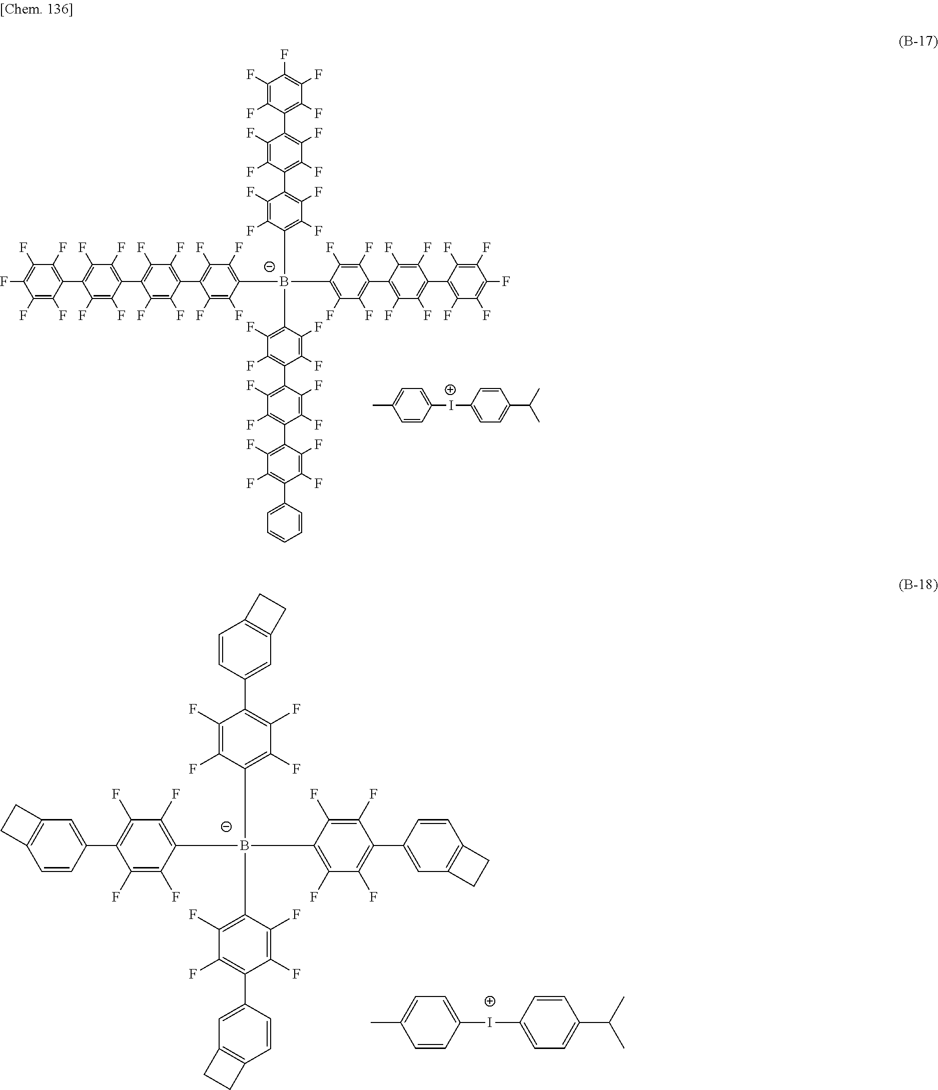

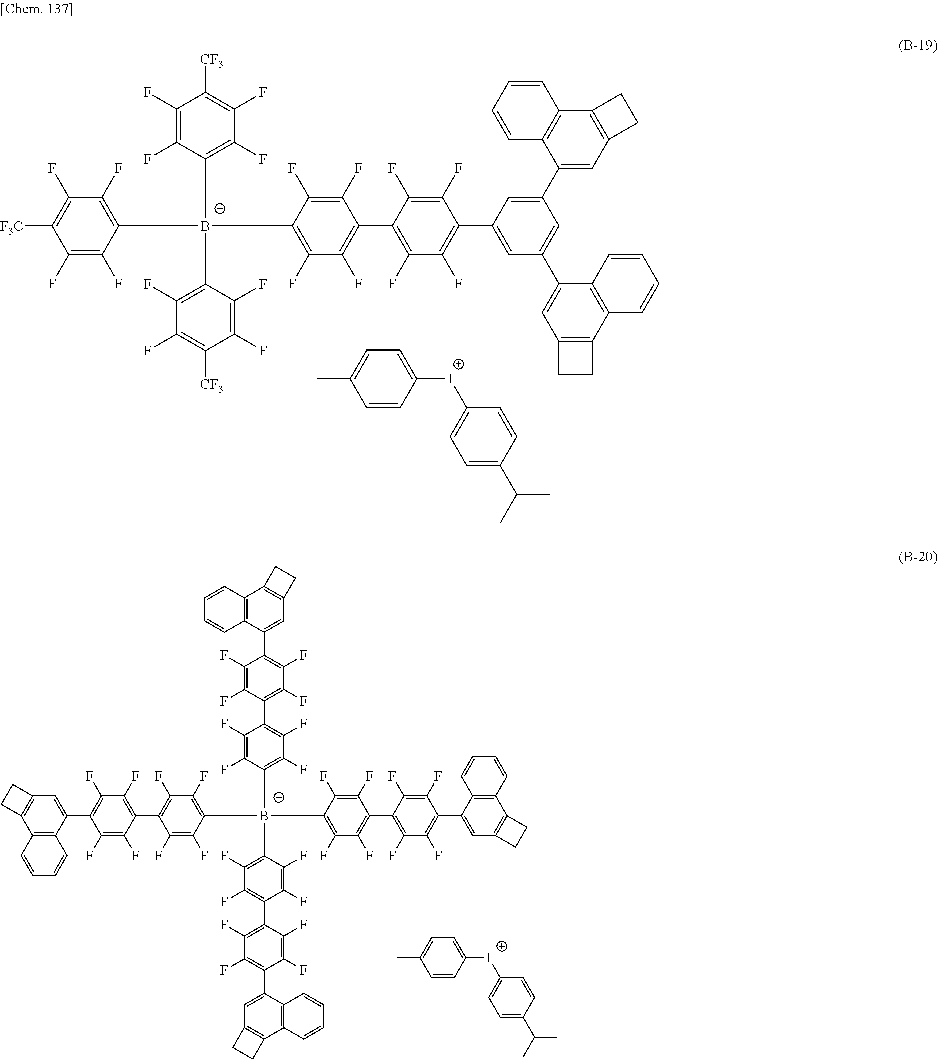

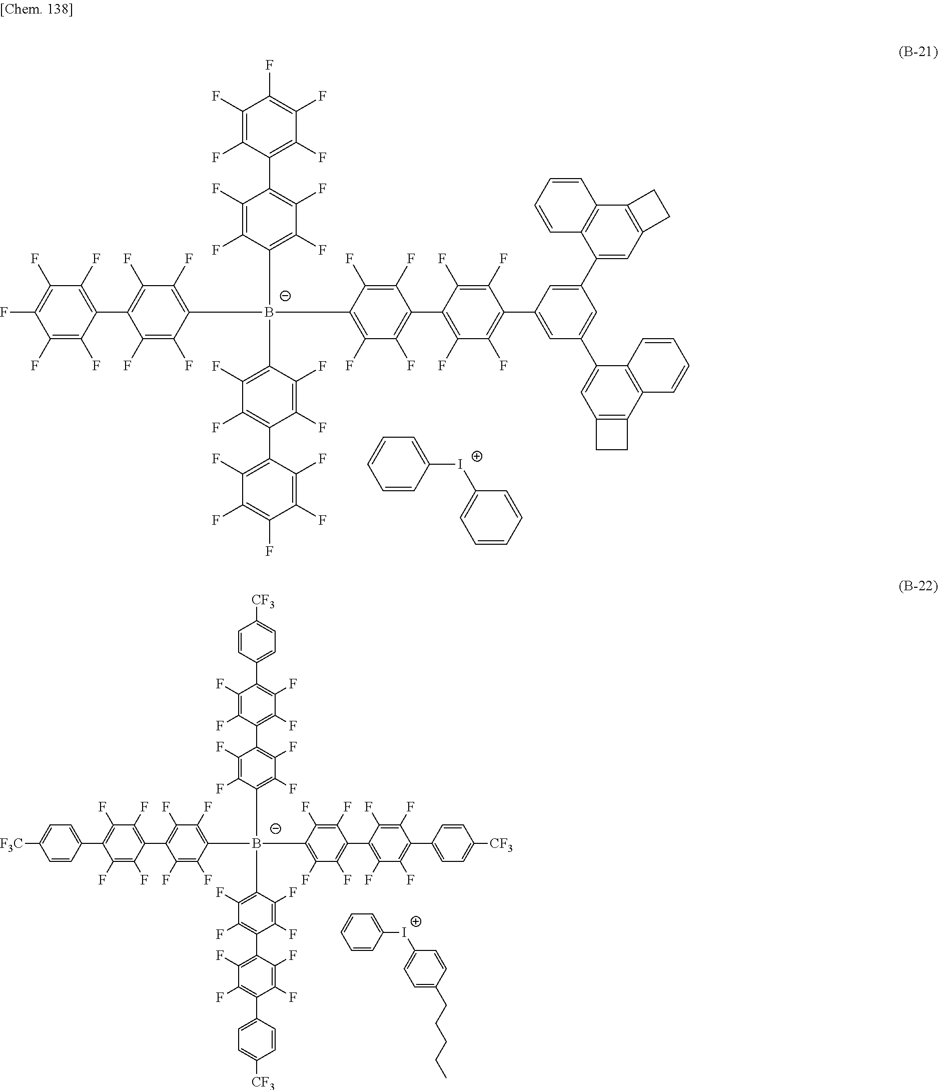

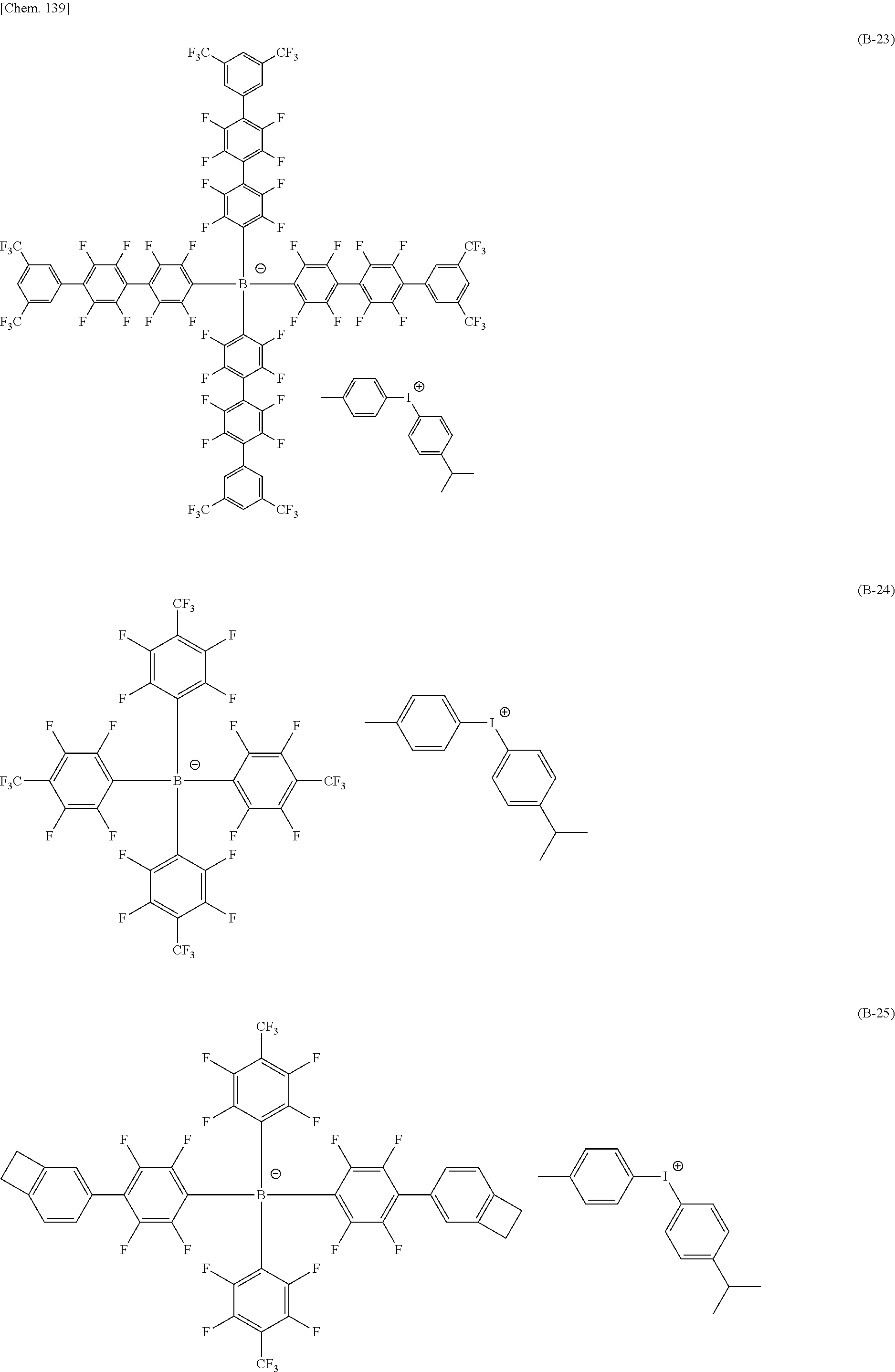

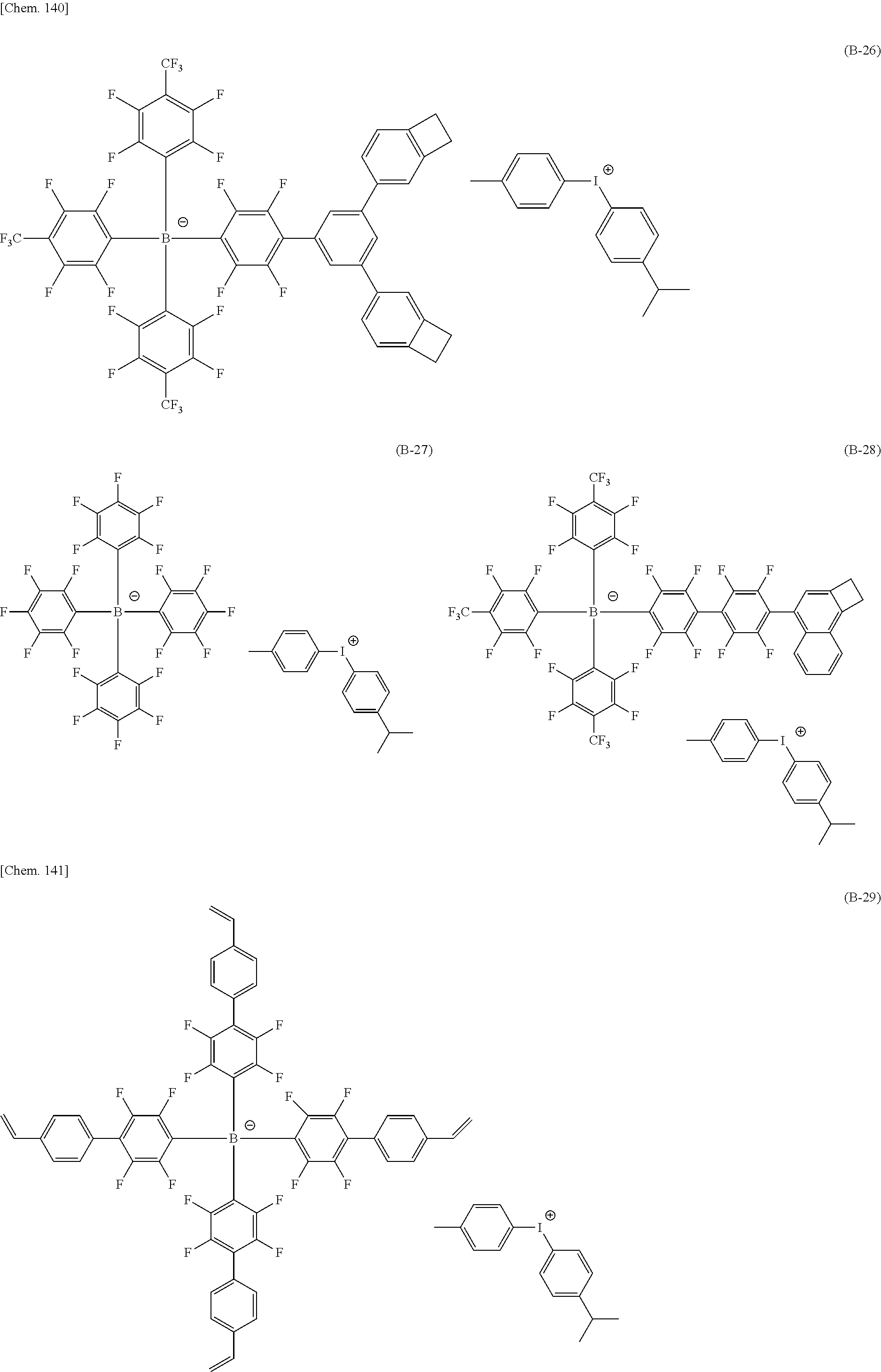

Among the specific examples, compounds (B-1) and (B-2) are preferred in terms of electron acceptability, heat resistance, and solubility. Further, (B-18), (B-19), (B-20), (B-21), (B-25), (B-26), (B-28), and (B-29) are more preferred from the viewpoint of high stability as the charge transport film composition, and (B-19), (B-21), (B-25), (B-26), (B-28), and (B-29) are particularly preferred from the viewpoint of stability of the organic electroluminescent element.

### <Hole Transport Material>

The hole injection layer preferably contains a hole transport material, and is preferably formed using the hole transport material. As the hole transport material, a compound having an ionization potential of 4.5 eV to 5.5 eV is preferred in terms of the hole transport ability. Examples thereof include an aromatic amine compound, a phthalocyanine derivative, a porphyrin derivative, and an oligothiophene derivative. Among them, an aromatic amine compound is preferred from the viewpoint of amorphous property, solubility in a solvent, and transmittance of visible light.

Among the aromatic amine compound, an aromatic tertiary amine compound is particularly preferred in the present invention. The aromatic tertiary amine compound in the present invention is a compound having an aromatic tertiary amine structure, and also contains a compound having a group derived from an aromatic tertiary amine.

The type of the aromatic tertiary amine compound is not particularly limited, and an aromatic tertiary amine high molecular weight compound, which is a high molecular weight compound, is preferred. A weight average molecular weight of the high molecular weight compound is preferably 5000 or more, more preferably 7000 or more, and particularly preferably 10000 or more, and is preferably 1000000 or less, more preferably 200000 or less, and particularly preferably 100000 or less, from the viewpoint of the surface smoothing effect. Among the aromatic tertiary amine high molecular weight compound, a high molecular weight compound having a triphenylamine structure as a main chain is more preferred from the viewpoint of the hole transportability.

### [Aromatic Tertiary Amine High Molecular Weight Compound]

Preferred examples of the aromatic tertiary amine high molecular weight compound include a high molecular weight compound having a repeating unit represented by the following formula (11).

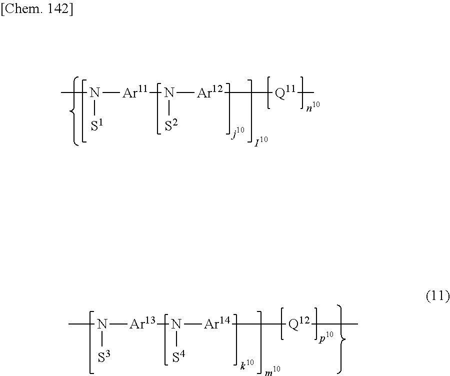

In the formula (11), j¹⁰, k¹⁰, l¹⁰, m¹⁰, n¹⁰, and p¹⁰ each independently represent an integer of 0 or more. Here, l¹⁰+m¹⁰≥1.

In the formula (11), Ar¹¹, Ar¹², and Ar¹⁴ each independently represent a divalent aromatic ring group which may have a substituent. Ar¹³ represents a divalent aromatic ring group which may have a substituent or a divalent group represented by the following formula (12), Q¹¹ and Q¹² each independently represent an oxygen atom, a sulfur atom, or a hydrocarbon chain having 6 or less carbon atoms which may have a substituent, and S¹ to S⁴ each independently represent a group represented by the following formula (13).

The aromatic ring group of Ar¹¹, Ar¹², and Ar¹⁴ represents a divalent aromatic hydrocarbon group which may have a substituent, a divalent aromatic heterocyclic group which may have a substituent, or a divalent group in which at least two groups selected from a divalent aromatic hydrocarbon group which may have a substituent and a divalent aromatic heterocyclic group which may have a substituent are linked. The carbon number of the aromatic ring group of Ar¹¹, Ar¹², and Ar¹⁴ is preferably 60 or less.

The number of carbon atoms of the aromatic hydrocarbon group is preferably 6 or more and 30 or less. Specific examples thereof include a 6-membered monocyclic or 2- to 5-fused divalent group, such as a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, or a fluorene ring.

The number of carbon atoms of the aromatic heterocyclic group is preferably 3 or more and 30 or less. Specific examples thereof include a divalent group such as a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a benzimidazole ring, a perimidine ring, a quinazoline ring, a quinazolinone ring, or an azulene ring.

Among them, a divalent group derived from a benzene ring, a naphthalene ring, a fluorene ring, a pyridine ring, or a carbazole ring, or a divalent biphenyl group is preferred, and a divalent group derived from a benzene ring, a fluorene ring, or a carbazole ring, or a divalent biphenyl group is more preferred, from the viewpoint of excellent charge transportability, durability, and heat resistance.

Accordingly, Ar¹¹, Ar¹², and Ar¹⁴ each preferably represent a group selected from a divalent benzene ring which may have a substituent, a divalent fluorene ring which may have a substituent, or a divalent carbazole ring which may have a substituent, or a divalent group in which two or more rings selected from these structures are linked, and the number of carbon atoms of the aromatic ring group of Ar¹¹, Ar¹², and Ar¹⁴ is preferably 60 or less.

The aromatic ring group may have a substituent, and the substituent which the aromatic ring group may have may be selected from the above substituent group Z.

The case where Ar¹³ is an aromatic ring group is the same as the case of Ar¹¹, Ar¹², and Ar¹⁴.

Ar¹³ is also preferably a divalent group represented by the following formula (12).

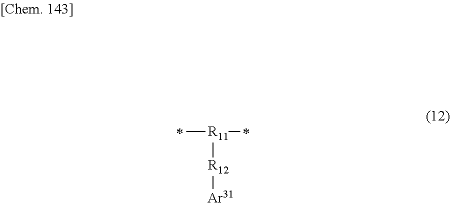

In the formula (12), R¹¹ represents an alkyl group, an aromatic ring group, or a trivalent group consisting of an alkyl group having 40 or less carbon atoms and an aromatic ring group, which may have a substituent. R¹² represents an alkyl group, an aromatic ring group, or a divalent group consisting of an alkyl group having 40 or less carbon atoms and an aromatic ring group, which may have a substituent. Ar³¹ represents a monovalent aromatic ring group or a monovalent crosslinking group, which may have a substituent. The asterisk (*) represents a bond with the nitrogen atom of the formula (11).

Specific examples of the aromatic ring group of R¹¹ include a phenyl ring, a naphthalene ring, a carbazole ring, a dibenzofuran ring, a dibenzothiophene ring, and a trivalent group formed by linking these rings and derived from a linking ring having 30 or less carbon atoms.

Specific examples of the alkyl group of R¹¹ include a trivalent group derived from methane, ethane, propane, isopropane, butane, isobutane, and pentane.

Specific examples of the aromatic ring group of R¹² include a phenyl ring, a naphthalene ring, a carbazole ring, a dibenzofuran ring, a dibenzothiophene ring, and a divalent group formed by linking these rings and derived from a linking ring having 30 or less carbon atoms.

Specific examples of the alkyl group of R¹² include a divalent group derived from methane, ethane, propane, isopropane, butane, isobutane, and pentane.

Specific examples of the aromatic ring group of Ar³¹ include a phenyl ring, a naphthalene ring, a carbazole ring, a dibenzofuran ring, a dibenzothiophene ring, and a monovalent group formed by linking these rings and derived from a linking ring having 30 or less carbon atoms.

The crosslinking group of Ar³¹ is not particularly limited, and is the same as the crosslinking group of the electron-accepting compound having the crosslinking group that is contained in the hole injection layer of the organic electroluminescent element of the present invention, and a crosslinking group represented by any one of the formulae (X1) to (X18) is preferred. Among them, preferred examples thereof include a group derived from a benzocyclobutene ring, a naphthocyclobutene ring, or an oxetane ring, a vinyl group, and an acryl group. From the viewpoint of the stability of the compound, a group derived from a benzocyclobutene ring or a naphthocyclobutene ring is preferred.

S¹ to S⁴ each independently represent a group represented by the following formula (13).

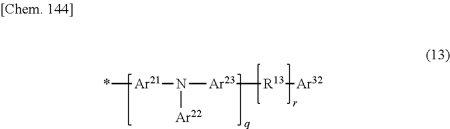

In the formula (13), q and r each independently represent an integer of 0 to 6.
q and r each independently preferably represent 0 to 4, and more preferably represent 0 or 1.

Ar²¹ and Ar²³ each independently represent a divalent aromatic ring group, which may have a substituent. Ar²² represents a monovalent aromatic ring group which may have a substituent, and R¹³ represents an alkyl group, an aromatic ring group, or a divalent group consisting of an alkyl group and an aromatic ring group, which may have a substituent. Ar³² represents a monovalent aromatic ring group or a monovalent crosslinking group, which may have a substituent. The asterisk (*) represents a bond with the nitrogen atom of the general formula (11).

Examples of the aromatic ring group of Ar²¹ and Ar²³ are the same as those of Ar¹¹, Ar¹², and Ar¹⁴.

The aromatic ring group of Ar²² and Ar³² represents a monovalent aromatic hydrocarbon group which may have a substituent, a monovalent aromatic heterocyclic group which may have a substituent, or a monovalent group in which at least two groups selected from a monovalent aromatic hydrocarbon group which may have a substituent and a monovalent aromatic heterocyclic group which may have a substituent are linked. The number of carbon atoms of the aromatic ring group of Ar²² and Ar³² is preferably 60 or less.

The number of carbon atoms of the aromatic hydrocarbon group is preferably 6 or more and 30 or less. Specific examples thereof include a 6-membered monocyclic or 2- to 5-fused monovalent group, such as a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, or a fluorene ring.

The number of carbon atoms of the aromatic heterocyclic group is preferably 3 or more and 30 or less. Specific examples thereof include a monovalent group such as a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a benzimidazole ring, a perimidine ring, a quinazoline ring, a quinazolinone ring, or an azulene ring.

Among them, a monovalent group derived from a benzene ring, a naphthalene ring, a fluorene ring, a pyridine ring or a carbazole ring, or a biphenyl group is preferred because of excellent charge transportability, durability, and heat resistance.

The aromatic ring group may have a substituent, and the substituent which the aromatic ring group may have may be selected from the above substituent group Z.

Examples of the alkyl group or aromatic ring group of R¹³ are the same as those of R¹².

The crosslinking group of Ar³² is not particularly limited, and is the same as the examples of the crosslinking group of Ar³¹, and preferred examples thereof are also the same.

Each of the above Ar¹¹ to Ar¹⁴, R¹¹, R¹², Ar²¹ to Ar²³, Ar³¹ to Ar³², Q¹¹, and Q¹² may further have a substituent without departing from the spirit of the present invention. A molecular weight of the substituent is generally 400 or less, and preferably about 250 or less. A type of the substituent is not particularly limited, and examples thereof include one kind or two or more kinds selected from the substituent group Z.

In particular, among the high molecular weight compound having a repeating unit represented by the formula (11), a high molecular weight compound having a repeating unit represented by the following formula (14) is preferred since hole injection and transport properties are very high.

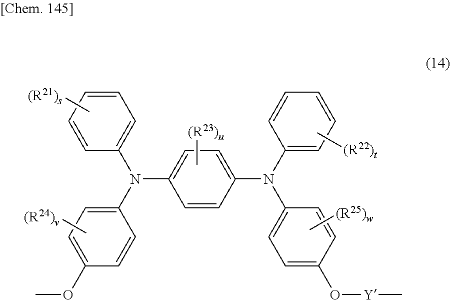

In the formula (14), R²¹ to R²⁵ each independently represent any substituent. Specific examples of the substituents of R²¹ to R²⁵ are the same as those described in the above substituent group Z.

Y′ represents a divalent aromatic ring group having 30 or less carbon atoms which may have a substituent. Examples of the aromatic ring group of Y′ are the same as those in the cases of Ar¹¹, Ar¹², and Ar¹⁴, and the substituents which the aromatic ring group of Y′ may have are also the same.

s and t each independently represent an integer of 0 or more and 5 or less.

u, v, and w each independently represent an integer of 0 or more and 4 or less.

Preferred examples of the aromatic tertiary amine high molecular weight compound include a high molecular weight compound having a repeating unit represented by the following formula (15) and/or formula (16).

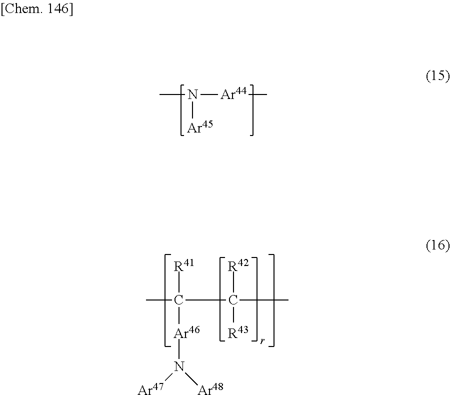

In the formulae (15) and (16), Ar⁴⁵, Ar⁴⁷, and Ar⁴⁸ each independently represent a monovalent aromatic hydrocarbon group which may have a substituent or a monovalent aromatic heterocyclic group which may have a substituent. Ar⁴⁴ and Ar⁴⁶ each independently represent a divalent aromatic hydrocarbon group which may have a substituent or a divalent aromatic heterocyclic group which may have a substituent. R⁴¹ to R⁴³ each independently represent a hydrogen atom or any substituent. r represents an integer of 0 to 2.

Specific examples and preferred examples of Ar⁴⁵, Ar⁴⁷, and Ar⁴⁸, examples of the substituent which Ar⁴⁵, Ar⁴⁷, and Ar⁴⁸ may have, and preferred examples of the substituent are each independently the same as those of Ar²² and Ar³².

Specific examples and preferred examples of Ar⁴⁴ and Ar⁴⁶, examples of the substituent which Ar⁴⁴ and Ar⁴⁶ may have, and preferred examples of the substituent are each independently the same as those of Ar¹¹ and Ar¹⁴.

R⁴¹ to R⁴³ each preferably represent a hydrogen atom or a substituent described in the above substituent group Z, and among them, a hydrogen atom, an alkyl group, an alkoxy group, an amino group, an aromatic hydrocarbon group, or an aromatic heterocyclic group is preferred.

r is preferably 0 or 1, and more preferably 0.

Preferred specific examples of the repeating unit represented by the formula (15) and the formula (16) applicable in the present invention are shown below, and the present invention is not limited thereto.

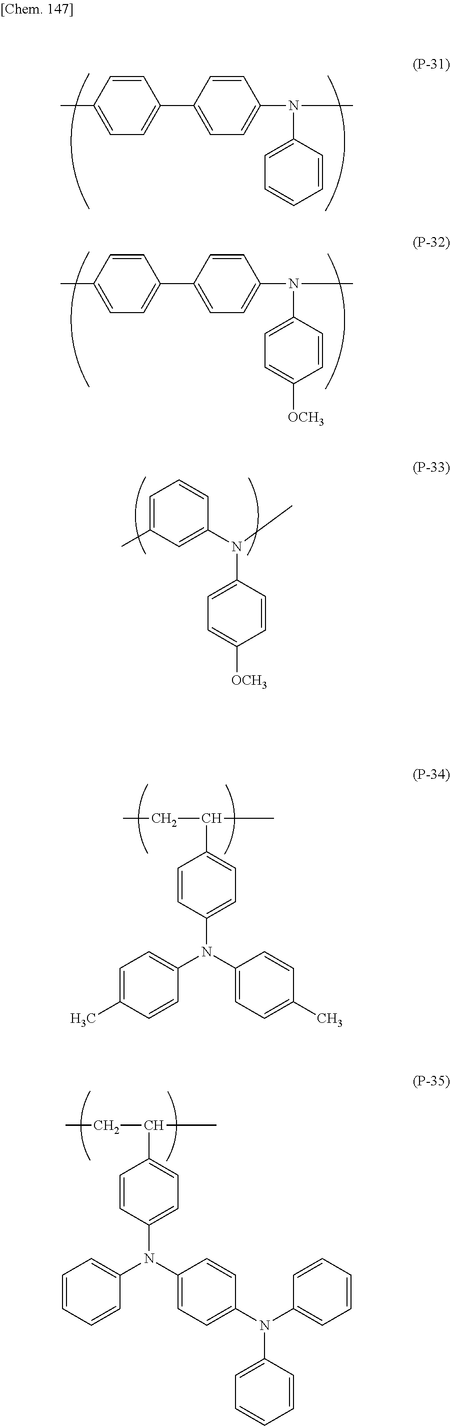

Other examples of the aromatic amine compound applicable as a hole transport material include related-art known compounds that are used as a hole injection and transport layer formation material in the organic electroluminescent element. Examples thereof include an aromatic diamine compound in which tertiary aromatic amine units are linked, such as 1,1-bis(4-di-p-tolylaminophenyl)cyclohexane (JPS59-194393A); an aromatic amine represented by 4,4′-bis[N-(1-naphthyl)-N-phenylamino]biphenyl, in which two or more tertiary amines are contained and two or more fused aromatic rings are substituted for nitrogen atoms (JPH05-234681A); an aromatic triamine which is a derivative of triphenylbenzene and has a starburst structure (U.S. Pat. No. 4,923,774); an aromatic diamine such as N,N′-diphenyl-N,N′-bis(3-methylphenyl)biphenyl-4,4′-diamine (U.S. Pat. No. 4,764,625); α,α,α′,α′-tetramethyl-α,α′-bis(4-di-p-tolylaminophenyl)-p-xylene (JPH03-269084A); a triphenylamine derivative having a spatially asymmetric structure as a whole molecule (JPH04-129271A); a compound in which a pyrenyl group is substituted with a plurality of aromatic diamino groups (JPH04-175395A); an aromatic diamine having a tertiary aromatic amine unit linked with an ethylene group (JPH04-264189A); an aromatic diamine having a styryl structure (JPH04-290851A); a compound having an aromatic tertiary amine unit linked with a thiophene group (JPH04-304466A); a starburst aromatic triamine (JPH04-308688A); a benzylphenyl compound (JPH04-364153A); a compound having a tertiary amine linked with a fluorene group (JPH05-25473A); a triamine compound (JPH05-239455A); bisdipyridylaminobiphenyl (JPH05-320634A); an N,N,N-triphenylamine derivative (JPH06-1972A); an aromatic diamine having a phenoxazine structure (JPH07-138562A); a diaminophenylphenanthridine derivative (JPH07-252474A); a hydrazone compound (JPH02-311591A); a silazane compound (U.S. Pat. No. 4,950,950); a silanamine derivative (JPH06-49079A); a phosphamine derivative (JPH06-25659A); and a quinacridone compound. These aromatic amine compounds may be used in combination of two or more thereof as necessary.

Other specific examples of the aromatic amine compound applicable as the hole transport material include a metal complex of an 8-hydroxyquinoline derivative having a diarylamino group. A central metal of the metal complex is selected from any one of alkali metals, alkaline earth metals, Sc, Y, V, Cr, Mn, Fe, Co, Ni, Cu, Zn, Cd, Al, Ga, In, Si, Ge, Sn, Sm, Eu, and Tb, and 8-hydroxyquinoline, which is a ligand, has one or more diarylamino groups as substituents, and may have any substituent other than the diarylamino group.

Preferred specific examples of the phthalocyanine derivative or porphyrin derivative applicable as the hole transport material include porphyrin, 5,10,15,20-tetraphenyl-21H,23H-porphyrin, 5,10,15,20-tetraphenyl-21H,23H-porphyrin cobalt(II), 5,10,15,20-tetraphenyl-21H,23H-porphyrin copper(II), 5,10,15,20-tetraphenyl-21H,23H-porphyrin zinc(II), 5,10,15,20-tetraphenyl-21H,23H-porphyrin vanadium(IV) oxide, 5,10,15,20-tetra(4-pyridyl)-21H,23H-porphyrin, 29H,31H-phthalocyanine copper(II), phthalocyanine zinc(II), phthalocyanine titanium, phthalocyanine magnesium oxide, phthalocyanine lead, phthalocyanine copper(II), and 4,4′,4″,4′″-tetraaza-29H,31H-phthalocyanine.

Preferred specific examples of the oligothiophene derivative applicable as the hole transport material include α-sexythiophene.

A molecular weight of the hole transport material is generally 5000 or less, preferably 3000 or less, more preferably 2000 or less, still more preferably 1700 or less, and particularly preferably 1400 or less, and is generally 200 or more, preferably 400 or more, and more preferably 600 or more, except for the case of a high molecular weight compound having the specific repeating unit described above. When the molecular weight of the hole transport material is too large, synthesis and purification are difficult, which is undesirable. On the other hand, when the molecular weight thereof is too small, the heat resistance may decrease, which is also undesirable.

The hole injection layer of the organic electroluminescent element of the present invention may contain one of the above hole transport materials alone, or may contain two or more thereof. When the hole injection layer contains two or more hole transport materials, the combination is any, and it is preferable to use one or more aromatic tertiary amine high molecular weight compounds in combination with one or more other hole transport materials. The type of hole transport material to be used in combination with the above high molecular weight compound is preferably an aromatic amine compound.

A content of the hole transport material in the hole injection layer of the organic electroluminescent element of the present invention is set to be within a range satisfying a ratio to the above electron-accepting compound. When two or more kinds of charge transport film compositions are used in combination, a total content thereof is set to be within the above range.

### [Charge-Transporting Ionic Compound]

The hole injection layer of the organic electroluminescent element of the present invention preferably contains a charge-transporting ionic compound in which the tetraarylborate ion and a cation radical of a hole transport material are ionically bonded to each other.

The hole injection layer of the organic electroluminescent element of the present invention particularly preferably contains a charge-transporting ionic compound in which the tetraarylborate ion and the cation radical of the aromatic tertiary amine high molecular weight compound are ionically bonded as a hole transport material.

The charge-transporting ionic compound can be obtained by any of the following methods.
i) The first ionic compound and the hole transport material are dissolved or dispersed in an organic solvent and mixed.
ii) The first ionic compound and the hole transport material are dissolved or dispersed in an organic solvent, mixed, and further heated.
iii) The composition obtained in i) or ii) is wet-formed into a film, and the film is heated.

Since the first ionic compound is an electron-accepting compound, the hole transport material is oxidized by the first ionic compound to form a cation radical by any of the above methods. As a result, a charge-transporting ionic compound is generated, which is an ionic compound having the tetraarylborate ion as a counter anion and the cation radical of the hole transport material as a counter cation.

The hole injection layer of the organic electroluminescent element of the present invention preferably contains the hole transport material and the first ionic compound containing the tetraarylborate ion as a counter anion, and more preferably contains the charge-transporting ionic compound having the tetraarylborate ion as a counter anion and the cation radical of the hole transport material as a counter cation, from the viewpoint of charge transportability.

### [Hole Injection Layer Formation Composition]

The hole injection layer of the organic electroluminescent element of the present invention is preferably obtained by wet-process film formation of a hole injection layer formation composition.

The hole injection layer formation composition is preferably a composition obtained through a process of dissolving or dispersing the first ionic compound having a tetraarylborate ion structure and the hole transport material in an organic solvent.

From the viewpoint of obtaining a uniform film of the hole injection layer, the hole injection layer formation composition is preferably a solution obtained by dissolving the first ionic compound and the hole transport material in an organic solvent.

Even when the hole injection layer formation composition obtained by the method i) does not contain the charge-transporting ionic compound, it is sufficient that the charge-transporting ionic compound can be obtained by the method ii) or iii), and even when the hole injection layer formation composition obtained by the method ii) does not contain the charge-transporting ionic compound, it is sufficient that the charge-transporting ionic compound can be obtained by the method iii).

A mixing ratio of the first ionic compound and the hole transport material for obtaining the hole injection layer formation composition is such that an amount of the first ionic compound is generally 0.1 parts by mass or more, and preferably 1 part by mass or more, and is generally 100 parts by mass or less, and preferably 40 parts by mass or less, with respect to 100 parts by mass of the hole transport material. It is preferable that the content of the first ionic compound is equal to or greater than the lower limit, since free carriers (cationic radicals of the hole transport material) can be sufficiently generated, and the hole transportability is improved. It is preferable that the content thereof is equal to or less than the upper limit, since sufficient charge transport ability can be ensured. When two or more kinds of the first ionic compounds are used in combination, a total content thereof is set to be within the above range. The same applies to the hole transport material.

### (Organic Solvent)

A concentration of the organic solvent in the hole injection layer formation composition is generally 10 mass % or more, preferably 30 mass % or more, more preferably 50 mass % or more, and still more preferably 70 mass % or more, and is generally 99.999 mass % or less, preferably 99.99 mass % or less, and still more preferably 99.9 mass % or less. When two or more kinds of organic solvents are mixed and used, a total amount of the organic solvents satisfies the range.

Preferred examples of the organic solvent include an ether-based solvent and an ester-based solvent. Specific examples of the ether-based solvent include aliphatic ethers such as ethylene glycol dimethyl ether, ethylene glycol diethyl ether, and propylene glycol-1-monomethyl ether acetate (PGMEA), and aromatic ethers such as 1,2-dimethoxybenzene, 1,3-dimethoxybenzene, anisole, phenetole, 2-methoxytoluene, 3-methoxytoluene, 4-methoxytoluene, 2,3-dimethylanisole, and 2,4-dimethylanisole. Examples of the ester-based solvent include aliphatic esters such as ethyl acetate, n-butyl acetate, ethyl lactate, and n-butyl lactate; and aromatic esters such as phenyl acetate, phenyl propionate, methyl benzoate, ethyl benzoate, propyl benzoate, and n-butyl benzoate. One of these solvents may be used alone, or any desired two or more thereof may be used in combination in any desired proportion.

Examples of usable solvents other than the ether-based solvent and ester-based solvent include aromatic hydrocarbon-based solvents such as benzene, toluene, and xylene, amide-based solvents such as N, N-dimethylformamide, and N, N-dimethylacetamide, and dimethyl sulfoxide. One of these solvents may be used alone, or any desired two or more thereof may be used in combination in any desired proportion. One or two or more of these solvents may be used in combination with one or two or more of the above-described ether-based solvents and ester-based solvents. In particular, the aromatic hydrocarbon-based solvents such as benzene, toluene, and xylene have a low ability to dissolve an electron-accepting compound and a free carrier (a cation radical), and therefore are preferably used in combination with the ether-based solvent and the ester-based solvent.

Among the organic solvents, a solvent having an aromatic hydrocarbon structure is more preferred.

### (Film Formation Method)

The hole injection layer can be formed by wet-process film formation using the hole injection layer formation composition. The wet-process film formation method is the same as the method of forming a film by wet-process film formation using an emission layer formation composition, and it is preferable to heat the film after coating and drying. A heating temperature is preferably 120° C. or higher, more preferably 150° C. or higher, and still more preferably 180° C. or higher, and is preferably 300° C. or lower, and more preferably 260° C. or lower.

The hole injection layer can be crosslinked by heating the film after coating and drying. At this time, a crosslinking reaction may occur in the following combination.
Crosslinking groups of the hole transport material
A crosslinking group of the hole transport material and a crosslinking group of the electron-accepting compound
Crosslinking groups of the electron-accepting compound
A crosslinking group of the hole transport material and a crosslinking group of the tetraarylborate ion in the present invention
Crosslinking groups of the tetraarylborate ion in the present invention
A crosslinking group of the electron-accepting compound and a crosslinking group of the tetraarylborate ion in the present invention

In this process, a crosslinking substance of the electron-accepting compound is formed in the hole injection layer.

The heating is preferred since the formation of the charge-transporting ionic compound, which is an ionic compound of a tetraarylborate ion which is a counter anion of the first ionic compound and a cation radical of a hole transport material, is promoted.

### <Structure of Organic Electroluminescent Element>

As an example of a structure of the organic electroluminescent element of the present invention, the FIGURE shows a schematic diagram (a cross section) of an example of the structure of an organic electroluminescent element 8. In the FIGURE, 1 represents a substrate, 2 represents an anode, 3 represents a hole injection layer, 4 represents a hole transport layer, 5 represents an emission layer, 6 represents an electron transport layer, and 7 represents a cathode.

### [Substrate]

The substrate 1 serves as a support of the organic electroluminescent element, and is generally made of a plate of quartz or glass, a metal sheet, a metal foil, a plastic film or sheet, or the like. Among them, a glass plate and a plate of a transparent synthetic resin such as polyester, polymethacrylate, polycarbonate, and polysulfone are preferred. The substrate is preferably formed of a material having a high gas barrier property because deterioration of the organic electroluminescent element due to the outside air is less likely to occur. Therefore, particularly when a material having low gas barrier properties, such as a synthetic resin substrate, is used, it is preferable to provide a dense silicon oxide film or the like on at least one surface of the substrate to improve the gas barrier properties.

### [Anode]

The anode 2 has a function of injecting holes into a layer on an emission layer 5 side.

The anode 2 is generally formed of a metal such as aluminum, gold, silver, nickel, palladium, and platinum; a metal oxide such as an oxide of indium and/or tin; a metal halide such as copper iodide; a conductive polymer such as carbon black, poly(3-methylthiophene), polypyrrole, and polyaniline, and the like.

The anode 2 is generally formed by a dry method such as sputtering or a vacuum deposition method. When fine particles of a metal such as silver, fine particles of copper iodide or the like, carbon black, fine particles of a conductive metal oxide, a fine powder of a conductive polymer, or the like is used to form the anode, such a particulate material is dispersed in an appropriate binder resin solution and the dispersion is applied to the substrate to thereby form the anode. Further, in the case of a conductive polymer, a thin film is directly formed on the substrate by electrolytic polymerization or the conductive polymer is applied to the substrate to form the anode (Appl. Phys. Lett., Vol. 60, p. 2711, 1992).

The anode 2 generally has a single-layer structure, but may have a multilayer structure as appropriate. When the anode 2 has a multilayer structure, a different conductive material may be superposed on the anode of a first layer.

A thickness of the anode 2 may be determined according to the required transparency, material, and the like. In particular, when high transparency is required, a thickness at which the transmittance of visible light is 60% or more is preferred, and a thickness at which the transmittance of visible light is 80% or more is more preferred. The thickness of the anode 2 is generally 5 nm or more, and preferably 10 nm or more, and is generally 1000 nm or less, and preferably 500 nm or less. On the other hand, when transparency is not required, the thickness of the anode 2 may be set to any thickness depending on the required strength or the like, and in this case, the thickness of the anode 2 may be the same as that of the substrate.

When another layer is to be formed on the surface of the anode 2, it is preferable to remove impurities on the anode 2 and adjust an ionization potential thereof by performing a treatment such as ultraviolet and ozone, oxygen plasma, or argon plasma before the film formation to improve the hole injection property.

### [Hole Injection Layer]

The hole injection layer in the organic electroluminescent element of the present invention is as described above. Regarding the method for forming the hole injection layer, a wet-process film formation method has been described above, but a vacuum deposition method may also be used.

### [Formation of Hole Injection Layer by Vacuum Deposition Method]

When the hole injection layer of the organic electroluminescent element of the present invention is formed by a vacuum deposition method, the first ionic compound can be used as the material containing tetraarylborate ions, and a low molecular weight hole transport material that can be deposited can be used as the hole transport material. The low molecular weight hole transport material that can be deposited is preferably a hole transport material having a molecular weight of 1500 or less, more preferably a hole transport material having a molecular weight of 1000 or less, preferably a hole transport material having a molecular weight of 400 or more, and more preferably a hole transport material having a molecular weight of 600 or more. The low molecular weight hole transport material is preferably an aromatic amine-based compound, and more preferably an aromatic tertiary amine compound.

When the hole injection layer 3 is formed by the vacuum deposition method, generally, one kind or two or more kinds of constituent materials of the hole injection layer 3 are placed in a crucible installed in a vacuum container (when two or more kinds of materials are used, generally, each is placed in a separate crucible), and the inside of the vacuum container is exhausted to about 10⁻⁴ Pa by a vacuum pump. Thereafter, the crucible is heated (when two or more kinds of materials are used, generally, each crucible is heated), and the material in the crucible is evaporated while controlling an evaporation amount (when two or more kinds of materials are used, generally, the materials are evaporated while controlling the evaporation amount independently of each other) to form a hole injection layer on the anode on the substrate placed facing the crucible. When two or more kinds of materials are used, a mixture of these materials can be placed in a crucible and heated to evaporate to form the hole injection layer.

A degree of vacuum during the deposition is not limited as long as the effect of the present invention is not significantly impaired, and is generally 0.1×10⁻⁶ Torr (0.13×10⁻⁴ Pa) or higher and 9.0×10⁻⁶ Torr (12.0×10⁻⁴ Pa) or lower. A rate of deposition is not limited as long as the effect of the present invention is not significantly impaired, and is generally 0.1 Å/sec or higher and 5.0 Å/sec or lower. A film formation temperature during the deposition is not limited as long as the effect of the present invention is not significantly impaired, and is preferably 10° C. or higher and 50° C. or lower.

### [Hole Transport Layer]

The hole transport layer 4 is a layer having a function of transporting holes from the anode 2 side to the emission layer 5 side. Although the hole transport layer 4 is not an essential layer in the organic electroluminescent element of the present invention, it is preferable to form this layer from the viewpoint of enhancing the function of transporting holes from the anode 2 to the emission layer 5. When the hole transport layer 4 is formed, the hole transport layer 4 is generally formed between the anode 2 and the emission layer 5. When the hole injection layer 3 described above is provided, the hole transport layer 4 is formed between the hole injection layer 3 and the emission layer 5.

A thickness of the hole transport layer 4 is generally 5 nm or more, and preferably 10 nm or more, and on the other hand, is generally 300 nm or less, and preferably 100 nm or less.

The hole transport layer 4 may be formed by a vacuum deposition method or a wet-process film formation method. From the viewpoint of excellent film formability, the film is preferably formed by the wet-process film formation method.

The hole transport layer 4 generally contains a hole-transporting compound.

Preferred examples of the hole-transporting compound include an aromatic diamine represented by 4,4′-bis[N-(1-naphthyl)-N-phenylamino]biphenyl, in which two or more tertiary amines are contained and two or more fused aromatic rings are substituted with nitrogen atoms (JPH05-234681A), an aromatic amine compound having a star burst structure, such as 4,4′,4″-tris(1-naphthylphenylamino)triphenylamine (J. Lumin., Vol. 72-74, pp. 985, 1997), an aromatic amine compound composed of tetramers of triphenylamine (Chem. Commun., P. 2175, 1996), a spiro compound such as 2,2′,7,7′-tetrakis(diphenylamino)-9,9′-spirobifluorene (Synth. Metals, Vol. 91, p. 209, 1997), and a carbazole derivative such as 4,4′-N,N′-dicarbazole biphenyl. For example, polyvinyl carbazole, polyvinyl triphenylamine (JPH07-53953A), polyarylene ether sulfone containing tetraphenylbenzidine (Polym. Adv. Tech., Vol. 7, p. 33, 1996) may be included.

### [Formation of Hole Transport Layer by Wet-Process Film Formation Method]

When the hole transport layer is formed by a wet-process film formation method, the hole transport layer is generally formed using a hole transport layer formation composition instead of the hole injection layer formation composition, in the same manner as when the hole injection layer is formed by the wet-process film formation method.

When the hole transport layer is formed by the wet-process film formation method, generally, the hole transport layer formation composition further includes a solvent. The solvent used in the hole transport layer formation composition may be the same as the solvent used in the hole injection layer formation composition described above.

A concentration of the hole-transporting compound in the hole transport layer formation composition may be in the same range as the concentration of the hole-transporting compound in the hole injection layer formation composition.

### (Formation of Hole Transport Layer by Vacuum Deposition Method)

When the hole transport layer is formed by the vacuum deposition method, the hole transport layer can be formed by using the hole transport layer formation composition instead of the hole injection layer formation composition, in the same manner as when the hole injection layer is formed by the vacuum deposition method described above. Film formation conditions such as a degree of vacuum, a rate of deposition, and a temperature during the deposition can be the same as those during the deposition of the hole injection layer.

### [Emission Layer]

The emission layer 5 is a layer having a function of emitting light by being excited by recombination of holes injected from the anode 2 and electrons injected from the cathode 7 when an electric field is applied between the pair of electrodes. The emission layer 5 is a layer formed between the anode 2 and the cathode 7. The emission layer 5 is formed between the hole injection layer and the cathode when the hole injection layer is present on the anode, and is formed between the hole transport layer and the cathode when the hole transport layer is present on the anode.

As described above, the emission layer of the organic electroluminescent element in the present invention preferably contains a luminescent compound, an organometallic compound, and a host material, and more preferably contains a polycyclic heterocyclic compound represented by the formula (1), an organometallic compound represented by the formula (201), and a host material.

A thickness of the emission layer 5 is any as long as the effect of the present invention is not significantly impaired, and a thick layer is preferred in that defects are less likely to occur in the film, and on the other hand, a thin layer is preferred in that a low operating voltage is likely to be obtained. Therefore, the thickness of the emission layer 5 is preferably 3 nm or more, still more preferably 5 nm or more, and on the other hand, generally, the thickness of the emission layer 5 is preferably 200 nm or less, and still more preferably 100 nm or less.

The emission layer 5 includes at least a material having a luminescence property (a luminescent material), and preferably includes one or more host materials.

### [Hole Blocking Layer]

The hole blocking layer may be provided between the emission layer 5 and an electron injection layer to be described later. The hole blocking layer is a layer laminated on the emission layer 5 so as to be in contact with an interface of the emission layer 5 on the cathode 7 side.

The hole blocking layer has a function of blocking holes which are moving thereinto from the anode 2 from reaching the cathode 7 and a function of efficiently transporting electrons injected from the cathode 7 toward the emission layer 5. Examples of physical properties required of a material constituting the hole blocking layer include: to have a high electron mobility and a low hole mobility; to have a large energy gap (a difference between HOMO and LUMO); and to have a high excited triplet level (T₁).

Examples of the material for the hole blocking layer which satisfy such requirements include metal complexes such as mixed-ligand complexes, e.g., bis(2-methyl-8-quinolinolato)(phenolato)aluminum and bis(2-methyl-8-quinolinolato)(triphenylsinolato)aluminum, and dinuclear metal complexes, e.g., bis(2-methyl-8-quinolato)aluminum-μ-oxo-bis(2-methyl-8-quinolinolato)aluminum, styryl compounds such as distyrylbiphenyl derivatives (JPH11-242996A), triazole derivatives such as 3-(4-biphenylyl)-4-phenyl-5-(4-tert-butylphenyl)-1,2,4-triazole (JPH07-41759A), and phenanthroline derivatives such as bathocuproine (JPHS10-79297A). Further, the compound having at least one pyridine ring substituted at the 2, 4, and 6 positions, which is described in WO2005/022962, is also preferred as a material for the hole blocking layer.

A method for forming the hole blocking layer is not limited. Accordingly, the hole blocking layer can be formed by a wet-process film formation method, a vapor deposition method, or other methods.

A thickness of the hole blocking layer is any as long as the effect of the present invention is not significantly impaired, and is generally 0.3 nm or more, and preferably 0.5 nm or more, and is generally 100 nm or less, and preferably 50 nm or less.

### [Electron Transport Layer]

An electron transport layer 6 is provided between the emission layer 5 and the cathode 7 for the purpose of further improving current efficiency (cd/A) of the element.

The electron transport layer 6 is formed of a compound capable of efficiently transporting electrons injected from the cathode 7 toward the emission layer 5 between the electrodes to which an electric field is applied. The electron-transporting compound to be used in the electron transport layer 6 is required to have a high efficiency of electron injection from the cathode 7, high electron mobility, and the ability to efficiently transport the injected electrons.

Specific examples of the electron-transporting compound used in the electron transport layer include metal complexes such as aluminum complexes of 8-hydroxyquinoline (JPS59-194393A), metal complexes of 10-hydroxybenzo[h]quinoline, oxadiazole derivatives, distyrylbiphenyl derivatives, silole derivatives, 3-hydroxyflavone metal complexes, 5-hydroxyflavone metal complexes, benzoxazole metal complexes, benzothiazole metal complexes, trisbenzimidazolylbenzene (U.S. Pat. No. 5,645,948), quinoxaline compounds (JPH06-207169A), phenanthroline derivatives (JPH05-331459A), 2-tert-butyl-9,10-N,N′-dicyanoanthraquinone diimine, n-type hydrogenated amorphous silicon carbide, n-type zinc sulfide, and n-type zinc selenide.

A thickness of the electron transport layer 6 is generally 1 nm or more, and preferably 5 nm or more, and is generally 300 nm or less, and preferably 100 nm or less.

The electron transport layer 6 is formed by being superposed on the hole blocking layer by the wet-process film formation method or the vacuum deposition method in the same manner as described above. Generally, the vacuum deposition method is used.

### [Electron Injection Layer]

The electron injection layer may be provided in order to efficiently inject electrons injected from the cathode 7 into the electron transport layer 6 or the emission layer 5.

In order to efficiently perform electron injection, a metal having a low work function is preferred as the material forming the electron injection layer. Examples thereof include alkali metals such as sodium and cesium, and alkaline earth metals such as barium and calcium. Generally, a thickness thereof is preferably 0.1 nm or more and 5 nm or less.

Further, to dope an organic electron transport material represented by nitrogen-containing heterocyclic compounds such as bathophenanthroline or by metal complexes such as aluminum complexes of 8-hydroxyquinoline with an alkali metal such as sodium, potassium, cesium, lithium, or rubidium (as described in JPH10-270171A, JP2002-100478A, and JP2002-100482A) is preferred because the doping can improve the electron injection and transport properties and further attain excellent film quality.

The thickness of the electron injection layer is generally 5 nm or more, and preferably 10 nm or more, and is generally 200 nm or less, and preferably 100 nm or less.

The electron injection layer is formed by being superposed on the emission layer 5 or the hole blocking layer or electron transport layer 6 thereon by the wet-process film formation method or the vacuum deposition method.

Details in the case of the wet-process film formation method are the same as those in the case of the emission layer described above.

The hole blocking layer, the electron transport layer, and the electron injection layer may be formed into a single layer by co-doping an electron transport material and a lithium complex.

### [Cathode]

The cathode 7 plays a role of injecting electrons into a layer (an electron injection layer or an emission layer) on the emission layer 5 side.

Although any of the materials usable as the anode 2 can be used as the material for the cathode 7, a metal having a low work function is preferably used from the standpoint of efficient injection of electrons. For example, metals such as tin, magnesium, indium, calcium, aluminum, and silver or alloys of these metals are used. Specific examples thereof include electrodes of alloys having a low work function, such as magnesium-silver alloys, magnesium-indium alloys, and aluminum-lithium alloys.

In terms of the stability of the organic electroluminescent element, it is preferable to protect the cathode made of a metal having a low work function by superposing a metal layer having a high work function and being stable to the air on the cathode. Examples of the metal to be superposed include metals such as aluminum, silver, copper, nickel, chromium, gold, and platinum.

A thickness of the cathode is generally the same as that of the anode.

### [Other Layers]

The organic electroluminescent element of the present invention may further have other layers as long as the effects of the present invention are not significantly impaired. That is, any other layer described above may be provided between the anode and the cathode.

### [Other Element Configurations]

The organic electroluminescent element of the present invention may have a structure opposite to that described above, that is, for example, a cathode, an electron injection layer, an electron transport layer, a hole blocking layer, an emission layer, a hole transport layer, a hole injection layer, and an anode may be superposed in this order on a substrate.

When the organic electroluminescent element of the present invention is applied to an organic electroluminescent device, a single organic electroluminescent element may be used, a plurality of organic electroluminescent elements may be arranged in an array, or an anode and a cathode may be arranged in an X-Y matrix.

### <Method for Producing Organic Electroluminescent Element>

A method for producing an organic electroluminescent element of the present invention is not particularly limited. Preferably, as described above, an organic electroluminescent element having an anode, an emission layer, and a cathode in this order on a substrate can be produced by including a step of forming an emission layer by a wet-process film formation method using the composition of the present invention.

As one aspect of the method for producing an organic electroluminescent element of the present invention, for example, a method for producing an organic electroluminescent element including an anode, an emission layer, and a cathode in this order on a substrate, the method including a step of forming an emission layer by a wet-process film formation method using the above-described composition, may be used.

### <Organic EL Display Device>

An organic EL display device (an organic electroluminescent element display device) of the present invention includes the organic electroluminescent element of the present invention. The type and structure of the organic EL display device of the present invention are not particularly limited, and the organic EL display device can be assembled using the organic electroluminescent element of the present invention according to a well-known method.

For example, the organic EL display device of the present invention can be formed by a method such as that described in “Organic EL Display” (Ohmsha, Ltd., published on Aug. 20, 2004, written by TOKITO Shizuo, ADACHI Chihaya, and MURATA Hideyuki).

### <Organic EL Illuminator>

An organic EL illuminator (an organic electroluminescent element illuminator) of the present invention includes the organic electroluminescent element of the present invention. The type and structure of the organic EL illuminator of the present invention are not particularly limited, and the organic EL display device can be assembled using the organic electroluminescent element of the present invention according to a well-known method.

As described above, the following matters are disclosed in the present description.

<1>

An organic electroluminescent element material, containing:
a luminescent compound;
an organometallic compound; and
a host material, in which
the organometallic compound has a molecular weight of 1,200 or more, and
the host material contains at least one selected from the group consisting of a compound represented by the following formula (240), a compound represented by the following formula (250), and a compound represented by the following formula (260), and
the following relational expression (E-1) and the following relational expression (E-2) are satisfied.

$$T 1 A \geq T 1 B \qquad Expression ( E - 1 )$$

$$Δ EST = S 1 B - T 1 B \leq 0.3 eV \qquad Expression ( E - 2 )$$

(In the expression (E-1) and the expression (E-2),
T1A: a triplet energy level (eV) of the organometallic compound
T1B: a triplet energy level (eV) of the luminescent compound
S1B: a singlet energy level (eV) of the luminescent compound)

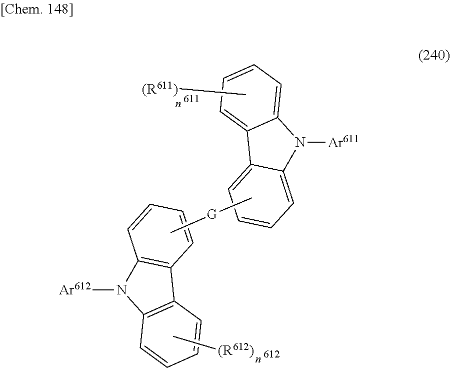

(In the formula (240),
Ar⁶¹¹ and Ar⁶¹² each independently represent a monovalent aromatic hydrocarbon group having 6 to 50 carbon atoms which may have a substituent,
R⁶¹¹ and R⁶¹² each independently represent a deuterium atom, a halogen atom, or a monovalent aromatic hydrocarbon group having 6 to 50 carbon atoms which may have a substituent,
G represents a single bond, or a divalent aromatic hydrocarbon group having 6 to 50 carbon atoms which may have a substituent, and
n⁶¹¹ and n⁶¹² each independently represent an integer of 0 to 4.)

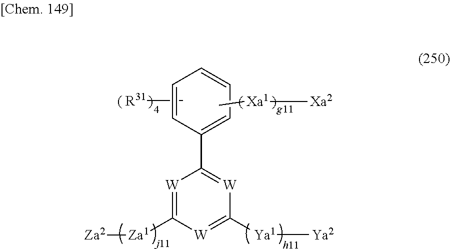

(In the formula (250),
W's each independently represent CH or N, and at least one W represents N,
Xa¹, Ya¹, and Za¹ each independently represent a divalent aromatic hydrocarbon group having 6 to 30 carbon atoms which may have a substituent, or a divalent aromatic heterocyclic group having 3 to 30 carbon atoms which may have a substituent,
Xa², Ya², and Za² each independently represent a hydrogen atom, a monovalent aromatic hydrocarbon group having 6 to 30 carbon atoms which may have a substituent, or a monovalent aromatic heterocyclic group having 3 to 30 carbon atoms which may have a substituent,
g11, h11, and j11 each independently represent an integer of 0 to 6,
at least one of g11, h11, and j11 represents an integer of 1 or more,
when g11 is 2 or more, a plurality of Xa¹'s may be the same as or different from each other,
when h11 is 2 or more, a plurality of Ya¹'s may be the same as or different from each other,
when j11 is 2 or more, a plurality of Za¹'s may be the same as or different from each other,
R³¹ represents a hydrogen atom or a substituent, and four R³¹'s may be the same as or different from each other, and
when g11, h11, or j11 is 0, the respective corresponding Xa², Ya², and Za² are not a hydrogen atom.

In Xa¹, Ya¹, Za¹, Xa², Ya² and Za², the substituent which the aromatic hydrocarbon group having 6 to 30 carbon atoms may have, and the substituent which the aromatic heterocyclic group having 3 to 30 carbon atoms may have are each independently selected from the following substituent group Z2, and the substituent selected from the following substituent group Z2 does not have any further substituent.

### <Substituent Group Z2>

Alkyl group, alkoxy group, aryloxy group, heteroaryloxy group, alkoxycarbonyl group, dialkylamino group, diarylamino group, arylalkylamino group, acyl group, halogen atom, haloalkyl group, alkylthio group, arylthio group, silyl group, siloxy group, cyano group, aromatic hydrocarbon group, and aromatic heterocyclic group)

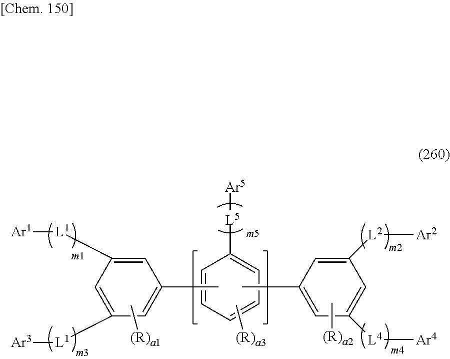

(In the formula (260),
Ar¹ to Ar⁵ each independently represent a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent,
R's each independently represent a substituent,
m1 to m5 each independently represent an integer of 0 to 5,
n represents an integer of 0 to 10,
a1 to a3 each independently represent an integer of 0 to 3, and
at least one of Ar¹, Ar², Ar³, Ar⁴, and at least one Ar⁵ when n is 1 or more is not a hydrogen atom.)
   <2>

The organic electroluminescent element material according to <1>, in which the organometallic compound is represented by the following formula (201),

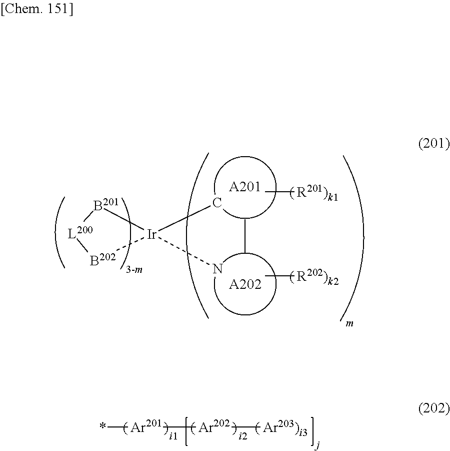

[Ring A201 represents an aromatic hydrocarbon ring structure which may have a substituent or an aromatic heterocyclic structure which may have a substituent.
Ring A202 represents an aromatic heterocyclic structure which may have a substituent.
R²⁰¹ and R²⁰² each independently represent a structure represented by the formula (202).

When a plurality of R²⁰¹'s and a plurality of R²⁰²'s are present, they may be the same as or different from each other.

Ar²⁰¹ and Ar²⁰³ each independently represent an aromatic hydrocarbon ring structure which may have a substituent or an aromatic heterocyclic structure which may have a substituent.

Ar²⁰² represents an aromatic hydrocarbon ring structure which may have a substituent, an aromatic heterocyclic structure which may have a substituent, or an aliphatic hydrocarbon structure which may have a substituent.

When a plurality of Ar²⁰¹'s, a plurality of Ar²⁰²'s, and a plurality of Ar²⁰³'s are present, they may be the same as or different from each other.
* represents bonding to ring A201 or ring A202.
B²⁰¹-L²⁰⁰-B²⁰² represents an anionic bidentate ligand. B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure. L²⁰⁰ represents a single bond or an atomic group constituting a bidentate ligand together with B²⁰¹ and B²⁰².

When a plurality of B²⁰¹-L²⁰⁰-B²⁰²'s are present, they may be the same as or different from each other.
i1 and i2 each independently represent an integer of 0 or more and 12 or less.
i3 is an integer of 0 or more, an upper limit of which is the number that can be substituted for Ar²⁰².
j is an integer of 0 or more, an upper limit of which is the number that can be substituted for Ar²⁰¹.
K1 and k2 each independently represent an integer of 0 or more, an upper limit of which is the number that can be substituted for ring A201 and ring A202.
m represents an integer of 1 to 3.]
   <3>

The organic electroluminescent element material according to <1> or <2>, in which the luminescent compound is a polycyclic heterocyclic compound represented by the following formula (1),

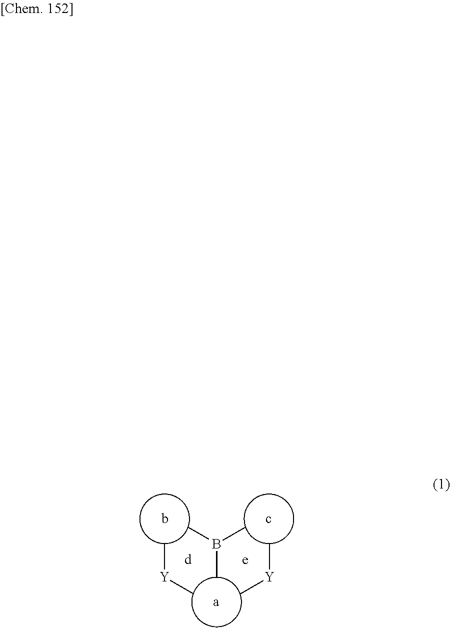

(In the formula (1),
ring a, ring b, and ring c each independently represent an aromatic hydrocarbon ring which may have a substituent or an aromatic heterocyclic ring which may have a substituent,
Y's each independently represent O, N—R, or S,
the R is an aromatic hydrocarbon ring group which may have a substituent, an aromatic heterocyclic group which may have a substituent, or an alkyl group,
the R may be bonded to a carbon atom adjacent to an atom bonded to the Yin at least one ring selected from the group consisting of the ring a, the ring b, and the ring c by —O—, —S—, —C(—R^{a})₂—, or a single bond,
the R^{a}'s each independently represent a hydrogen atom or an alkyl group, and
the adjacent carbon atom is not a carbon atom constituting a central fused bicyclic structure of the formula (1) containing B and the Y.

At least one hydrogen atom in the polycyclic heterocyclic compound represented by the formula (1) may be substituted with a halogen atom or deuterium.

Ring d is a ring constituted by B, Y, and some of atoms constituting ring a and ring b, and ring e is a ring constituted by B, Y, and some of atoms constituting ring a and ring c.)

<4>

The organic electroluminescent element material according to any one of <1> to <3>, in which the organometallic compound is represented by the following formula (201), and the luminescent compound is a polycyclic heterocyclic compound represented by the following formula (1).

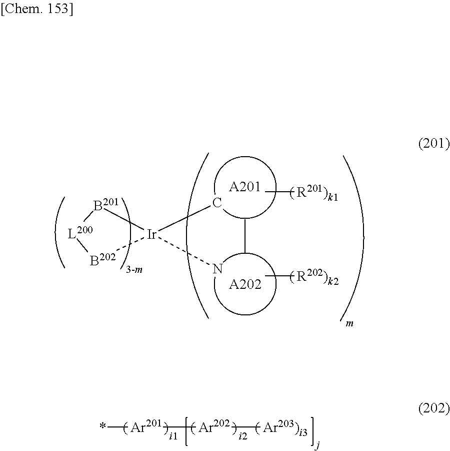

[Ring A201 represents an aromatic hydrocarbon ring structure which may have a substituent or an aromatic heterocyclic structure which may have a substituent.
Ring A202 represents an aromatic heterocyclic structure which may have a substituent.
R²⁰¹ and R²⁰² each independently represent a structure represented by the formula (202).

When a plurality of R²⁰¹'s and a plurality of R²⁰²'s are present, they may be the same as or different from each other.

Ar²⁰¹ and Ar²⁰³ each independently represent an aromatic hydrocarbon ring structure which may have a substituent or an aromatic heterocyclic structure which may have a substituent.

Ar²⁰² represents an aromatic hydrocarbon ring structure which may have a substituent, an aromatic heterocyclic structure which may have a substituent, or an aliphatic hydrocarbon structure which may have a substituent.

When a plurality of Ar²⁰¹'s, a plurality of Ar²⁰²'s, and a plurality of Ar²⁰³'s are present, they may be the same as or different from each other.
* represents bonding to ring A201 or ring A202.
B²⁰¹-L²⁰⁰-B²⁰² represents an anionic bidentate ligand. B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure. L²⁰⁰ represents a single bond or an atomic group constituting a bidentate ligand together with B²⁰¹ and B²⁰².

When a plurality of B²⁰¹-L²⁰⁰-B²⁰²'s are present, they may be the same as or different from each other.
i1 and i2 each independently represent an integer of 0 or more and 12 or less.
i3 is an integer of 0 or more, an upper limit of which is the number that can be substituted for Ar²⁰².
j is an integer of 0 or more, an upper limit of which is the number that can be substituted for Ar²⁰¹.
K1 and k2 each independently represent an integer of 0 or more, an upper limit of which is the number that can be substituted for ring A201 and ring A202.
m represents an integer of 1 to 3.]

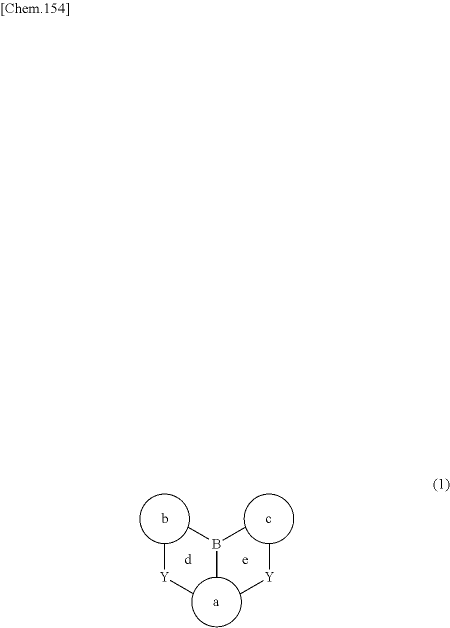

(In the formula (1),
ring a, ring b, and ring c each independently represent an aromatic hydrocarbon ring which may have a substituent or an aromatic heterocyclic ring which may have a substituent,
Y's each independently represent O, N—R, or S,
the R is an aromatic hydrocarbon ring group which may have a substituent, an aromatic heterocyclic group which may have a substituent, or an alkyl group,
the R may be bonded to a carbon atom adjacent to an atom bonded to the Yin at least one ring selected from the group consisting of the ring a, the ring b, and the ring c by —O—, —S—, —C(—R^{a})₂—, or a single bond,
the R^{a}'s each independently represent a hydrogen atom or an alkyl group, and
the adjacent carbon atom is not a carbon atom constituting a central fused bicyclic structure of the formula (1) containing B and the Y.

At least one hydrogen atom in the polycyclic heterocyclic compound represented by the formula (1) may be substituted with a halogen atom or deuterium.

Ring d is a ring constituted by B, Y, and some of atoms constituting ring a and ring b, and ring e is a ring constituted by B, Y, and some of atoms constituting ring a and ring c.)

<5>

The organic electroluminescent element material according to <3> or <4>, in which the polycyclic heterocyclic compound represented by the formula (1) is represented by the following formula (21).

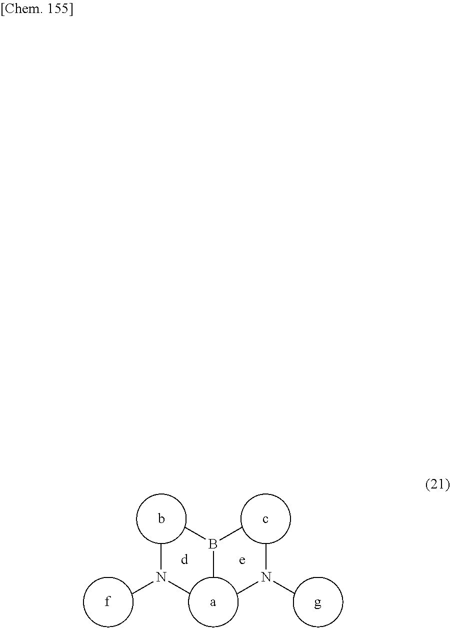

(In the formula (21),
ring a, ring b, and ring c are the same as those defined in the formula (1),
ring d is a ring constituted by B, N, and some of atoms constituting ring a and ring b, and ring e is a ring constituted by B, N, and some of atoms constituting ring a and ring c,
ring f and ring g each independently represent an aromatic hydrocarbon ring which may have a substituent or an aromatic heterocyclic ring which may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group,
the adjacent carbon atom is not a carbon atom constituting ring d and ring e each containing B and N, and
at least one hydrogen atom in the polycyclic heterocyclic compound represented by the formula (21) may be substituted with a halogen atom or deuterium.)
   <6>

The organic electroluminescent element material according to <3> or <4>, in which the polycyclic heterocyclic compound represented by the formula (1) is represented by the following formula (22).

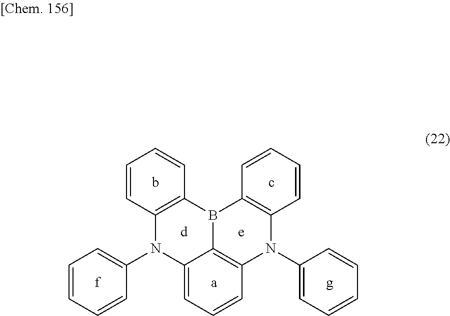 [SMILES: c1ccc(N2c3ccccc3B3c4ccccc4N(c4ccccc4)c4cccc2c43)cc1]

(In the formula (22),
ring d is a ring constituted by B, N, and some of atoms constituting ring a and ring b, and ring e is a ring constituted by B, N, and some of atoms constituting ring a and ring c,
ring a, ring b, ring c, ring f, and ring g may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group, and
at least one hydrogen atom in the polycyclic heterocyclic compound represented by the formula (22) may be substituted with a halogen atom or deuterium.)
   <7>

The organic electroluminescent element material according to <3> or <4>, in which the polycyclic heterocyclic compound represented by the formula (1) is represented by the following formula (71).

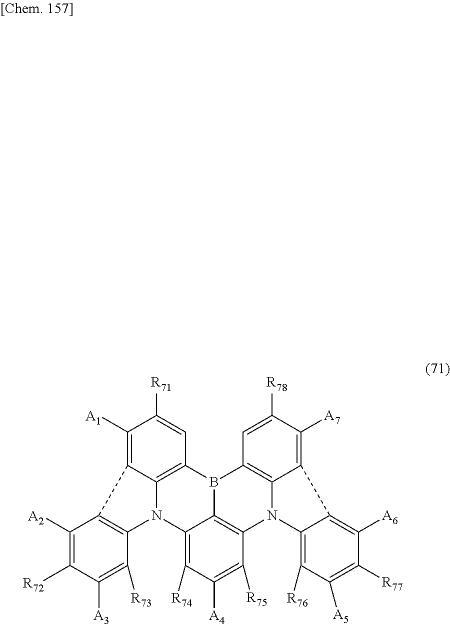

(In the formula (71),
A₁ to A₇ each independently represent a hydrogen atom; a fluorine atom; an alkyl group which may have a substituent; an electron-accepting heteroaryl group; a nitro group; a cyano group; or an aromatic hydrocarbon group or an aromatic heterocyclic group which has an electron-accepting heteroaryl group, a nitro group, or a cyano group as a substituent,
R₇₁ to R₇₈ each independently represent a hydrogen atom, an alkyl group which may have a substituent, an aromatic hydrocarbon group which may have a substituent, an aromatic heterocyclic group which may have a substituent, an electron-donating substituent, or a combination thereof,
at least one hydrogen atom in the polycyclic heterocyclic compound represented by the formula (71) may be substituted with a halogen atom or deuterium, and a dotted line represents a single bond or no bond.)
   <8>

The organic electroluminescent element material according to <7>, in which A₁ to A₇ in the formula (71) are an electron-accepting substituent, and each independently represent a group represented by the following formula (71-5), a group represented by the following formula (71-6), a group represented by the following formula (71-7), or a group represented by the following formula (71-8).

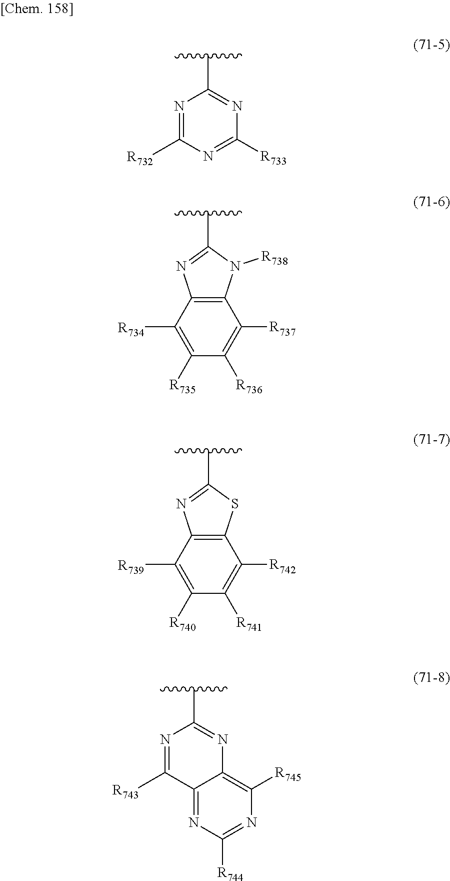

(In the formulae (71-5) to (71-8),
R₇₃₂ to R₇₄₅ each independently represent a hydrogen atom, an alkyl group which may have a substituent, or an aromatic hydrocarbon group which may have a substituent.)
   <9>

The organic electroluminescent element material according to <7>, in which R₇₁ to R₇₈ in the formula (71) are an electron-donating substituent, and each independently represent a group represented by the following formula (71-2), a group represented by the following formula (71-3), or a group represented by the following formula (71-4).

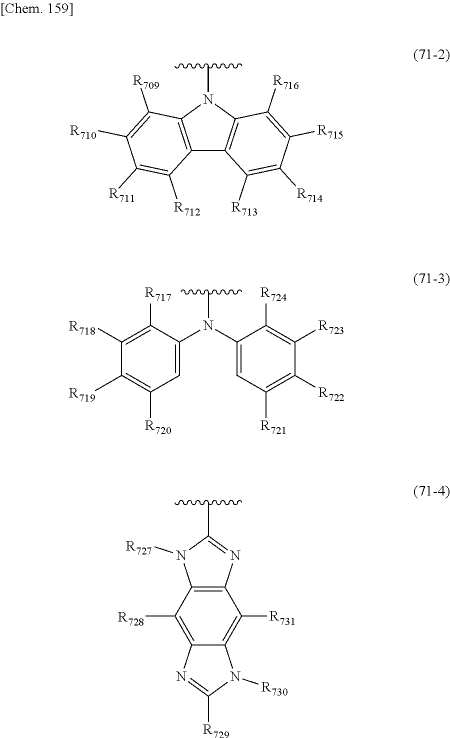

(In the formulae (71-2) to (71-4),
R₇₀₉ to R₇₂₄ and R₇₂₇ to R₇₃₁ each independently represent an alkyl group which may have a substituent, an aromatic hydrocarbon group which may have a substituent, or a hydrogen atom.)
   <10>

The organic electroluminescent element material according to any one of <1> to <9>, in which the T1A is 2.10 eV or more and 2.80 eV or less.

<11>

The organic electroluminescent element material according to any one of <1> to <10>, in which MwA/MwB is 2.0 or more, where MwA is a molecular weight of the organometallic compound and MwB is a molecular weight of the luminescent compound.

<12>

The organic electroluminescent element material according to any one of <1> to <11>, in which in the formula (250), (Xa¹)_{g11} when g11 is 1 or more, (Ya¹)ₕ₁₁ when h11 is 1 or more, and (Za¹)ⱼ₁₁ when j11 is 1 or more each independently have a partial structure selected from partial structures each represented by the following formulae (11) to (17).

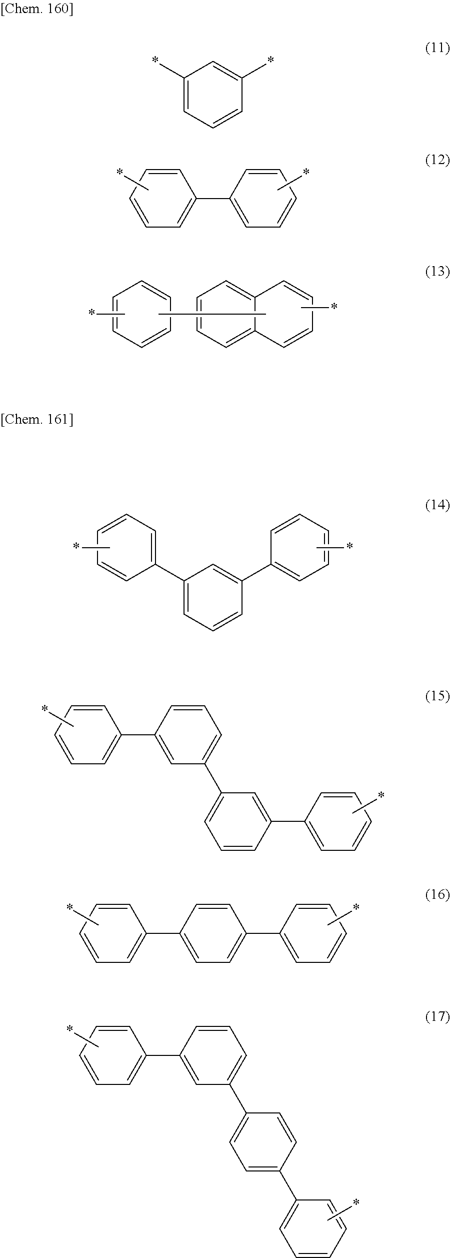

(In each of the formulae (11) to (17), * represents a bond with an adjacent structure, or when Xa², Ya², or Za² in the formula (250) represents a hydrogen atom, * represents the hydrogen atom, and at least one of two present *'s represents a bonding site with an adjacent structure.)

<13>

The organic electroluminescent element material according to any one of <1> to <12>, in which at least two of W's in the formula (250) are N.

<14>

The organic electroluminescent element material according to any one of <1> to <13>, in which at least one of -(Xa¹)_{g11}-(Xa²), -(Ya¹)ₕ₁₁-(Ya²), and -(Za¹)ⱼ₁₁-(Za²) in the formula (250) has any one of partial structures or terminal structures each represented by the following formula (250-1) to formula (250-10).

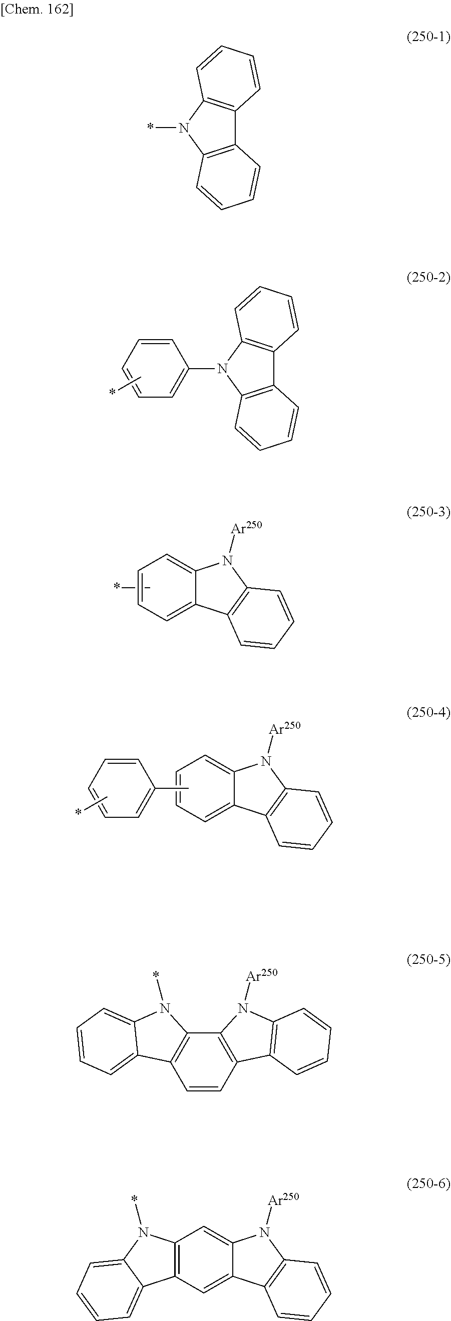

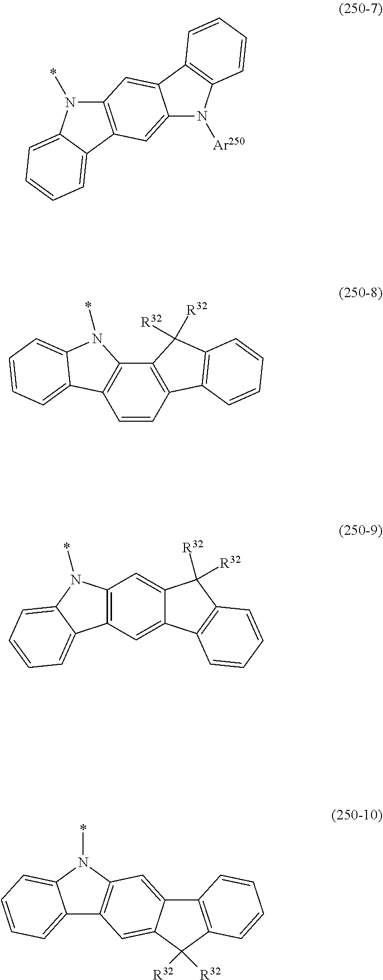

[In the formula (250-1) to formula (250-10), * represents a bonding site. Ar²⁵⁰ represents an aromatic hydrocarbon group having 6 to 20 carbon atoms. R³² represents a substituent, and the structures each represented by the formula (250-1) to formula (250-10) may further have a substituent.]

<15>

The organic electroluminescent element material according to any one of <1> to <14>, in which Ar⁶¹¹ and Ar⁶¹² in the formula (240) each independently have a partial structure selected from the following formulae (11) to (13) and (21) to (24).

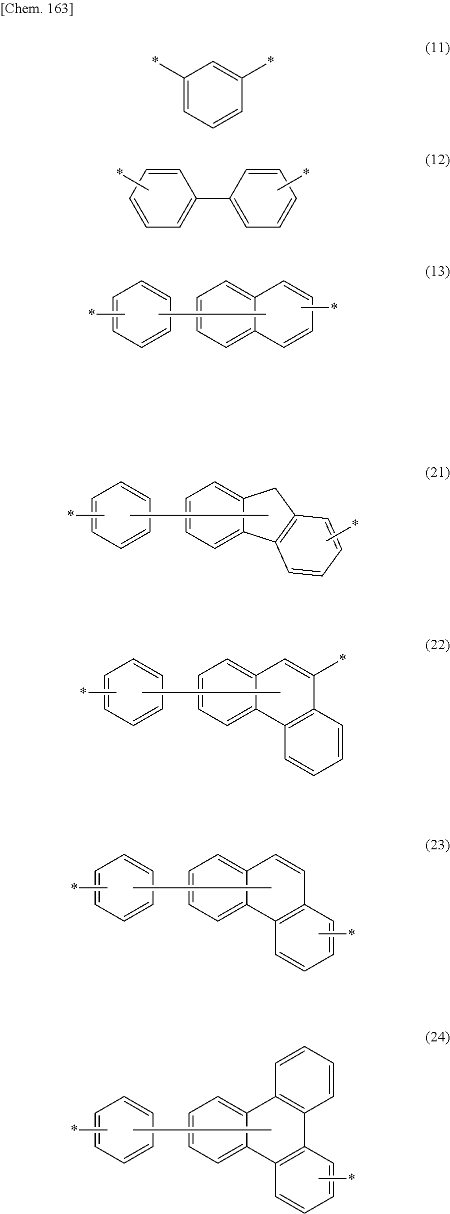

(In each of the formula (11) to formula (13) and formula (21) to formula (24), * represents a bond with an adjacent structure or a hydrogen atom, and at least one of two present *'s represents a bonding site with an adjacent structure.)

<16>

The organic electroluminescent element material according to any one of <1> to <15>, in which in the formula (260), (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more each independently have a partial structure selected from partial structures each represented by the following formula (11) to formula (17).

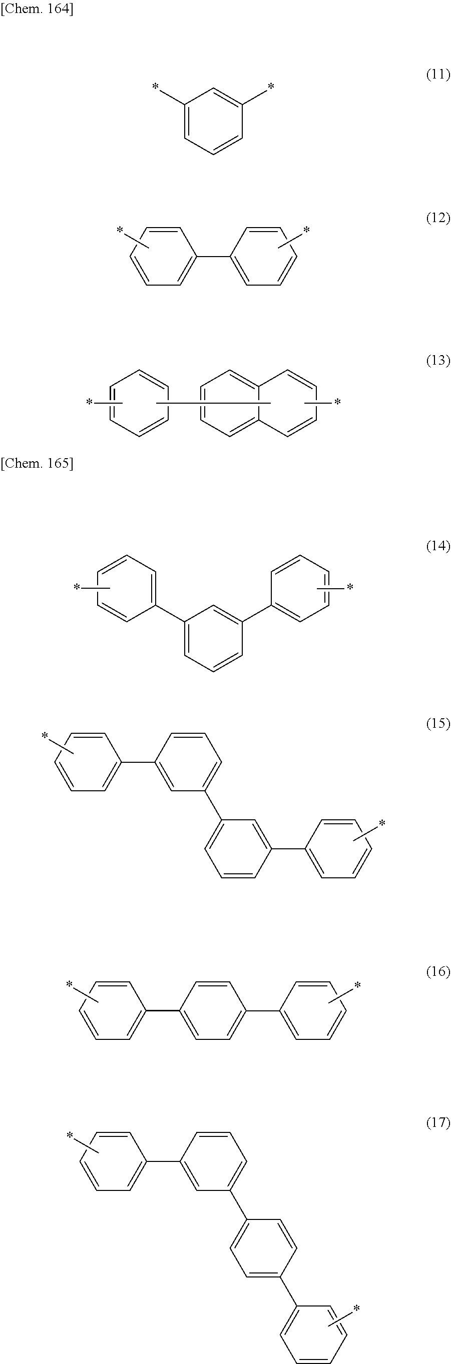

(In each of the formula (11) to formula (17), * represents a bond with an adjacent structure, or when Ar¹, Ar², Ar³, Ar⁴, or Ar⁵ represents a hydrogen atom, * represents the hydrogen atom, and at least one of two present *'s represents a bonding site with an adjacent structure.)

<17>

The organic electroluminescent element material according to any one of <1> to <16>, in which in the formula (260), one or more and three or less of Ar¹, Ar², and at least one Ar⁵ are represented by the following formula (4) or the following formula (5).

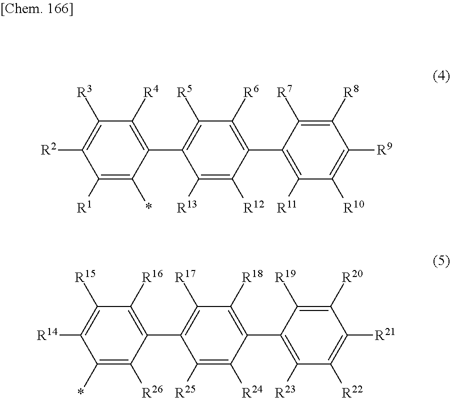

(In the formula (4) and formula (5),
* represents a bonding site with the formula (260), and
R¹ to R²⁶ each independently represent a hydrogen atom or a substituent.)
   <18>

An organic electroluminescent element including:
an anode;
a cathode;
an emission layer; and
a hole injection layer, in which
the emission layer is provided between the anode and the cathode,
the hole injection layer is provided between the anode and the emission layer, and
the emission layer contains the organic electroluminescent element material according to any one of <1> to <17>.
   <19>

An organic EL display device or an organic EL illuminator, including the organic electroluminescent element according to <18>.

<20>

An organic electroluminescent element formation composition, containing the organic electroluminescent element material according to any one of <1> to <17>; and an organic solvent.

<21>

A method for producing an organic electroluminescent element, the organic electroluminescent element including an anode, an emission layer, and a cathode in this order on a substrate, the method including:
a step of forming the emission layer by a wet-process film formation method using the composition according to <20>.

### EXAMPLES

### Example 1

An organic electroluminescent element was prepared by the following method.

An indium tin oxide (ITO) transparent conductive film was deposited on a glass substrate in a thickness of 50 nm (a sputtered film product manufactured by GEOMATEC Co., Ltd.) was patterned into stripes having a width of 2 mm using an ordinary photolithography technique and hydrochloric acid etching to form an anode. The substrate on which such an ITO was patterned in this manner was subjected to ultrasonic cleaning with a surfactant aqueous solution, washing with ultrapure water, ultrasonic washing with ultrapure water, and washing with ultrapure water in this order, then dried with compressed air, and finally subjected to ultraviolet/ozone washing.

As a hole injection layer formation composition, a composition was prepared by dissolving 3.0 wt % of a hole transporting high molecular weight compound having a repeating structure represented by the following formula (P-1) and 0.6 wt % of an electron-accepting compound (HI-1) in ethyl benzoate.

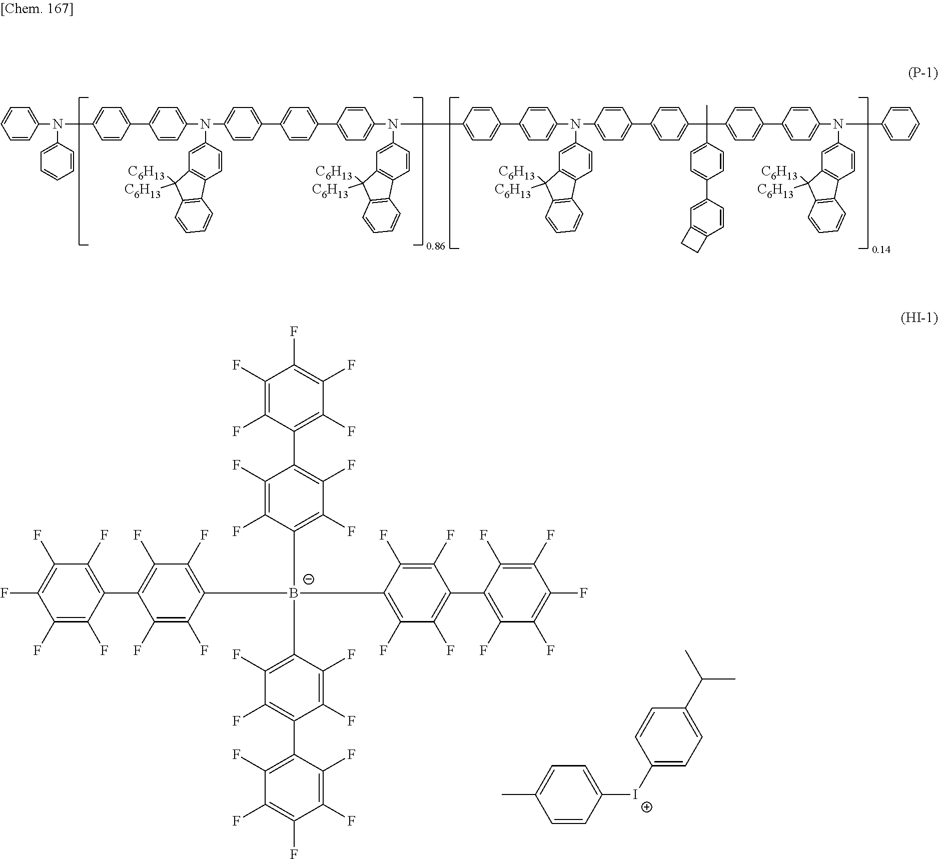

This solution was applied on the substrate by spin coating in the air, and dried on a hot plate in the air at 240° C. for 30 minutes to form a uniform thin film having a film thickness of 40 nm, which was used as a hole injection layer.

Next, a charge-transporting high molecular weight compound having the following structural formula (HT-1) was dissolved in 1,3,5-trimethylbenzene to prepare a 2.0 wt % solution.

This solution was applied, by spin coating, on the substrate on which the above hole injection layer was coated and formed in a nitrogen glove box, and dried on a hot plate in the nitrogen glove box at 230° C. for 30 minutes to form a uniform thin film having a film thickness of 40 nm, which was used as a hole transport layer.

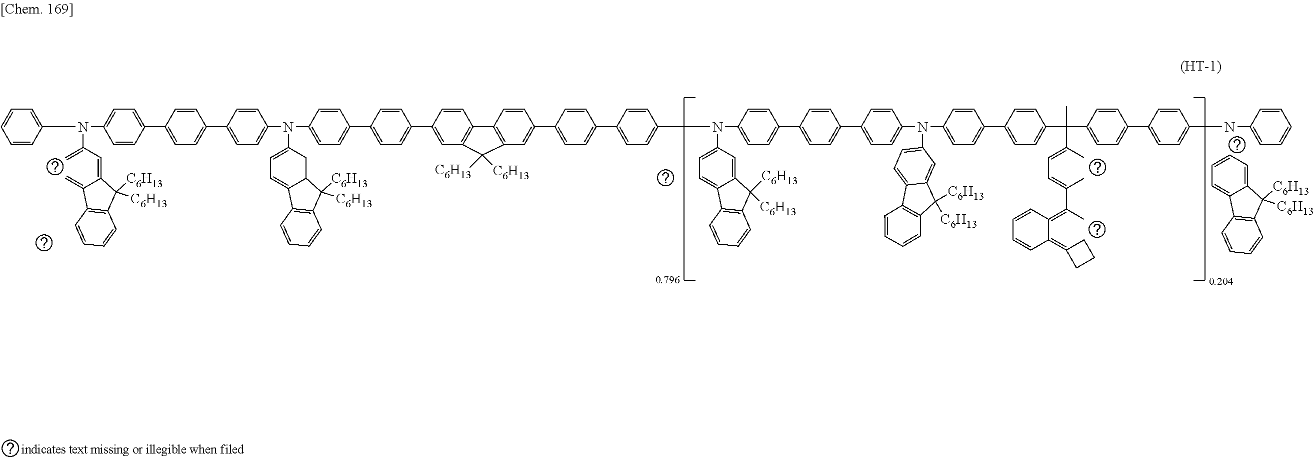

Subsequently, as materials for the emission layer, 2.6 wt % of a compound (H-1) having the following structure, 2.6 wt % of a compound (H-2), 1.56 wt % of an organometallic compound (A-1, molecular weight 2252.85), and 0.26 wt % of a luminescent compound (D-1) were dissolved in cyclohexylbenzene to prepare an emission layer formation composition.

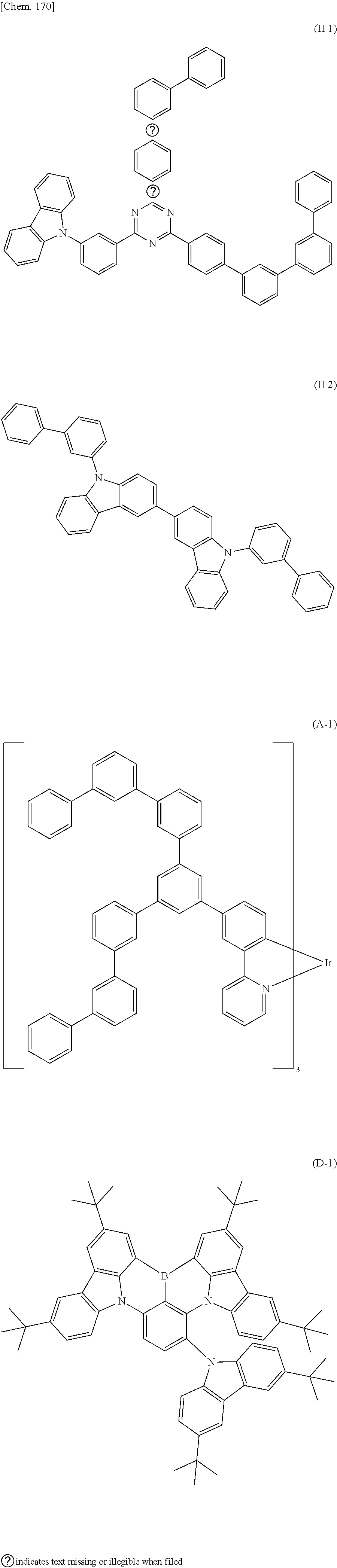

This solution was applied, by spin coating, on the substrate on which the above hole transport layer was coated and formed in a nitrogen glove box, and dried on a hot plate in the nitrogen glove box at 120° C. for 20 minutes to form a uniform thin film having a film thickness of 70 nm, which was used as an emission layer.

The substrate on which layers up to the emission layer were formed was placed in a vacuum deposition device, and the inside of the device was evacuated to 2×10⁻⁴ Pa or lower.

Next, a compound (ET-1) having the following structural formula and 8-hydroxyquinolinolato lithium were co-deposited on the emission layer at a thickness ratio of 2:3 by a vacuum deposition method to form an electron transport layer having a film thickness of 30 nm.

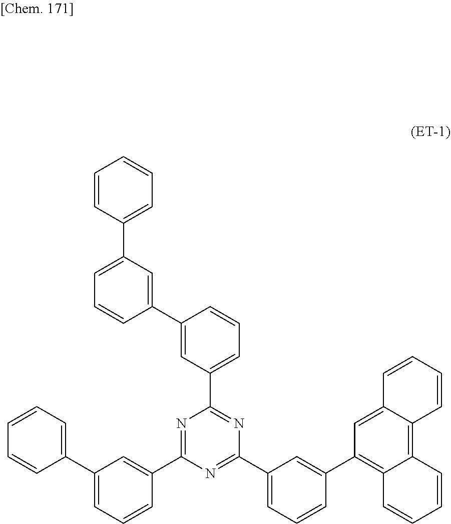 [SMILES: c1ccc(-c2cccc(-c3cccc(-c4nc(-c5cccc(-c6ccccc6)c5)nc(-c5cccc(-c6cc7ccccc7c7ccccc67)c5)n4)c3)c2)cc1]

Subsequently, a shadow-mask in the form of stripes with a width of 2 mm as a mask for cathode deposition was brought into close contact with the substrate such that these stripes were perpendicular to the ITO stripes of the anode, and aluminum was heated by a molybdenum boat to form an aluminum layer having a film thickness of 80 nm, thereby forming a cathode. As described above, an organic electroluminescent element having a luminescence area portion of a size of 2 mm×2 mm was obtained.

The luminescent efficiency and operating lifetime of the obtained element were measured, and both were found to be good.

### Example 2

An organic electroluminescent element was prepared in the same manner as in Example 1, except that an organometallic compound (A-2, molecular weight 1922.51) having the following structure was used as an organometallic complex in the emission layer.

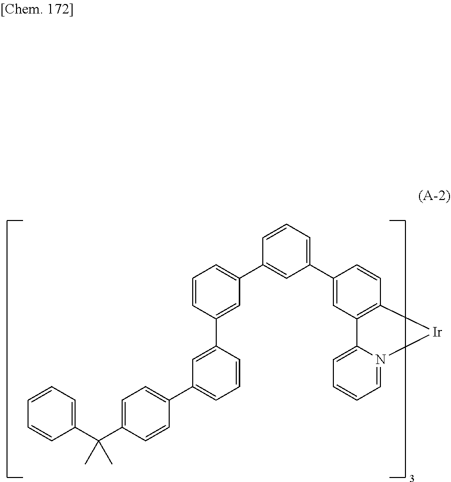

### Example 3

An organic electroluminescent element was prepared in the same manner as in Example 1 except that an organometallic compound (A-3, molecular weight: 1694.21) having the following structure was used as an organometallic complex in the emission layer.

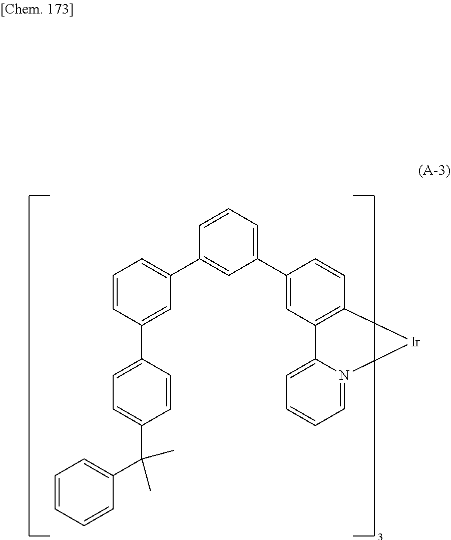

### Example 4

An organic electroluminescent element was prepared in the same manner as in Example 1, except that an organometallic compound (A-4, molecular weight 1347.74) having the following structure was used as an organometallic complex in the emission layer.

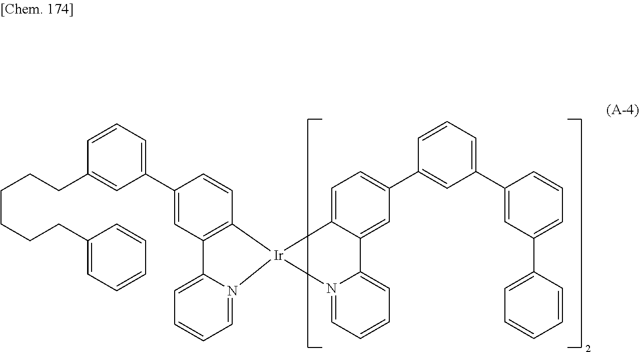

### Comparative Example 1

An organic electroluminescent element was prepared in the same manner as in Example 1 except that an organometallic compound (CA-1, molecular weight: 1177.65) having the following structure was used as an organometallic complex in the emission layer.

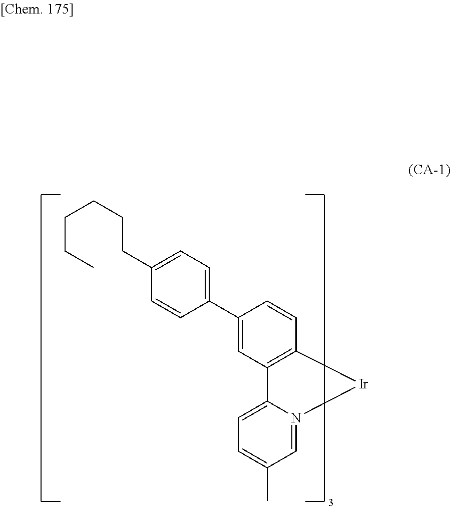

### Comparative Example 2

An organic electroluminescent element was prepared in the same manner as in Example 1, except that an organometallic compound (CA-2, molecular weight: 823.11) having the following structure was used as an organometallic complex in the emission layer.

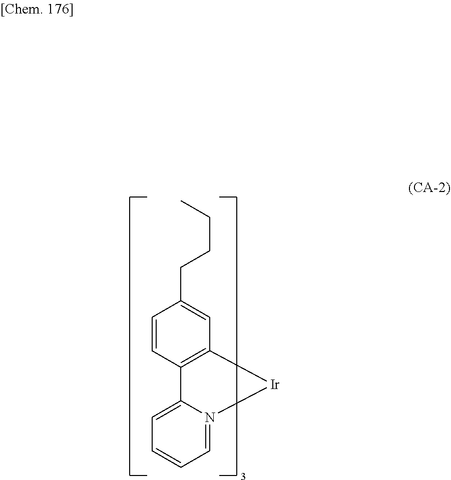

### [Evaluation of Element]

The organic electroluminescent elements obtained in Examples 1 to 4 and Comparative Examples 1 and 2 were measured for current efficiency (cd/A) when emitting light at 1,000 cd/m². As the operating lifetime, a time (LT95) until the luminance decreased to 90% of the initial luminance when a current was continuously applied to the element at a current density of 15 mA/cm² was measured. Measurement results of those are shown in Table 1. For numerical values in Table 1, regarding the current efficiency and the operating lifetime, relative values, with the value of Comparative Example 2 taken as 1.00, are shown as relative current efficiency and a relative lifetime, respectively.

From the results in Table 1, it was found that the organic electroluminescent element having the emission layer of the present invention had improved performance.

TABLE 1

| | Molecular weight of | | |
|---|---|---|---|
| | organometallic | Relative current | |
| | compound | efficiency | Relative lifetime |
| Example 1 | 2252.85 | 1.34 | 4.63 |
| Example 2 | 1922.51 | 1.43 | 3.14 |
| Example 3 | 1694.21 | 1.33 | 3.08 |
| Example 4 | 1347.74 | 1.37 | 4.05 |
| Comparative | 1177.65 | 1.27 | 1.67 |
| Example 1 | | | |
| Comparative | 823.11 | 1.00 | 1.00 |
| Example 2 | | | |

In Examples 1 to 4 and Comparative Examples 1 and 2, when T1A, T1B, and S1B are determined by the method described in the description, all of them satisfy the relationship of the expression (E-1) and the expression (E-2).

The organic electroluminescent elements obtained in Examples 1 to 4 had higher current efficiency and longer operating lifetime than the organic electroluminescent elements obtained in Comparative Examples 1 and 2.

### Example 5

The procedure was the same as in Example 1 up to the formation of the hole injection layer.

Next, a charge-transporting high molecular weight compound having the following structural formula (HT-11) was dissolved in 1,3,5-trimethylbenzene to prepare a 2.0 wt % solution, thereby preparing a hole transport layer formation composition.

This solution was applied, by spin coating, on the substrate on which the above hole injection layer was coated and formed in a nitrogen glove box, and dried on a hot plate in the nitrogen glove box at 230° C. for 30 minutes to form a uniform thin film having a film thickness of 40 nm, which was used as a hole transport layer.

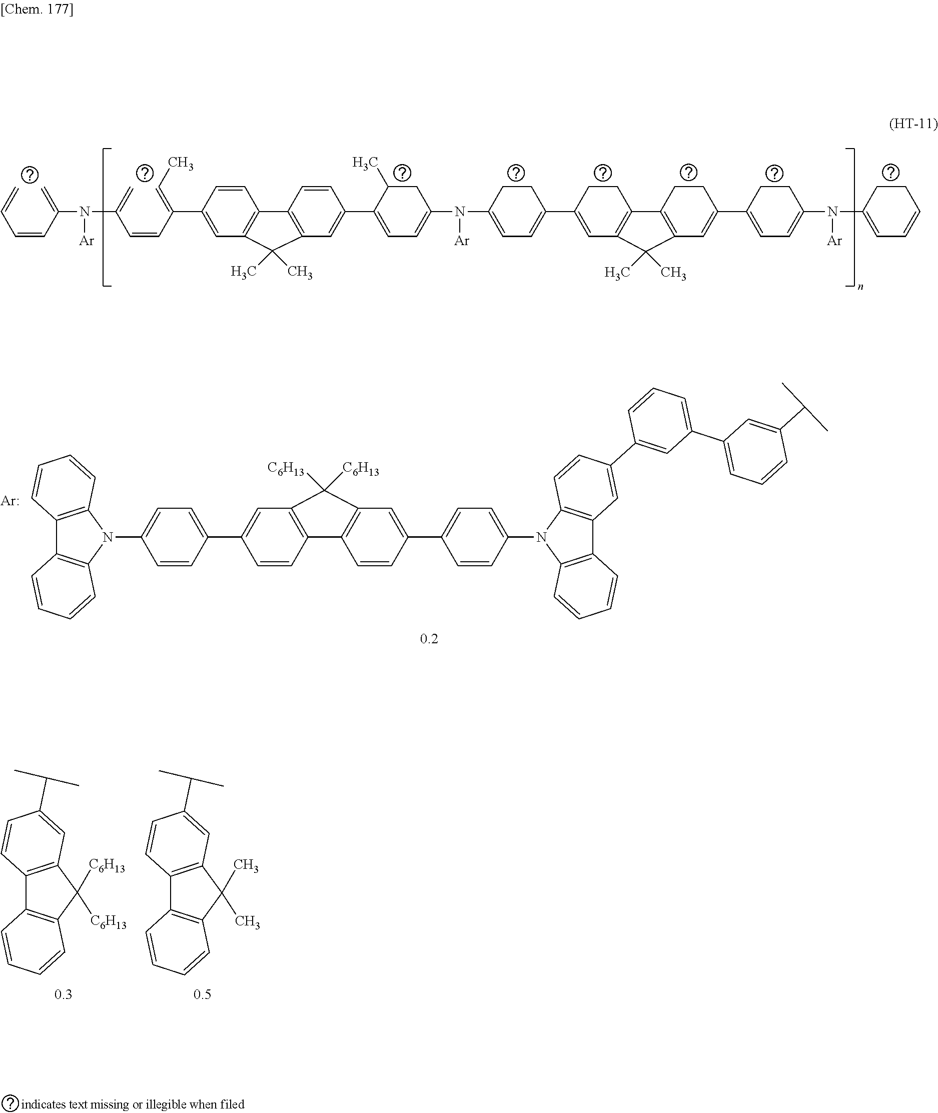

Subsequently, as materials for the emission layer, 1.17 wt % of a compound (H-11) having the following structure, 1.17 wt % of a compound (H-12), 0.78 wt % of a compound (H-13), 0.93 wt % of an organometallic compound (A-11), and 0.16 wt % of a polycyclic heterocyclic compound (D-11) were dissolved in cyclohexylbenzene to prepare an emission layer formation composition.

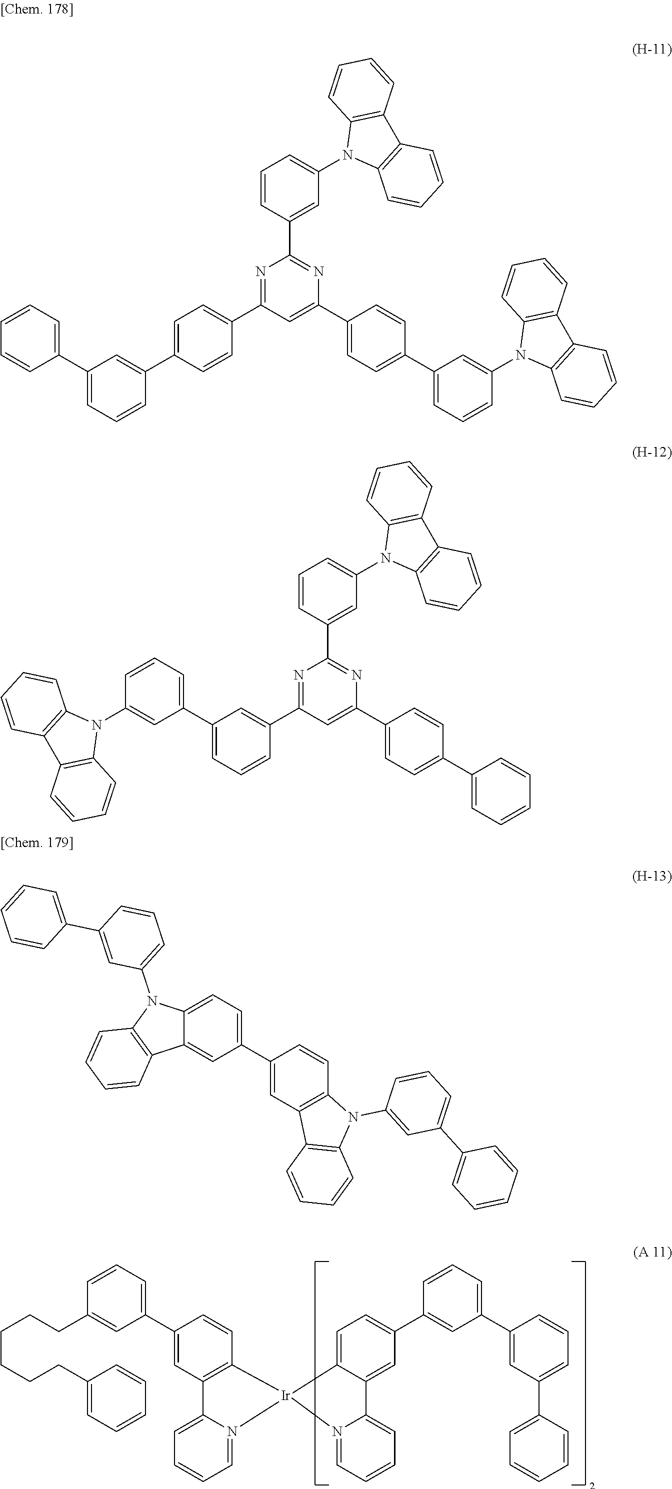

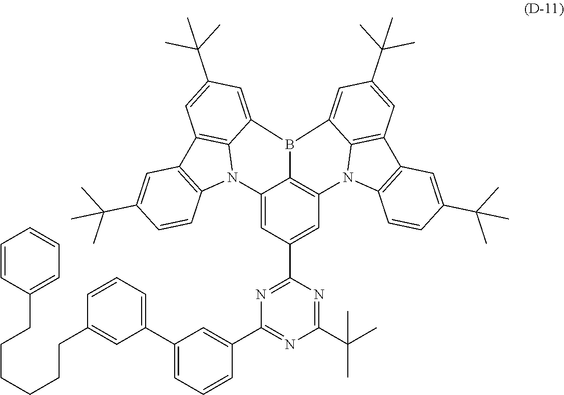 [SMILES: CC(C)(C)c1ccc2c(c1)c1cc(C(C)(C)C)cc3c1n2-c1cc(-c2nc(-c4cccc(-c5cccc(CCCCCCc6ccccc6)c5)c4)nc(C(C)(C)C)n2)cc2c1B3c1cc(C(C)(C)C)cc3c4cc(C(C)(C)C)ccc4n-2c13]

This solution was applied, by spin coating, on the substrate on which the above hole transport layer was coated and formed in a nitrogen glove box, and dried on a hot plate in the nitrogen glove box at 120° C. for 20 minutes to form a uniform thin film having a film thickness of 40 nm, which was used as an emission layer.

Subsequently, an electron transport layer and a cathode were formed in the same manner as in Example 1 to obtain an organic electroluminescent element having a luminescence area portion of a size of 2 mm×2 mm.

The luminescent efficiency and operating lifetime of the obtained element were measured, and both were found to be good.

In Example 1 and Example 5, when T1A, T1B, and S1B are determined by the method described in the description, all of them satisfy the relationship of the expression (E-1) and the expression (E-2).

### Example 6

As materials for the emission layer, 2.33 wt % of a compound (H-21) having the following structure, 0.78 wt % of a compound (H-22), 0.93 wt % of an organometallic compound (A-21), and 0.16 wt % of a luminescent compound (D-21) were dissolved in cyclohexylbenzene to prepare an emission layer formation composition.

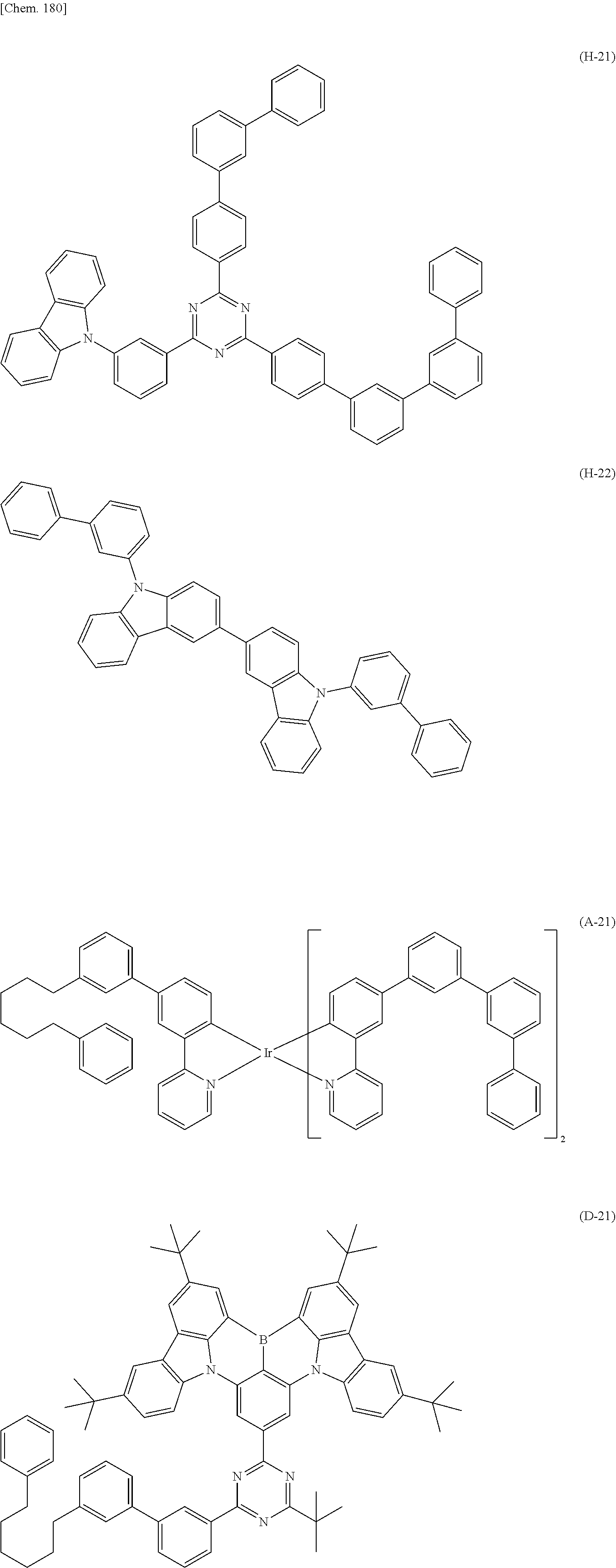

An organic electroluminescent element was prepared in the same manner as in Example 5, except that this solution was applied, by spin coating, on the substrate on which the above hole transport layer was coated and formed in a nitrogen glove box, and dried on a hot plate in the nitrogen glove box at 120° C. for 20 minutes to form a uniform thin film having a film thickness of 40 nm, which was used as an emission layer.

### Example 7

An organic electroluminescent element was prepared in the same manner as in Example 6, except that a compound (H-23) having the following structure was used instead of the compound (H-21) as a material for the emission layer.

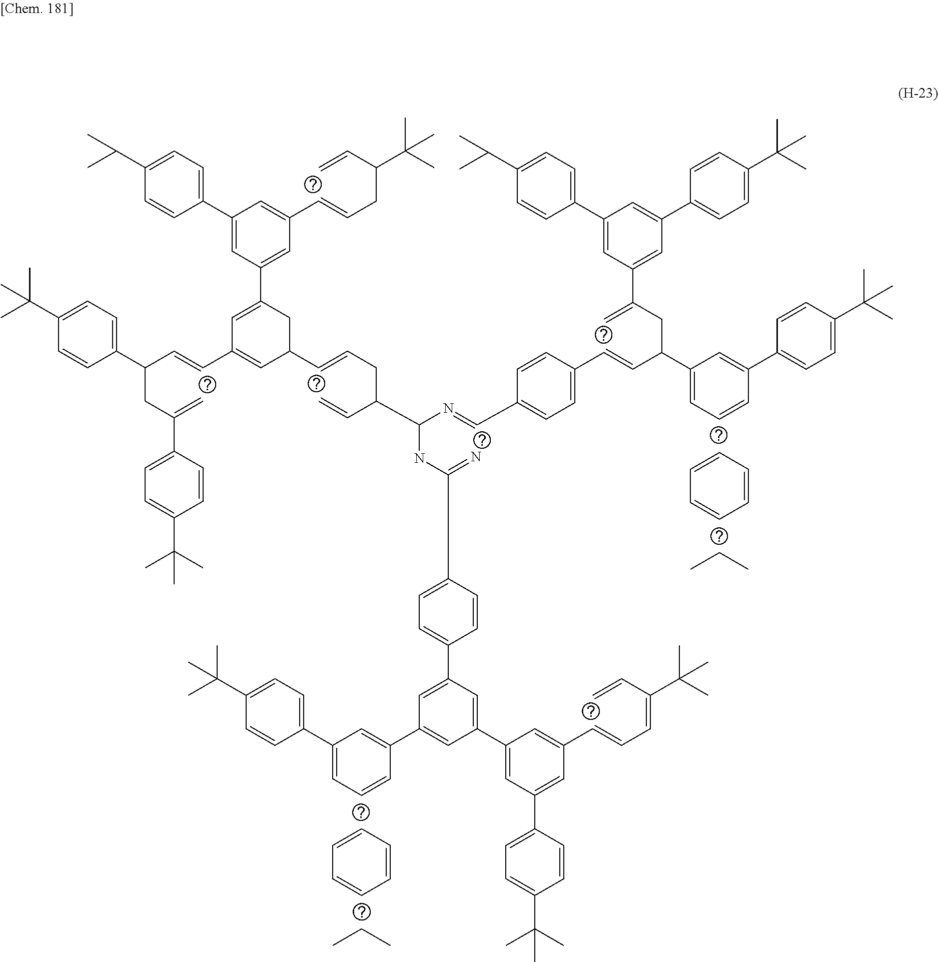

### Example 8

An organic electroluminescent element was prepared in the same manner as in Example 6, except that a compound (11-24) having the following structure was used instead of the compound (H-21) as a material for the emission layer.

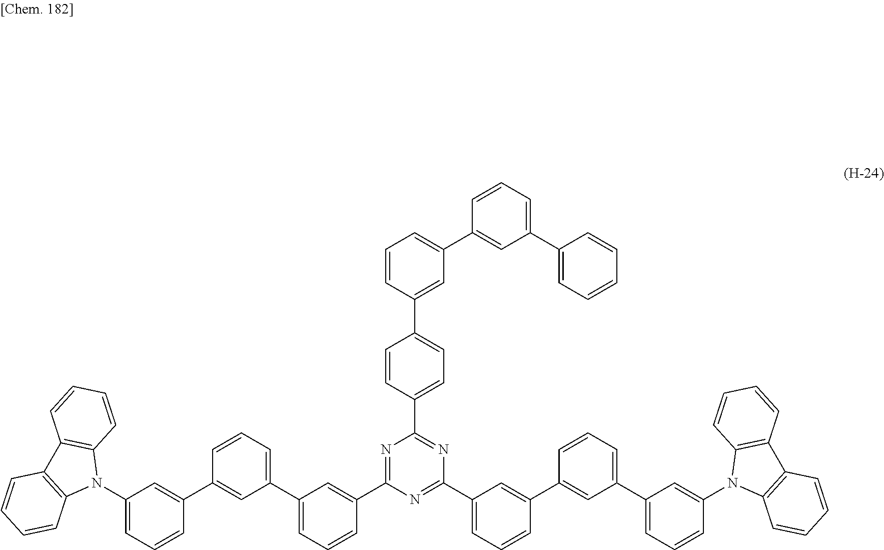 [SMILES: c1ccc(-c2cccc(-c3cccc(-c4ccc(-c5nc(-c6cccc(-c7cccc(-c8cccc(-n9c%10ccccc%10c%10ccccc%109)c8)c7)c6)nc(-c6cccc(-c7cccc(-c8cccc(-n9c%10ccccc%10c%10ccccc%109)c8)c7)c6)n5)cc4)c3)c2)cc1]

### Example 9

An organic electroluminescent element was prepared in the same manner as in Example 8, except that a compound (H-25) having the following structure was used instead of the compound (H-22) as a material for the emission layer.

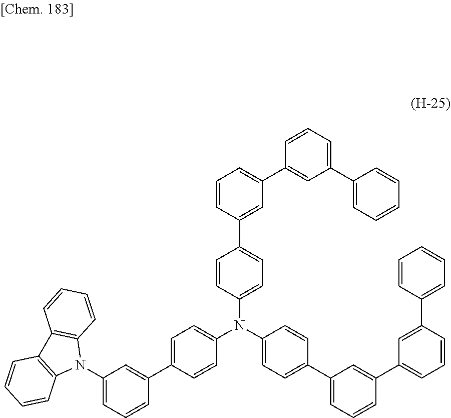 [SMILES: c1ccc(-c2cccc(-c3cccc(-c4ccc(N(c5ccc(-c6cccc(-c7cccc(-c8ccccc8)c7)c6)cc5)c5ccc(-c6cccc(-n7c8ccccc8c8ccccc87)c6)cc5)cc4)c3)c2)cc1]

### Example 10

An organic electroluminescent element was prepared in the same manner as in Example 8, except that a compound (H-26) having the following structure was used instead of the compound (H-22) as a material for the emission layer.

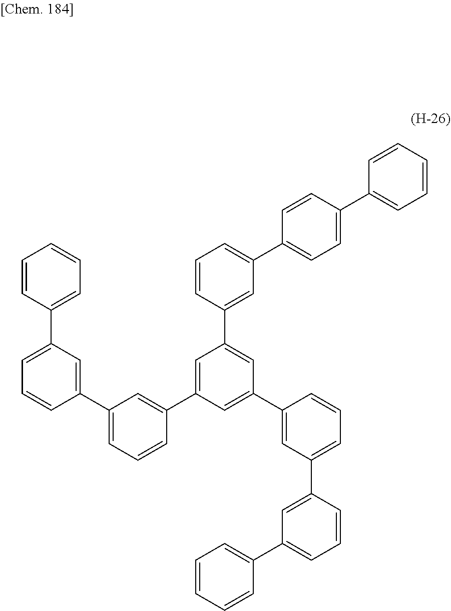 [SMILES: c1ccc(-c2ccc(-c3cccc(-c4cc(-c5cccc(-c6cccc(-c7ccccc7)c6)c5)cc(-c5cccc(-c6cccc(-c7ccccc7)c6)c5)c4)c3)cc2)cc1]

### Example 11

An organic electroluminescent element was prepared in the same manner as in Example 6, except that a luminescent compound (D-22) having the following structure was used instead of the luminescent compound (D-21) as a material for the emission layer.

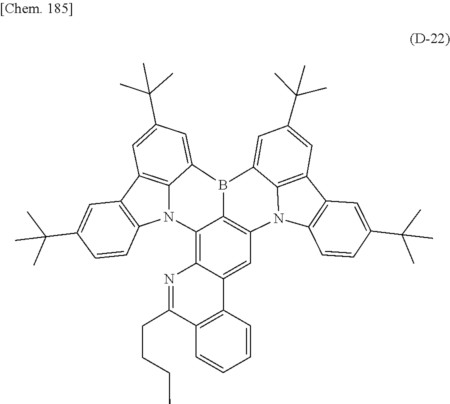 [SMILES: CCCCc1nc2c3c4c(cc2c2ccccc12)-n1c2ccc(C(C)(C)C)cc2c2cc(C(C)(C)C)cc(c21)B4c1cc(C(C)(C)C)cc2c4cc(C(C)(C)C)ccc4n-3c12]

### Example 12

An organic electroluminescent element was prepared in the same manner as in Example 5, except that as a material for the emission layer, 3.11 wt % of the compound (H-21), 0.93 wt % of the organometallic compound (A-21), and 0.16 wt % of the luminescent compound (D-21) were dissolved in cyclohexylbenzene to prepare an emission layer formation composition.

### Example 13

An organic electroluminescent element was prepared in the same manner as in Example 12, except that the compound (H-24) was used instead of the compound (H-21) as a material for the emission layer.

### Comparative Example 3

An organic electroluminescent element was prepared in the same manner as in Example 12, except that the compound (H-23) was used instead of the compound (H-21) as a material for the emission layer.

### [Evaluation of Element]

The organic electroluminescent elements obtained in Examples 6 to 13 and Comparative Example 3 were measured for a voltage (V) and current efficiency (cd/A) when emitting light at 1,000 cd/m². As the operating lifetime, a time (LT90) until the luminance decreased to 90% of the initial luminance when a current was continuously applied to the element at a current density of 15 mA/cm² was measured. Measurement results of those are shown in Table 2. For numerical values in Table 2, regarding the voltage, a voltage difference with Comparative Example 3 as a reference is shown as a relative voltage (V), and regarding the current efficiency and operating lifetime, relative values, with Comparative Example 3 taken as 1.00, are shown as relative current efficiency and a relative lifetime, respectively.

From the results in Table 2, it was found that the organic electroluminescent element having the emission layer of the present invention had improved performance.

TABLE 2

| | | Relative current | |
|---|---|---|---|
| | Relative voltage (V) | efficiency | Relative lifetime |
| Example 6 | −1.46 | 1.18 | 25.60 |
| Example 7 | −0.66 | 0.95 | 5.60 |
| Example 8 | −1.23 | 0.98 | 32.00 |
| Example 9 | −1.19 | 1.00 | 32.00 |
| Example 10 | −1.17 | 1.09 | 42.40 |
| Example 10 | −1.31 | 0.88 | 1.40 |
| Example 12 | −1.25 | 1.14 | 34.60 |
| Example 13 | −1.11 | 1.16 | 37.72 |
| Comparative | 0.00 | 1.00 | 1.00 |
| Example 3 | | | |

Although various embodiments have been described above with reference to the drawing, it goes without saying that the present invention is not limited to such examples. It is clear that those skilled in the art can come up with various changes or modifications within the scope of the claims, and it is understood that these also naturally fall within the technical scope of the present invention. In addition, each of the constituent elements in the above embodiments may be freely combined without departing from the spirit of the present invention.

The present application is based on a Japanese Patent Application (No. 2022-103028) filed on Jun. 27, 2022 and a Japanese Patent Application (No. 2022-103031) filed on Jun. 27, 2022, contents of which are incorporated by reference into the present application.

### INDUSTRIAL APPLICABILITY

The organic electroluminescent element of the present invention and the composition of the present invention can be suitably used for, for example, an organic EL display device and an organic EL illuminator.

### REFERENCE SIGNS LIST

1 Substrate
2 Anode
3 Hole injection layer
4 Hole transport layer
5 Emission layer
6 Electron transport layer
7 Cathode
8 Organic electroluminescent element

1. An organic electroluminescent element material, comprising:
a luminescent compound;
an organometallic compound; and
a host material, wherein
the organometallic compound has a molecular weight of 1,200 or more,
the host material contains at least one selected from the group consisting of a compound represented by formula (240), a compound represented by formula (250), and a compound represented by formula (260), and
Expression (E-1) and Expression (E-2) are satisfied,
$$T 1 A \geq T 1 B \qquad Expression ( E - 1 )$$
$$Δ EST = S 1 B - T 1 B \leq 0.3 eV \qquad Expression ( E - 2 )$$
in Expression (E-1) and Expression (E-2),
T1A is a triplet energy level (eV) of the organometallic compound,
T1B is a triplet energy level (eV) of the luminescent compound, and
S1B is a singlet energy level (eV) of the luminescent compound, 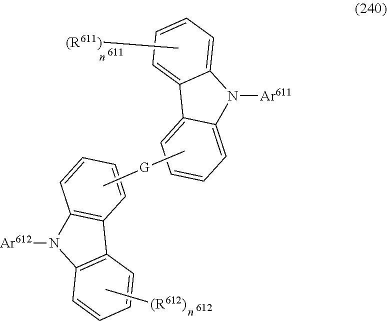
in Formula (240),
Ar⁶¹¹ and Ar⁶¹² each independently represent a monovalent aromatic hydrocarbon group having 6 to 50 carbon atoms which may have a substituent,
R⁶¹¹ and R⁶¹² each independently represent a deuterium atom, a halogen atom, or a monovalent aromatic hydrocarbon group having 6 to 50 carbon atoms which may have a substituent,
G represents a single bond, or a divalent aromatic hydrocarbon group having 6 to 50 carbon atoms which may have a substituent, and
n⁶¹¹ and n⁶¹² each independently represent an integer of 0 to 4, 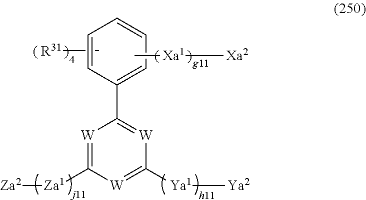
in Formula (250),
W's each independently represents CH or N, and at least one W represents N,
Xa¹, Ya¹, and Za¹ each independently represent a divalent aromatic hydrocarbon group having 6 to 30 carbon atoms which may have a substituent, or a divalent aromatic heterocyclic group having 3 to 30 carbon atoms which may have a substituent,
Xa², Ya², and Za² each independently represent a hydrogen atom, a monovalent aromatic hydrocarbon group having 6 to 30 carbon atoms which may have a substituent, or a monovalent aromatic heterocyclic group having 3 to 30 carbon atoms which may have a substituent,
g11, h11, and j11 each independently represent an integer of 0 to 6,
at least one of g11, h11, and j11 represents an integer of 1 or more,
when g11 is 2 or more, a plurality of Xa¹'s may be the same as or different from each other,
when h11 is 2 or more, a plurality of Ya¹'s may be the same as or different from each other,
when j11 is 2 or more, a plurality of Za¹'s may be the same as or different from each other,
R³¹ represents a hydrogen atom or a substituent, and four R³¹'s may be the same as or different from each other, and
when g11 is 0, Xa² is not a hydrogen atom,
when h11 is 0, Ya² is not a hydrogen atom,
when j11 is 0, Za² is not a hydrogen atom,
in Xa¹, Ya¹, Za¹, Xa², Ya² and Za², the substituent which the aromatic hydrocarbon group having 6 to 30 carbon atoms may have, and the substituent which the aromatic heterocyclic group having 3 to 30 carbon atoms may have are each independently selected from the following substituent group Z2, and the substituent selected from the following substituent group Z2 does not have any further substituent,
<substituent group Z2>
alkyl group, alkoxy group, aryloxy group, heteroaryloxy group, alkoxycarbonyl group, dialkylamino group, diarylamino group, arylalkylamino group, acyl group, halogen atom, haloalkyl group, alkylthio group, arylthio group, silyl group, siloxy group, cyano group, aromatic hydrocarbon group, and aromatic heterocyclic group, 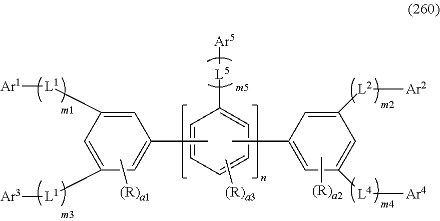
in Formula (260),
Ar¹ to Ar⁵ each independently represent a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent,
R's each independently represent a substituent,
m1 to m5 each independently represent an integer of 0 to 5,
n represents an integer of 0 to 10,
a1 to a3 each independently represent an integer of 0 to 3, and
at least one of Ar¹, Ar², Ar³, Ar⁴, and at least one Ar⁵ when n is 1 or more is not a hydrogen atom.

2. The organic electroluminescent element material according to claim 1, wherein the organometallic compound comprises a compound represented by Formula (201), 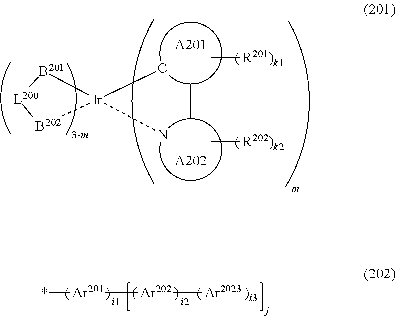
in Formula (201),
ring A201 represents an aromatic hydrocarbon ring structure which may have a substituent or an aromatic heterocyclic structure which may have a substituent,
ring A202 represents an aromatic heterocyclic structure which may have a substituent,
R²⁰¹ and R²⁰² each independently represent a structure represented by Formula (202),
when a plurality of R²⁰¹'s and a plurality of R²⁰²'s are present, the plurality of R²⁰¹'s are the same as or different from each other, and the plurality of R²⁰²'s are the same as or different from each other,
Ar²⁰¹ and Ar²⁰³ each independently represent an aromatic hydrocarbon ring structure which may have a substituent or an aromatic heterocyclic structure which may have a substituent,
Ar²⁰² represents an aromatic hydrocarbon ring structure which may have a substituent, an aromatic heterocyclic structure which may have a substituent, or an aliphatic hydrocarbon structure which may have a substituent,
when a plurality of Ar²⁰¹'s, a plurality of Ar²⁰²'s, and a plurality of Ar²⁰³'s are present, the plurality of Ar²⁰¹'s are the same as or different from each other, and the plurality of Ar²⁰³'s are the same as or different from each other
* represents bonding to ring A201 or ring A202,
B²⁰¹-L²⁰⁰-B²⁰² represents an anionic bidentate ligand, B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure, L²⁰⁰ represents a single bond or an atomic group constituting a bidentate ligand together with B²⁰¹ and B²⁰²,
when a plurality of B²⁰¹-L²⁰⁰-B²⁰²'s are present, the plurality of B²⁰¹-L²⁰⁰-B²⁰²'s may be the same as or different from each other,
i1 and i2 each independently represent an integer of 0 or more and 12 or less,
i3 is an integer of 0 or more, an upper limit of which is the number that can be substituted for Ar²⁰²,
j is an integer of 0 or more, an upper limit of which is the number that can be substituted for Ar²⁰¹,
K1 and k2 each independently represent an integer of 0 or more, an upper limit of which is the number that can be substituted for ring A201 and ring A202, and
m represents an integer of 1 to 3.

3. The organic electroluminescent element material according to claim 1, wherein the luminescent compound comprises a polycyclic heterocyclic compound represented by Formula (1), 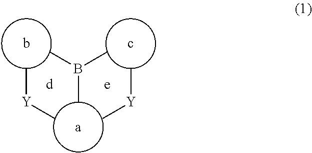
in Formula (1),
ring a, ring b, and ring c each independently represent an aromatic hydrocarbon ring which may have a substituent or an aromatic heterocyclic ring which may have a substituent,
Y's each independently represent O, N—R, or S,
R is an aromatic hydrocarbon ring group which may have a substituent, an aromatic heterocyclic group which may have a substituent, or an alkyl group,
R may be bonded to a carbon atom adjacent to an atom bonded to the Y in at least one ring selected from the group consisting of the ring a, the ring b, and the ring c by —O—, —S—, —C(—R^{a})₂—, or a single bond,
R^{a}'s each independently represent a hydrogen atom or an alkyl group, and
the adjacent carbon atom is not a carbon atom constituting a central fused bicyclic structure of Formula (1) containing B and the Y,
at least one hydrogen atom in the polycyclic heterocyclic compound represented by Formula (1) may be substituted with a halogen atom or deuterium, and
ring d is a ring constituted by B, Y, and some of atoms constituting ring a and ring b, and ring e is a ring constituted by B, Y, and some of atoms constituting ring a and ring c).

4. The organic electroluminescent element material according to claim 1, wherein the organometallic compound comprises a compound represented by Formula (201), and the luminescent compound comprises a polycyclic heterocyclic compound represented by Formula (1), 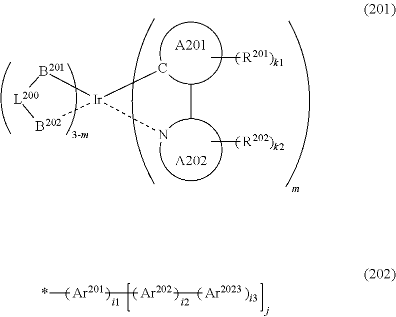
in Formula (201),
ring A201 represents an aromatic hydrocarbon ring structure which may have a substituent or an aromatic heterocyclic structure which may have a substituent,
ring A202 represents an aromatic heterocyclic structure which may have a substituent,
R²⁰¹ and R²⁰² each independently represent a structure represented by the above Formula (202),
when a plurality of R²⁰¹'s and a plurality of R²⁰²'s are present, the plurality of R²⁰¹'s are the same as or different from each other, and the plurality of R²⁰²'s are the same as or different from each other
Ar²⁰¹ and Ar²⁰³ each independently represent an aromatic hydrocarbon ring structure which may have a substituent or an aromatic heterocyclic structure which may have a substituent,
Ar²⁰² represents an aromatic hydrocarbon ring structure which may have a substituent, an aromatic heterocyclic structure which may have a substituent, or an aliphatic hydrocarbon structure which may have a substituent,
when a plurality of Ar²⁰¹'s, the plurality of Ar²⁰¹'s are the same as or different from each other,
when a plurality of Ar²⁰²'s, the plurality of Ar²⁰²'s are the same as or different from each other,
when a plurality of Ar²⁰³'s are present, the plurality of Ar²⁰³'s are the same as or different from each other,
* represents bonding to ring A201 or ring A202,
B²⁰¹-L²⁰⁰-B²⁰² represents an anionic bidentate ligand, B²⁰¹ and B²⁰² each independently represent a carbon atom, an oxygen atom, or a nitrogen atom, and the atom may be an atom constituting a ring, and in this case, B²⁰¹ and/or B²⁰² represents a ring structure, L²⁰⁰ represents a single bond or an atomic group constituting a bidentate ligand together with B²⁰¹ and B²⁰²,
when a plurality of B²⁰¹-L²⁰⁰-B²⁰²'s are present, the plurality of B²⁰¹-L²⁰⁰-B²⁰²'s are the same as or different from each other,
i1 and i2 each independently represent an integer of 0 or more and 12 or less,
i3 is an integer of 0 or more, an upper limit of which is the number that can be substituted for Ar²⁰²,
j is an integer of 0 or more, an upper limit of which is the number that can be substituted for Ar²⁰¹,
k1 and k2 each independently represent an integer of 0 or more, upper limits of k1 and k2 are the number that can be substituted for ring A201 and ring A202, and
m represents an integer of 1 to 3, 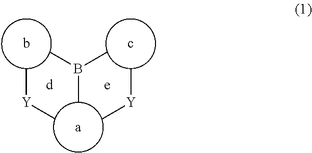
in Formula (1),
ring a, ring b, and ring c each independently represent an aromatic hydrocarbon ring which may have a substituent or an aromatic heterocyclic ring which may have a substituent,
Y's each independently represent O, N—R, or S,
R is an aromatic hydrocarbon ring group which may have a substituent, an aromatic heterocyclic group which may have a substituent, or an alkyl group,
R may be bonded to a carbon atom adjacent to an atom bonded to the Y in at least one ring selected from the group consisting of the ring a, the ring b, and the ring c by —O—, —S—, —C(—R^{a})₂—, or a single bond,
R^{a}'s each independently represent a hydrogen atom or an alkyl group, and
the adjacent carbon atom is not a carbon atom constituting a central fused bicyclic structure of Formula (1) containing B and the Y,
at least one hydrogen atom in the polycyclic heterocyclic compound represented by Formula (1) may be substituted with a halogen atom or deuterium, and
ring d is a ring constituted by B, Y, and a part of atoms constituting ring a and ring b, and ring e is a ring constituted by B, Y, and a part of atoms constituting ring a and ring c.

5. The organic electroluminescent element material according to claim 4, wherein the polycyclic heterocyclic compound represented by Formula (1) comprises a compound represented by Formula (21), 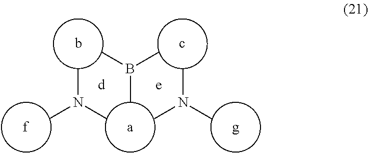
in Formula (21),
ring a, ring b, and ring c are the same as those defined in Formula (1),
ring d is a ring constituted by B, N, and some of atoms constituting ring a and ring b, and ring e is a ring constituted by B, N, and some of atoms constituting ring a and ring c,
ring f and ring g each independently represent an aromatic hydrocarbon ring which may have a substituent or an aromatic heterocyclic ring which may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group,
the adjacent carbon atom is not a carbon atom constituting ring d and ring e each containing B and N, and
at least one hydrogen atom in the polycyclic heterocyclic compound represented by Formula (21) may be substituted with a halogen atom or deuterium.

6. The organic electroluminescent element material according to claim 4, wherein the polycyclic heterocyclic compound represented by Formula (1) comprises a compound represented by Formula (22), 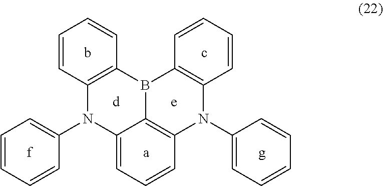 [SMILES: c1ccc(N2c3ccccc3B3c4ccccc4N(c4ccccc4)c4cccc2c43)cc1]
in Formula (22),
ring d is a ring constituted by B, N, and some of atoms constituting ring a and ring b, and ring e is a ring constituted by B, N, and some of atoms constituting ring a and ring c,
ring a, ring b, ring c, ring f, and ring g may have a substituent,
ring f may be bonded to a carbon atom adjacent to an atom bonded to N in at least one of ring a and ring b by —O—, —S—, —C(—R^{a})₂—, or a single bond,
ring g may be bonded to a carbon atom adjacent to an atom bonded to N in at least one of ring a and ring c by —O—, —S—, —C(—R^{a})₂—, or a single bond,
the R^{a}'s each independently represent a hydrogen atom or an alkyl group, and
at least one hydrogen atom in the polycyclic heterocyclic compound represented by Formula (22) may be substituted with a halogen atom or deuterium.

7. The organic electroluminescent element material according to claim 4, wherein the polycyclic heterocyclic compound represented by Formula (1) comprises a compound represented by Formula (71), 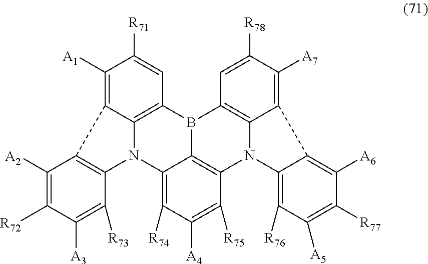
in Formula (71),
A₁ to A₇ each independently represent a hydrogen atom; a fluorine atom; an alkyl group which may have a substituent; an electron-accepting heteroaryl group; a nitro group; a cyano group; or an aromatic hydrocarbon group or an aromatic heterocyclic group which has an electron-accepting heteroaryl group, a nitro group, or a cyano group as a substituent,
R₇₁ to R₇₈ each independently represent a hydrogen atom, an alkyl group which may have a substituent, an aromatic hydrocarbon group which may have a substituent, an aromatic heterocyclic group which may have a substituent, an electron-donating substituent, or a combination thereof,
at least one hydrogen atom in the polycyclic heterocyclic compound represented by Formula (71) may be substituted with a halogen atom or deuterium, and
a dotted line represents a single bond or no bond.

8. The organic electroluminescent element material according to claim 7, wherein A₁ to A₇ in Formula (71) are an electron-accepting substituent, and each independently represent a group represented by Formula (71-5), a group represented by Formula (71-6), a group represented by Formula (71-7), or a group represented by Formula (71-8), 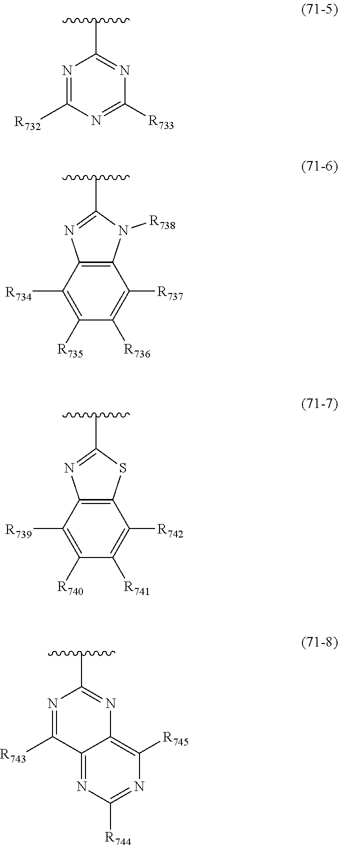
in Formulae (71-5) to (71-8),
R₇₃₂ to R₇₄₅ each independently represent a hydrogen atom, an alkyl group which may have a substituent, or an aromatic hydrocarbon group which may have a substituent).

9. The organic electroluminescent element material according to claim 7, wherein R₇₁ to R₇₈ in Formula (71) are an electron-donating substituent, and each independently represent a group represented by Formula (71-2), a group represented by Formula (71-3), or a group represented by Formula (71-4), 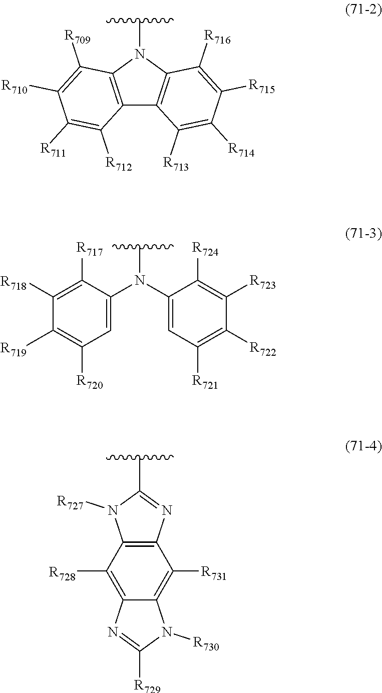
in Formulae (71-2) to (71-4),
R₇₀₉ to R₇₂₄ and R₇₂₇ to R₇₃₁ each independently represent an alkyl group which may have a substituent, an aromatic hydrocarbon group which may have a substituent, or a hydrogen atom.

10. The organic electroluminescent element material according to claim 1, wherein T1A is 2.10 eV or more and 2.80 eV or less.

11. The organic electroluminescent element material according to claim 1, wherein MwA/MwB is 2.0 or more, where MwA is a molecular weight of the organometallic compound and MwB is a molecular weight of the luminescent compound.

12. The organic electroluminescent element material according to claim 1, wherein in Formula (250), when g11 is 1 or more, when h11 is 1 or more, or when j11 is 1 or more, (Xa¹)_{g11}, (Ya¹)ₕ₁₁ and (Za¹)ⱼ₁₁ each independently have a partial structure selected from Formulae (11) to (17), 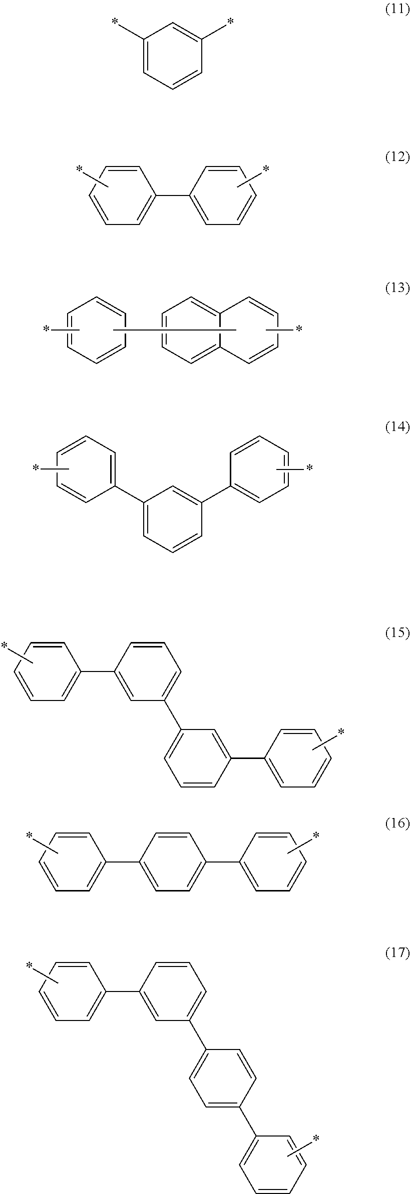
in each of Formulae (11) to (17), * represents a bond with an adjacent structure, or when Xa², Ya², or Za² in Formula (250) represents a hydrogen atom, * represents the hydrogen atom, and at least one of two *'s represents a bonding site with an adjacent structure.

13. The organic electroluminescent element material according to claim 1, wherein at least two of W's in Formula (250) are N.

14. The organic electroluminescent element material according to claim 1, wherein at least one of -(Xa¹)_{g11}-(Xa²), -(Ya¹)ₕ₁₁-(Ya²), and -(Za¹)ⱼ₁₁-(Za²) in Formula (250) has any one of partial structures or terminal structures each represented by Formula (250-1) to formula (250-10), 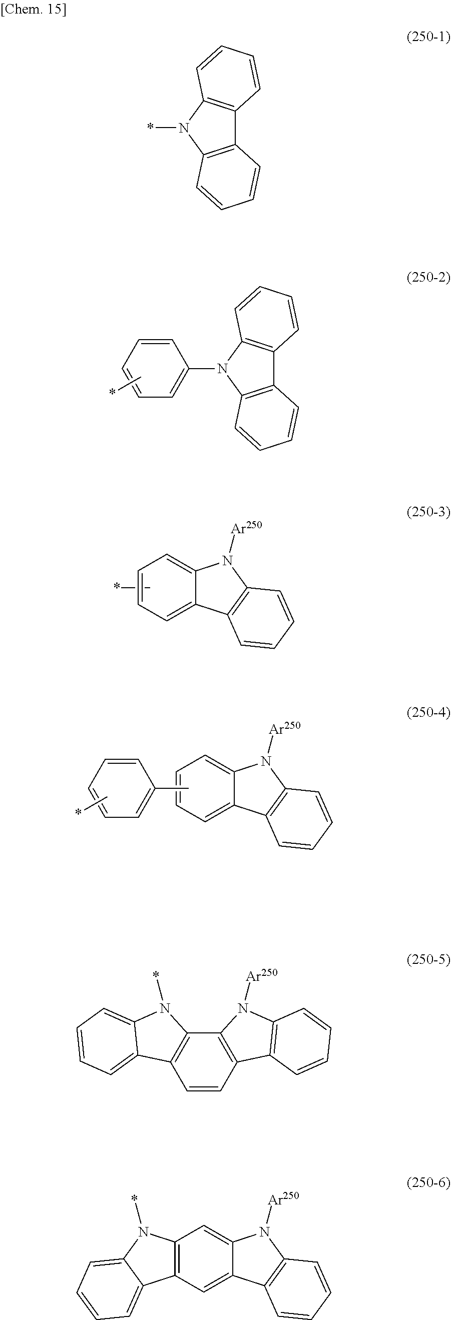 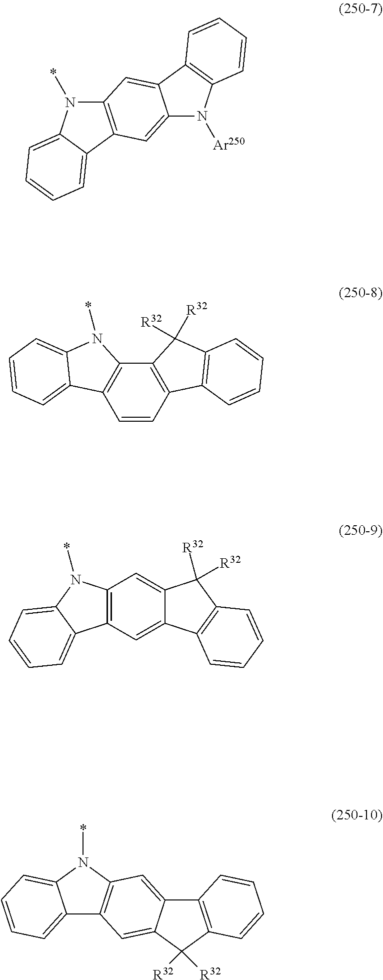
in Formula (250-1) to Formula (250-10), * represents a bonding site, Ar²⁵⁰ represents an aromatic hydrocarbon group having 6 to 20 carbon atoms, and R³² represents a substituent, and the structures each represented by Formula (250-1) to Formula (250-10) may further have a substituent.

15. The organic electroluminescent element material according to claim 1, wherein in Formula (240), Ar⁶¹¹ and Ar⁶¹² each independently have a partial structure selected from Formulae (11) to (13) and (21) to (24), 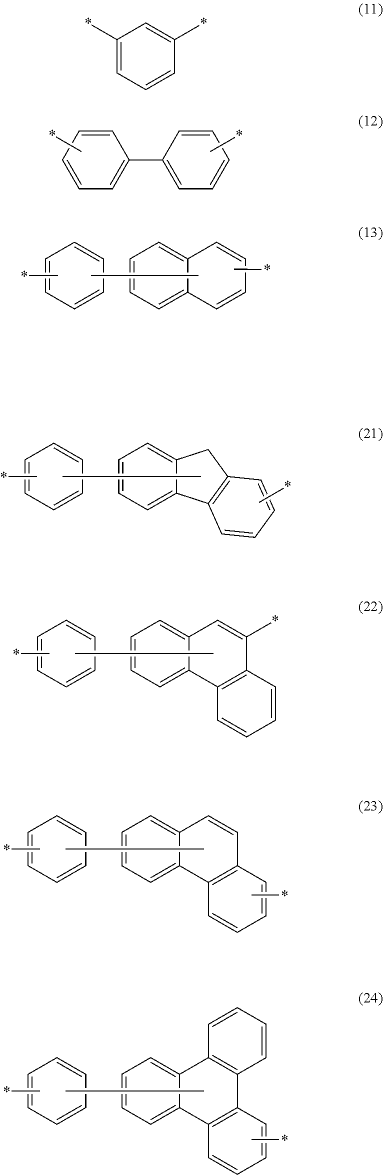
in each of Formula (11) to Formula (13) and Formula (21) to Formula (24), * represents a bond with an adjacent structure or a hydrogen atom, and at least one of two present *'s represents a bonding site with an adjacent structure.

16. The organic electroluminescent element material according to claim 1, wherein in Formula (260), (L¹)ₘ₁ when m1 is 1 or more, (L²)ₘ₂ when m2 is 1 or more, (L³)ₘ₃ when m3 is 1 or more, (L⁴)ₘ₄ when m4 is 1 or more, and (L⁵)ₘ₅ when n is 1 or more and m5 is 1 or more each independently have a partial structure selected from partial structures each represented by Formula (11) to Formula (17), 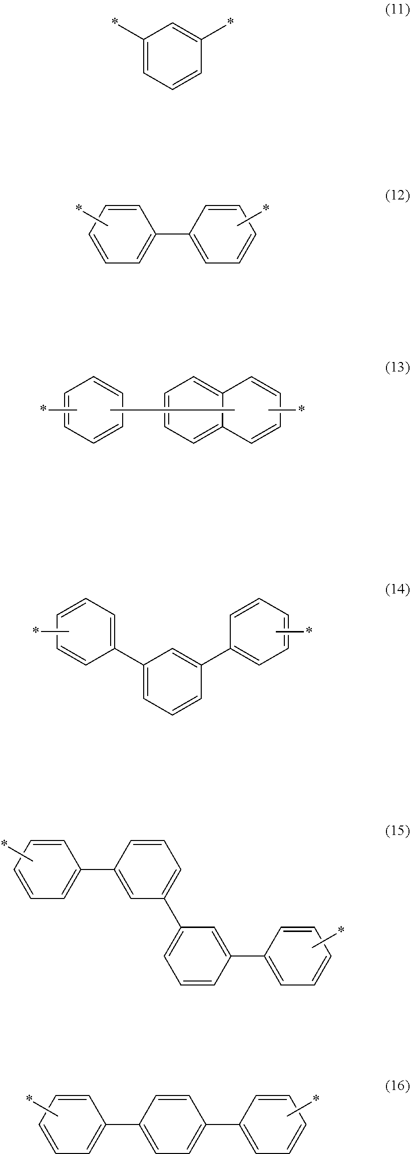 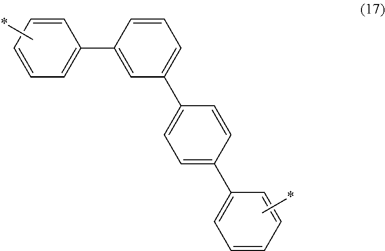
in each of Formula (11) to Formula (17), * represents a bond with an adjacent structure, or when Ar¹, Ar², Ar³, Ar⁴, or Ar⁵ represents a hydrogen atom, * represents the hydrogen atom, and at least one of two present *'s represents a bonding site with an adjacent structure.

17. The organic electroluminescent element material according to claim 1, wherein in Formula (260), one or more and three or less of Ar¹, Ar², and at least one Ar⁵ are represented by Formula (4) or Formula (5), 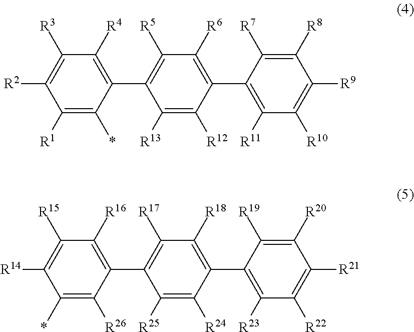
in Formula (4) and Formula (5),
* represents a bonding site with Formula (260), and
R¹ to R²⁶ each independently represent a hydrogen atom or a substituent.

18. An organic electroluminescent element comprising:
an anode;
a cathode;
an emission layer; and
a hole injection layer, wherein
the emission layer is provided between the anode and the cathode,
the hole injection layer is provided between the anode and the emission layer, and
the emission layer contains the organic electroluminescent element material according to claim 1.

19. An organic EL display device or an organic EL illuminator, comprising the organic electroluminescent element according to claim 18.

20. An organic electroluminescent element formation composition, comprising the organic electroluminescent element material according to claim 1; and an organic solvent.

21. A method for producing an organic electroluminescent element, the organic electroluminescent element including an anode, an emission layer, and a cathode in this order on a substrate, the method including:
a step of forming the emission layer by a wet-process film formation method using the organic electroluminescent element formation composition according to claim 20.
